(19) United States
(12) Patent Application Publication
(10) Pub. No.: US 2024/0334828 A1
(43) Pub. Date: Oct. 3, 2024

(54) LIGHT EMITTING ELEMENT AND FUSED POLYCYCLIC COMPOUND FOR THE LIGHT EMITTING ELEMENT

(71) Applicant: Samsung Display Co., Ltd., Yongin-si (KR)

(72) Inventors: MUN-KI SIM, Yongin-si (KR); TAEIL KIM, Yongin-si (KR); JUNHA PARK, Yongin-si (KR); MinJae SUNG, Yongin-si (KR); MINJUNG JUNG, Yongin-si (KR); Seonhyoung HUR, Yongin-si (KR)

(73) Assignee: Samsung Display Co., Ltd., Yongin-si (KR)

(21) Appl. No.: 18/428,600

(22) Filed: Jan. 31, 2024

(30) Foreign Application Priority Data
Mar. 15, 2023 (KR) 10-2023-0034195

(51) Int. Cl. H10K 85/60; C07B 59/00; C09K 11/06; H10K 85/30; H10K 85/40

(52) U.S. Cl. CPC H10K 85/658; C07B 59/004; C09K 11/06; H10K 85/346; H10K 85/40; H10K 85/654; H10K 85/6572; H10K 85/6574; C07B 2200/05

(57) ABSTRACT

Embodiments provide a fused polycyclic compound, a light emitting element that includes the fused polycyclic compound, and an electronic device that includes the light emitting element. The light emitting element includes a first electrode, a second electrode disposed on the first electrode, and an emission layer disposed between the first electrode and the second electrode and including the fused polycyclic compound. The fused polycyclic compound is represented by Formula 1, which is explained in the specification:

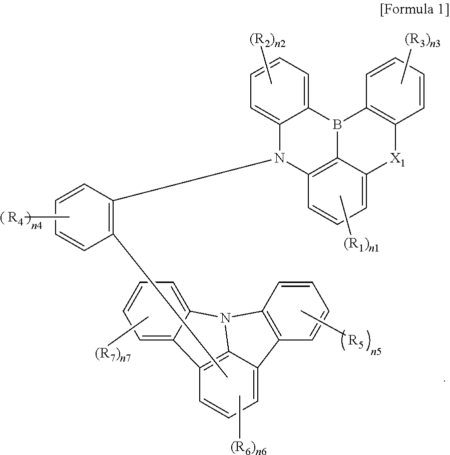

### CROSS-REFERENCE TO RELATED APPLICATION(S)

This application claims priority to and benefits of Korean Patent Application No. 10-2023-0034195 under 35 U.S.C. § 119, filed on Mar. 15, 2023 in the Korean Intellectual Property Office, the entire contents of which are incorporated herein by reference.

### BACKGROUND

### 1. Technical Field

The disclosure relates to a light emitting element and a fused polycyclic compound used in the light emitting element.

### 2. Description of the Related Art

Active development continues for an organic electroluminescence display as an image display. In contrast to a liquid crystal display, an organic electroluminescence display is a so-called a self-luminescent display in which holes and electrons respectively injected from a first electrode and a second electrode recombine in an emission layer so that a light emitting material including an organic compound in the emission layer emits light to achieve display.

In the application of an organic electroluminescence device to a display, there is a demand for an organic electroluminescence device having a low driving voltage, high emission efficiency, and a long service life, and continuous development is required on materials for an organic electroluminescence device that are capable of stably achieving such characteristics.

In order to implement an organic electroluminescence device with high efficiency, technologies pertaining to phosphorescence emission, which uses energy in a triplet state, or to fluorescence emission, which generates singlet excitons by the collision of triplet excitons (triplet-triplet annihilation (TTA)), are being developed. Development is presently directed to thermally activated delayed fluorescence (TADF) materials which use delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element having improved emission efficiency and element lifetime.

The disclosure also provides a fused polycyclic compound which is capable of improving the emission efficiency and element lifetime of a light emitting element.

An embodiment provides a light emitting element which may include a first electrode, a second electrode disposed on the first electrode, and an emission layer disposed between the first electrode and the second electrode, and including a first compound represented by Formula 1:

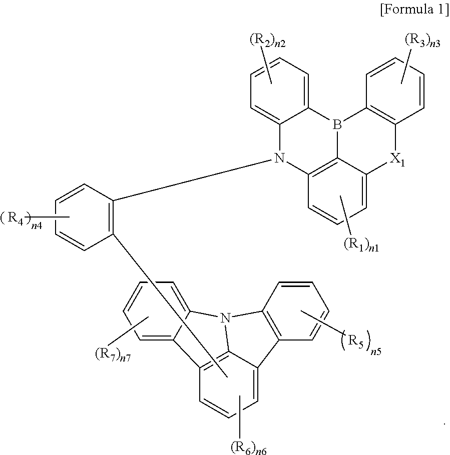

In Formula 1, X₁ may be O, S, or N(Rₐ); R₁ to R₇ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring; Rₐ may be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms: n1 and n6 may each independently be an integer from 0 to 3; n2 to n5 and n7 may each independently be an integer from 0 to 4; and a sum of n6 and n7 is equal to or less than 6.

In an embodiment, the first compound represented by Formula 1 may be represented by Formula 2:

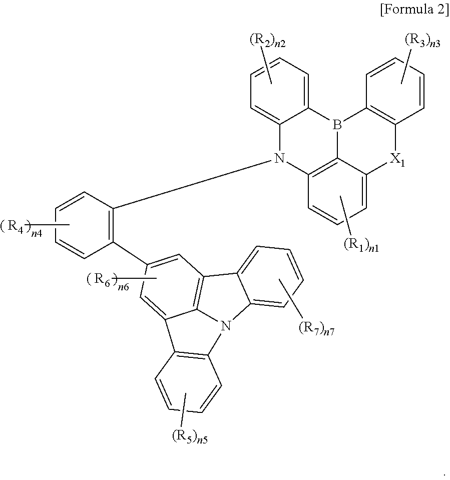

In Formula 2, X₁, R₁ to R₇, and n1 to n7 are the same as defined in Formula 1.

In an embodiment, the first compound represented by Formula 1 may be represented by Formula 3:

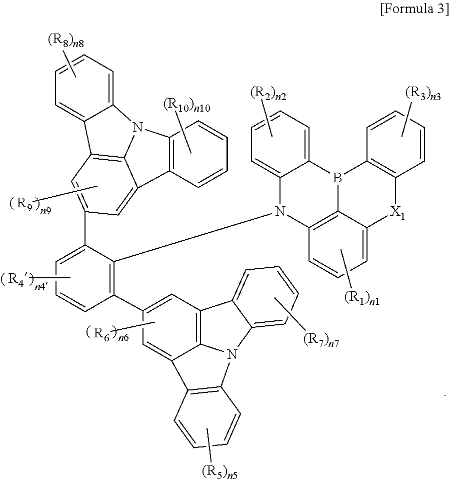

In Formula 3, R₄′ and R₈ to R₁₀ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; n4′ may be an integer from 0 to 3; n8 and n10 may each independently be an integer from 0 to 4; and n9 may be an integer from 0 to 2.

In Formula 3, X₁, R₁ to R₃, R₅ to R₇, n1 to n3, and n5 to n7 are the same as defined in Formula 1.

In an embodiment, the first compound represented by Formula 1 may be represented by Formula 4:

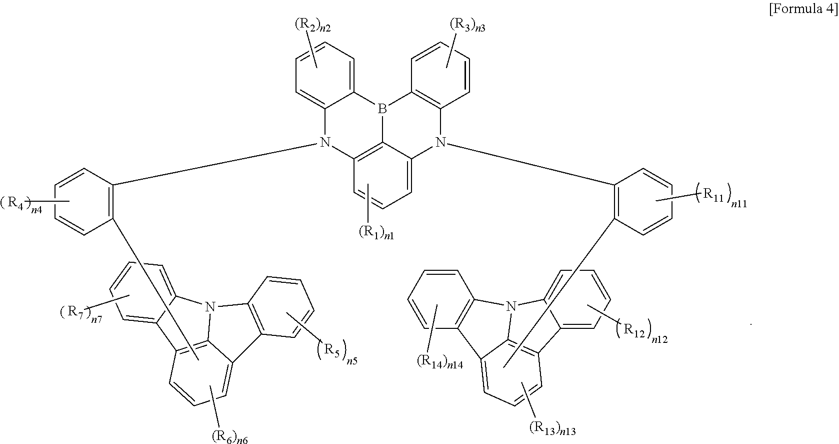

In Formula 4, R₁₁ to R₁₄ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring; n11, n12, and n14 may each independently be an integer from 0 to 4; n13 may be an integer from 0 to 3; and a sum of n12 and n13 is equal to or less than 6.

In Formula 4, R₁ to R₇ and n1 to n7 are the same as defined in Formula 1.

In an embodiment, the first compound represented by Formula 4 may be represented by Formula 5:

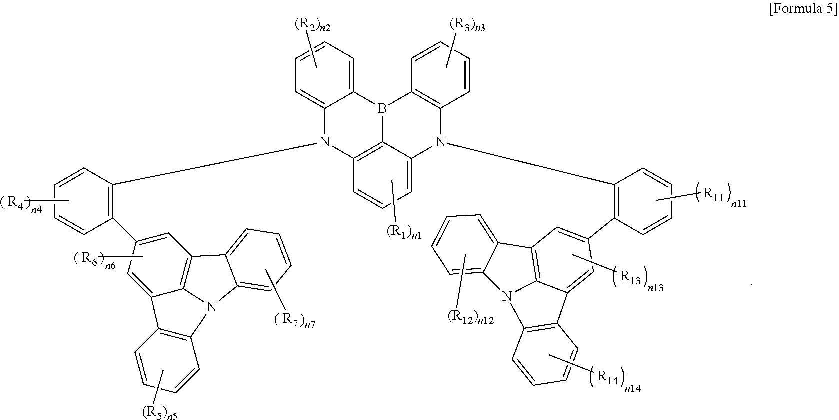

In Formula 5, R₁ to R₇ and n1 to n7 are the same as defined in Formula 1; and R₁₁ to R₁₄ and n11 to n14 are the same as defined in Formula 4.

In an embodiment, the first compound represented by Formula 4 may be represented by one of Formula 6-1 to Formula 6-4.

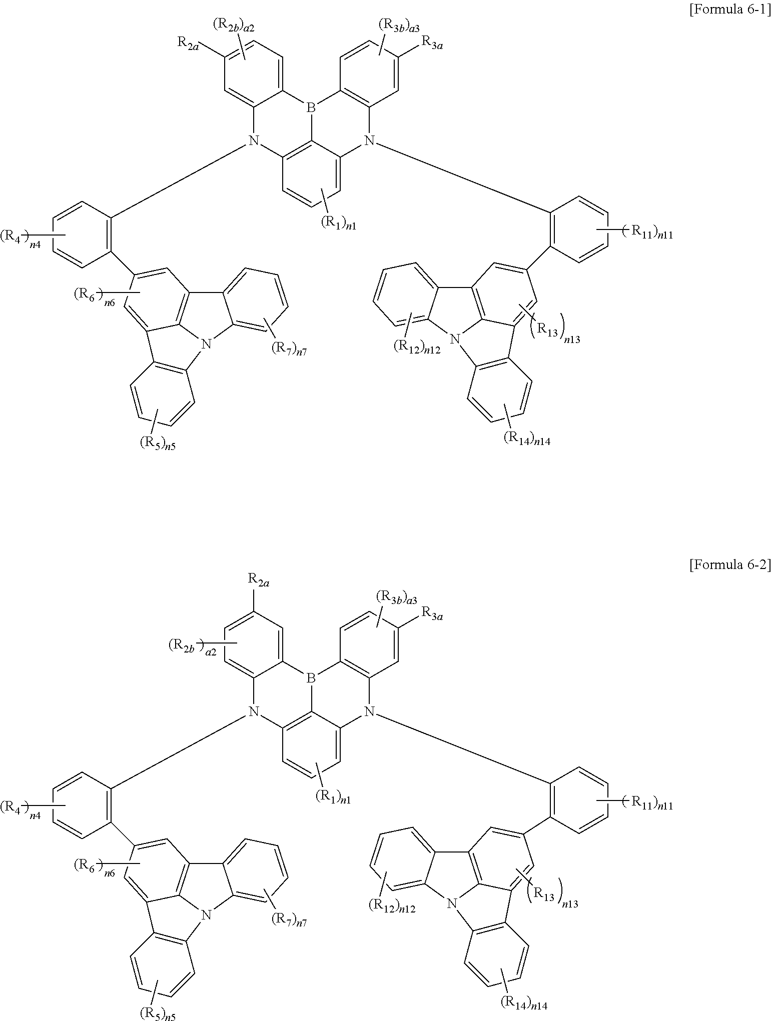

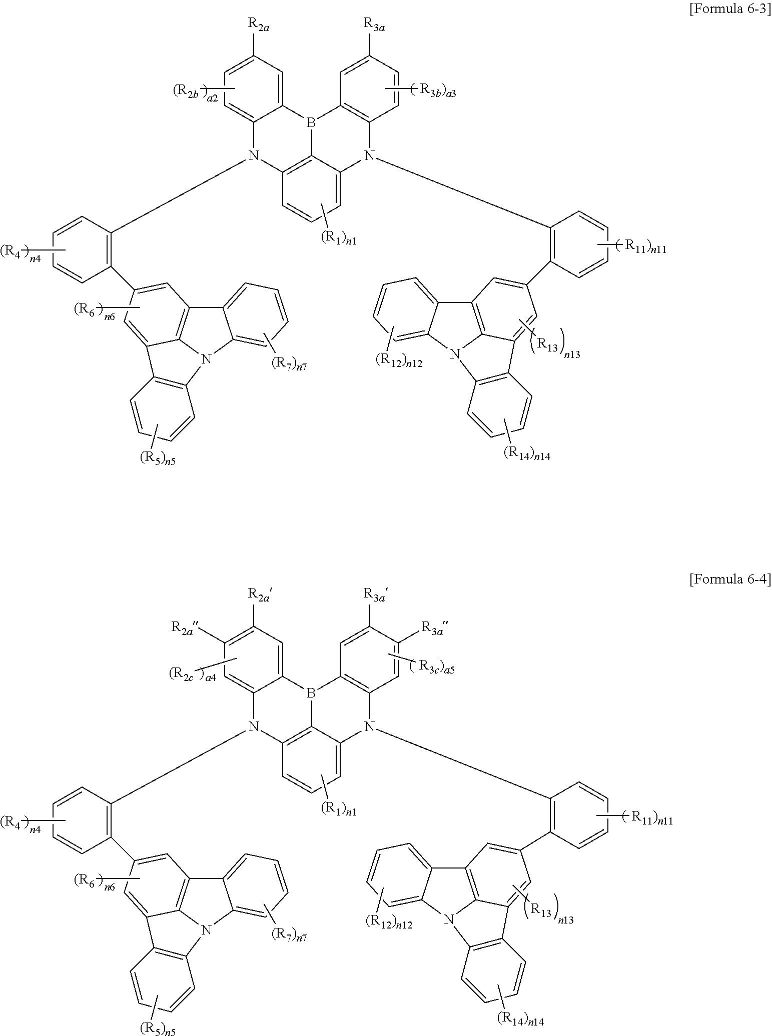

In Formula 6-1 to Formula 6-4, R₂ₐ, R₂ₐ′, R₂ₐ″, R₃ₐ, R₃ₐ′, and R₃ₐ″ may each independently be a group represented by one of Formula A-1 to Formula A-5; R_{2b}, R₃6, R_{2c}, and R_{3c} may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; a2 and a3 may each independently be an integer from 0 to 3; and a4 and a5 may each independently be an integer from 0 to 2.

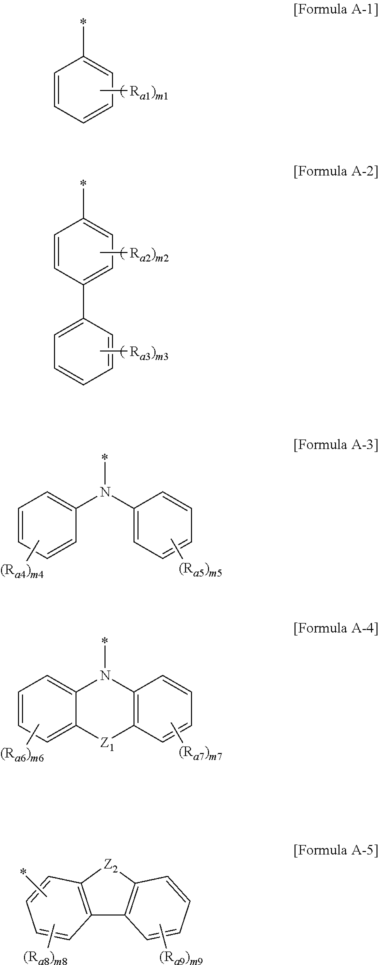

In Formula A-1 to Formula A-5, Z₁ may be a direct linkage, O, or C(Rₐ₁₀)(Rₐ₁₁); Z₂ may be O, S, N(Rₐ₁₂), or C(Rₐ₁₃)(Rₐ₁₄); Rₐ₁ to Rₐ₁₄ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; m1, m3, m4, and m5 may each independently be an integer from 0 to 5; m2, m6, m7, and m9 may each independently be an integer from 0 to 4; and m8 may be an integer from 0 to 3.

In Formula 6-1 to Formula 6-4, R₁, R₄ to R₇, n1, and n4 to n7 are the same as defined in Formula 1; and R₁ to R₁₄ and n11 to n14 are the same as defined in Formula 4.

In an embodiment, the first compound represented by Formula 4 may be represented by Formula 7-1 or Formula 7-2:

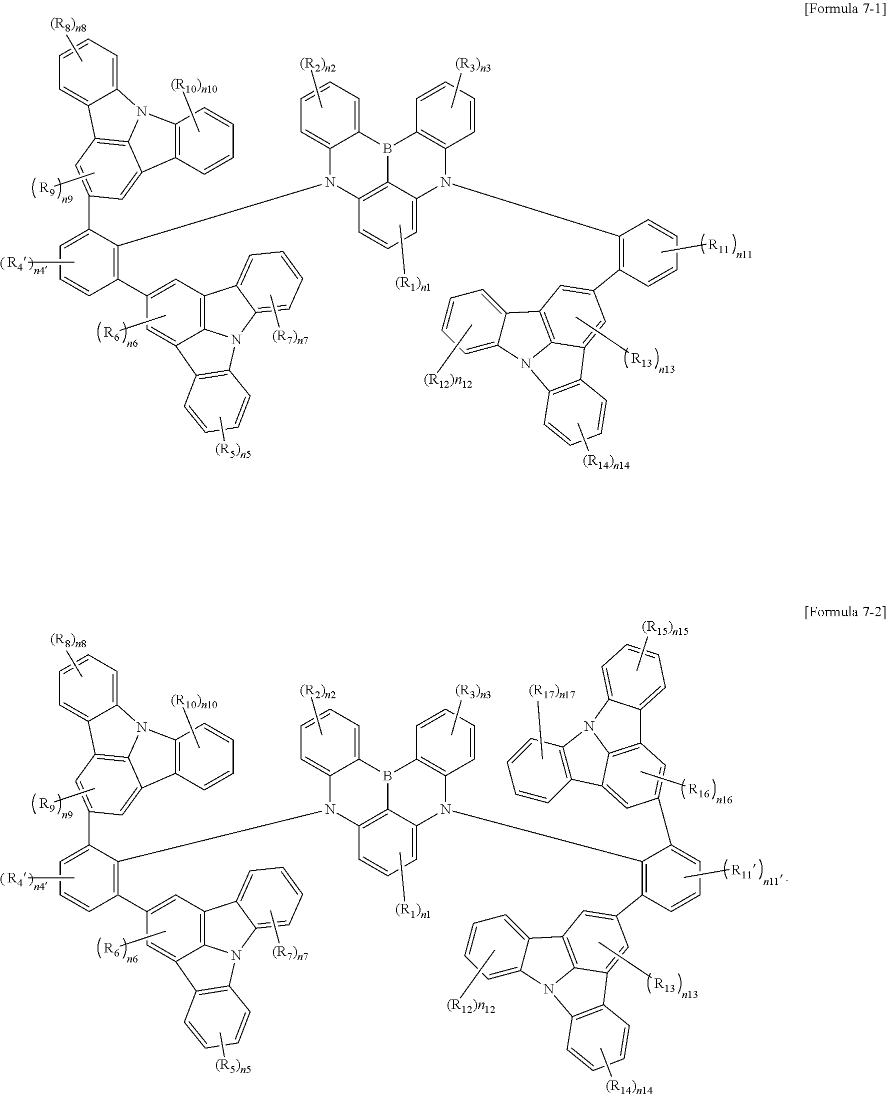

In Formula 7-1 and Formula 7-2, R₄′, R₈ to R₁₀, R₁₁′, and R₁₅ to R₁₇ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; n4′ and n11′ may each independently be an integer from 0 to 3; n8, n10, n15, and n17 may each independently be an integer from 0 to 4; n9 and n16 may each independently be an integer from 0 to 2.

In Formula 7-1 and Formula 7-2, R₁ to R₃, R₅ to R₇, n1 to n3, and n5 to n7 are the same as defined in Formula 1; and R₁₁ to R₁₄ and n11 to n14 are the same as defined in Formula 4.

In an embodiment, the first compound represented by Formula 1 may be represented by Formula 8-1 or Formula 8-2:

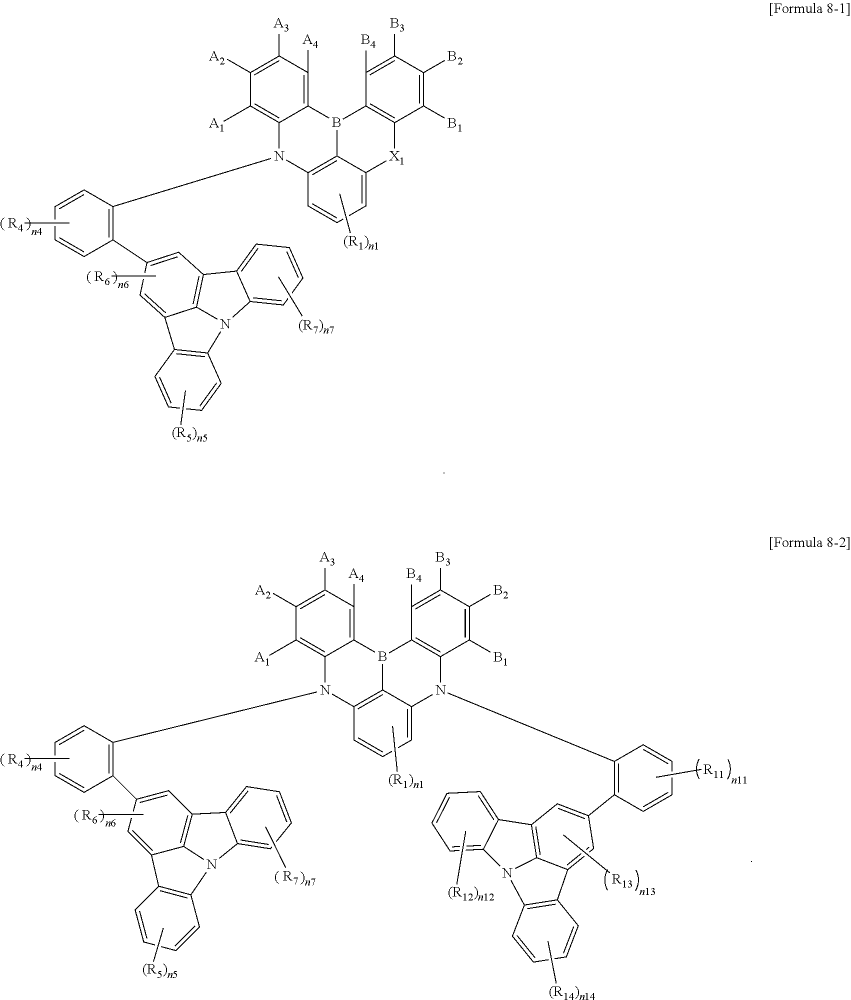

In Formula 8-1 and Formula 8-2, A₁ to A₄, B₁ to B₄, and R₁₁ to R₁₄ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring; n11, n12, and n14 may each independently be an integer from 0 to 4; n13 may be an integer from 0 to 2; and at least one adjacent pair among A₁ to A₄ and at least one adjacent pair among B₁ to B₄ may each independently be fused with a group represented by Formula B-1 or Formula B-2:

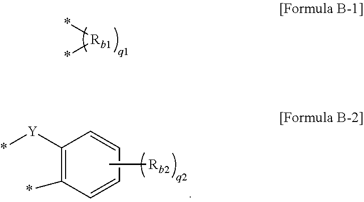

In Formula B-1 and Formula B-2, R_{b1} may be C(R_{b3})(R_{b4}) or N(R_{b5}); Y may be O, S, N(R_{b6}), or C(R_{b7})(R_{b8}); R_{b2} to Res may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring; q1 may be 3 or 4; and q2 may be an integer from 0 to 4.

In Formula 8-1 and Formula 8-2, X₁, R₁, R₄ to R₇, n1, and n4 to n7 are the same as defined in Formula 1.

In an embodiment, the first compound represented by Formula 1 may be represented by Formula 9-1 or Formula 9-2:

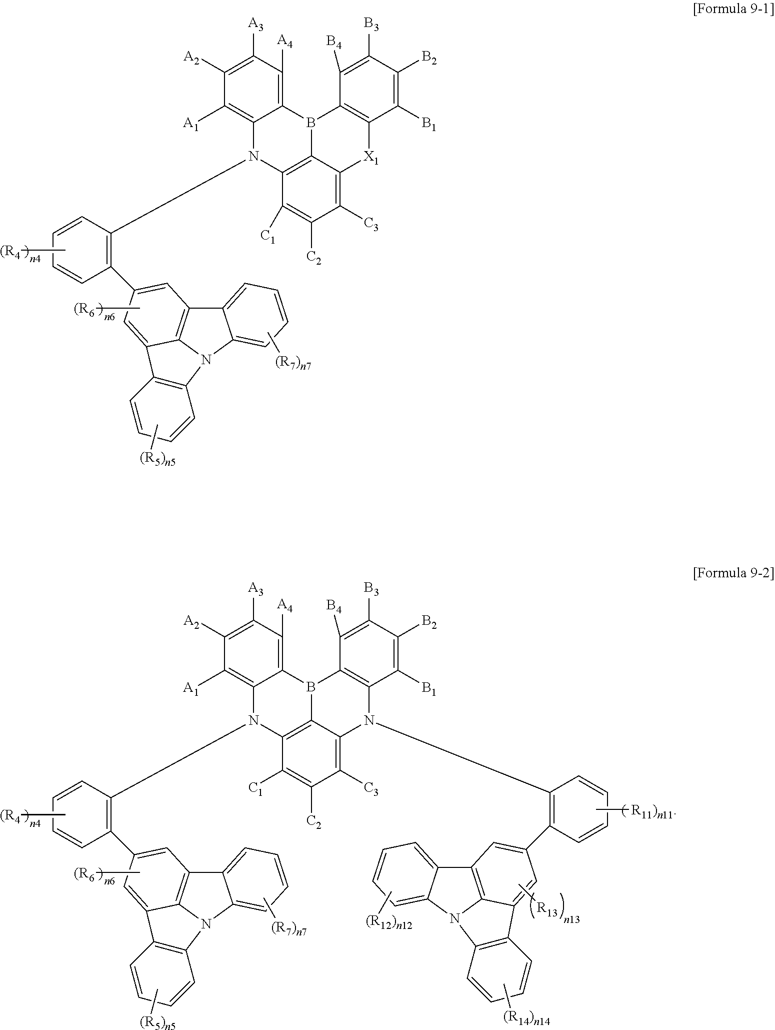

In Formula 9-1 and Formula 9-2, A₁ to A₄, B₁ to B₄, C₁ to C₃, and R₁₁ to R₁₄ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring; n11, n12, and n14 may each independently be an integer from 0 to 4; n13 may be an integer from 0 to 2; and at least one among A₁ to A₄, B₁ to B₄, and C₁ to C₃ is selected from Substituent Group 1.

In Formula 9-1 and Formula 9-2, X₁, R₄ to R₇, and n4 to n7 are the same as defined in Formula 1.

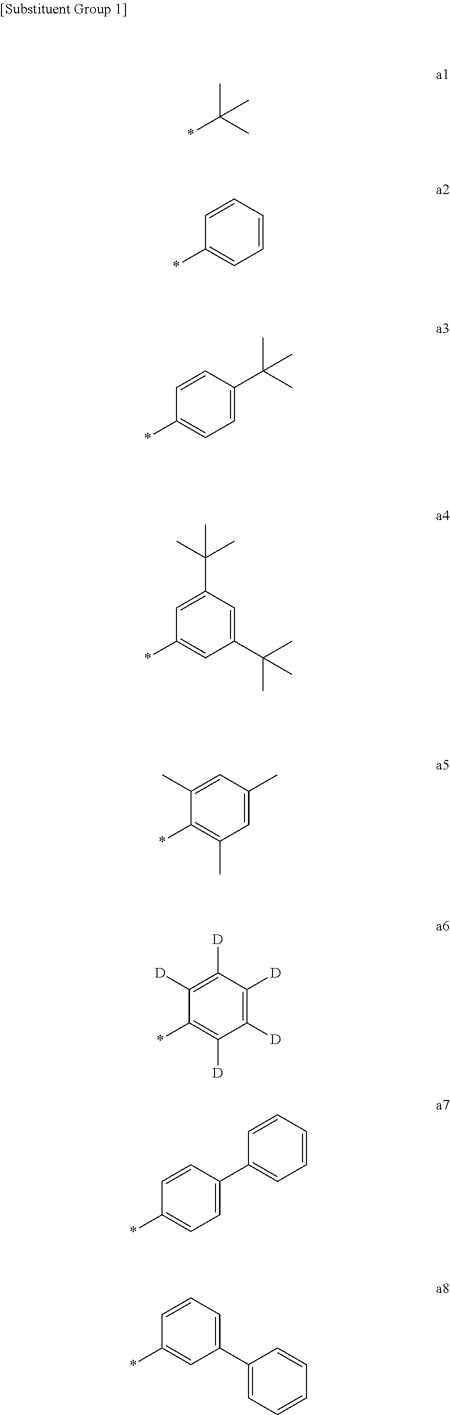

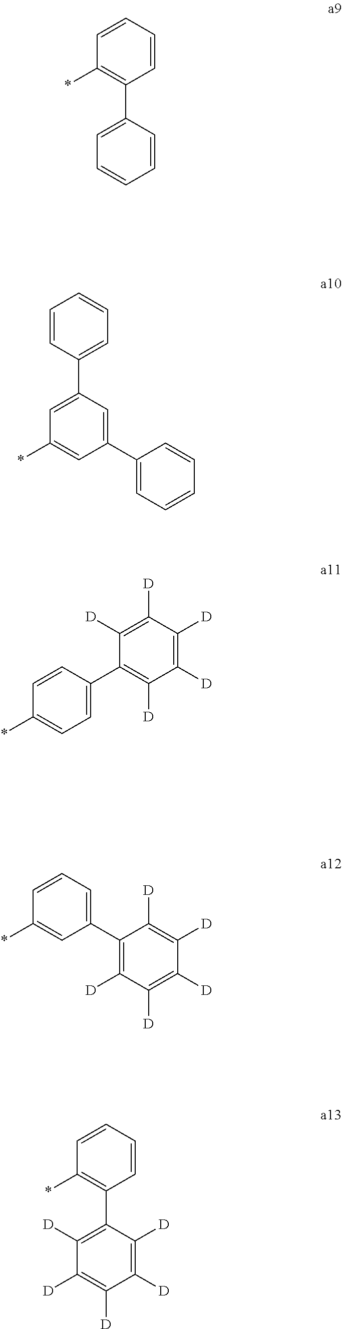 [SMILES: *c1ccccc1-c1ccccc1 ; *c1cc(-c2ccccc2)cc(-c2ccccc2)c1 ; *c1ccc(-c2c([2H])c([2H])c([2H])c([2H])c2[2H])cc1 ; *c1cccc(-c2c([2H])c([2H])c([2H])c([2H])c2[2H])c1 ; *c1ccccc1-c1c([2H])c([2H])c([2H])c([2H])c1[2H]]

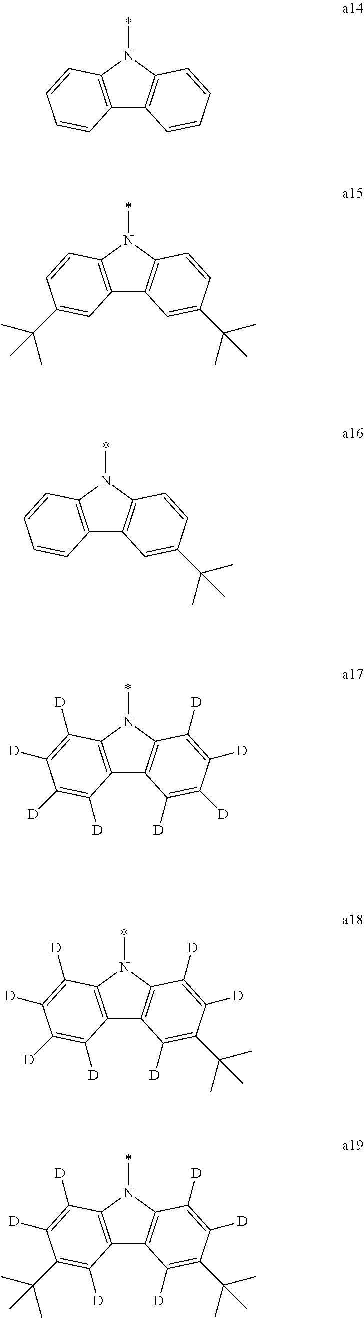

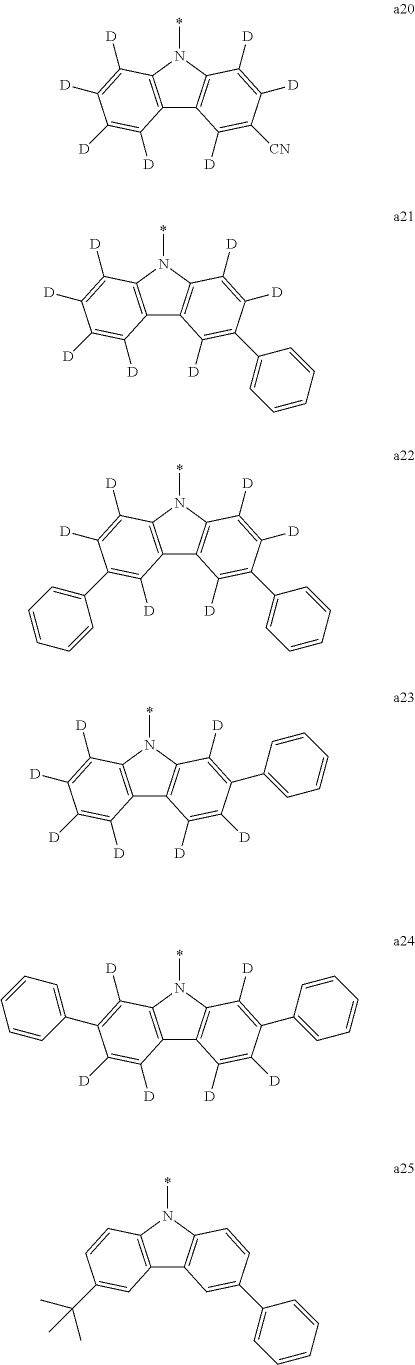 [SMILES: *n1c2c([2H])c([2H])c([2H])c([2H])c2c2c([2H])c(C#N)c([2H])c([2H])c21 ; *n1c2c([2H])c([2H])c([2H])c([2H])c2c2c([2H])c(-c3ccccc3)c([2H])c([2H])c21 ; *n1c2c([2H])c([2H])c(-c3ccccc3)c([2H])c2c2c([2H])c(-c3ccccc3)c([2H])c([2H])c21 ; *n1c2c([2H])c([2H])c([2H])c([2H])c2c2c([2H])c([2H])c(-c3ccccc3)c([2H])c21 ; *n1c2c([2H])c(-c3ccccc3)c([2H])c([2H])c2c2c([2H])c([2H])c(-c3ccccc3)c([2H])c21 ; *n1c2ccc(-c3ccccc3)cc2c2cc(C(C)(C)C)ccc21]

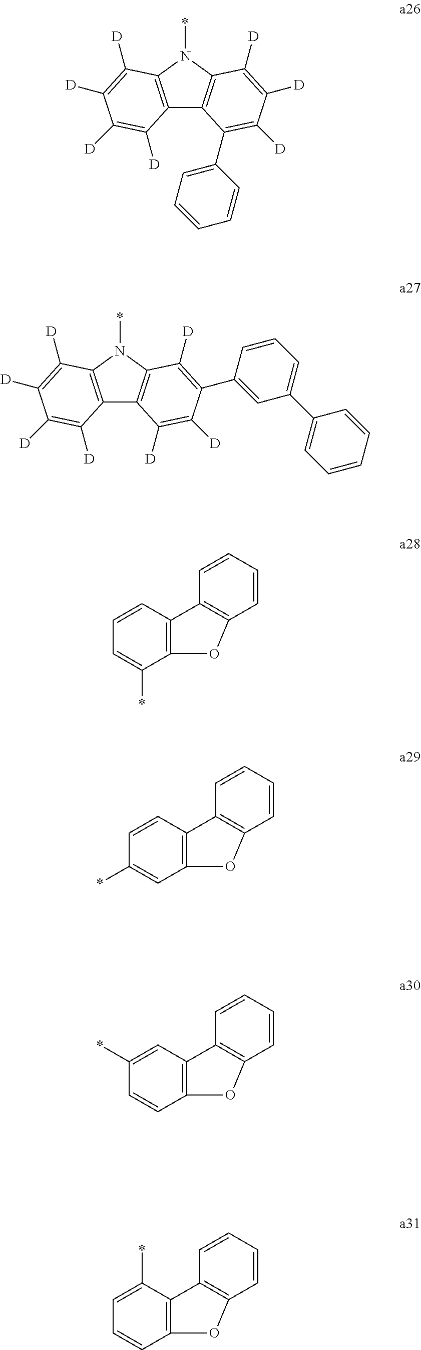 [SMILES: *n1c2c([2H])c([2H])c([2H])c([2H])c2c2c(-c3ccccc3)c([2H])c([2H])c([2H])c21 ; *n1c2c([2H])c([2H])c([2H])c([2H])c2c2c([2H])c([2H])c(-c3cccc(-c4ccccc4)c3)c([2H])c21 ; *c1cccc2c1oc1ccccc12 ; *c1ccc2c(c1)oc1ccccc12 ; *c1ccc2oc3ccccc3c2c1 ; *c1cccc2oc3ccccc3c12]

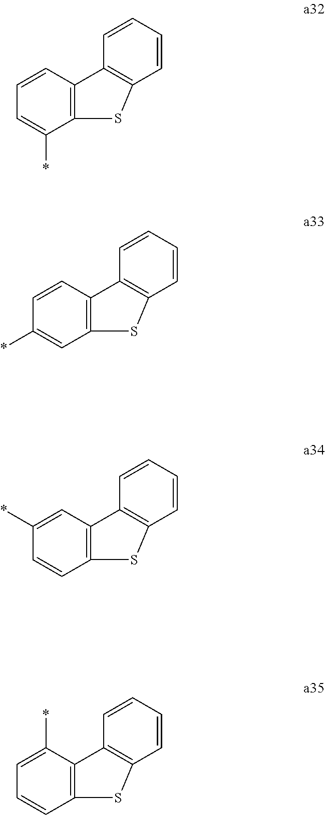 [SMILES: *c1cccc2c1sc1ccccc12 ; *c1ccc2c(c1)sc1ccccc12 ; *c1ccc2sc3ccccc3c2c1 ; *c1cccc2sc3ccccc3c12]

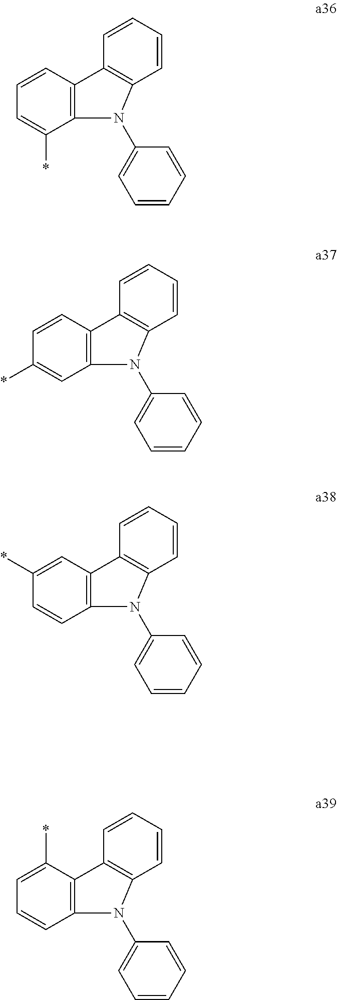 [SMILES: *c1cccc2c3ccccc3n(-c3ccccc3)c12 ; *c1ccc2c3ccccc3n(-c3ccccc3)c2c1 ; *c1ccc2c(c1)c1ccccc1n2-c1ccccc1 ; *c1cccc2c1c1ccccc1n2-c1ccccc1]

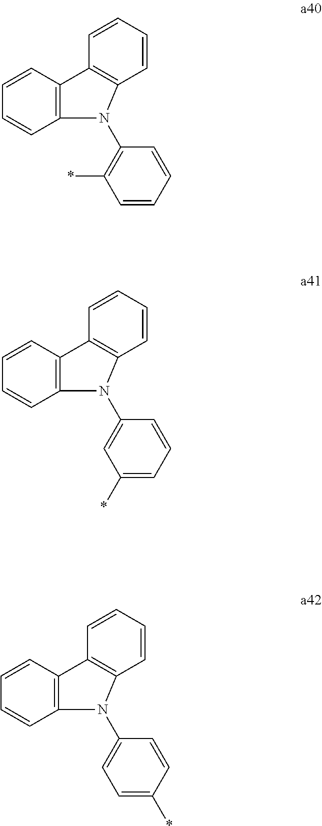 [SMILES: *c1ccccc1-n1c2ccccc2c2ccccc21 ; *c1cccc(-n2c3ccccc3c3ccccc32)c1 ; *c1ccc(-n2c3ccccc3c3ccccc32)cc1]

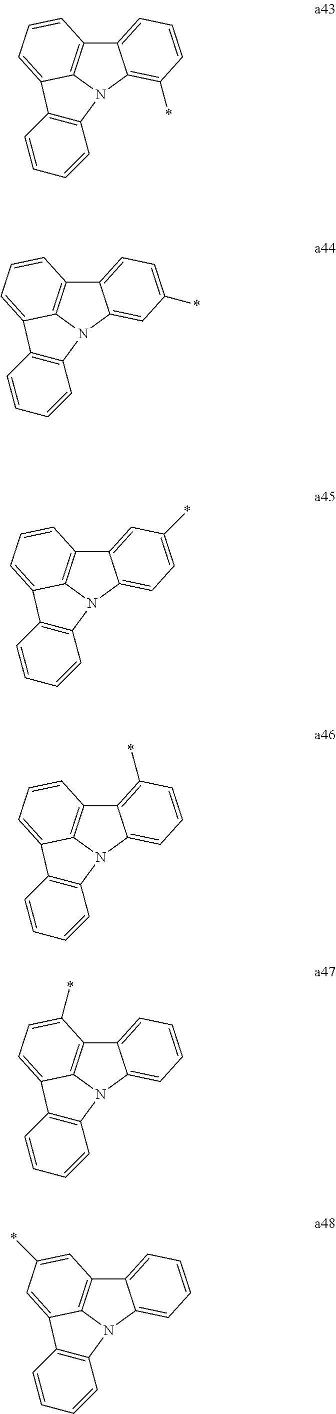

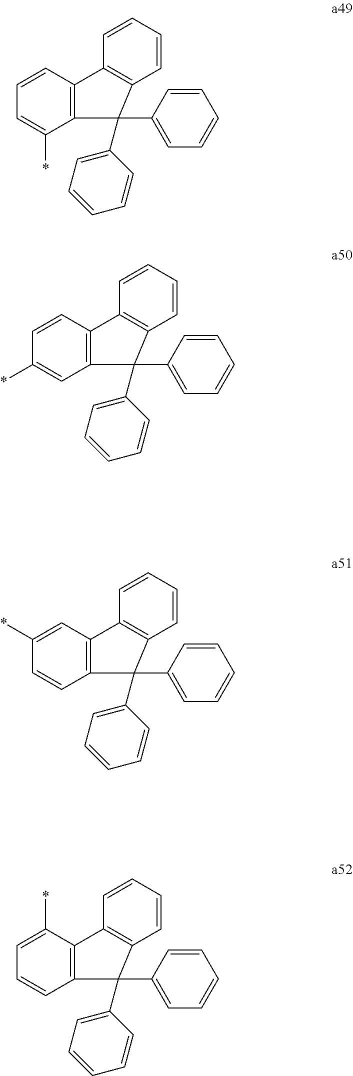 [SMILES: *c1cccc2c1C(c1ccccc1)(c1ccccc1)c1ccccc1-2 ; *c1ccc2c(c1)C(c1ccccc1)(c1ccccc1)c1ccccc1-2 ; *c1ccc2c(c1)-c1ccccc1C2(c1ccccc1)c1ccccc1 ; *c1cccc2c1-c1ccccc1C2(c1ccccc1)c1ccccc1]

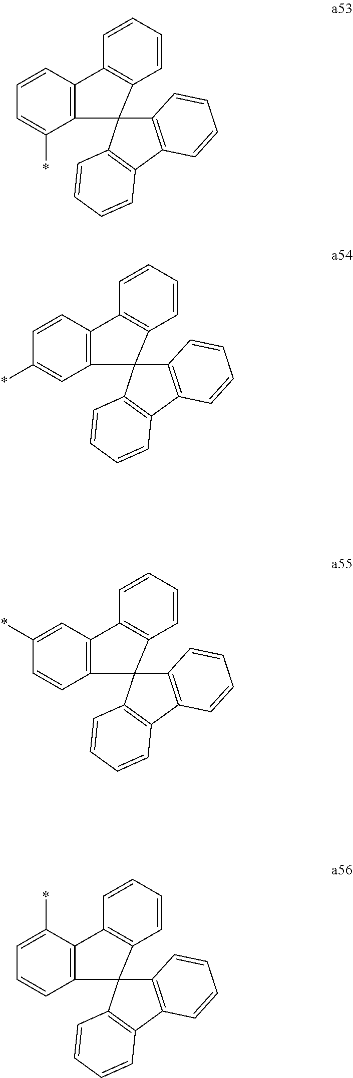 [SMILES: *c1cccc2c1C1(c3ccccc3-c3ccccc31)c1ccccc1-2 ; *c1ccc2c(c1)C1(c3ccccc3-c3ccccc31)c1ccccc1-2 ; *c1ccc2c(c1)-c1ccccc1C21c2ccccc2-c2ccccc21 ; *c1cccc2c1-c1ccccc1C21c2ccccc2-c2ccccc21]

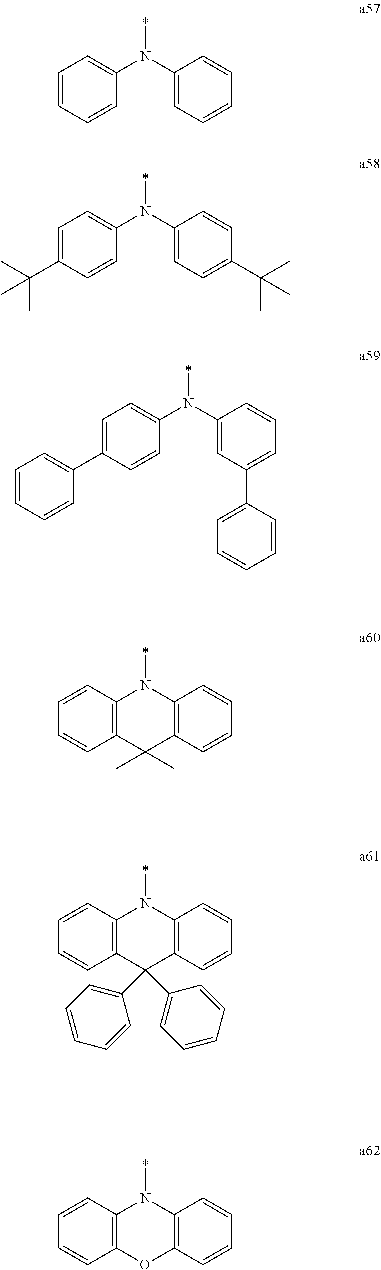 [SMILES: *N(c1ccccc1)c1ccccc1 ; *N(c1ccc(C(C)(C)C)cc1)c1ccc(C(C)(C)C)cc1 ; *N(c1ccc(-c2ccccc2)cc1)c1cccc(-c2ccccc2)c1 ; *N1c2ccccc2C(C)(C)c2ccccc21 ; *N1c2ccccc2C(c2ccccc2)(c2ccccc2)c2ccccc21 ; *N1c2ccccc2Oc2ccccc21]

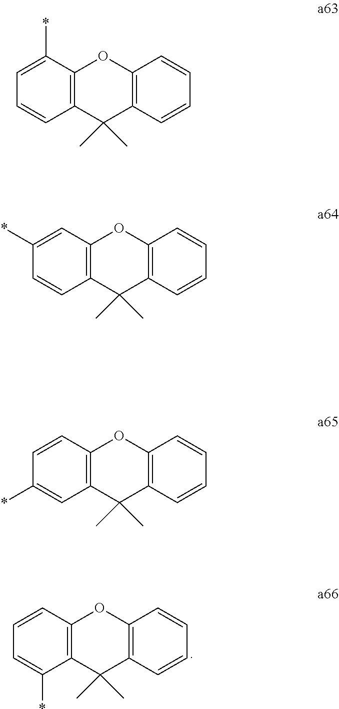 [SMILES: *c1cccc2c1Oc1ccccc1C2(C)C ; *c1ccc2c(c1)Oc1ccccc1C2(C)C ; *c1ccc2c(c1)C(C)(C)c1ccccc1O2 ; *c1cccc2c1C(C)(C)c1ccccc1O2]

In an embodiment, the first compound represented by Formula 1 may be represented by one of Formula 10-1 to Formula 10-4:

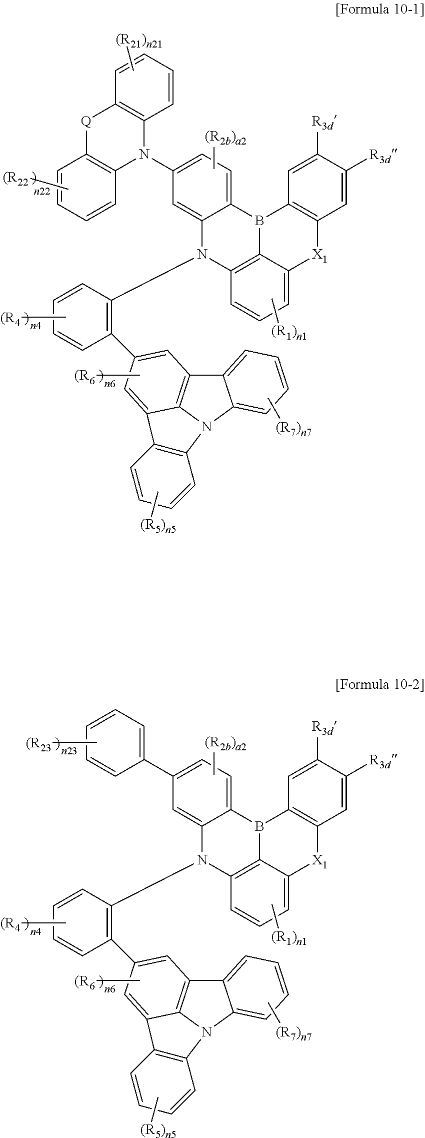

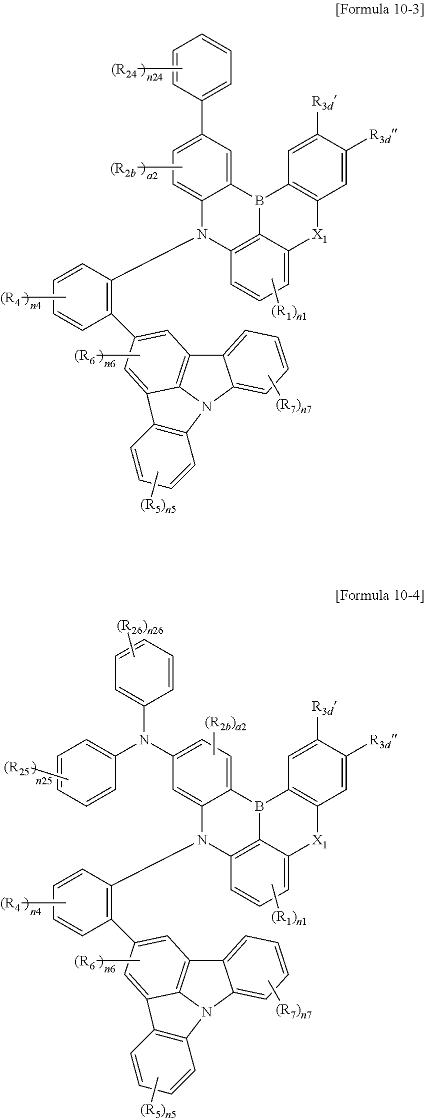

In Formula 10-1 to Formula 10-4, Q may be a direct linkage, O, or C(R₂₇)(R₂₈); R_{3d}′ and R_{3d}″ may each independently be a hydrogen atom or a group represented by one of Formula A-1 to Formula A-5; R₂₁ to R₂₈ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; n21 and n22 may each independently be an integer from 0 to 4; and n23 to n26 may each independently be an integer from 0 to 5.

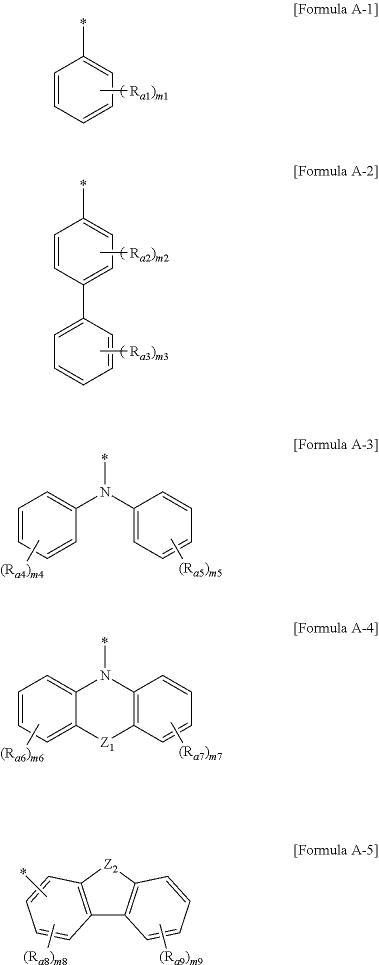

In Formula A-1 to Formula A-5, Z₁ may be a direct linkage, O, or C(Rₐ₁₀)(Rₐ₁₁); Z₂ may be O, S, N(Rₐ₁₂), or C(Rₐ₁₃)(Rₐ₁₄); Rai to Rₐ₁₄ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; m1, m3, m4, and m5 may each independently be an integer from 0 to 5; m2, m6, m7, and m9 may each independently be an integer from 0 to 4; and m8 may be an integer from 0 to 3.

In Formula 10-1 to Formula 10-4, X₁, R₁, R₄ to R₇, n1, and n4 to n7 are the same as defined in Formula 1.

In an embodiment, the emission layer may further include at least one of a second compound represented by Formula HT-1, a third compound represented by Formula ET-1, and a fourth compound represented by Formula D-1:

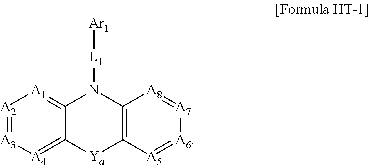

In Formula HT-1, A₁ to A₈ may each independently be N or C(R₅₁); Lᵢ may be a direct linkage, a substituted or unsubstituted arylene group of 6 to 30 ring-forming carbon atoms, or a substituted or unsubstituted heteroarylene group of 2 to 30 ring-forming carbon atoms; Yₐ may be a direct linkage, C(R₅₂)(R₅₃), or Si(R₅₄)(R₅₅); Ar₁ may be a substituted or unsubstituted aryl group of 6 to 30 ring-forming carbon atoms or a substituted or unsubstituted heteroaryl group of 2 to 30 ring-forming carbon atoms; and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring.

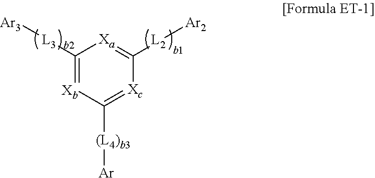

In Formula ET-1, at least one of Xₐ to X_{c} may each be N; the remainder of Xₐ to X_{c} may each independently be C(R₅₆); R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms; b1 to b3 may each independently be an integer from 0 to 10; Ar₂ to Ar₄ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; and L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms.

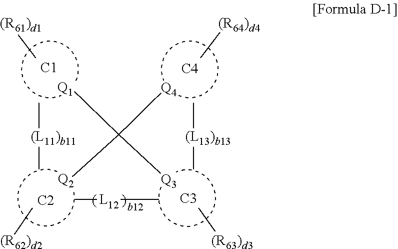

In Formula D-1, Q₁ to Q₄ may each independently be C or N; C1 to C4 may each independently be a substituted or unsubstituted hydrocarbon ring of 5 to 30 ring-forming carbon atoms or a substituted or unsubstituted heterocycle of 2 to 30 ring-forming carbon atoms; L₁₁ to L₁₃ may each independently be a direct linkage,

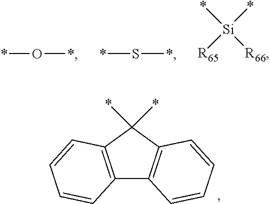

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms; b11 to b13 may each independently be 0 or 1; R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring; and d1 to d4 may each independently be an integer from 0 to 4.

An embodiment provides an electronic device which may include at least one light emitting element, wherein the electronic device may be a television, a monitor, a billboard, a personal computer, a laptop computer, a personal digital terminal, a vehicle display device, a game console, or a camera; and the light emitting element may include a first compound represented by Formula 1, which is explained herein.

An embodiment provides a fused polycyclic compound which may be represented by Formula 1, which is explained herein.

In an embodiment, the fused polycyclic compound represented by Formula 1 may be represented by Formula 2, which is explained herein.

In an embodiment, the fused polycyclic compound represented by Formula 1 may be represented by Formula 3, which is explained herein.

In an embodiment, the fused polycyclic compound represented by Formula 1 may be represented by Formula 4, which is explained herein.

In an embodiment, the fused polycyclic compound represented by Formula 4 may be represented by Formula 5, which is explained herein.

In an embodiment, the fused polycyclic compound represented by Formula 4 may be represented by one of Formula 6-1 to Formula 6-4, which are explained herein.

In an embodiment, the fused polycyclic compound represented by Formula 4 may be represented by Formula 7-1 or Formula 7-2, which are explained herein.

In an embodiment, the fused polycyclic compound may be selected from Compound Group 1, which is explained below.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display apparatus according to an embodiment;

FIG. 2 is a schematic cross-sectional view of a display apparatus according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display apparatus according to an embodiment;

FIG. 8 is a schematic cross-sectional view of a display apparatus according to an embodiment;

FIG. 9 is a schematic cross-sectional view of a display apparatus according to an embodiment;

FIG. 10 is a schematic cross-sectional view of a display apparatus according to an embodiment;

FIG. 11 is a schematic perspective view of a vehicle including a display apparatus according to an embodiment;

FIG. 12A and FIG. 12B are diagrams showing three-dimensional molecular models of the Comparative Compound; and

FIG. 13A and FIG. 13b are diagrams showing three-dimensional molecular models of the Example Compound.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “combined with an adjacent group to form a ring” may be interpreted as a group that is bonded to an adjacent group to form a substituted or unsubstituted hydrocarbon ring or a substituted or unsubstituted heterocycle. The hydrocarbon ring may be aliphatic or aromatic. The heterocycle or aliphatic or aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group including at least one carbon-carbon double bond in the middle or at a terminus of an alkyl group having 2 or more carbon atoms. An alkenyl group may be linear or branched. The number of carbon atoms in an alkenyl group is not particularly limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group including at least one carbon-carbon triple bond in the middle or at a terminus of an alkyl group having 2 or more carbon atoms. An alkynyl group may be linear or branched. The number of carbon atoms in an alkynyl group is not particularly limited, but may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

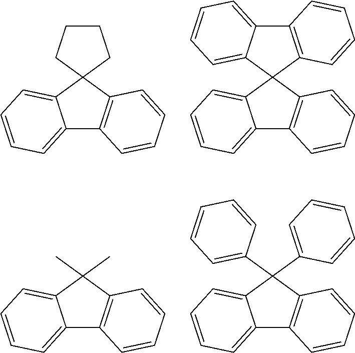

In the specification, a heterocyclic group may be any functional group or substituent derived from a ring including at least one of B, O, N, P, Si, S, and Se as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

In the specification, a heterocyclic group may include at least one of B, O, N, P, Si, S, and Se as a heteroatom. If a heterocyclic group includes two or more heteroatoms, the two or more heteroatoms may be the same as or different from each other. A heterocyclic group may be monocyclic or polycyclic. A heterocyclic group may be a heteroaryl group. The number of ring-forming carbon atoms in a heterocyclic group may be 2 to 30, 2 to 20, or 2 to 10.

In the specification, an aliphatic heterocyclic group may include at least one of B, O, N, P, Si, S, and Se as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B, O, N, P, Si, S, and Se as a heteroatom. If a heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, but may be 1 to 40, 1 to 30, or 1 to 20. For example, a carbonyl group may have one of the following structures, but embodiments are not limited thereto.

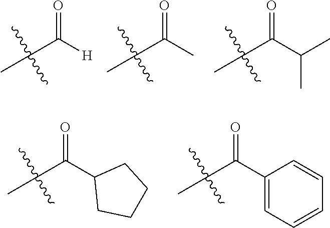

In the specification, the number of carbon atoms in a sulfinyl group or in a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an oxy group is not particularly limited, but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

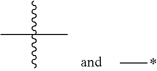

each represent a bond to a neighboring atom in a corresponding formula or moiety.

Hereinafter, embodiments will be described with reference to the accompanying drawings.

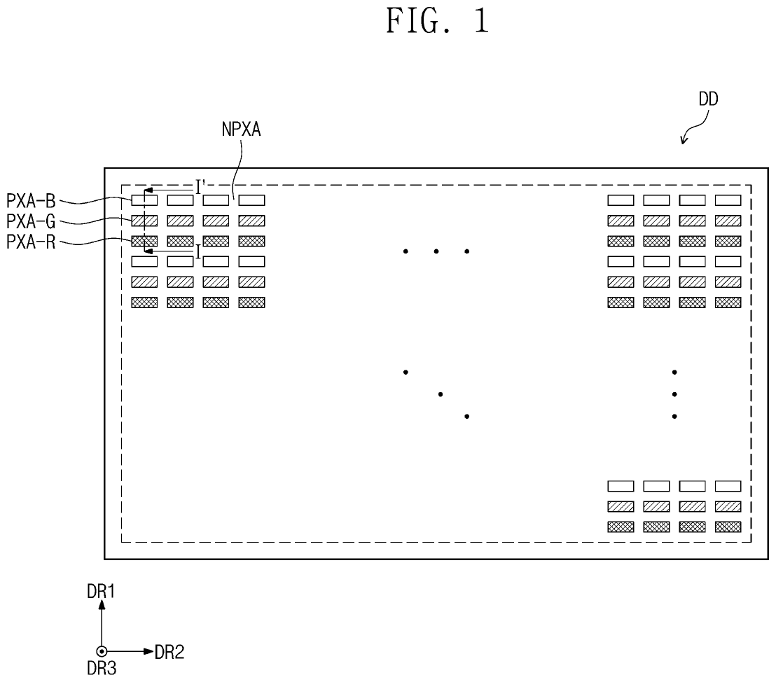

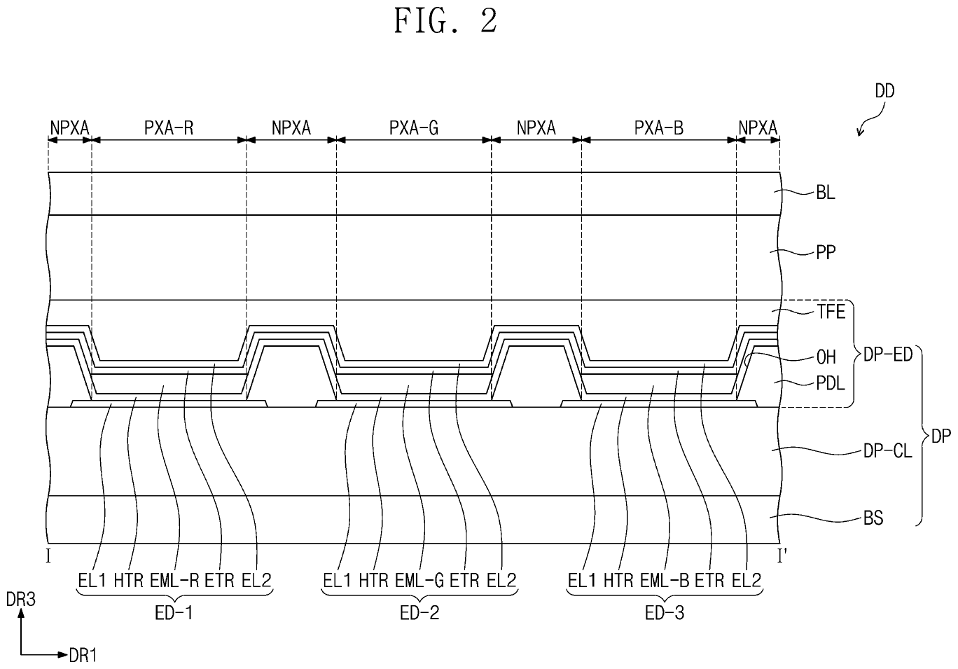

FIG. 1 is a schematic plan view of a display apparatus DD according to an embodiment. FIG. 2 is a schematic cross-sectional view of a display apparatus DD according to an embodiment. FIG. 2 is a schematic cross-sectional view illustrating a part taken along line I-I′ in FIG. 1.

The display apparatus DD may include a display panel DP and an optical layer PP disposed on the display panel DP. The display panel DP includes light emitting elements ED-1, ED-2, and ED-3. The display apparatus DD may include multiples of each of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display apparatus DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display apparatus DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display device layer DP-ED. The display device layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display device layer DP-ED.

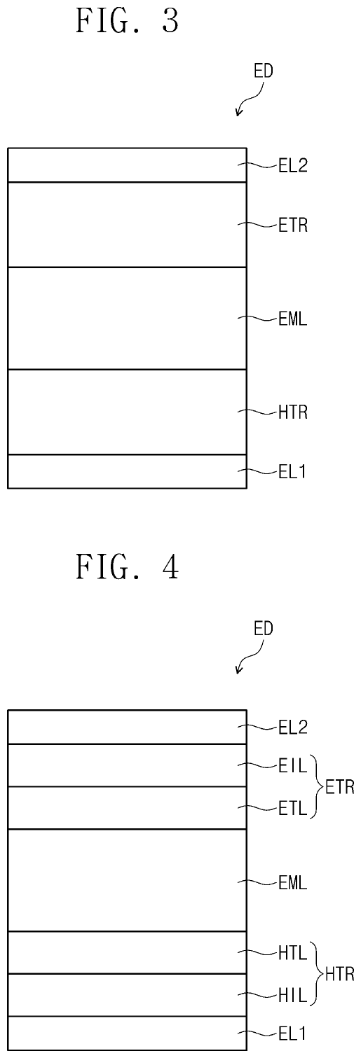

The light emitting elements ED-1, ED-2, and ED-3 may each have a structure of a light emitting element ED of an embodiment according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for the light emitting elements ED-1, ED-2, and ED-3. However, embodiments are not limited thereto. Although not illustrated in FIG. 2, in an embodiment, the hole transport region HTR and the electron transport region ETR may each be provided by being patterned in the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 may each be provided by being patterned through an inkjet printing method.

The encapsulation layer TFE may cover the light emitting elements ED-1, ED-2, and ED-3. The encapsulation layer TFE may seal the display device layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). In an embodiment, the encapsulation layer TFE may include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display apparatus DD may include non-light emitting regions NPXA and light emitting regions PXA-R, PXA-G, and PXA-B. The light emitting regions PXA-R, PXA-G, and PXA-B may each be a region that emits light respectively generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining film PDL. The non-light emitting regions NPXA may be areas between the adjacent light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display apparatus DD according to an embodiment illustrated in FIGS. 1 and 2, three light emitting regions PXA-R, PXA-G, and PXA-B, which respectively emit red light, green light, and blue light, are illustrated as an example. For example, the display apparatus DD may include a red light emitting region PXA-R, a green light emitting region PXA-G, and a blue light emitting region PXA-B, which are distinct from each other.

In the display apparatus DD according to an embodiment, the light emitting elements ED-1, ED-2, and ED-3 may emit light having wavelengths that are different from each other. For example, in an embodiment, the display apparatus DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display apparatus DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range, or at least one light emitting element may emit light in a wavelength range that is different from the remainder. For example, the first to third light emitting elements ED-1, ED-2, and ED-3 may each emit blue light.

The light emitting regions PXA-R, PXA-G, and PXA-B in the display apparatus DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be alternately arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size or shape from each other, according to a wavelength range of emitted light. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations, according to the display quality characteristics that are required for the display apparatus DD. For example, the light emitting regions PXA-R, PXA-G, and PXA-B may be arranged in a pentile configuration (such as PENTILE™) or in a diamond configuration (such as Diamond Pixel™).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIG. 3 to FIG. 6 are each a schematic cross-sectional view of a light emitting element according to an embodiment. The light emitting element ED according to an embodiment may include a first electrode EL1, a second electrode EL2 oppositely disposed to the first electrode EL1, and at least one functional layer disposed between the first electrode EL1 and the second electrode EL2. The light emitting element ED may include a fused polycyclic compound according to an embodiment, which will be explained later, in the at least one functional layer.

The light emitting element ED may include a hole transport region HTR, an emission layer EML, an electron transport region ETR, or the like, as the at least one functional layer. Referring to FIG. 3, the light emitting element ED according to an embodiment may include a first electrode EL1, a hole transport region HTR, an emission layer EML, an electron transport region ETR, and a second electrode EL2.

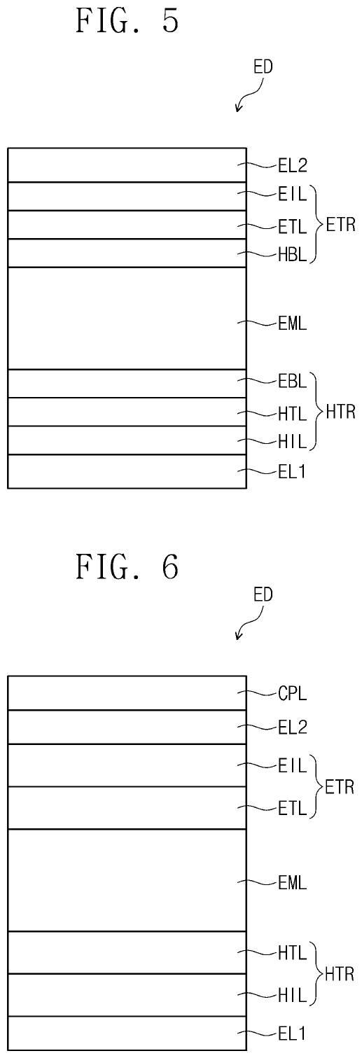

In comparison to FIG. 3, FIG. 4 is a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 is a schematic cross-sectional view of a light emitting element ED according to an embodiment that includes a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. In an embodiment, the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), and an electron blocking layer EBL. A thickness of the hole transport region HTR may be, for example, in a range of about 50 Å to about 15,000 Å.

The hole transport region HTR may be a layer consisting of a single material, a layer including different materials, or a structure including multiple layers including different materials.

In embodiments, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

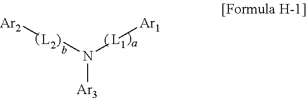

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, a compound represented by Formula H-1 may be a monoamine compound. In an embodiment, a compound represented by Formula H-1 may be a diamine compound in which at least one of Ar₁ to Ar₃ includes an amine group as a substituent. In another embodiment, a compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and the compound represented by Formula H-1 is not limited to Compound Group H:

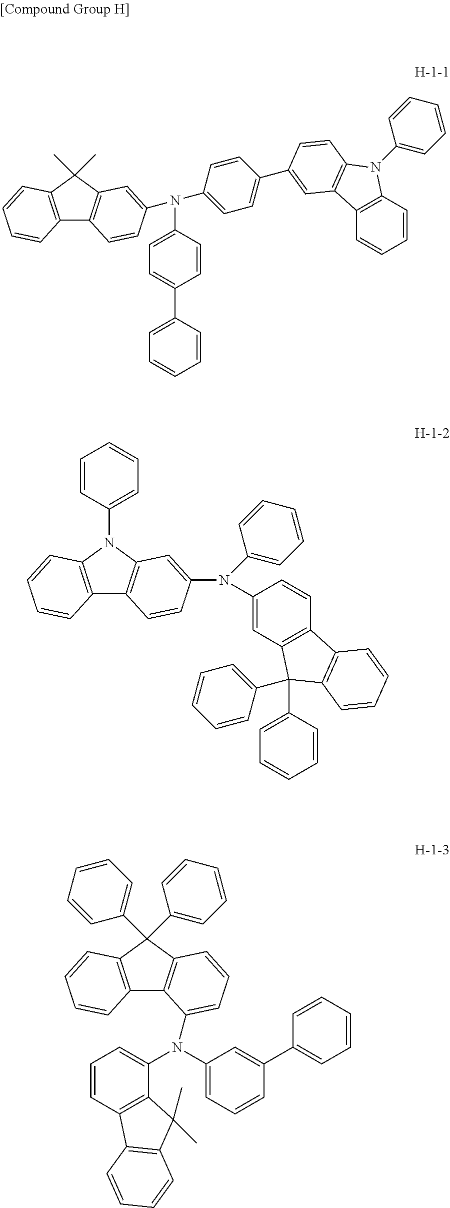 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

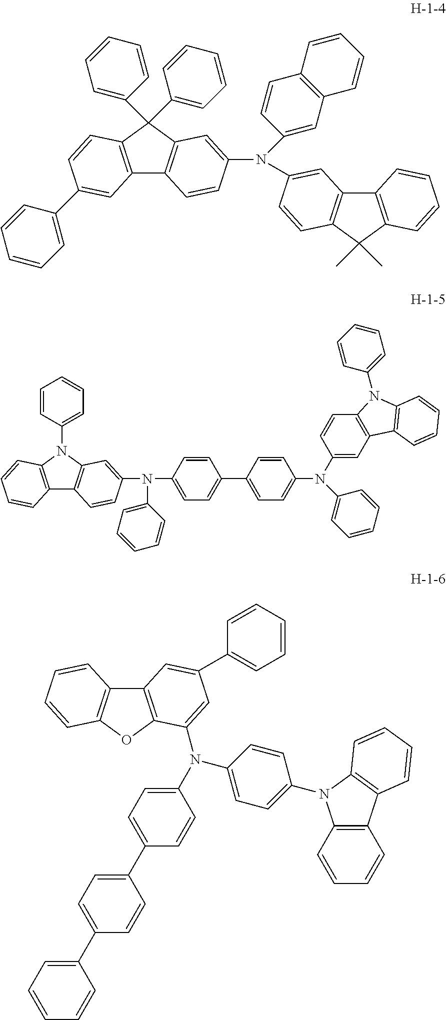 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

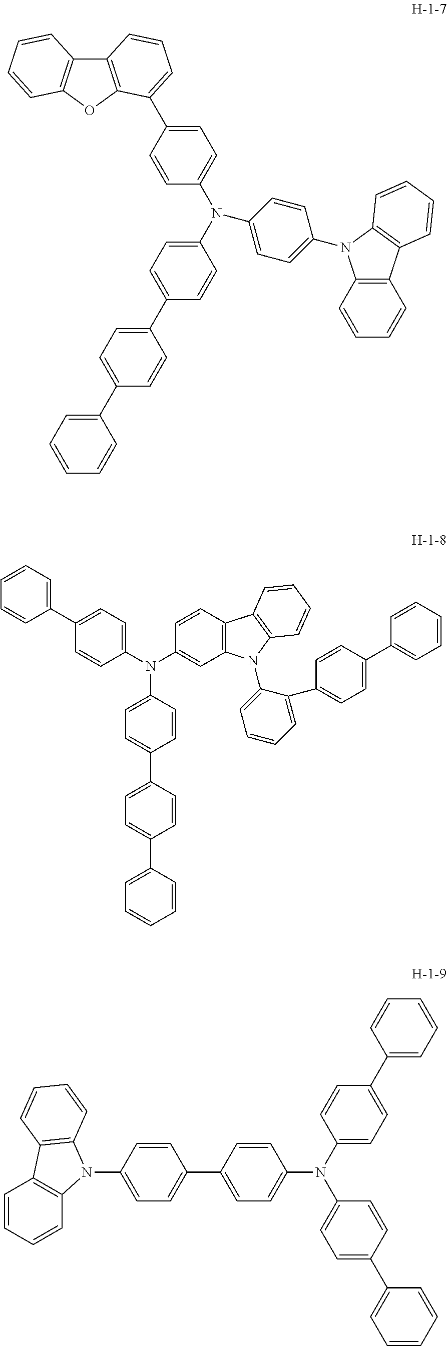 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

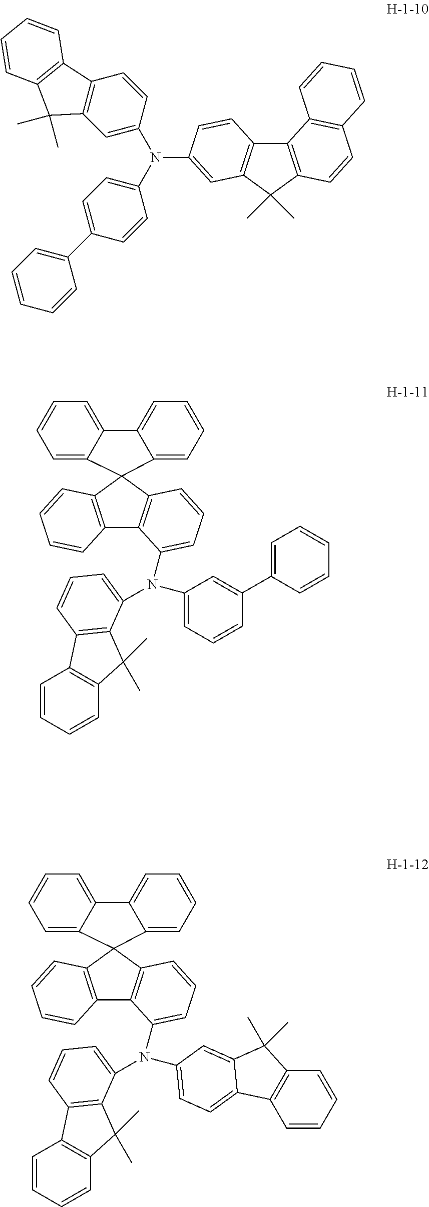 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

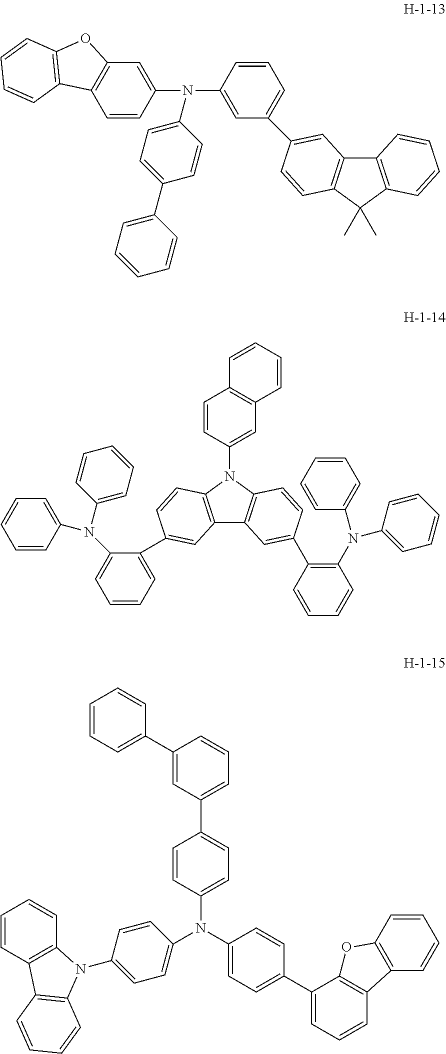 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

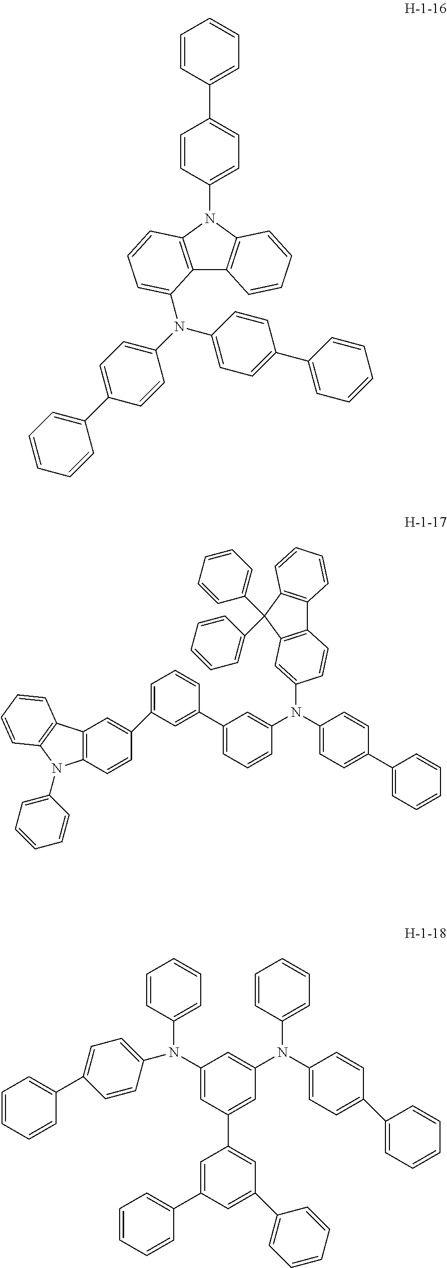 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

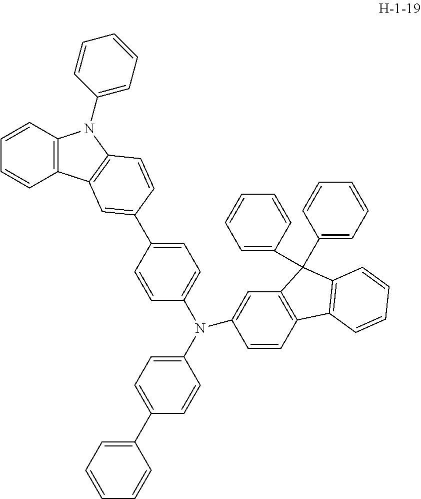 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto.

For example, the p-dopant may include a metal halide compound such as CuI or RbI; a quinone derivative such as tetracyanoquinodimethane (TCNQ) or 2,3,5,6-tetrafluoro-7,7′8,8-tetracyanoquinodimethane (F4-TCNQ); a metal oxide such as tungsten oxide or molybdenum oxide; a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) and an electron blocking layer EBL, in addition to a hole injection layer HIL and a hole transport layer HTL. The buffer layer (not shown) may compensate for a resonance distance according to a wavelength of light emitted from the emission layer EML and may thus increase light emission efficiency. A material that may be included in the hole transport region HTR may be used as a material in the buffer layer (not shown). The electron blocking layer EBL may prevent injection of electrons from an electron transport region ETR to the hole transport region HTR.

The emission layer EML may be provided on the hole transport region HTR. The emission layer EML may have a thickness in a range of about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

The light emitting element ED according to an embodiment may include the fused polycyclic compound represented by Formula 1 in at least one functional layer disposed between the first electrode EL1 and the second electrode EL2. In the light emitting element ED, the emission layer EML may include the fused polycyclic compound according to an embodiment. In an embodiment, the emission layer EML may include the fused polycyclic compound as a dopant. The fused polycyclic compound may be a dopant material of the emission layer EML. In the specification, the fused polycyclic compound according to an embodiment may be referred to as a first compound.

The fused polycyclic compound may have a structure in which multiple aromatic rings are fused together via a boron atom and at least two heteroatoms. For example, the fused polycyclic compound may include a fused ring core in which multiple aromatic rings are fused together via a boron atom and at least two heteroatoms.

In an embodiment, the fused polycyclic compound may have a structure that includes multiple aromatic rings that are fused together via a boron atom, a first nitrogen atom, and a first heteroatom. For example, the fused polycyclic compound may include a structure that includes first to third aromatic rings that are fused together via a first boron atom, a first nitrogen atom, and a first heteroatom. The first to third aromatic rings may each be connected to the first boron atom, the first aromatic ring and the second aromatic ring may be connected to each other via the first nitrogen atom, and the first aromatic ring and the third aromatic ring may be connected to each other via the first heteroatom. In the specification, a structure in which the first to third aromatic rings are fused together via the boron atom, the first nitrogen atom, and the first heteroatom may be referred to as a “fused ring core”.

In an embodiment, the first to third aromatic rings may each independently be a substituted or unsubstituted monocyclic aromatic hydrocarbon ring of 6 to 30 ring-forming carbon atoms or a substituted or unsubstituted monocyclic aromatic heterocycle of 2 to 30 ring-forming carbon atoms. For example, the first to third aromatic rings may each independently be a six-member aromatic hydrocarbon ring. In an embodiment, the first heteroatom may be an oxygen atom (O), a sulfur atom (S), or a nitrogen atom (N).

The fused polycyclic compound of an embodiment may include a first substituent bonded to the fused ring core. The first substituent may be bonded to the first nitrogen atom of the fused ring core. The first substituent may include an indolocarbazole moiety. In the specification, an indolocarbazole moiety may be an aromatic heterocycle in which three benzene rings form a fused structure with a nitrogen atom as a central atom, as in Formula S below. Any of the three benzene rings of the indolocarbazole moiety included in the first substituent may be connected to the first nitrogen atom. The first substituent may be connected to the first nitrogen atom of the fused ring core via a first linker. In an embodiment, the first linker may include a benzene moiety. For example, the first linker may be a substituted or unsubstituted phenylene linker. The first substituent may be bonded to the phenylene linker at an ortho position to the first nitrogen atom of the fused ring core. The carbon number of the first substituent may be given as shown in Formula S below. In an embodiment, the first substituent may be connected to the first nitrogen atom of the fused ring core at the 2-position carbon of the indolocarbazole moiety. However, embodiments are not limited thereto.

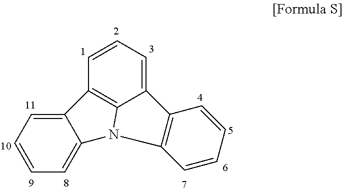 [SMILES: c1ccc2c(c1)c1cccc3c4ccccc4n2c13]

The fused polycyclic compound according to an embodiment may be represented by Formula 1:

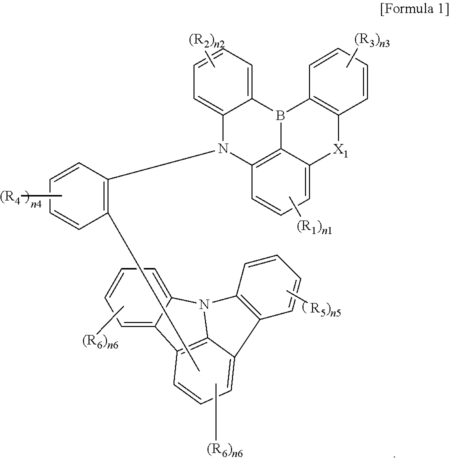

In Formula 1, X₁ may be O, S, or N(Rₐ). For example, X₁ may be N(Rₐ).

In Formula 1, R₁ to R₇ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring. For example, R₁ to R₇ may each independently be a hydrogen atom, a deuterium atom, a substituted or unsubstituted alkyl group of 1 to 10 carbon atoms, a substituted or unsubstituted phenyl group, a substituted or unsubstituted biphenyl group, a substituted or unsubstituted arylamine group, a substituted or unsubstituted aryloxy group, a substituted or unsubstituted fluorenyl group, a substituted or unsubstituted dibenzofuran group, a substituted or unsubstituted carbazole group, a substituted or unsubstituted acridine group, a substituted or unsubstituted phenoxazine group, or a substituted or unsubstituted indolocarbazole group. For example, in Formula 1, multiple R₂ groups may be provided, and the multiple R₂ groups may be combined with each other to form an additional fused ring. For example, in Formula 1, multiple R₃ groups may be provided, and the multiple R₃ groups may be combined with each other to form an additional fused ring. However, embodiments are not limited thereto.

In Formula 1, Rₐ may be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Rₐ may be a substituted or unsubstituted phenyl group, a substituted or unsubstituted biphenyl group, a substituted or unsubstituted terphenyl group, a substituted or unsubstituted quaterphenyl group, or a substituted or unsubstituted quinquephenyl group.

In Formula 1, n1 and n6 may each independently be an integer from 0 to 3; n2 to n5 and n7 may each independently be an integer from 0 to 4; and a sum of n6 and n7 is equal to or less than 6.

If n1 and n6 are each 0, the fused polycyclic compound may not be substituted with R₁ and R₆, respectively. A case where n1 and n6 are each 3 and all R₁ groups and all R₆ groups are hydrogen atoms may be the same as a case where n1 and n6 are each 0. If n1 and n6 are each 2 or more, multiple R₁ groups and multiple R₆ groups may be all the same, or at least one group thereof may be different from the remainder.

If n2 to n5 and n7 are each 0, the fused polycyclic compound may not be substituted with R₂ to R₅ and R₇, respectively. A case where n2 to n5 and n7 are each 4 and all groups of each of R₂ to R₅ and R₇ are hydrogen atoms may be the same as a case where n2 to n5 and n7 are each 0. If n2 to n5 and n7 are each 2 or more, multiple groups of each of R₂ to R₅ and R₇ may be all the same, or at least one group thereof may be different from the remainder.

In an embodiment, the fused polycyclic compound represented by Formula 1 may be represented by Formula 2:

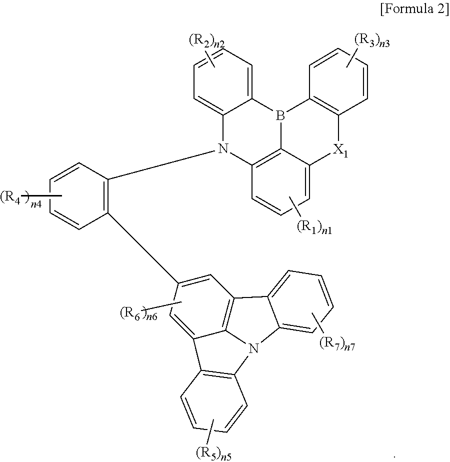

In Formula 2, X₁, R₁ to R₇, and n1 to n7 are the same as defined in Formula 1.

In an embodiment, the fused polycyclic compound represented by Formula 1 may be represented by one of Formula 2-1 to Formula 2-5:

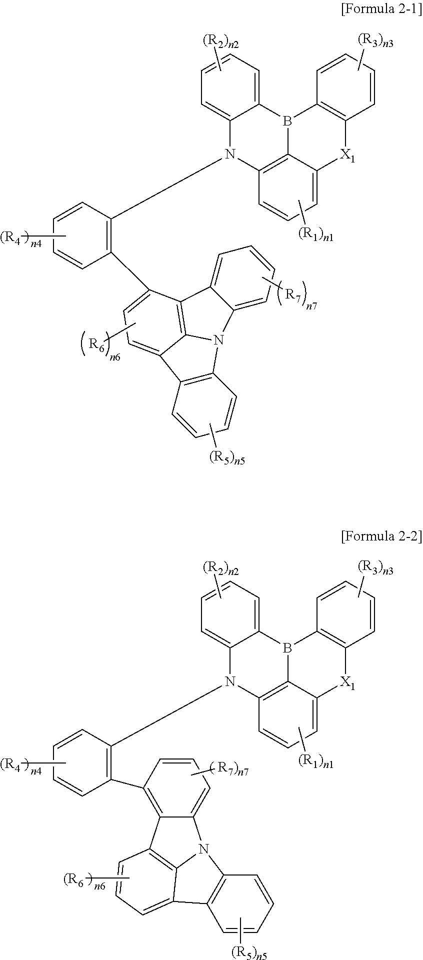

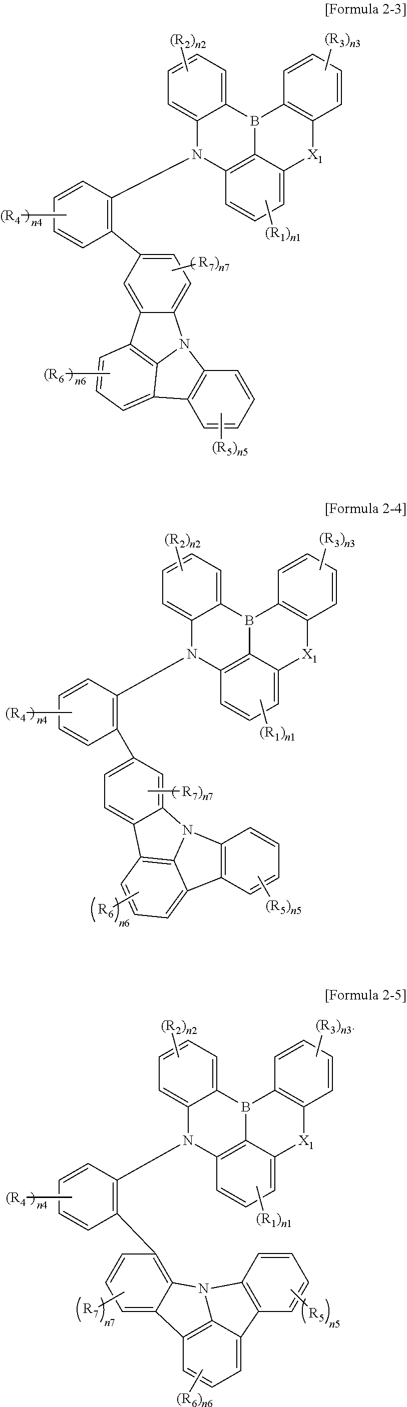

In Formula 2-1 to Formula 2-5, X₁, R₁ to R₇, and n1 to n7 are the same as defined in Formula 1.

In an embodiment, the fused polycyclic compound may further include a second substituent, in addition to the first substituent. The second substituent may include an indolocarbazole moiety. The first substituent and the second substituent may each be connected to the first nitrogen atom of the fused ring core via the first linker. The first and second substituents may each be bonded to the first linker at an ortho position to the first nitrogen atom of the fused ring core. The first and second substituents may each be bonded to a carbon atom that is at an ortho position with respect to a carbon atom of the first linker that is bonded to the first nitrogen atom of the fused ring core.

In an embodiment, the fused polycyclic compound represented by Formula 1 may be represented by Formula 3-a:

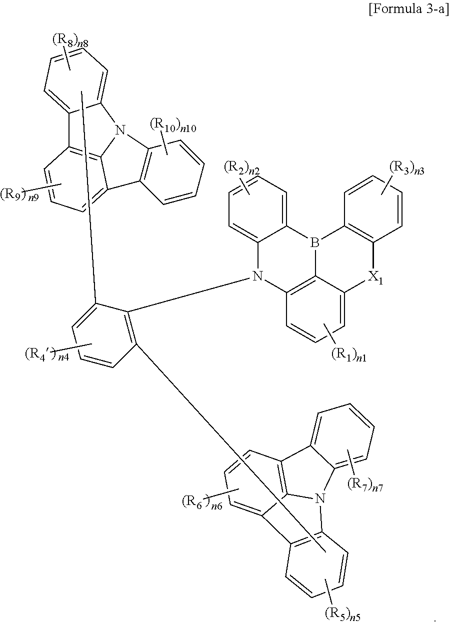

In Formula 3-a, R₄ and R₈ to R₁₀ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₄ and R₅ to R₁₀ may each independently be a hydrogen atom, a deuterium atom, a substituted or unsubstituted t-butyl group, a substituted or unsubstituted phenyl group, or a substituted or unsubstituted biphenyl group.

In Formula 3-a, n4′ may be an integer from 0 to 3. If n4′ is 0, the fused polycyclic compound may not be substituted with R₄′. A case where n4′ is 3 and all R₄′ groups are hydrogen atoms may be the same as a case where n4′ is 0. If n4′ is 2 or more, multiple R₄′ groups may be all the same, or at least one R₄′ group may be different from the remainder.

In Formula 3-a, n8 and n10 may each independently be an integer from 0 to 4. If n8 and n10 are each 0, the fused polycyclic compound may not be substituted with R₈ and R₁₀, respectively. A case where n8 and n10 are each 4 and all R₈ groups and all R₁₀ groups are hydrogen atoms may be the same as a case where n8 and n10 are each 0. If n8 and n10 are each 2 or more, multiple R₈ groups and multiple R₁₀ groups may be all the same, or at least one group thereof may be different from the remainder.

In Formula 3-a, n9 may be an integer from 0 to 2. If n9 is 0, the fused polycyclic compound may not be substituted with R₉. A case where n9 is 2 and all R₉ groups are hydrogen atoms may be the same as a case where n9 is 0. If n9 is 2, two R₉ groups may be the same, or one R₉ group may be different from the other R₉ group.

In Formula 3-a, X₁, R₁ to R₃, R₅ to R₇, n1 to n3, and n5 to n7 are the same as defined in Formula 1.

In an embodiment, the fused polycyclic compound represented by Formula 1 may be represented by Formula 3:

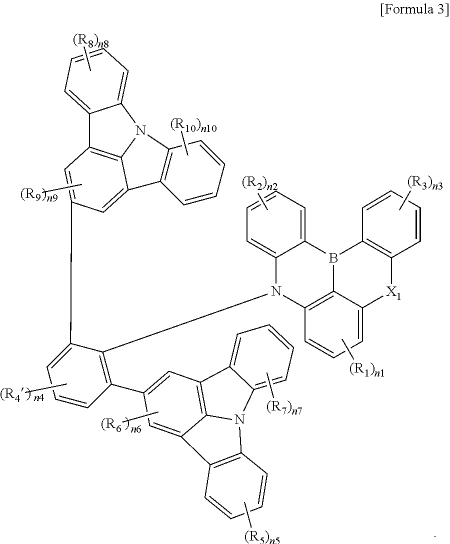

In Formula 3, R₄′, and R₅ to R₁₀, n4′, and n8 to n10 are the same as defined in Formula 3-a.

In Formula 3, X₁, R₁ to R₃, R₅ to R₇, n1 to n3, and n5 to n7 are the same as defined in Formula 1.

In an embodiment, the fused polycyclic compound may have a structure that includes first to third aromatic rings that are fused together via a first boron atom, a first nitrogen atom, and a second nitrogen atom. The fused polycyclic compound may further include a third substituent, in addition to the first substituent. The third substituent may include an indolocarbazole moiety. The third substituent may be connected to the second nitrogen atom of the fused ring core via a second linker. In an embodiment, the second linker may include a benzene moiety. For example, the second linker may be a substituted or unsubstituted phenylene linker. The fused polycyclic compound may include the first substituent connected to the first nitrogen atom via the first linker and the third substituent connected to the second nitrogen atom via the second linker. The first substituent may be bonded to the first linker at an ortho position to the first nitrogen atom, and the third substituent may be bonded to the second linker at an ortho position to the second nitrogen atom.

In an embodiment, the fused polycyclic compound represented by Formula 1 may be represented by Formula 4:

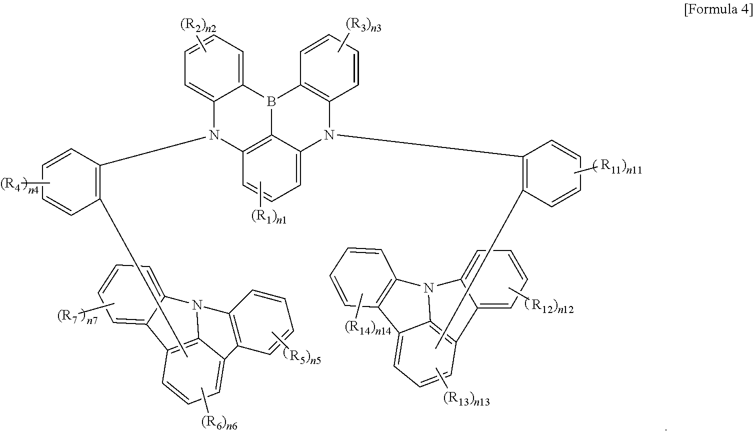

In Formula 4, R₁₁ to R₁₄ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring. For example, R₁₁ to R₁₄ may each independently be a hydrogen atom, a deuterium atom, a substituted or unsubstituted t-butyl group, a substituted or unsubstituted phenyl group, a substituted or unsubstituted biphenyl group, or a substituted or unsubstituted indolocarbazole group.

In Formula 4, n11, n12, and n14 may each independently be an integer from 0 to 4; n13 may be an integer from 0 to 3; and a sum of n12 and n13 is equal to or less than 6.

If n11, n12, and n14 are each 0, the fused polycyclic compound may not be substituted with R₁₁, R₁₂ and R₁₄, respectively. A case where n11, n12, and n14 are each 4 and all groups of each of R₁, R₁₂, and R₁₄ are hydrogen atoms may be the same as a case where n11, n12, and n14 are each 0. If n1, n12, and n14 are each 2 or more, multiple groups of each of R₁₁, R₁₂, and R₁₄ may be all the same, or at least one group thereof may be different from the remainder.

If n13 is 0, the fused polycyclic compound may not be substituted with R₁₃. A case where n13 is 3 and all R₁₃ groups are hydrogen atoms may be the same as a case where n13 is 0. If n13 is 2 or more, multiple groups of R₁₃ may be all the same, or at least one R₁₃ group may be different from the remainder.

In Formula 4, R₁ to R₇, and n1 to n7 are the same as defined in Formula 1.

In an embodiment, the fused polycyclic compound represented by Formula 4 may be represented by Formula 5:

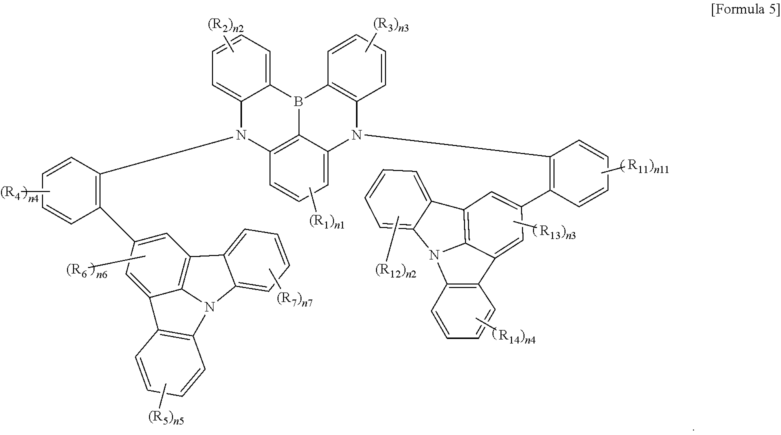

In Formula 5, Ru to R₁₄ and n11 to n14 are the same as defined in Formula 4.

In Formula 5, R₁ to R₇ and n1 to n7 are the same as defined in Formula 1.

In an embodiment, the fused polycyclic compound represented by Formula 4 may be represented by one of Formula 6-1 to Formula 6-4:

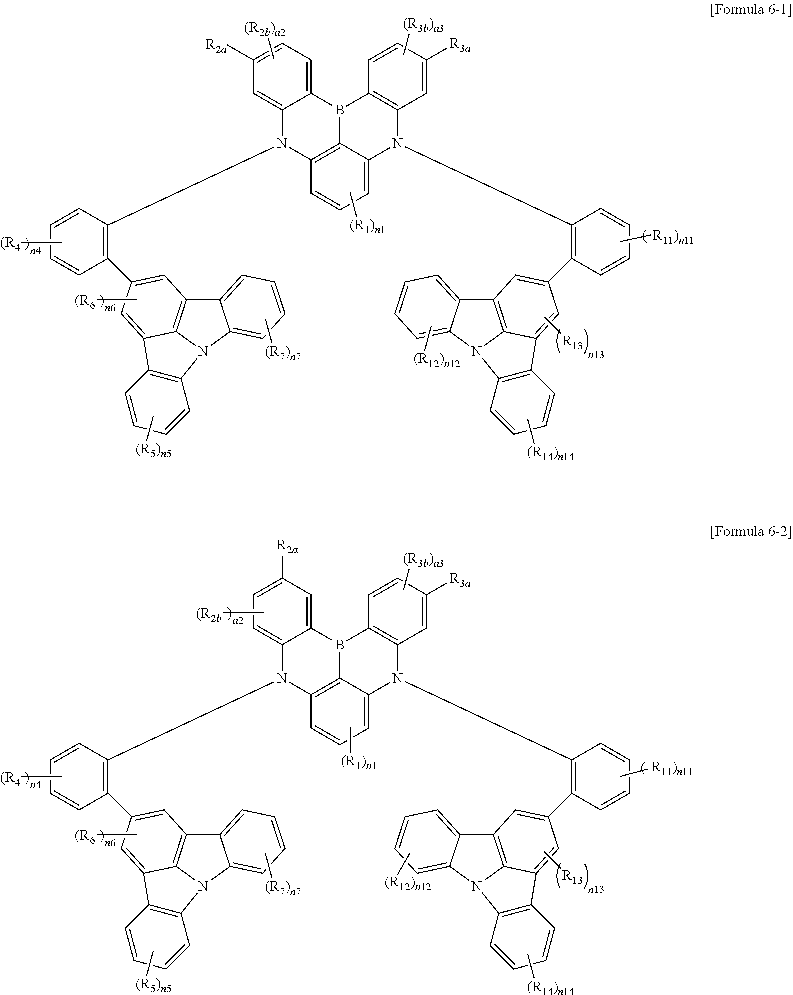

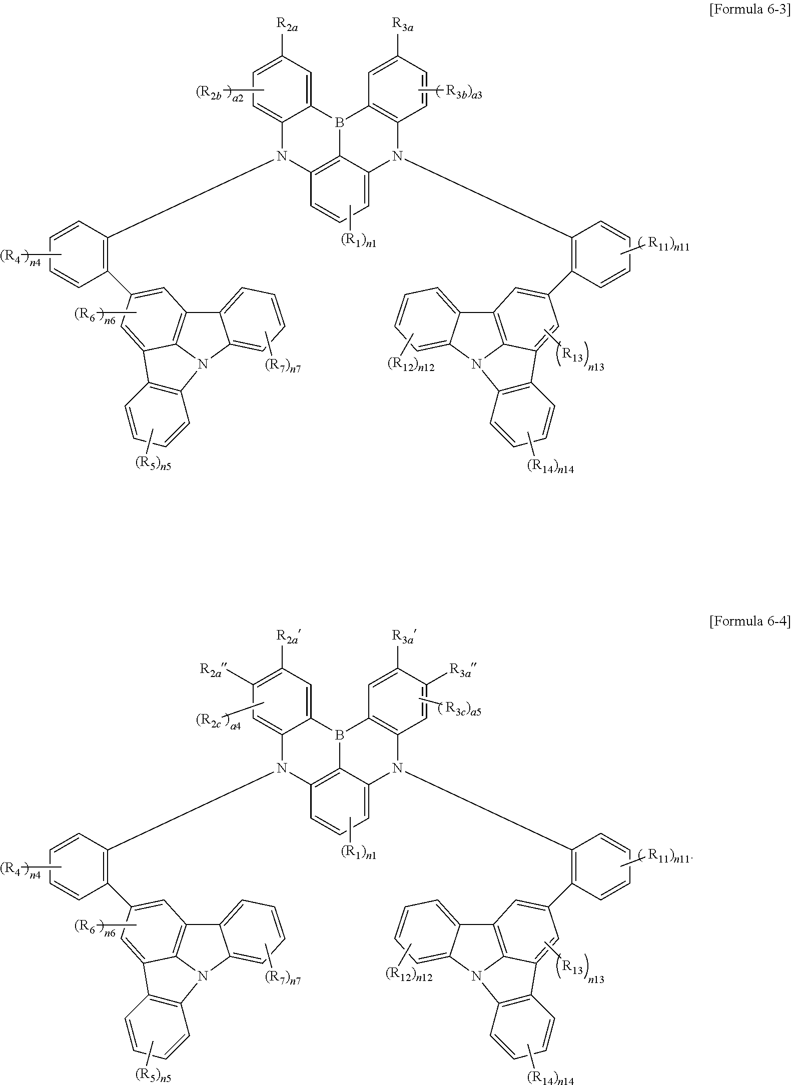

In Formula 6-1 to Formula 6-4, R₂ₐ, R₂ₐ′, R₂ₐ″, R₃ₐ, R₃ₐ′, and R₃ₐ″ may each independently be a group represented by one of Formula A-1 to Formula A-5.

In Formula 6-1 to Formula 6-4, R_{2b}, R_{3b}, R_{2c}, and R_{3c} may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R_{2b}, R_{3b}, R_{2c}, and R_{3c} may each be a hydrogen atom.

In Formula 6-1 to Formula 6-3, a2 and a3 may each independently be an integer from 0 to 3. If a2 and a3 are each 0, the fused polycyclic compound may not be substituted with R_{2b} and R_{3b}, respectively. A case where a2 and a3 are each 3 and all R_{2b} group and all R_{3b} groups are hydrogen atoms may be the same as a case where a2 and a3 are each 0. If a2 and a3 are each 2 or more, multiple R_{2b} groups and multiple R_{3b} groups may be all the same, or at least one group thereof may be different from the remainder.

In Formula 6-4, a4 and a5 may each independently be an integer from 0 to 2. If a4 and a5 are each 0, the fused polycyclic compound may not be substituted with R_{2c} and R_{3c}, respectively. A case where a4 and a5 are each 2 and all R₂, groups and all R_{3c} groups are hydrogen atoms may be the same as a case where a4 and a5 are each 0. If a4 and a5 are each 2, two R₂, groups and two R_{3c} groups may be all the same, or at least one group thereof may be different from the remainder.

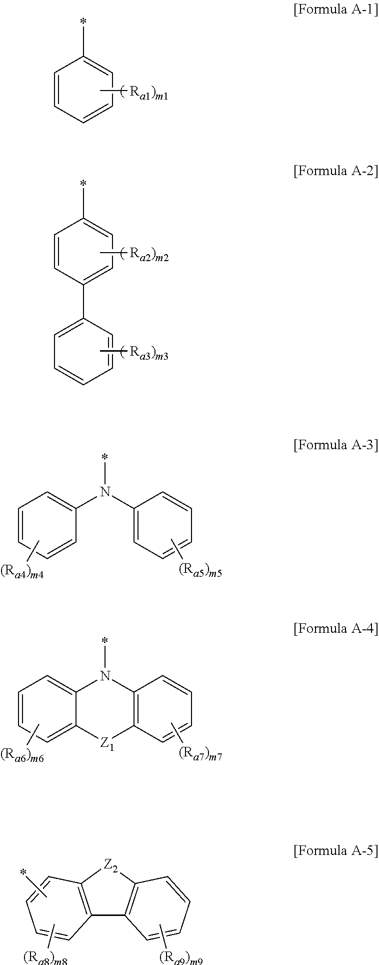

In Formula A-4, Z₁ may be a direct linkage, O, or C(Rₐ₁₀)(Rₐ₁₁). For example, Z₁ may be a direct linkage or C(Rₐ₁₃)(Rₐ₁₄).

In Formula A-5, Z₂ may be O, S, N(Rₐ₁₂), or C(Rₐ₁₃)(Rₐ₁₄). For example, Z₂ may be O, N(Rₐ₁₂), or C(Rₐ₁₃)(Rₐ₁₄).

In Formula A-1 to Formula A-5, Rₐ₁ to Rₐ₁₄ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Rₐ₁ to Rₐ₉ may each independently be a hydrogen atom, a deuterium atom, a cyano group, a substituted or unsubstituted t-butyl group, a substituted or unsubstituted phenyl group, or a substituted or unsubstituted biphenyl group. For example, Rₐ₁₀ to Rₐ₁₄ may each independently be a hydrogen atom, a substituted or unsubstituted methyl group, or a substituted or unsubstituted phenyl group.

In Formula A-1 to Formula A-5, m1, m3, m4, and m5 may each independently be an integer of 0 to 5; m2, m6, m7, and m9 may each independently be an integer from 0 to 4; and m8 may be an integer from 0 to 3.

If m1, m3, m4, and m5 are each 0, the fused polycyclic compound may not be substituted with Rₐ₁, Rₐ₃, Rₐ₄, and Rₐ₅, respectively. A case where m1, m3, m4, and m5 are each 5 and all groups of each of Rₐ₁, Rₐ₃, Rₐ₄, and Rₐ₅ are hydrogen atoms may be the same as a case where m1, m3, m4, and m5 are each 0. If m1, m3, m4, and m5 are each 2 or more, multiple groups of each of Rₐ₁, Rₐ₃, Rₐ₄, and Rₐ₅ may be all the same, or at least one group thereof may be different from the remainder.

If m2, m6, m7, and m9 are each 0, the fused polycyclic compound may not be substituted with Rₐ₂, Rₐ₆, Rₐ₇, and Rₐ₉, respectively. A case where m2, m6, m7, and m9 are each 4 and all groups of each of Rₐ₂, Rₐ₆, Rₐ₇, and Rₐ₉ are hydrogen atoms may be the same as a case where m2, m6, m7, and m9 are each 0. If m2, m6, m7, and m9 are each 2 or more, multiple groups of each of Rₐ₂, Rₐ₆, Rₐ₇, and Rₐ₉ may be all the same, or at least one group thereof may be different from the remainder.

In Formula 6-1 to Formula 6-4, R₁, R₄ to R₇, n1, and n4 to n7 are the same as defined in Formula 1; and R₁₁ to R₁₄ and n11 to n14 are the same as defined in Formula 4.

In an embodiment, the fused polycyclic compound may further include at least one of a second substituent, a third substituent, and a fourth substituent, in addition to the first substituent. For example, the fused polycyclic compound may include a first substituent, a second substituent, and a third substituent. As another example, the fused polycyclic compound may include a first substituent, a second substituent, a third substituent, and a fourth substituent. The second and third substituents may be the same as defined in Formula 3-a and Formula 4, respectively. The fourth substituent may include an indolocarbazole moiety. The third substituent and the fourth substituent may each be connected to the second nitrogen atom of the fused ring core via the second linker. The third and fourth substituents may each be bonded to the fused ring core via the second linker at an ortho position to the second nitrogen atom. The third and fourth substituents may each be bonded to a carbon atom that is at an ortho position with respect to a carbon atom of the second linker that is bonded to the second nitrogen atom of the fused ring core.

In an embodiment, the fused polycyclic compound represented by Formula 4 may be represented by Formula 7-1 or Formula 7-2:

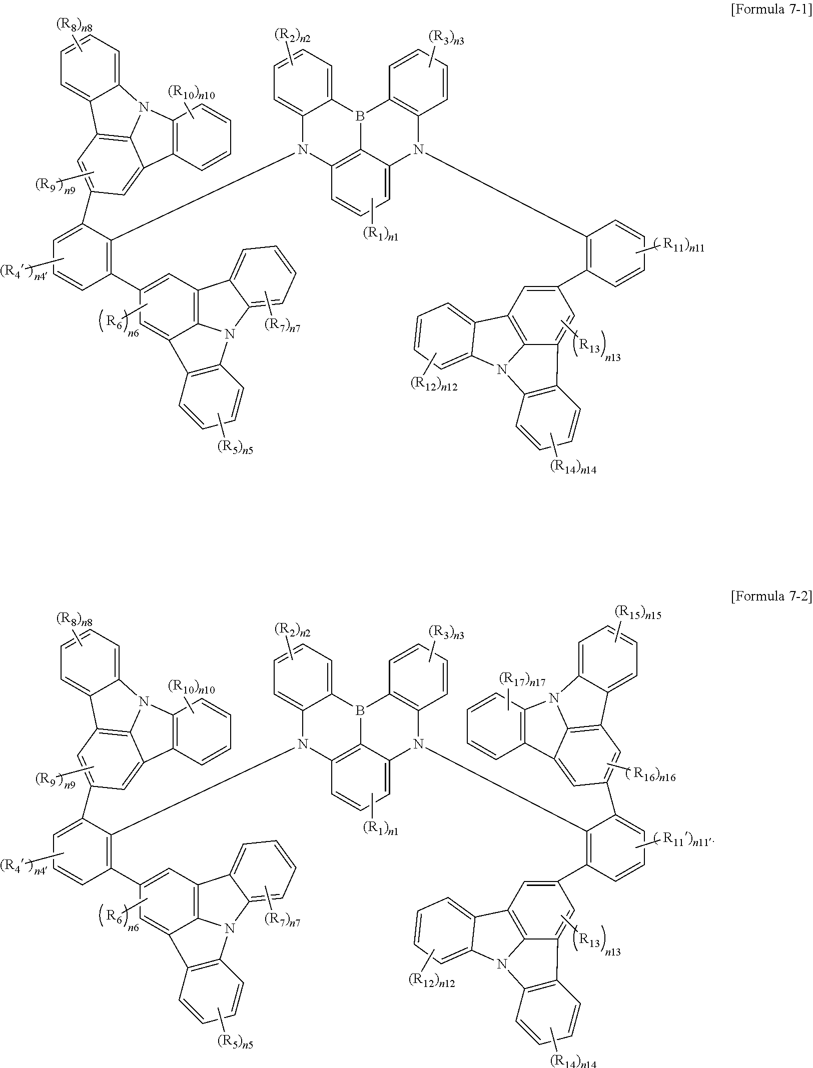

In Formula 7-1 and Formula 7-2, R₄′, R₈ to R₁₀, R₁₁′, and R₁₅ to R₁₇ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula 7-1 and Formula 7-2, n4′ and n11′ may each independently be an integer from 0 to 3; n8, n10, n15, and n17 may each independently be an integer from 0 to 4; and n9 and n16 may each independently be an integer from 0 to 2.

If n4′ and n11′ are each 0, the fused polycyclic compound may not be substituted with R₄‘ and Ru’, respectively. A case where n4′ and n11′ are each 3 and all R₄′ groups and all R₁₁′ groups are hydrogen atoms may be the same as a case where n4′ and n11′ are each 0. If n4′ and n11′ are each 2 or more, multiple R₄′ groups and multiple R₁₁′ groups may be all the same, or at least one group thereof may be different from the remainder.

If n8, n10, n15, and n17 are each 0, the fused polycyclic compound may not be substituted with R₈, R₁₀, R₁₅, and R₁₇, respectively. A case where n8, n10, n15, and n17 are each 4 and all groups of each of R₈, R₁₀, R₁₅, and R₁₇ are hydrogen atoms may be the same as a case where n8, n10, n15, and n17 are each 0. If n8, n10, n15, and n17 are each 2 or more, multiple groups of each of R₈, R₁₀, R₁₅, and R₁₇ may be all the same, or at least one group thereof may be different from the remainder.

If n9 and n16 are each 0, the fused polycyclic compound may not be substituted with R₉ and R₁₀, respectively. A case where n9 and n16 are each 2 and all R₉ groups and all R₁₆ groups are hydrogen atoms may be the same as a case where n9 and n16 are each 0. If n9 and n16 are each 2 or more, multiple R₉ groups and multiple R₁₆ groups may be all the same, or at least one group thereof may be different from the remainder.

In Formula 7-1 and Formula 7-2, R₁ to R₃, R₅ to R₇, n1 to n3, and n5 to n7 are the same as defined in Formula 1; and R₁₁ to R₁₄ and n11 to n14 are the same as defined in Formula 4.

In an embodiment, the fused polycyclic compound represented by Formula 1 may be represented by Formula 8-1 or Formula 8-2:

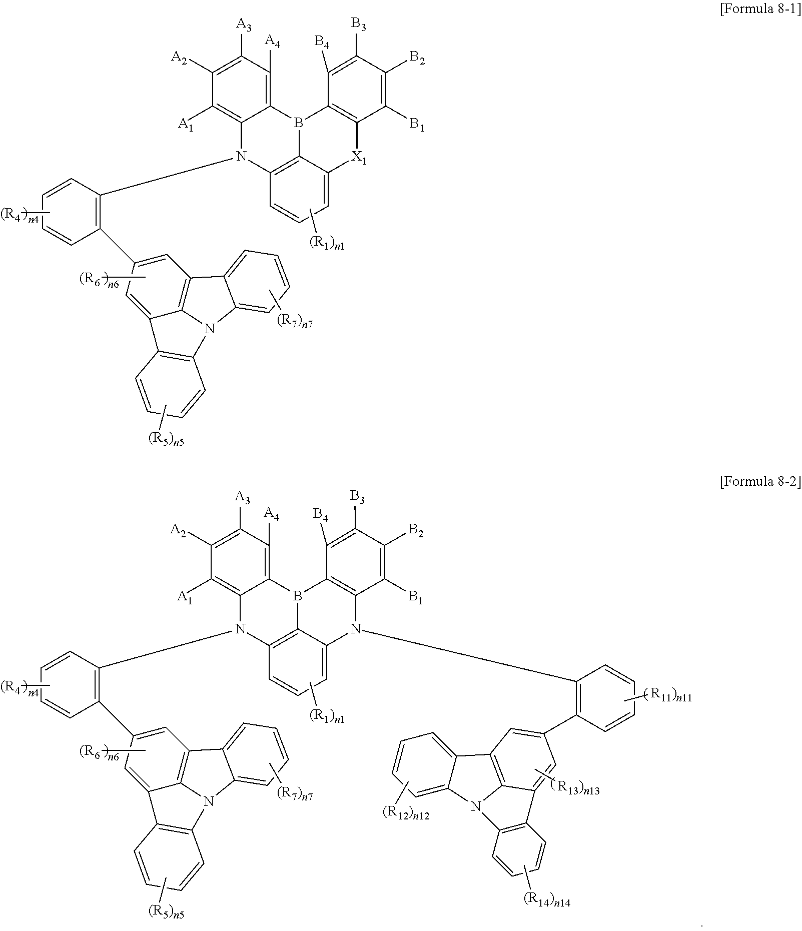

In Formula 8-1 and Formula 8-2, A₁ to A₄, B₁ to B₄, and R₁₁ to R₁₄ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring.

In Formula 8-2, n11, n12, and n14 may each independently be an integer from 0 to 4; and n13 may be an integer from 0 to 2.

If n11, n12, and n14 are each 0, the fused polycyclic compound may not be substituted with R₁₁, R₁₂, and R₁₄, respectively. A case where n11, n12, and n14 are each 4 and all groups of each of R₁, R₁₂, and R₁₄ are hydrogen atoms may be the same as a case where n11, n12, and n14 are each 0. If n11, n12, and n14 are each 2 or more, multiple groups of each of Rn, R₁₂, and R₁₄ may be all the same, or at least one group thereof may be different from the remainder.

If n13 is 0, the fused polycyclic compound may not be substituted with R₁₃. A case where n13 is 2 and all R₁₃ groups are hydrogen atoms may be the same as a case where n13 is 0. If n13 is 2, two R₁₃ groups may be all the same, or one R₁₃ group may be different from another R₁₃ group.

In Formula 8-1 and Formula 8-2, at least one adjacent pair among A₁ to A₄ and at least one adjacent pair among B₁ to B4 may each independently be fused with a group represented by Formula B-1 or Formula B-2. For example, at least one adjacent pair among A₁ to A₄ and at least one adjacent pair among B₁ to B4 may each independently form a fused ring with a group represented by Formula B-2. For example, in Formula 8-1 and Formula 8-2, A₂ and A₃, and B₂ and B₃ may each independently be combined with a group represented by Formula B-2 to form a fused ring. As another example, in Formula 8-1 and Formula 8-2, A₁ and A₂, and B₁ and B₂ may each independently be combined with a group represented by Formula B-2 to form a fused ring.

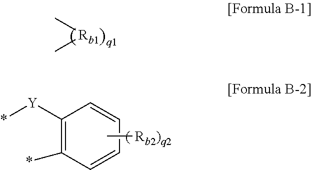

In Formula B-1, R_{b1} may be C(R_{b3})(R_{b4}), or N(R_{b5}).

In Formula B-2, Y may be O, S, N(R_{b6}), or C(R_{b7})(R_{b8}). For example, Y may be O, N(R_{b6}), or C(R_{b7})(R_{b8}).

In Formula B-1 and Formula B-2, R_{b2} to R_{b8} may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring. For example, R_{b2} to R_{b8} may each independently be a hydrogen atom, a substituted or unsubstituted methyl group, a substituted or unsubstituted ethyl group, or a substituted or unsubstituted phenyl group.

In Formula B-1, q1 may be 3 or 4. In an embodiment, q1 may be 4. In Formula B-1, if q1 is 3, Formula B-1 may be represented by Formula B-1a. In Formula B-1, if q1 is 4, Formula B-1 may be represented by Formula B-1b.

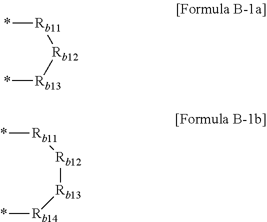

In Formula B-1a and Formula B-1b, R_{b1} to R_{b14} may each independently be C(R_{b3})(R_{b4}), or N(R_{b5}). For example, in Formula B-1a, R_{b1} to R_{b13} may each independently be C(R_{b3})(R_{b4}). For example, in Formula B-1b, R_{b1} to R_{b14} may each independently be C(R_{b3})(R_{b4}). As another example, in Formula B-1b, at least one of R_{b1} to R_{b14} may each independently be N(R_{b5}), and the remainder R_{b1} to R_{b14} may each independently be C(R_{b3})(R_{b4}). For example, in Formula B-1b, R_{b11} may be N(R_{b5}), and R_{b12} to R_{b14} may each independently be C(R_{b3})(R_{b4}). In Formula B-1a and Formula B-1b, R_{b3} to R_{b5} are the same as defined in Formula B-1.

In Formula B-2, q2 may be an integer from 0 to 4. If q2 is 0, the fused polycyclic compound may not be substituted with R_{b2}. In Formula B-2, a case where q2 is 4 and all R_{b2} groups are hydrogen atoms may be the same as a case where q2 is 0. If q2 is 2 or more, multiple R_{b2} groups may be all the same, or at least one R_{b2} group may be different from the remainder.

In Formula 8-1 and Formula 8-2, X₁, R₁, R₄ to R₇, n1, and n4 to n7 are the same as defined in Formula 1.

In an embodiment, the fused polycyclic compound represented by Formula 1 may be represented by Formula 9-1 or Formula 9-2:

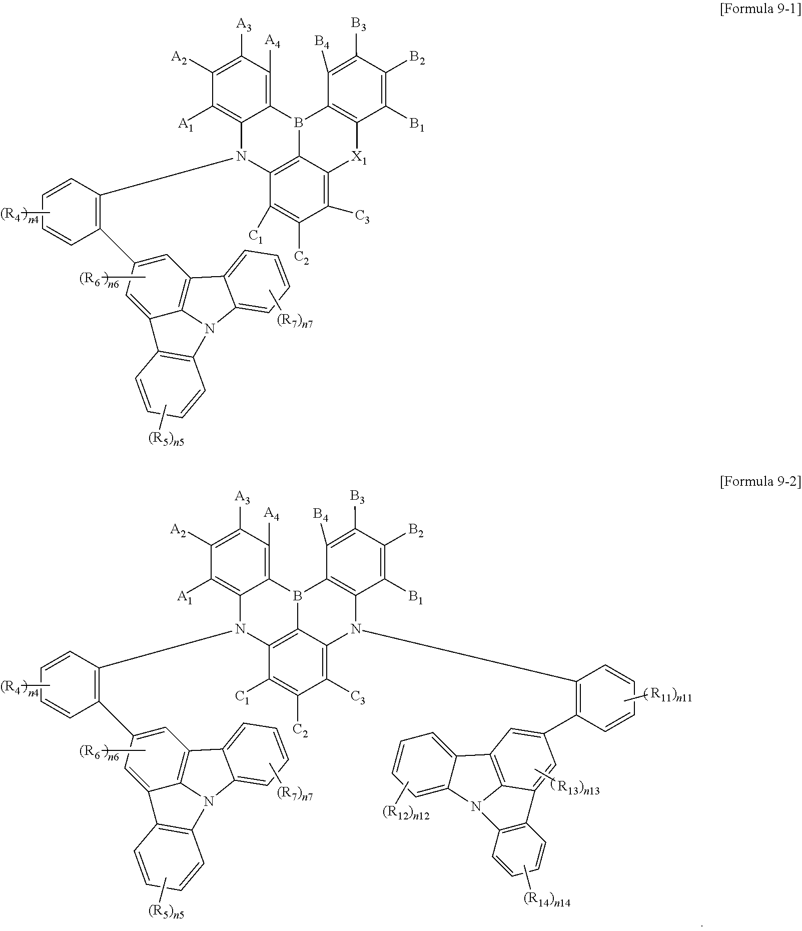

In Formula 9-1 and Formula 9-2, A₁ to A₄, B₁ to B₄, C₁ to C₃, and R₁₁ to R₁₄ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring.

In Formula 9-2, n11, n12, and n14 may each independently be an integer from 0 to 4; and n13 may be an integer from 0 to 2.

If n11, n12, and n14 are 0, the fused polycyclic compound may not be substituted with R₁₁, R₁₂, and R₁₄, respectively. A case where n11, n12, and n14 are each 4 and all groups of each of R₁, R₁₂, and R₁₄ are hydrogen atoms may be the same as a case where n11, n12, and n14 are each 0. If n11, n12, and n14 are each 2 or more, multiple groups of each of Rn, R₁₂, and R₁₄ may be all the same, or at least one group thereof may be different from the remainder.

If n13 is 0, the fused polycyclic compound may not be substituted with R₁₃. A case where n13 is 2 and all R₁₃ groups are hydrogen atoms may be the same as a case where n13 is 0. If n13 is 2, two R₁₃ groups may be all the same, or one R₁₃ group may be different from another R₁₃ group.

In Formula 9-1 and Formula 9-2, at least one A₁ to A₄, B₁ to B₄, and C₁ to C₃ may each independently be a group selected from Substituent Group 1.

In Formula 9-1 and Formula 9-2, X₁, R₄ to R₇, and n4 to n7 are the same as defined in Formula 1.

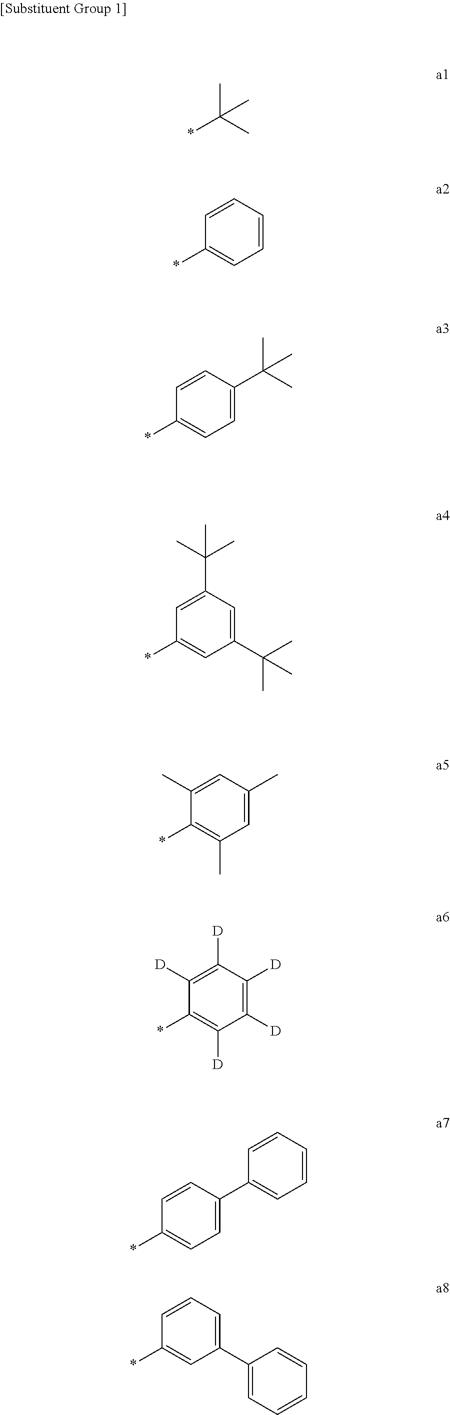

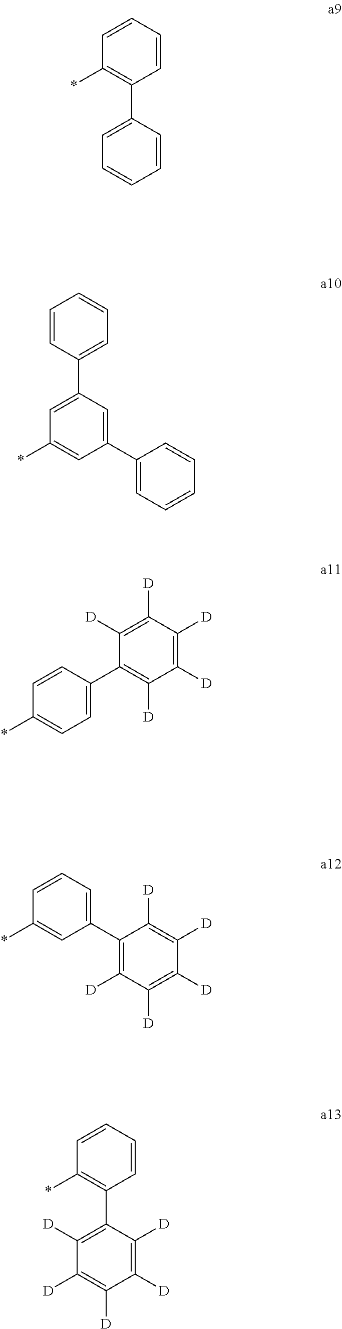 [SMILES: *c1ccccc1-c1ccccc1 ; *c1cc(-c2ccccc2)cc(-c2ccccc2)c1 ; *c1ccc(-c2c([2H])c([2H])c([2H])c([2H])c2[2H])cc1 ; *c1cccc(-c2c([2H])c([2H])c([2H])c([2H])c2[2H])c1 ; *c1ccccc1-c1c([2H])c([2H])c([2H])c([2H])c1[2H]]

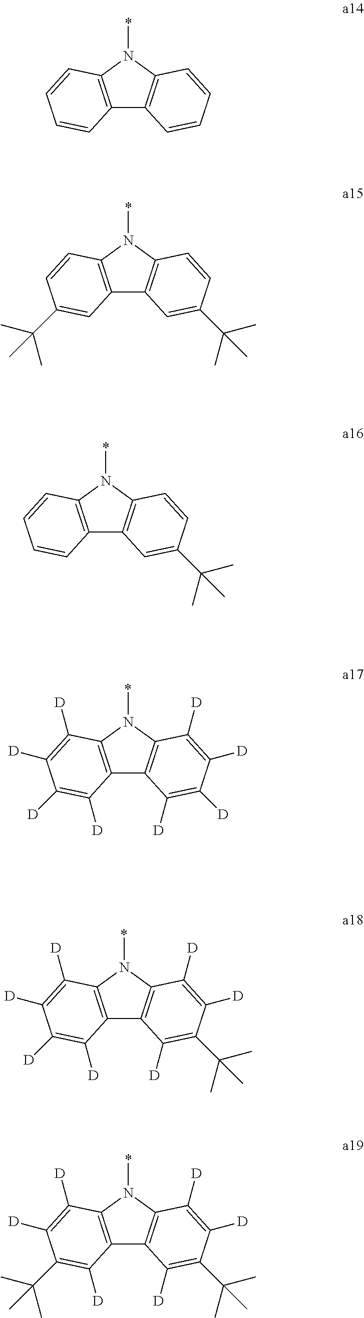

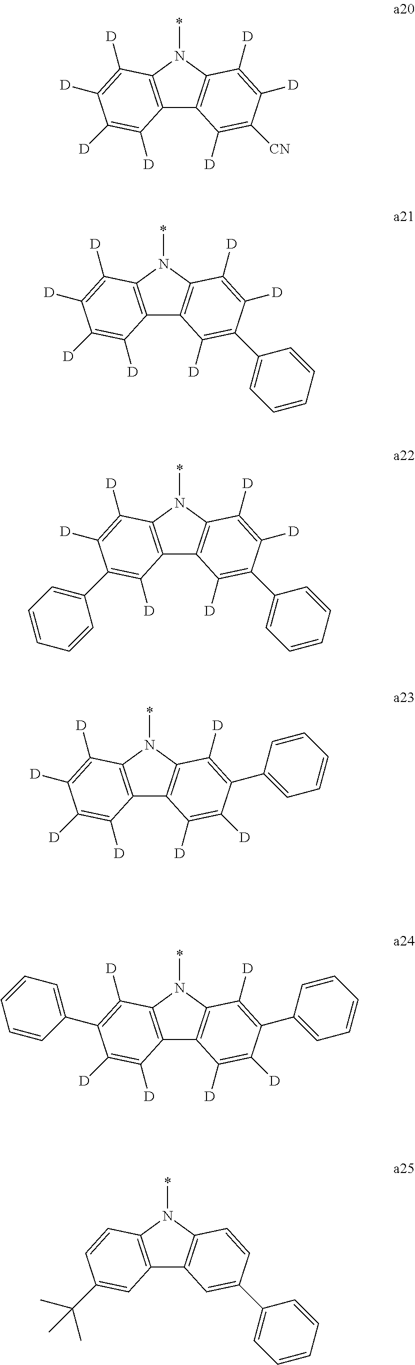 [SMILES: *n1c2c([2H])c([2H])c([2H])c([2H])c2c2c([2H])c(C#N)c([2H])c([2H])c21 ; *n1c2c([2H])c([2H])c([2H])c([2H])c2c2c([2H])c(-c3ccccc3)c([2H])c([2H])c21 ; *n1c2c([2H])c([2H])c(-c3ccccc3)c([2H])c2c2c([2H])c(-c3ccccc3)c([2H])c([2H])c21 ; *n1c2c([2H])c([2H])c([2H])c([2H])c2c2c([2H])c([2H])c(-c3ccccc3)c([2H])c21 ; *n1c2c([2H])c(-c3ccccc3)c([2H])c([2H])c2c2c([2H])c([2H])c(-c3ccccc3)c([2H])c21 ; *n1c2ccc(-c3ccccc3)cc2c2cc(C(C)(C)C)ccc21]

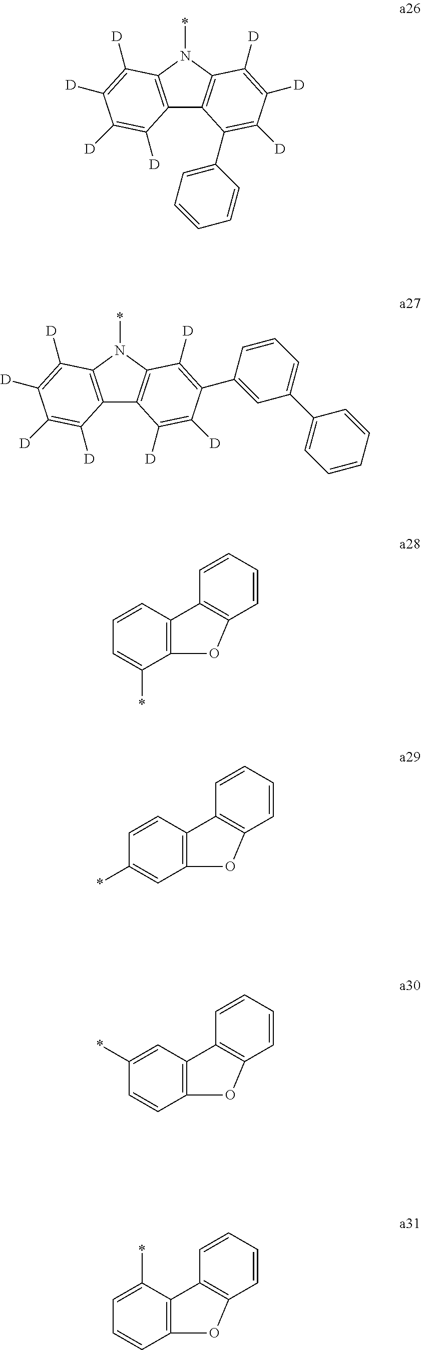 [SMILES: *n1c2c([2H])c([2H])c([2H])c([2H])c2c2c(-c3ccccc3)c([2H])c([2H])c([2H])c21 ; *n1c2c([2H])c([2H])c([2H])c([2H])c2c2c([2H])c([2H])c(-c3cccc(-c4ccccc4)c3)c([2H])c21 ; *c1cccc2c1oc1ccccc12 ; *c1ccc2c(c1)oc1ccccc12 ; *c1ccc2oc3ccccc3c2c1 ; *c1cccc2oc3ccccc3c12]

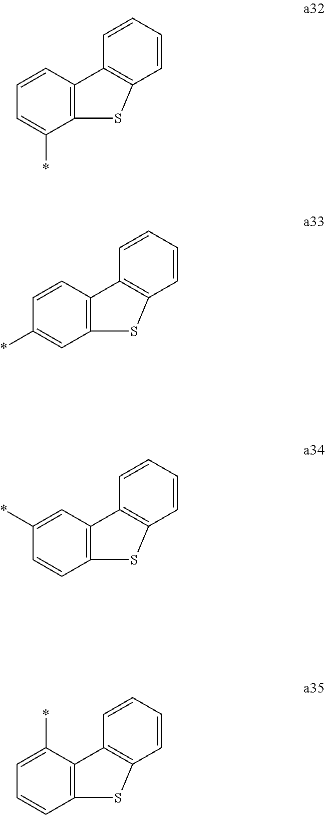 [SMILES: *c1cccc2c1sc1ccccc12 ; *c1ccc2c(c1)sc1ccccc12 ; *c1ccc2sc3ccccc3c2c1 ; *c1cccc2sc3ccccc3c12]

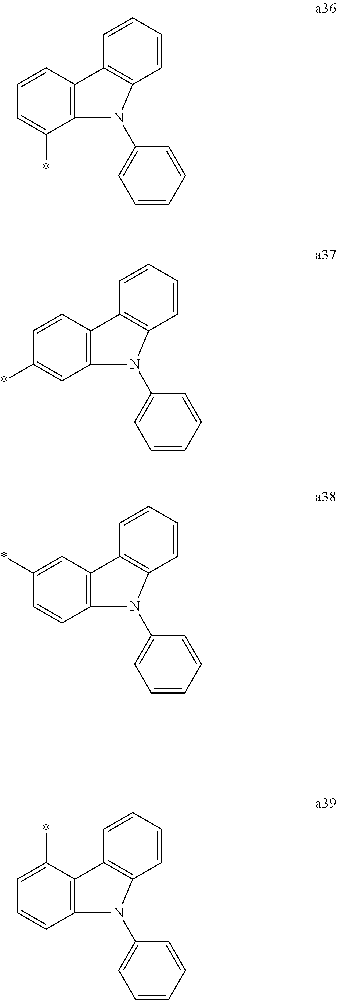 [SMILES: *c1cccc2c3ccccc3n(-c3ccccc3)c12 ; *c1ccc2c3ccccc3n(-c3ccccc3)c2c1 ; *c1ccc2c(c1)c1ccccc1n2-c1ccccc1 ; *c1cccc2c1c1ccccc1n2-c1ccccc1]

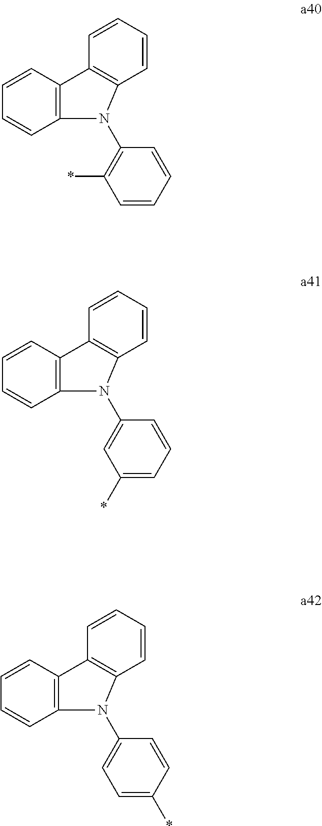 [SMILES: *c1ccccc1-n1c2ccccc2c2ccccc21 ; *c1cccc(-n2c3ccccc3c3ccccc32)c1 ; *c1ccc(-n2c3ccccc3c3ccccc32)cc1]

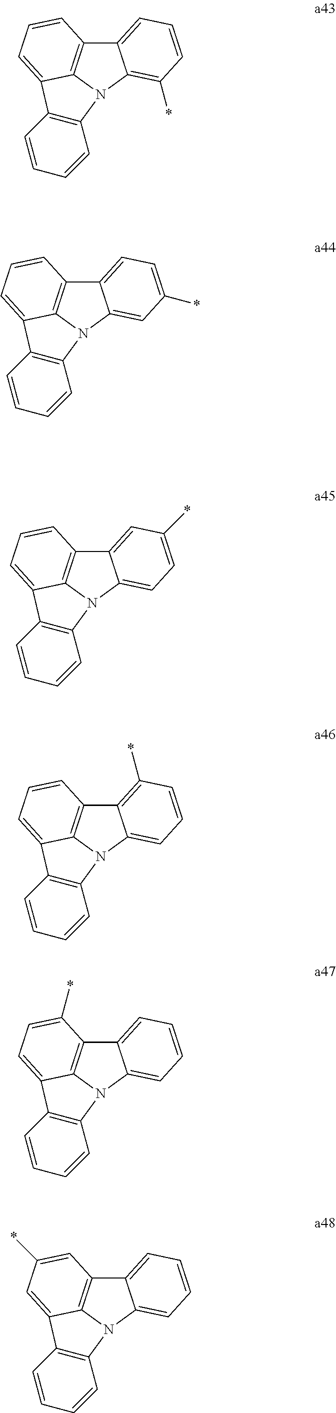

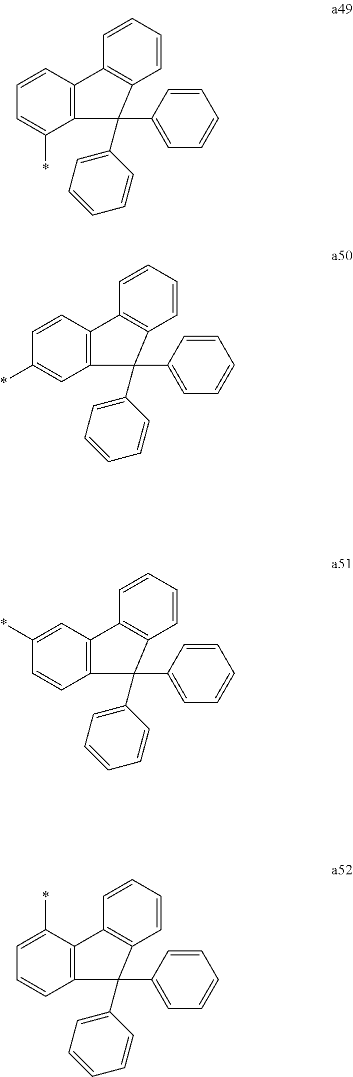 [SMILES: *c1cccc2c1C(c1ccccc1)(c1ccccc1)c1ccccc1-2 ; *c1ccc2c(c1)C(c1ccccc1)(c1ccccc1)c1ccccc1-2 ; *c1ccc2c(c1)-c1ccccc1C2(c1ccccc1)c1ccccc1 ; *c1cccc2c1-c1ccccc1C2(c1ccccc1)c1ccccc1]

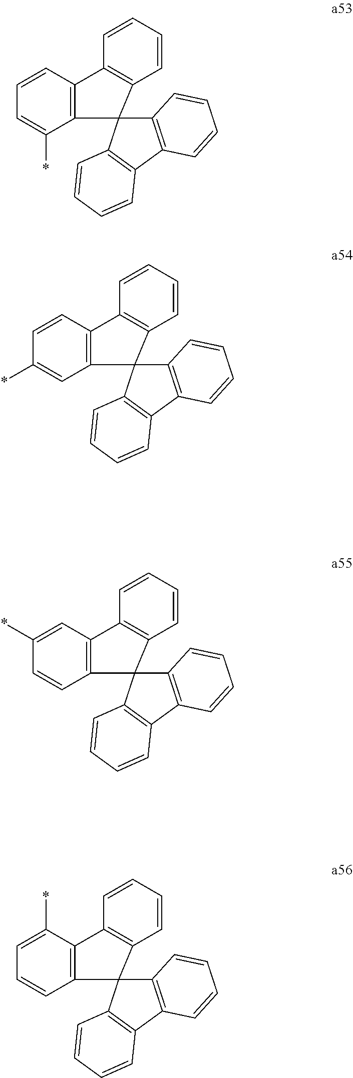 [SMILES: *c1cccc2c1C1(c3ccccc3-c3ccccc31)c1ccccc1-2 ; *c1ccc2c(c1)C1(c3ccccc3-c3ccccc31)c1ccccc1-2 ; *c1ccc2c(c1)-c1ccccc1C21c2ccccc2-c2ccccc21 ; *c1cccc2c1-c1ccccc1C21c2ccccc2-c2ccccc21]

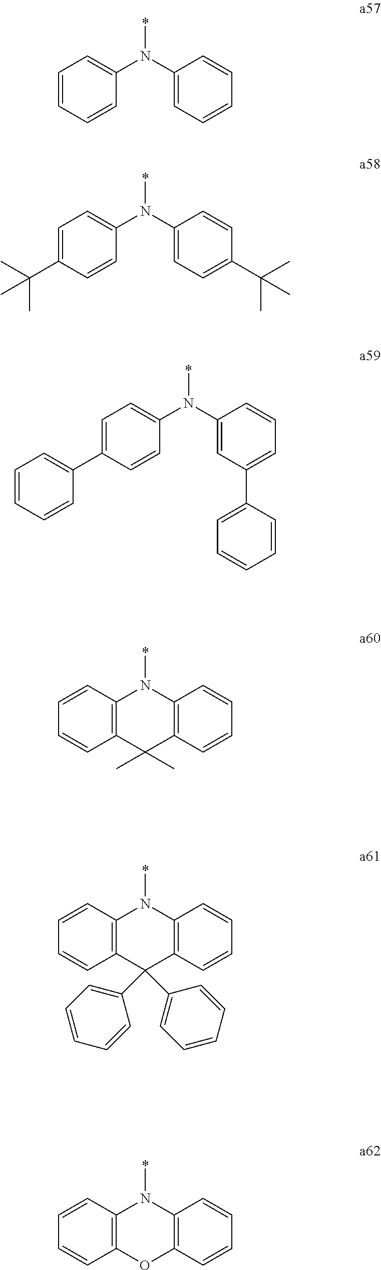 [SMILES: *N(c1ccccc1)c1ccccc1 ; *N(c1ccc(C(C)(C)C)cc1)c1ccc(C(C)(C)C)cc1 ; *N(c1ccc(-c2ccccc2)cc1)c1cccc(-c2ccccc2)c1 ; *N1c2ccccc2C(C)(C)c2ccccc21 ; *N1c2ccccc2C(c2ccccc2)(c2ccccc2)c2ccccc21 ; *N1c2ccccc2Oc2ccccc21]

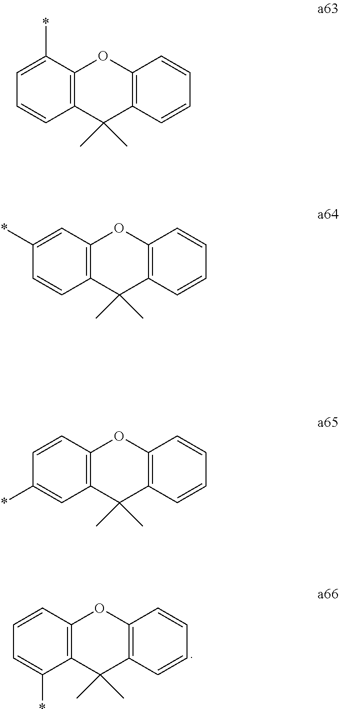 [SMILES: *c1cccc2c1Oc1ccccc1C2(C)C ; *c1ccc2c(c1)Oc1ccccc1C2(C)C ; *c1ccc2c(c1)C(C)(C)c1ccccc1O2 ; *c1cccc2c1C(C)(C)c1ccccc1O2]

In an embodiment, the fused polycyclic compound represented by Formula 1 may be represented by one of Formula 10-1 to Formula 10-4:

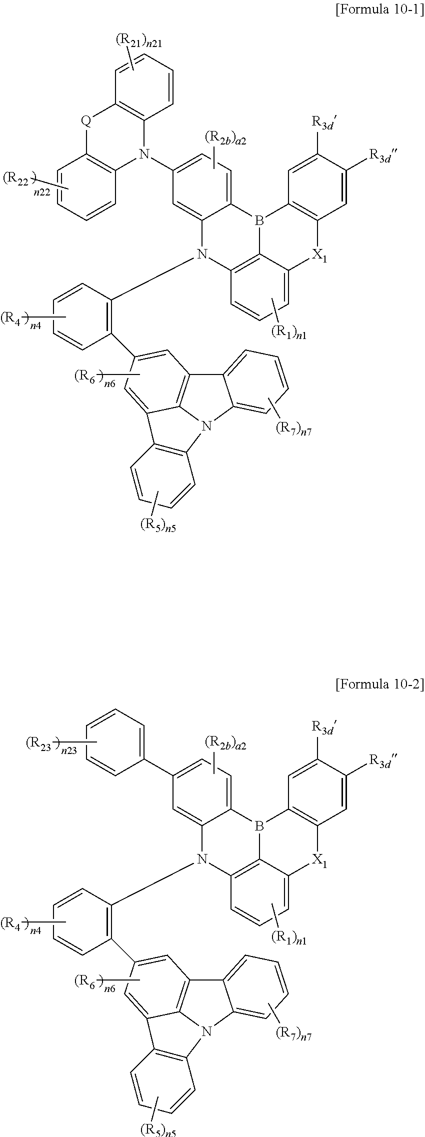

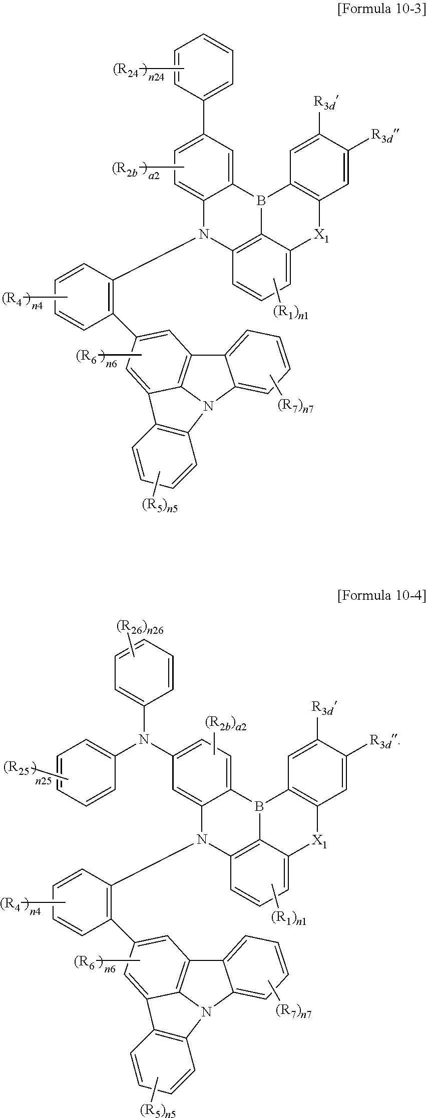

In Formula 10-1, Q may be a direct linkage, O, or C(R₂₇)(R₂₈). For example, Q may be a direct linkage or C(R₂₇)(R₂₈).

In Formula 10-1 to Formula 10-4, R_{3d}′ and R_{3d}″ may each independently be a hydrogen atom or a group represented by one of Formula A-1 to Formula A-5. In an embodiment, R_{3d}′ and R_{3d}″ may each independently be a hydrogen atom or a group selected from Substituent Group 1.

In Formula 10-1 to Formula 10-4, R₂₁ to R₂₈ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₂₁ to R₂₆ may each independently be a hydrogen atom, a deuterium atom, a cyano group, a substituted or unsubstituted t-butyl group, a substituted or unsubstituted phenyl group, or a substituted or unsubstituted biphenyl group. For example, R₂₇ and R₂₈ may each independently be a substituted or unsubstituted methyl group or a substituted or unsubstituted phenyl group.

In Formula 10-1, n21 and n22 may each independently be an integer from 0 to 4. If n21 and n22 are each 0, the fused polycyclic compound may not be substituted with R₂₁ and R₂₂, respectively. A case where n21 and n22 are each 4 and all R₂₁ groups and all R₂₂ groups are hydrogen atoms may be the same as a case where n21 and n22 are each 0. If n21 and n22 are each 2 or more, multiple R₂₁ groups and multiple R₂₂ groups may be all the same, or at least one group thereof may be different from the remainder.

In Formula 10-2 and Formula 10-4, n23 to n26 may each independently be an integer from 0 to 5. If n23 to n26 are each 0, the fused polycyclic compound may not be substituted with R₂₃ to R₂₆, respectively. A case where n23 to n26 are each 5 and all groups of each of R₂₃ to R₂₆ are hydrogen atoms may be the same as a case where n23 to n26 are each 0. If n23 to n26 are each 2 or more, multiple groups of each of R₂₃ to R₂₆ may be all the same, or at least one group thereof may be different from the remainder.

In Formula 10-1 to Formula 10-4, X₁, R₁, R₄ to R₇, n1, and n4 to n7 are the same as defined in Formula 1.

In an embodiment, the fused polycyclic compound represented by Formula 1 may include at least one deuterium atom as a substituent.

In an embodiment, the fused polycyclic compound may be any compound selected from Compound Group 1. In an embodiment, in the light emitting element ED, the at least one functional layer (for example, an emission layer EML) may include at least one fused polycyclic compound selected from Compound Group 1:

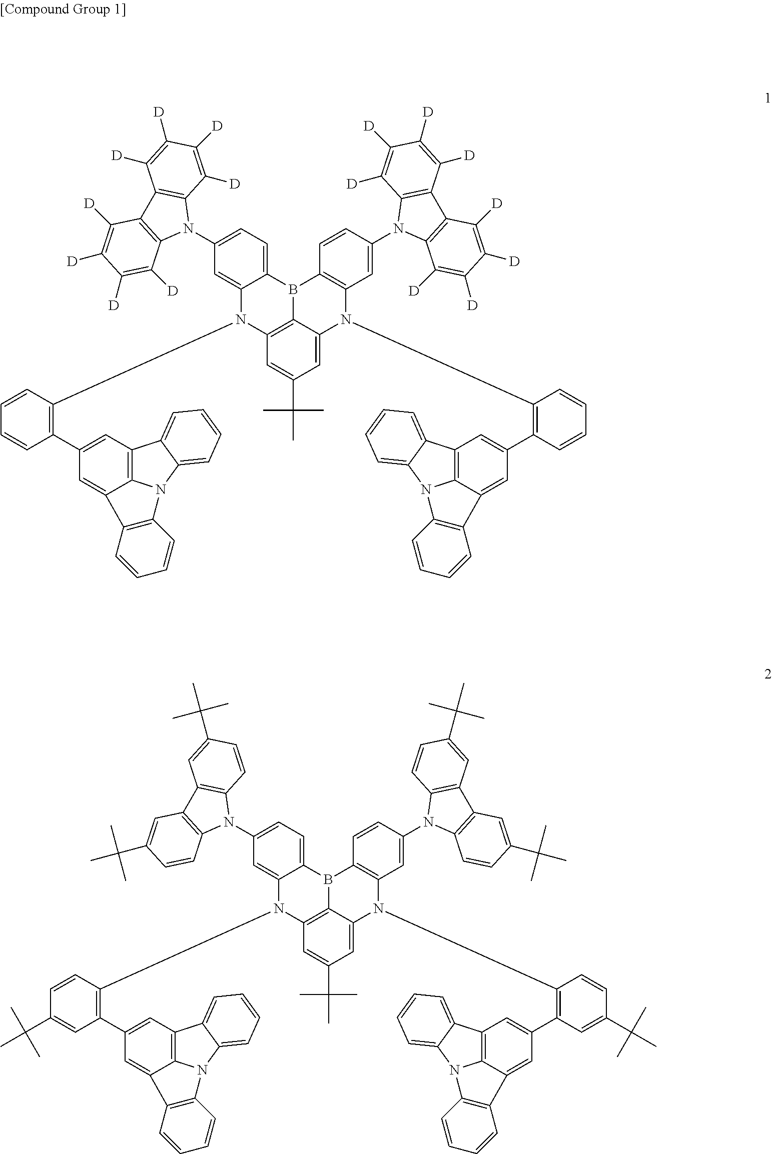 [SMILES: [2H]c1c([2H])c([2H])c2c(c1[2H])c1c([2H])c([2H])c([2H])c([2H])c1n2-c1ccc2c(c1)N(c1ccccc1-c1cc3c4ccccc4n4c5ccccc5c(c1)c34)c1cc(C(C)(C)C)cc3c1B2c1ccc(-n2c4c([2H])c([2H])c([2H])c([2H])c4c4c([2H])c([2H])c([2H])c([2H])c42)cc1N3c1ccccc1-c1cc2c3ccccc3n3c4ccccc4c(c1)c23 ; CC(C)(C)c1ccc(N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(C(C)(C)C)cc4-c4cc5c6ccccc6n6c7ccccc7c(c4)c56)c4cc(C(C)(C)C)cc2c43)c(-c2cc3c4ccccc4n4c5ccccc5c(c2)c34)c1]

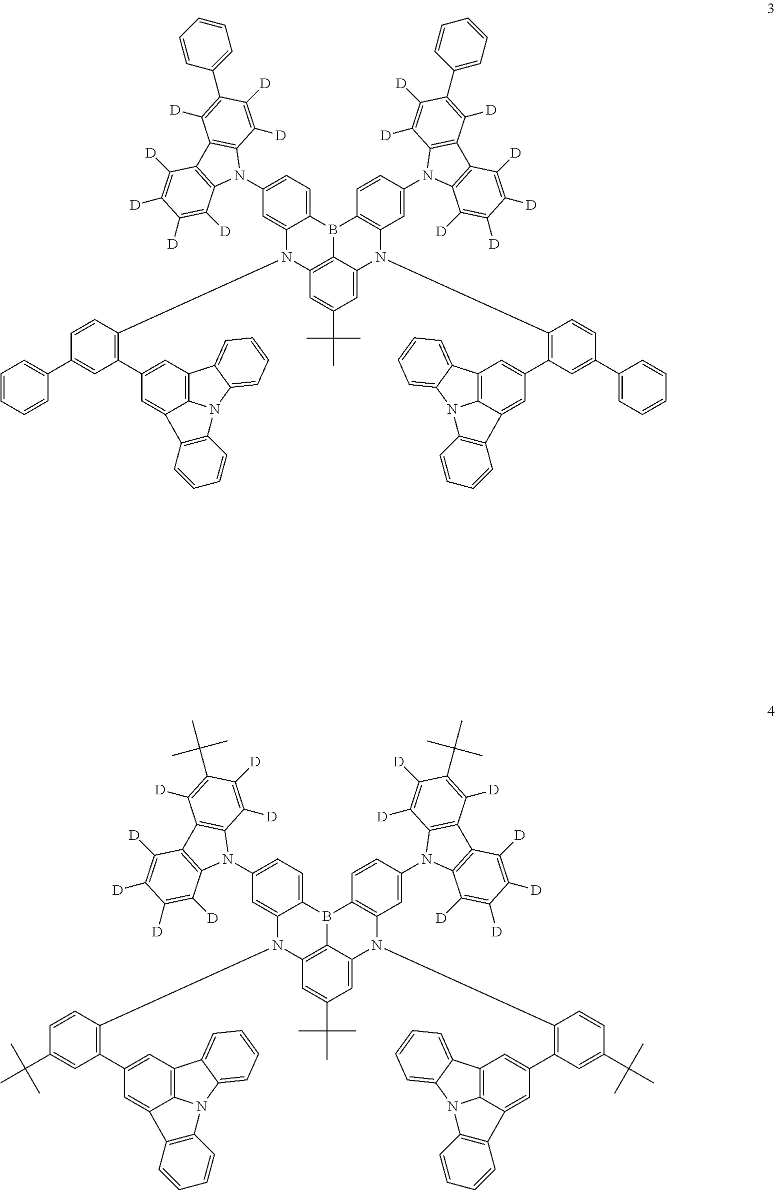

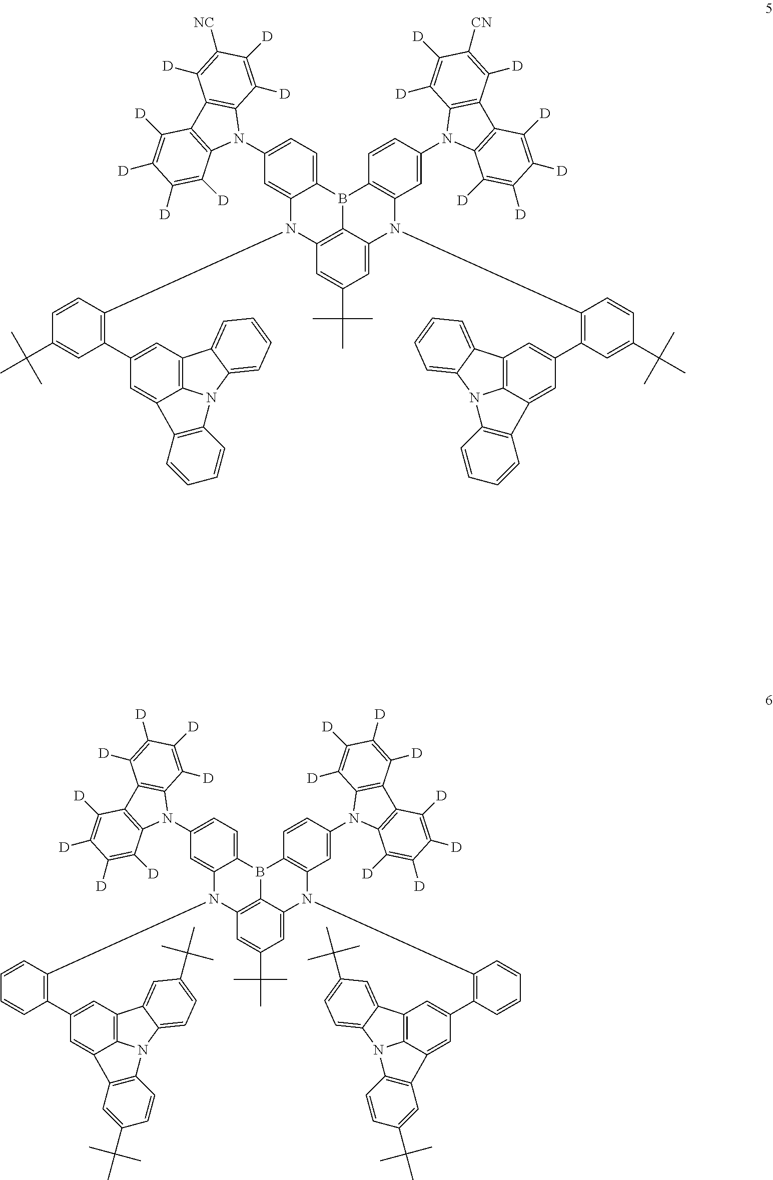

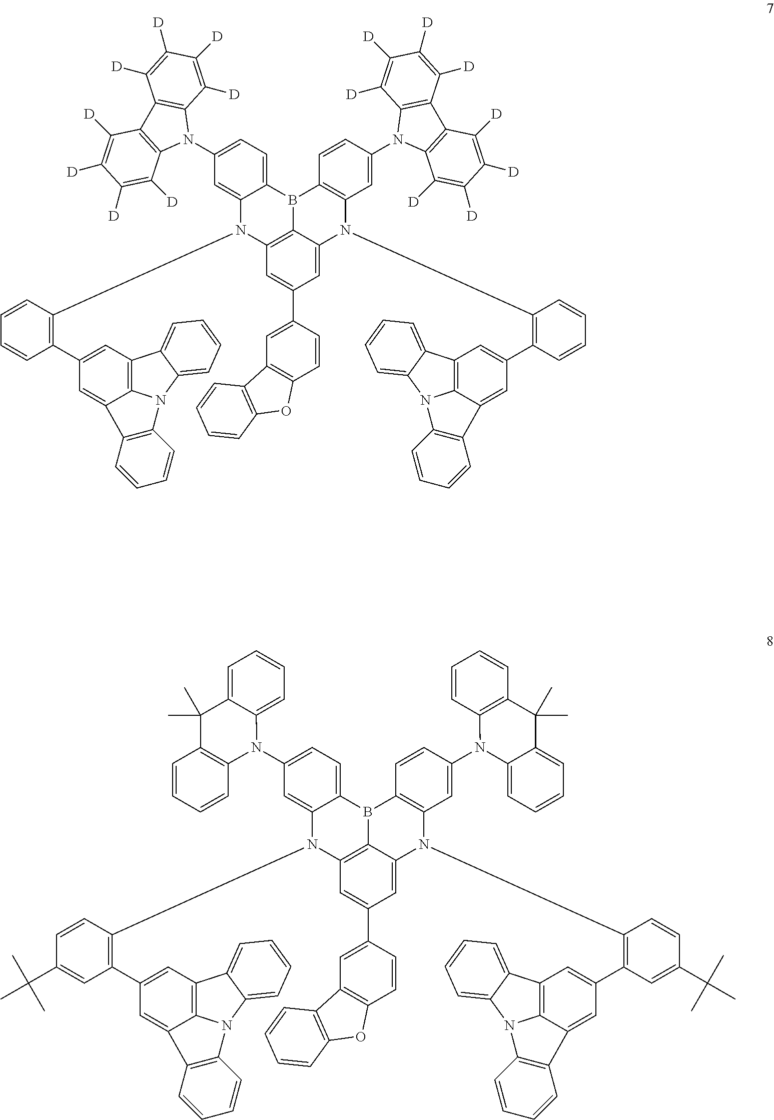 [SMILES: [2H]c1c([2H])c([2H])c2c(c1[2H])c1c([2H])c([2H])c([2H])c([2H])c1n2-c1ccc2c(c1)N(c1ccccc1-c1cc3c4ccccc4n4c5ccccc5c(c1)c34)c1cc(-c3ccc4oc5ccccc5c4c3)cc3c1B2c1ccc(-n2c4c([2H])c([2H])c([2H])c([2H])c4c4c([2H])c([2H])c([2H])c([2H])c42)cc1N3c1ccccc1-c1cc2c3ccccc3n3c4ccccc4c(c1)c23 ; CC(C)(C)c1ccc(N2c3cc(N4c5ccccc5C(C)(C)c5ccccc54)ccc3B3c4ccc(N5c6ccccc6C(C)(C)c6ccccc65)cc4N(c4ccc(C(C)(C)C)cc4-c4cc5c6ccccc6n6c7ccccc7c(c4)c56)c4cc(-c5ccc6oc7ccccc7c6c5)cc2c43)c(-c2cc3c4ccccc4n4c5ccccc5c(c2)c34)c1]

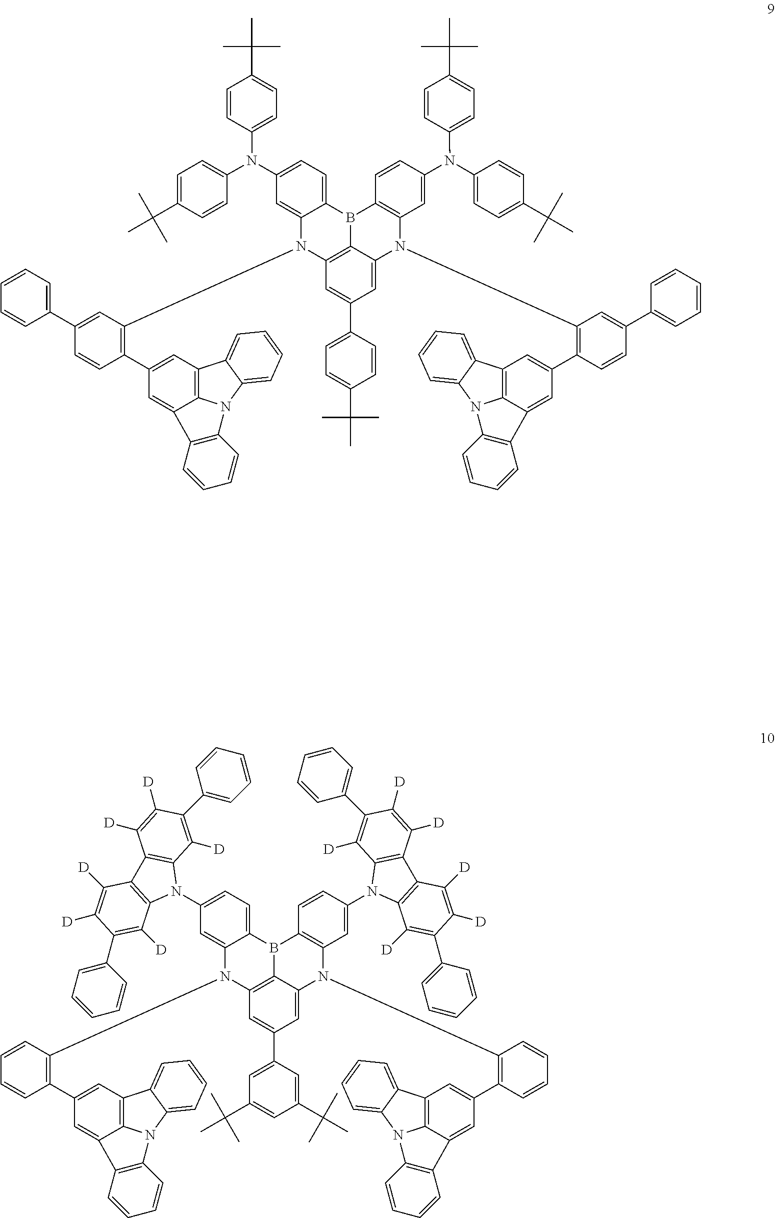

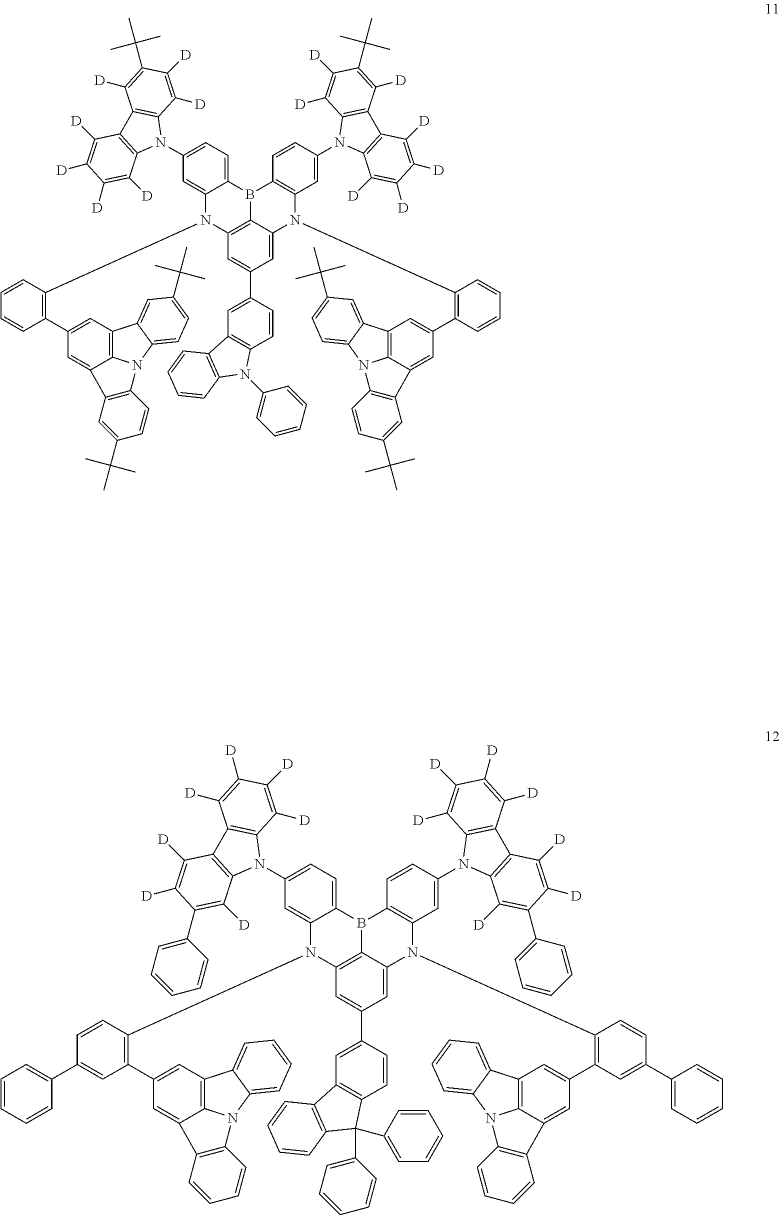

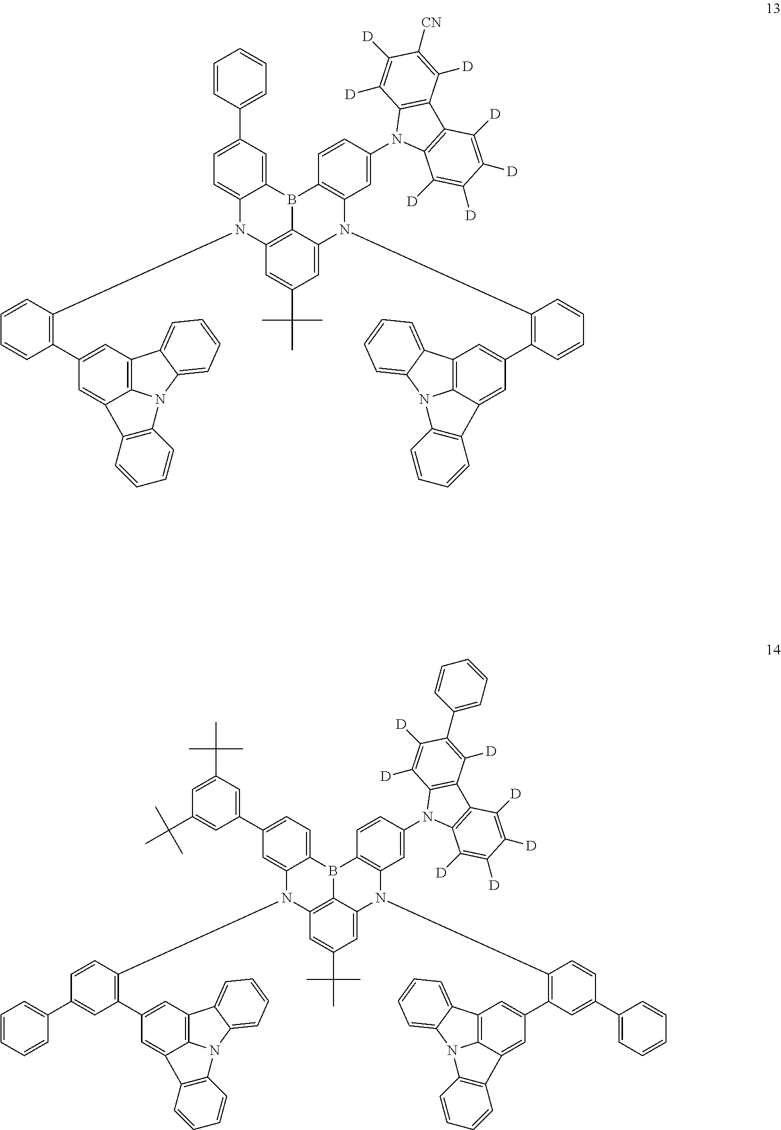 [SMILES: [2H]c1c([2H])c([2H])c2c(c1[2H])c1c([2H])c(C#N)c([2H])c([2H])c1n2-c1ccc2c(c1)N(c1ccccc1-c1cc3c4ccccc4n4c5ccccc5c(c1)c34)c1cc(C(C)(C)C)cc3c1B2c1cc(-c2ccccc2)ccc1N3c1ccccc1-c1cc2c3ccccc3n3c4ccccc4c(c1)c23 ; [2H]c1c([2H])c([2H])c2c(c1[2H])c1c([2H])c(-c3ccccc3)c([2H])c([2H])c1n2-c1ccc2c(c1)N(c1ccc(-c3ccccc3)cc1-c1cc3c4ccccc4n4c5ccccc5c(c1)c34)c1cc(C(C)(C)C)cc3c1B2c1ccc(-c2cc(C(C)(C)C)cc(C(C)(C)C)c2)cc1N3c1ccc(-c2ccccc2)cc1-c1cc2c3ccccc3n3c4ccccc4c(c1)c23]

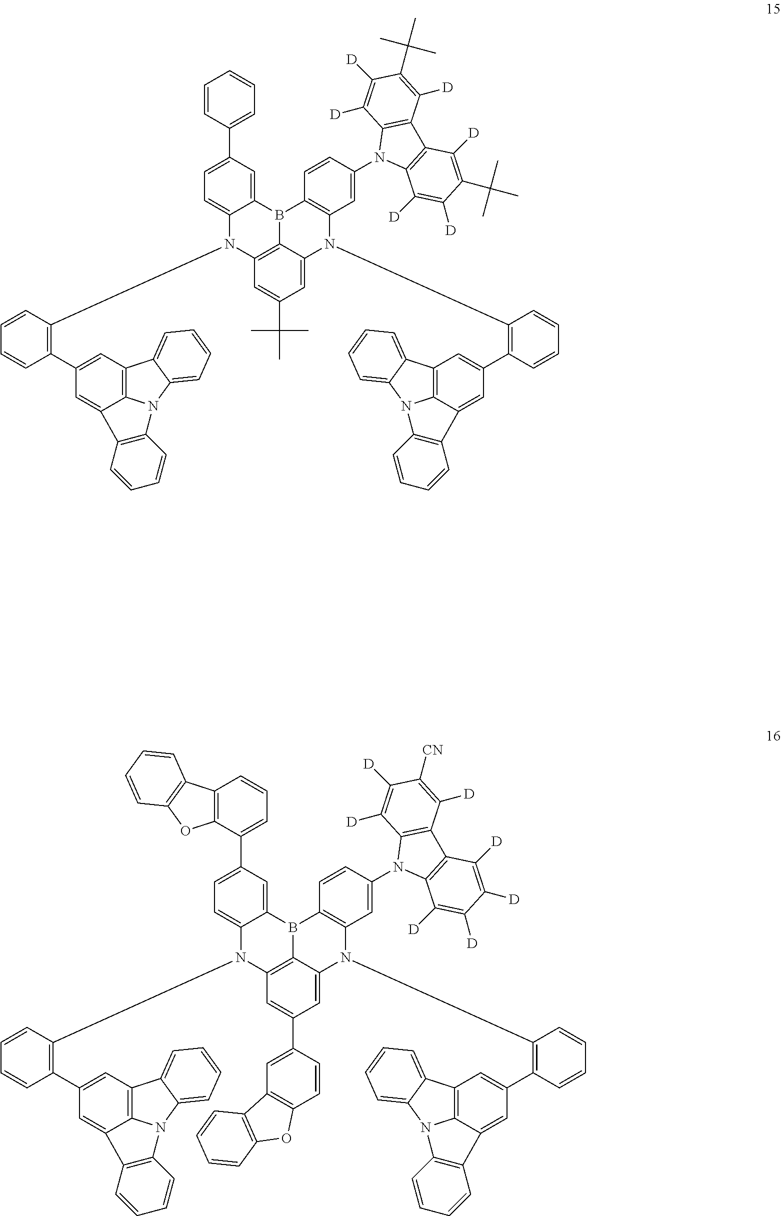 [SMILES: [2H]c1c(C(C)(C)C)c([2H])c2c3c([2H])c(C(C)(C)C)c([2H])c([2H])c3n(-c3ccc4c(c3)N(c3ccccc3-c3cc5c6ccccc6n6c7ccccc7c(c3)c56)c3cc(C(C)(C)C)cc5c3B4c3cc(-c4ccccc4)ccc3N5c3ccccc3-c3cc4c5ccccc5n5c6ccccc6c(c3)c45)c2c1[2H] ; [2H]c1c([2H])c([2H])c2c(c1[2H])c1c([2H])c(C#N)c([2H])c([2H])c1n2-c1ccc2c(c1)N(c1ccccc1-c1cc3c4ccccc4n4c5ccccc5c(c1)c34)c1cc(-c3ccc4oc5ccccc5c4c3)cc3c1B2c1cc(-c2cccc4c2oc2ccccc24)ccc1N3c1ccccc1-c1cc2c3ccccc3n3c4ccccc4c(c1)c23]

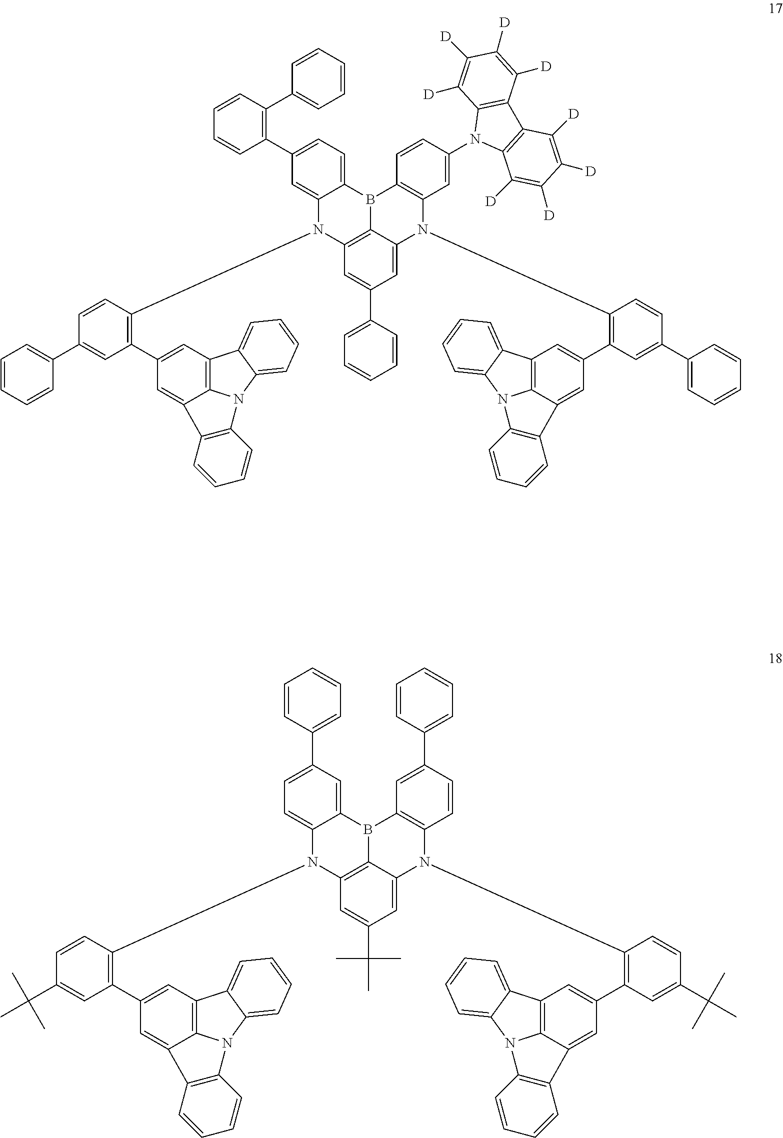 [SMILES: [2H]c1c([2H])c([2H])c2c(c1[2H])c1c([2H])c([2H])c([2H])c([2H])c1n2-c1ccc2c(c1)N(c1ccc(-c3ccccc3)cc1-c1cc3c4ccccc4n4c5ccccc5c(c1)c34)c1cc(-c3ccccc3)cc3c1B2c1ccc(-c2ccccc2-c2ccccc2)cc1N3c1ccc(-c2ccccc2)cc1-c1cc2c3ccccc3n3c4ccccc4c(c1)c23 ; CC(C)(C)c1ccc(N2c3ccc(-c4ccccc4)cc3B3c4cc(-c5ccccc5)ccc4N(c4ccc(C(C)(C)C)cc4-c4cc5c6ccccc6n6c7ccccc7c(c4)c56)c4cc(C(C)(C)C)cc2c43)c(-c2cc3c4ccccc4n4c5ccccc5c(c2)c34)c1]

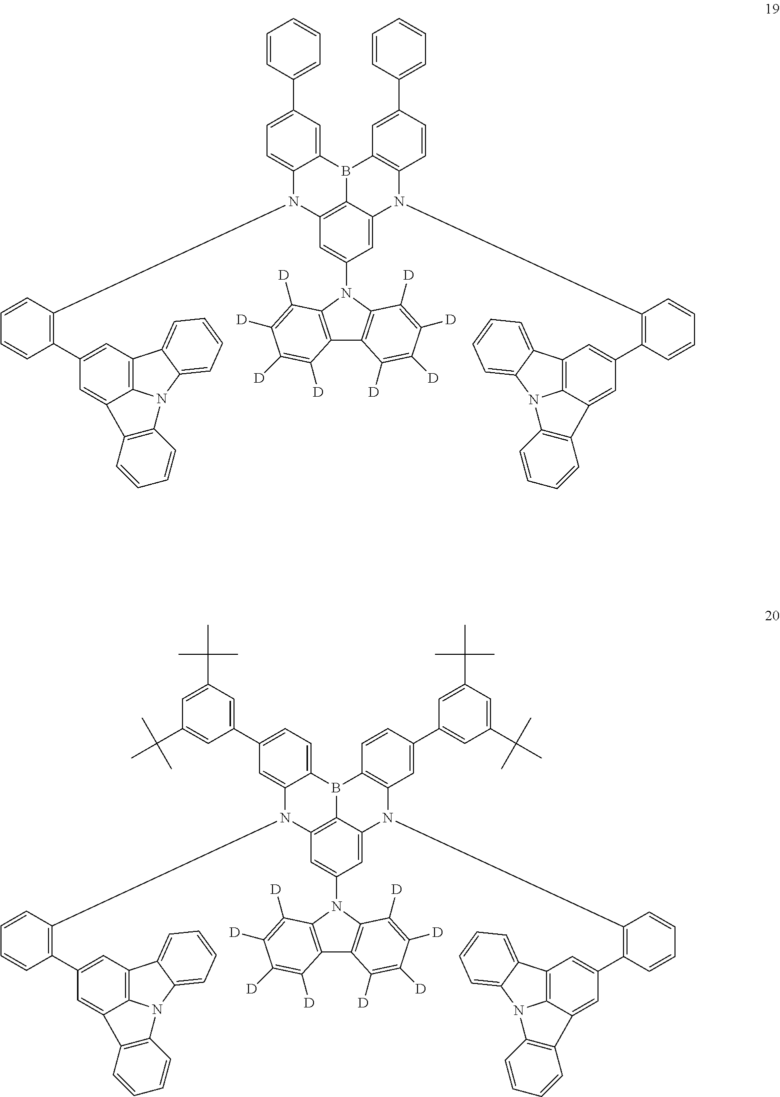 [SMILES: [2H]c1c([2H])c([2H])c2c(c1[2H])c1c([2H])c([2H])c([2H])c([2H])c1n2-c1cc2c3c(c1)N(c1ccccc1-c1cc4c5ccccc5n5c6ccccc6c(c1)c45)c1ccc(-c4ccccc4)cc1B3c1cc(-c3ccccc3)ccc1N2c1ccccc1-c1cc2c3ccccc3n3c4ccccc4c(c1)c23 ; [2H]c1c([2H])c([2H])c2c(c1[2H])c1c([2H])c([2H])c([2H])c([2H])c1n2-c1cc2c3c(c1)N(c1ccccc1-c1cc4c5ccccc5n5c6ccccc6c(c1)c45)c1cc(-c4cc(C(C)(C)C)cc(C(C)(C)C)c4)ccc1B3c1ccc(-c3cc(C(C)(C)C)cc(C(C)(C)C)c3)cc1N2c1ccccc1-c1cc2c3ccccc3n3c4ccccc4c(c1)c23]

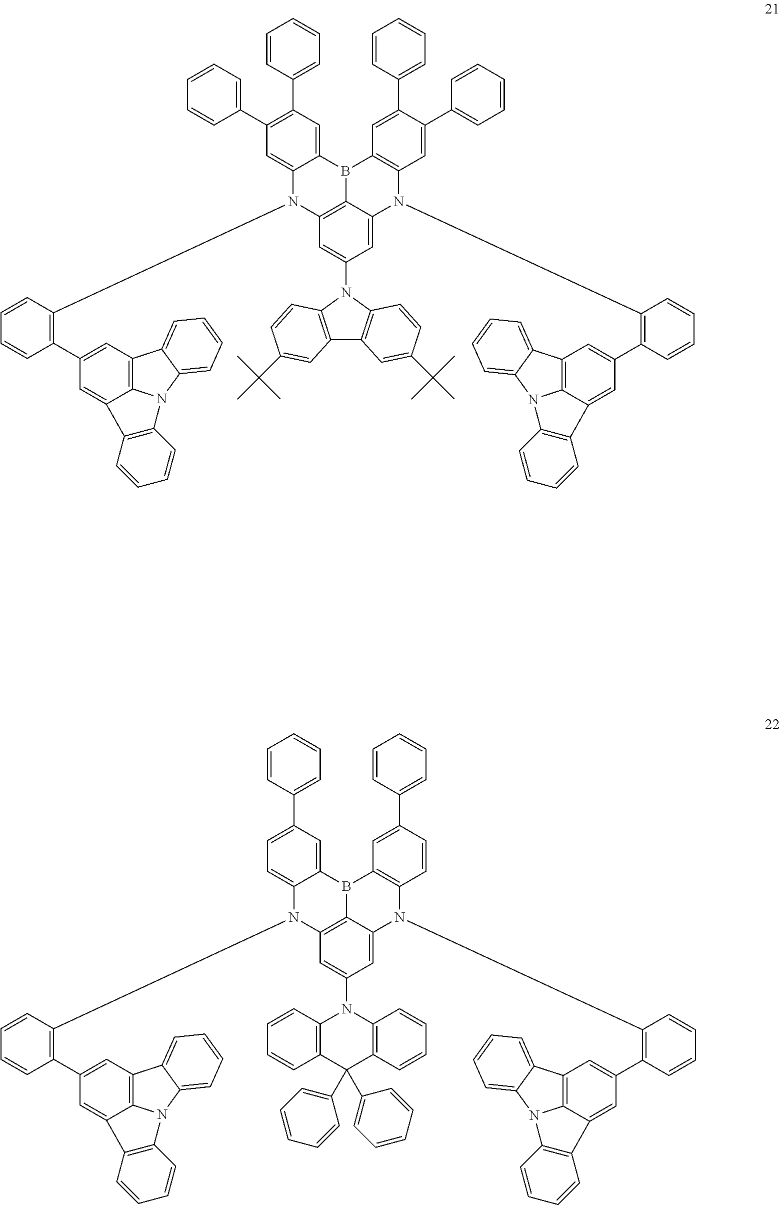 [SMILES: CC(C)(C)c1ccc2c(c1)c1cc(C(C)(C)C)ccc1n2-c1cc2c3c(c1)N(c1ccccc1-c1cc4c5ccccc5n5c6ccccc6c(c1)c45)c1cc(-c4ccccc4)c(-c4ccccc4)cc1B3c1cc(-c3ccccc3)c(-c3ccccc3)cc1N2c1ccccc1-c1cc2c3ccccc3n3c4ccccc4c(c1)c23 ; c1ccc(-c2ccc3c(c2)B2c4cc(-c5ccccc5)ccc4N(c4ccccc4-c4cc5c6ccccc6n6c7ccccc7c(c4)c56)c4cc(N5c6ccccc6C(c6ccccc6)(c6ccccc6)c6ccccc65)cc(c42)N3c2ccccc2-c2cc3c4ccccc4n4c5ccccc5c(c2)c34)cc1]

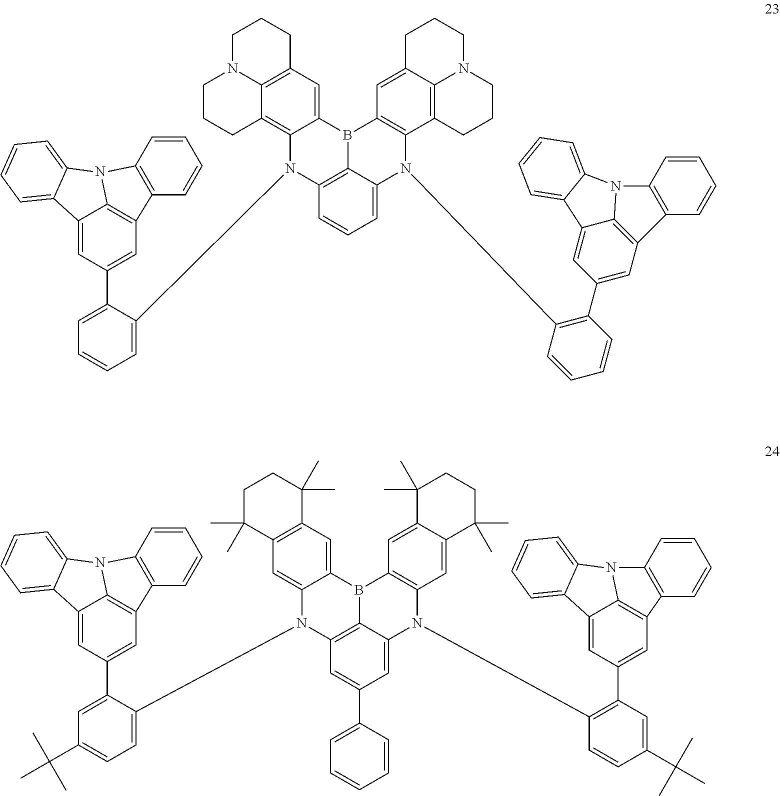 [SMILES: c1ccc(N2c3cccc4c3B(c3cc5c6c(c32)CCCN6CCC5)c2cc3c5c(c2N4c2ccccc2-c2cc4c6ccccc6n6c7ccccc7c(c2)c46)CCCN5CCC3)c(-c2cc3c4ccccc4n4c5ccccc5c(c2)c34)c1 ; CC(C)(C)c1ccc(N2c3cc4c(cc3B3c5cc6c(cc5N(c5ccc(C(C)(C)C)cc5-c5cc7c8ccccc8n8c9ccccc9c(c5)c78)c5cc(-c7ccccc7)cc2c53)C(C)(C)CCC6(C)C)C(C)(C)CCC4(C)C)c(-c2cc3c4ccccc4n4c5ccccc5c(c2)c34)c1]

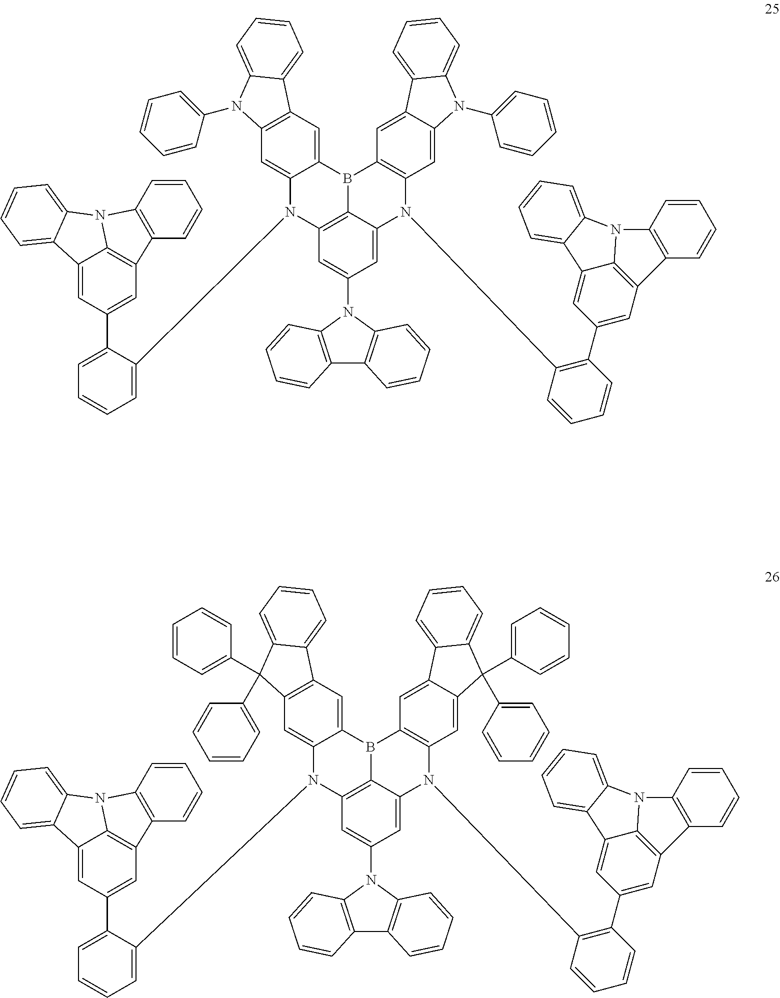 [SMILES: c1ccc(-n2c3ccccc3c3cc4c(cc32)N(c2ccccc2-c2cc3c5ccccc5n5c6ccccc6c(c2)c35)c2cc(-n3c5ccccc5c5ccccc53)cc3c2B4c2cc4c5ccccc5n(-c5ccccc5)c4cc2N3c2ccccc2-c2cc3c4ccccc4n4c5ccccc5c(c2)c34)cc1 ; c1ccc(C2(c3ccccc3)c3ccccc3-c3cc4c(cc32)N(c2ccccc2-c2cc3c5ccccc5n5c6ccccc6c(c2)c35)c2cc(-n3c5ccccc5c5ccccc53)cc3c2B4c2cc4c(cc2N3c2ccccc2-c2cc3c5ccccc5n5c6ccccc6c(c2)c35)C(c2ccccc2)(c2ccccc2)c2ccccc2-4)cc1]

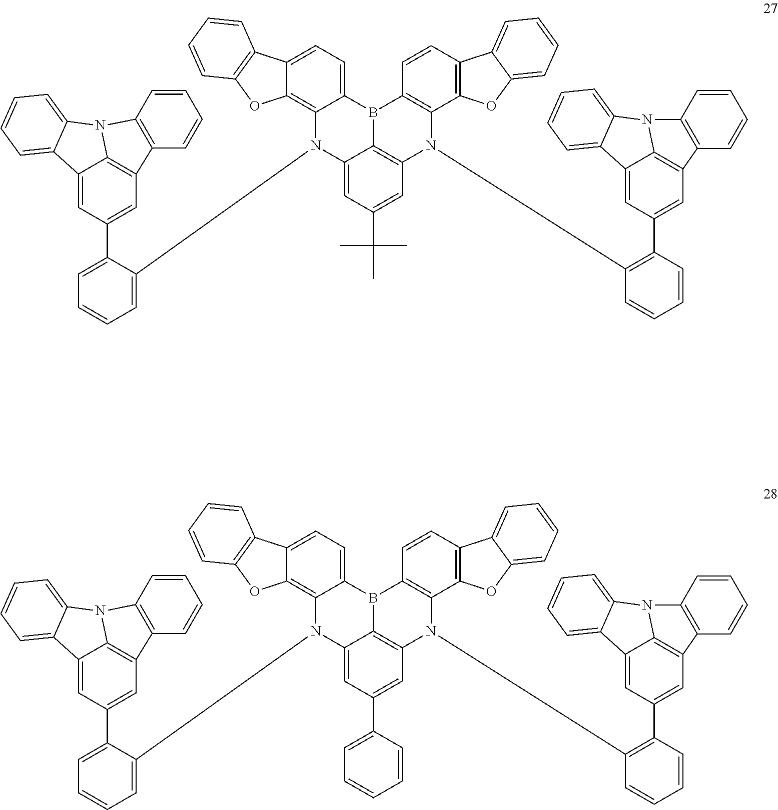 [SMILES: CC(C)(C)c1cc2c3c(c1)N(c1ccccc1-c1cc4c5ccccc5n5c6ccccc6c(c1)c45)c1c(ccc4c1oc1ccccc14)B3c1ccc3c(oc4ccccc43)c1N2c1ccccc1-c1cc2c3ccccc3n3c4ccccc4c(c1)c23 ; c1ccc(-c2cc3c4c(c2)N(c2ccccc2-c2cc5c6ccccc6n6c7ccccc7c(c2)c56)c2c(ccc5c2oc2ccccc25)B4c2ccc4c(oc5ccccc54)c2N3c2ccccc2-c2cc3c4ccccc4n4c5ccccc5c(c2)c34)cc1]

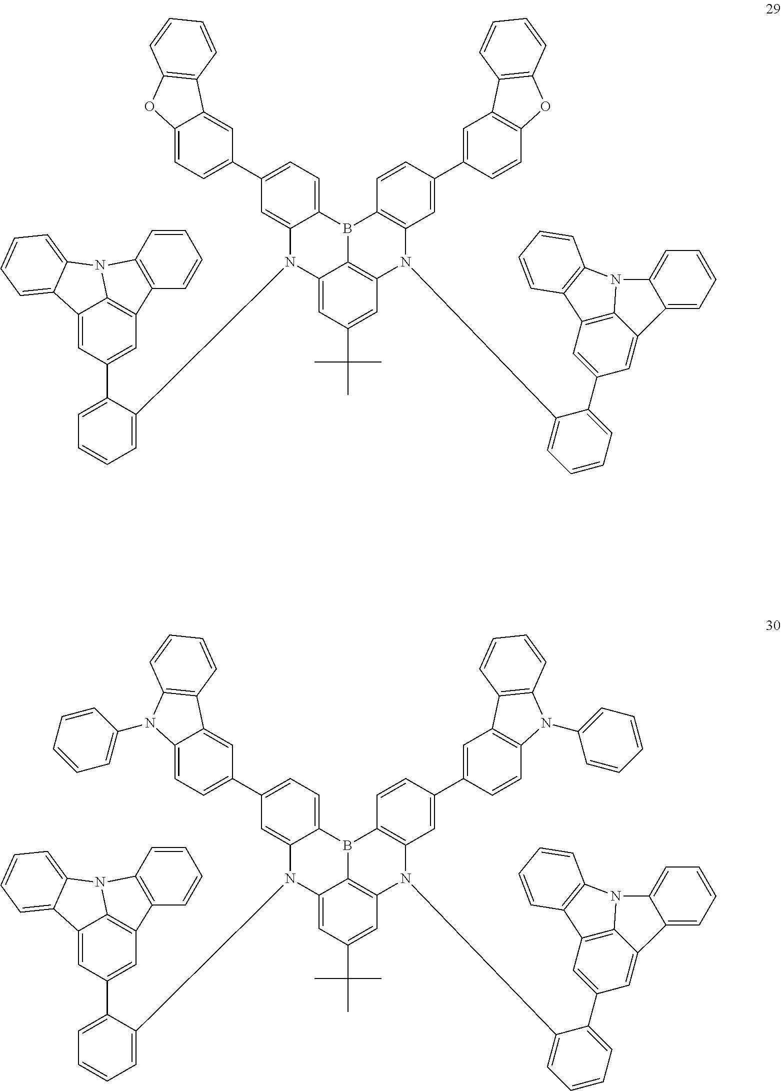 [SMILES: CC(C)(C)c1cc2c3c(c1)N(c1ccccc1-c1cc4c5ccccc5n5c6ccccc6c(c1)c45)c1cc(-c4ccc5oc6ccccc6c5c4)ccc1B3c1ccc(-c3ccc4oc5ccccc5c4c3)cc1N2c1ccccc1-c1cc2c3ccccc3n3c4ccccc4c(c1)c23 ; CC(C)(C)c1cc2c3c(c1)N(c1ccccc1-c1cc4c5ccccc5n5c6ccccc6c(c1)c45)c1cc(-c4ccc5c(c4)c4ccccc4n5-c4ccccc4)ccc1B3c1ccc(-c3ccc4c(c3)c3ccccc3n4-c3ccccc3)cc1N2c1ccccc1-c1cc2c3ccccc3n3c4ccccc4c(c1)c23]

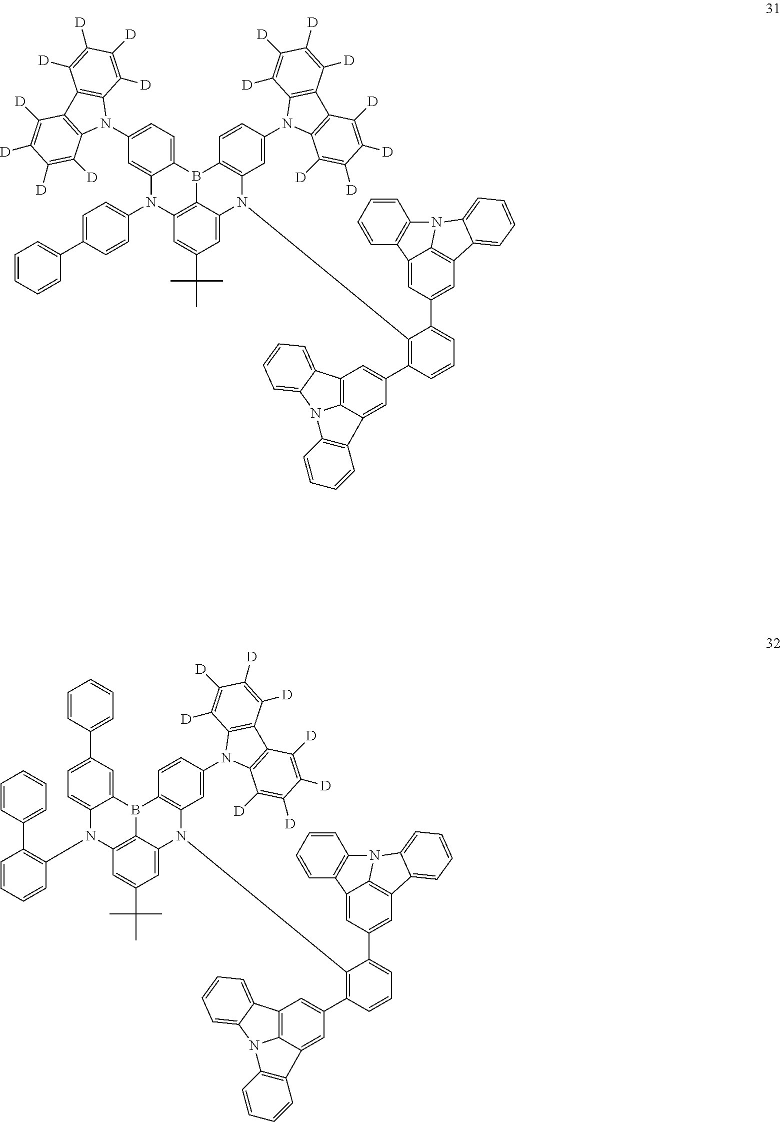 [SMILES: [2H]c1c([2H])c([2H])c2c(c1[2H])c1c([2H])c([2H])c([2H])c([2H])c1n2-c1ccc2c(c1)N(c1ccc(-c3ccccc3)cc1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2cc3c4ccccc4n4c5ccccc5c(c2)c34)cccc1-c1cc2c3ccccc3n3c4ccccc4c(c1)c23 ; [2H]c1c([2H])c([2H])c2c(c1[2H])c1c([2H])c([2H])c([2H])c([2H])c1n2-c1ccc2c(c1)N(c1c(-c3cc4c5ccccc5n5c6ccccc6c(c3)c45)cccc1-c1cc3c4ccccc4n4c5ccccc5c(c1)c34)c1cc(C(C)(C)C)cc3c1B2c1cc(-c2ccccc2)ccc1N3c1ccccc1-c1ccccc1]

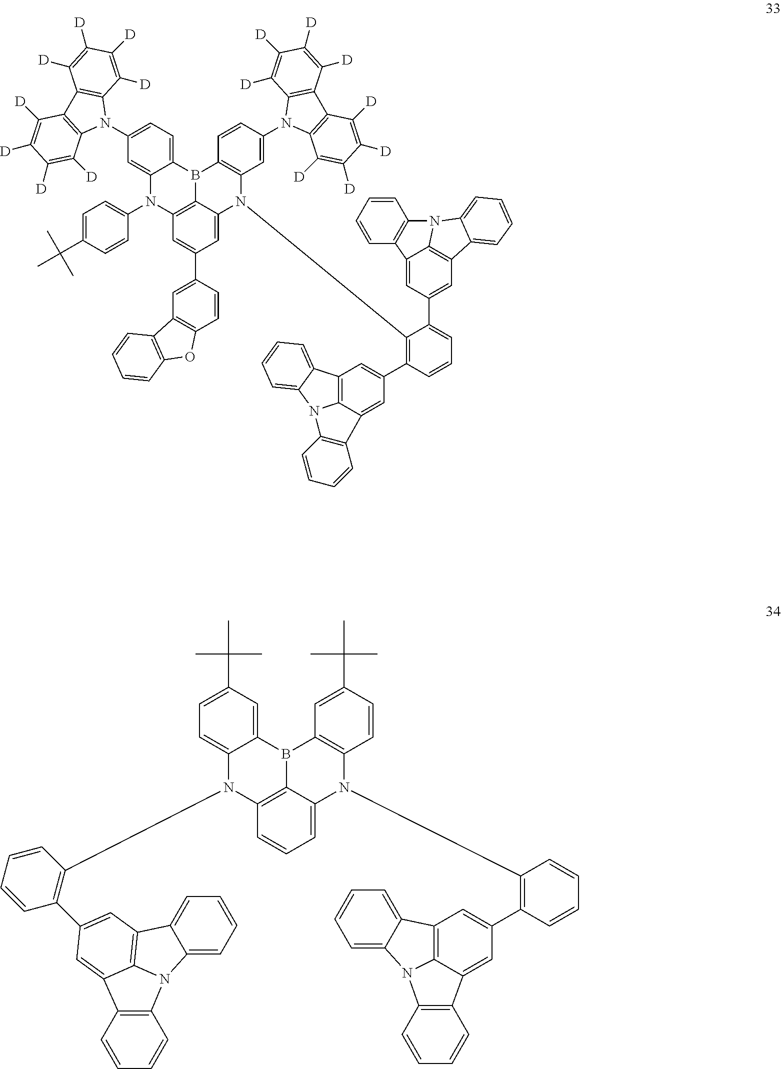 [SMILES: [2H]c1c([2H])c([2H])c2c(c1[2H])c1c([2H])c([2H])c([2H])c([2H])c1n2-c1ccc2c(c1)N(c1ccc(C(C)(C)C)cc1)c1cc(-c3ccc4oc5ccccc5c4c3)cc3c1B2c1ccc(-n2c4c([2H])c([2H])c([2H])c([2H])c4c4c([2H])c([2H])c([2H])c([2H])c42)cc1N3c1c(-c2cc3c4ccccc4n4c5ccccc5c(c2)c34)cccc1-c1cc2c3ccccc3n3c4ccccc4c(c1)c23 ; CC(C)(C)c1ccc2c(c1)B1c3cc(C(C)(C)C)ccc3N(c3ccccc3-c3cc4c5ccccc5n5c6ccccc6c(c3)c45)c3cccc(c31)N2c1ccccc1-c1cc2c3ccccc3n3c4ccccc4c(c1)c23]

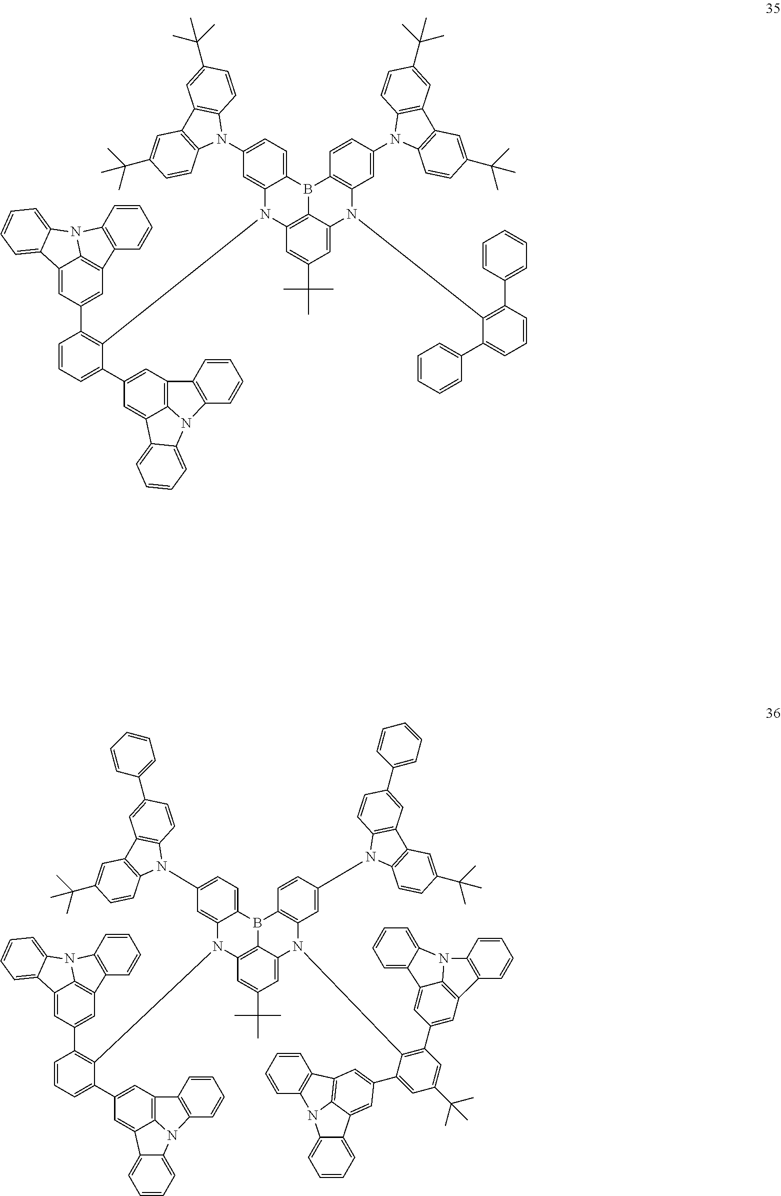

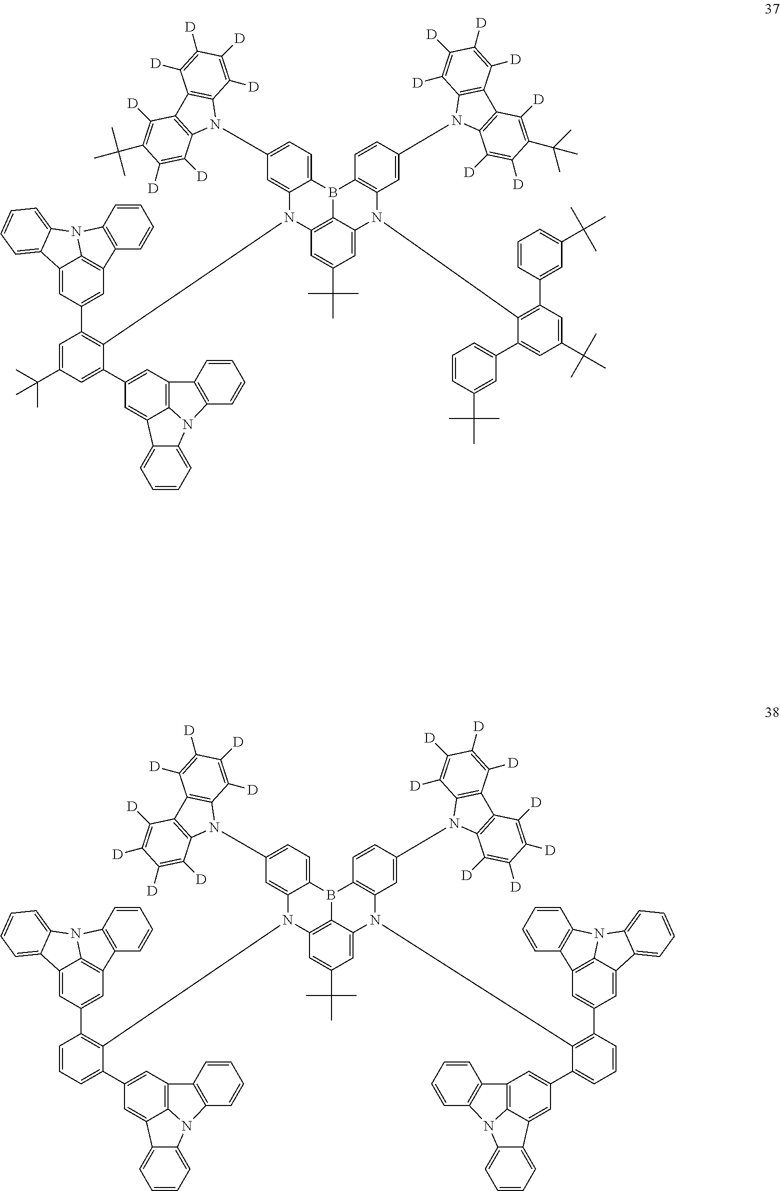

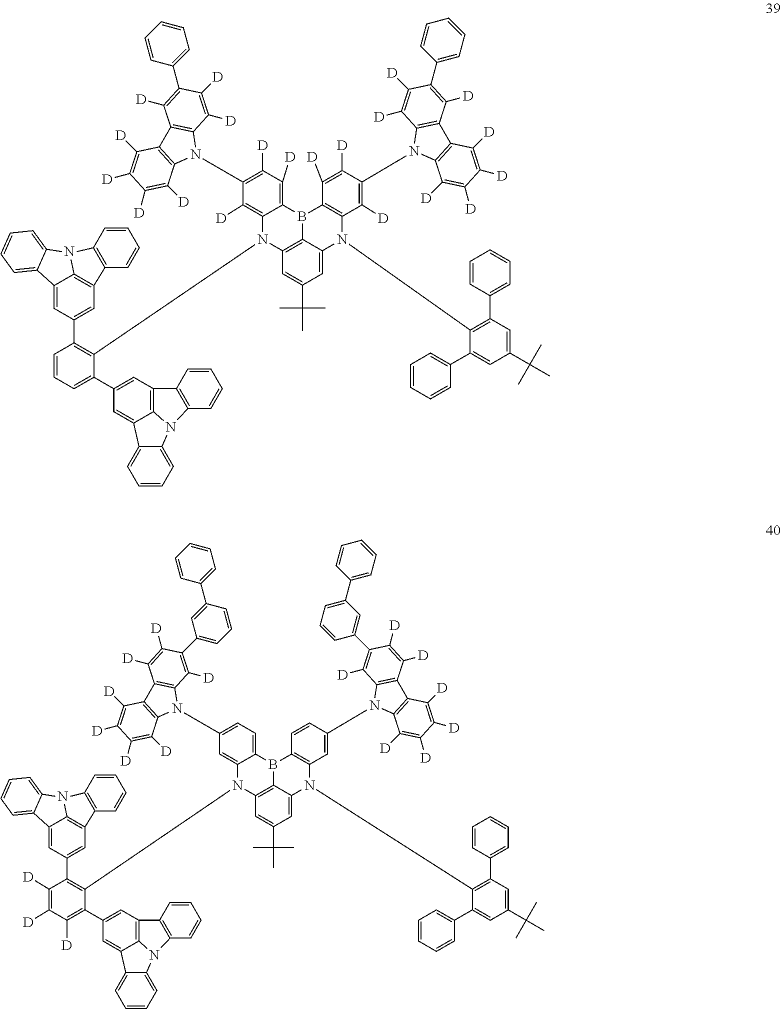

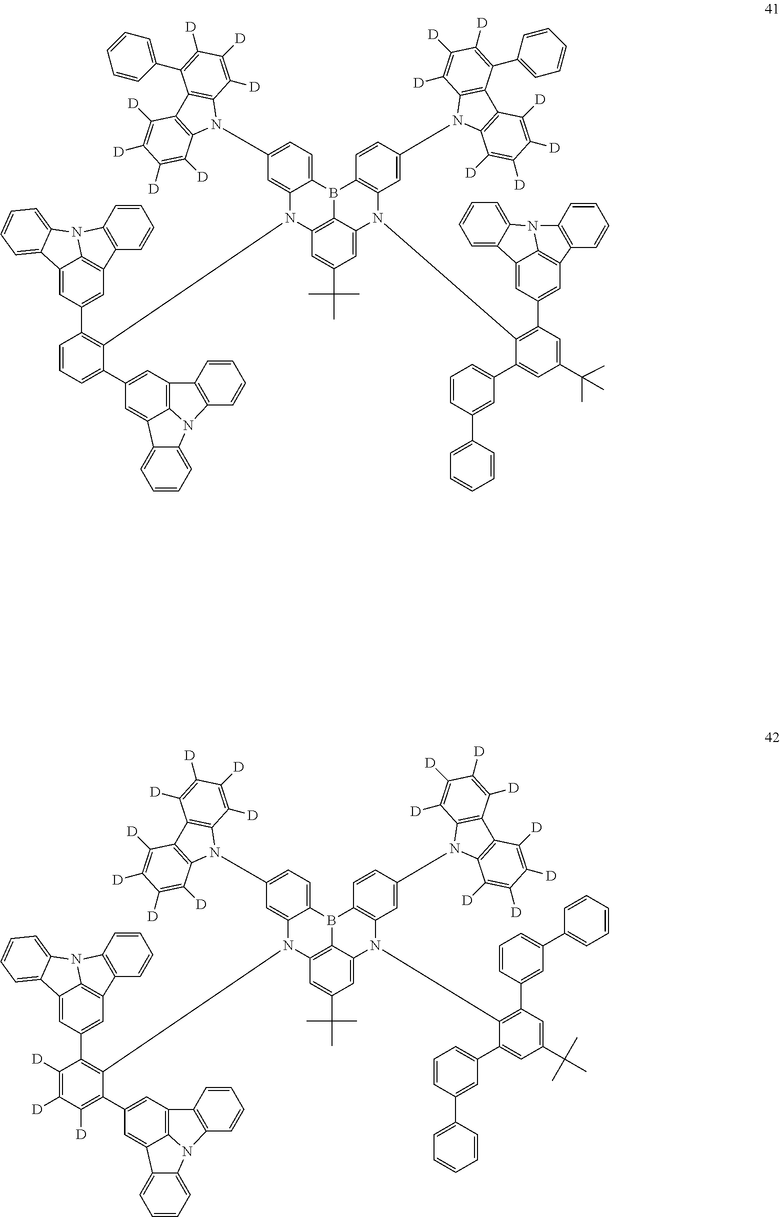

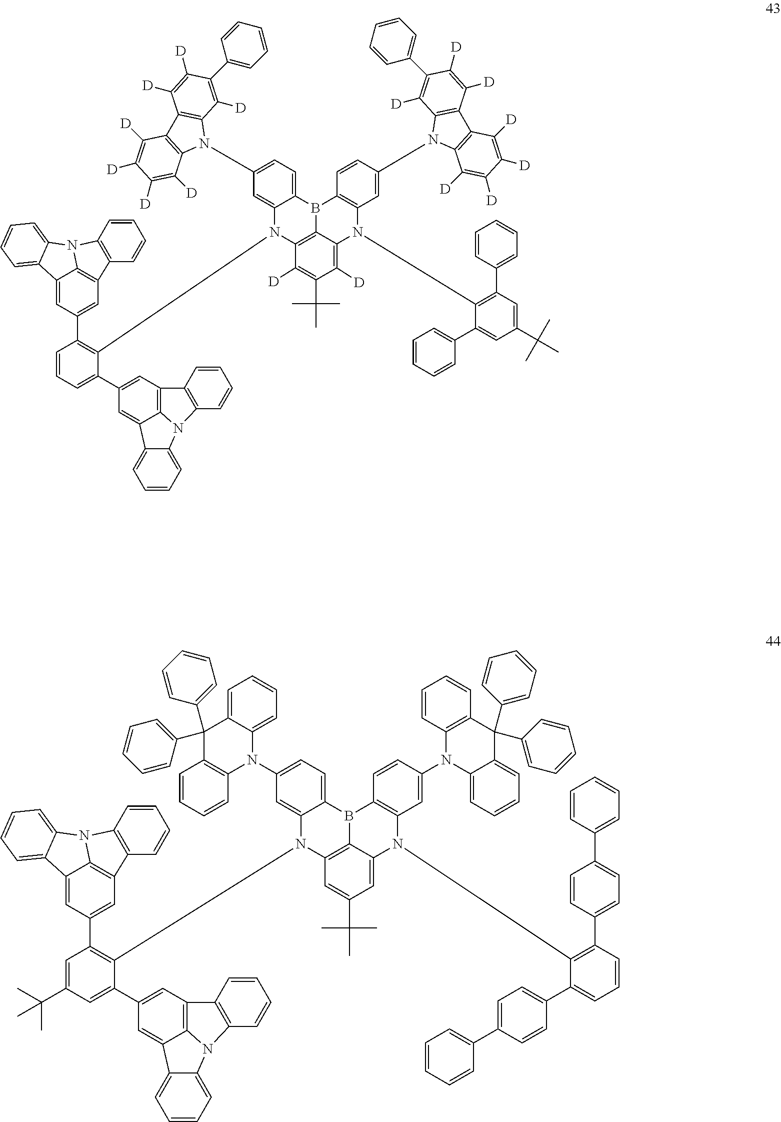

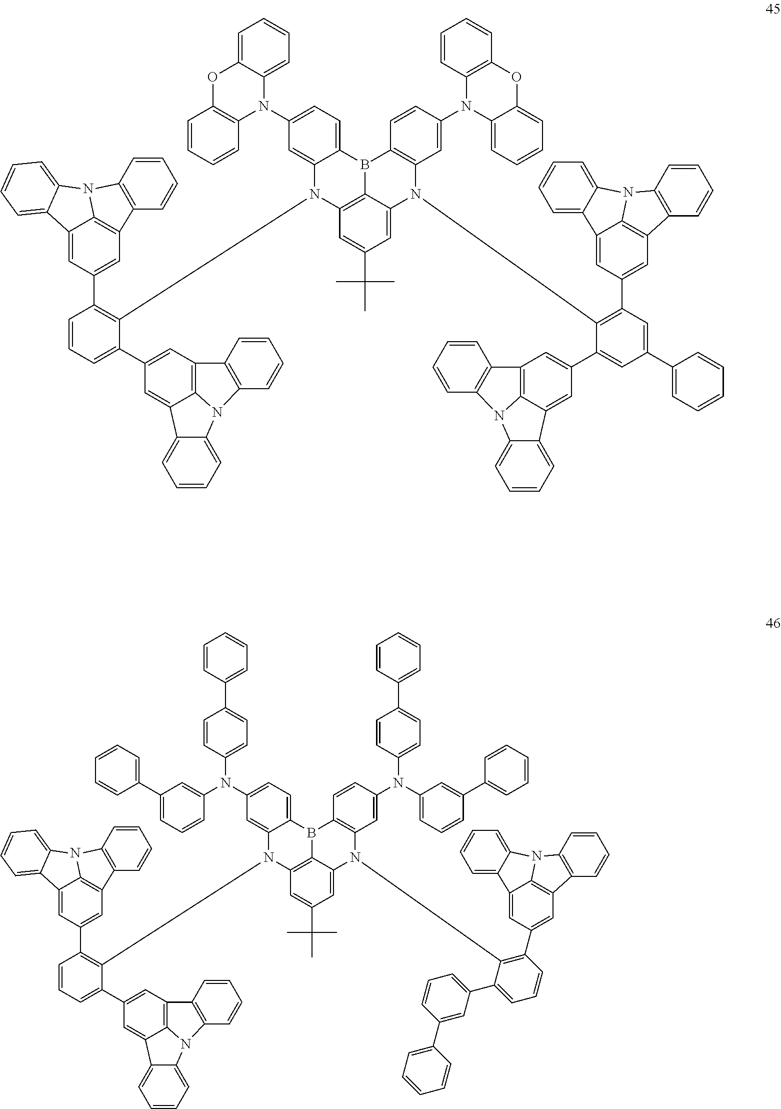

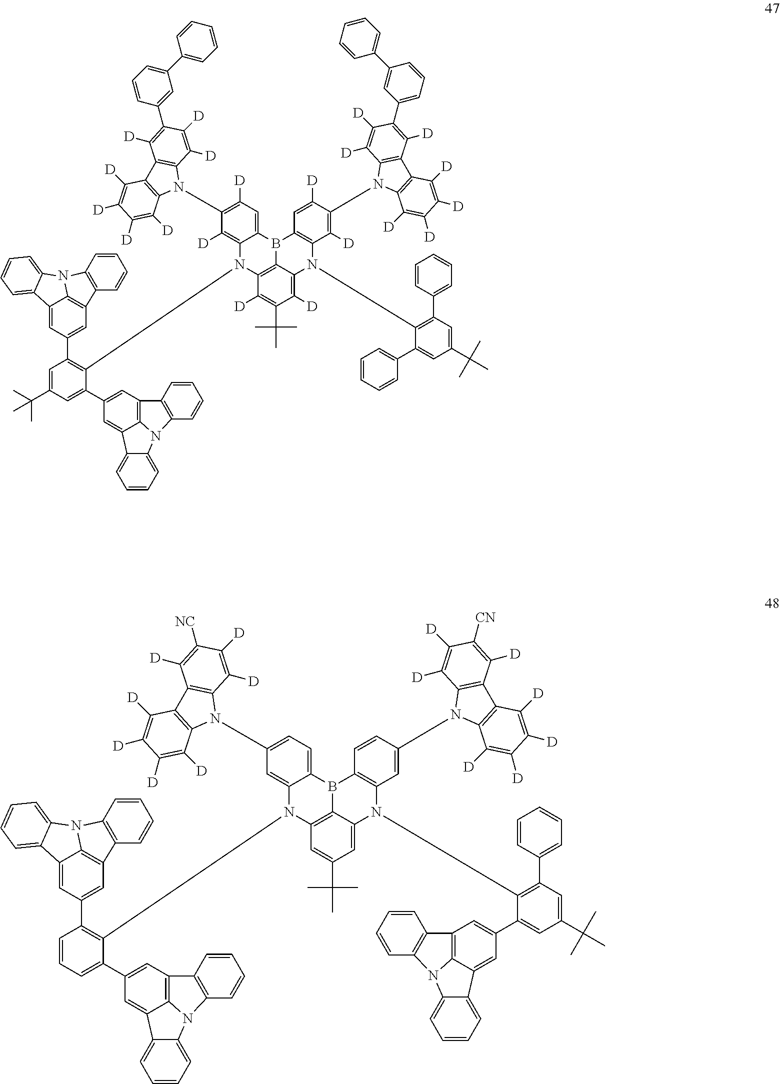

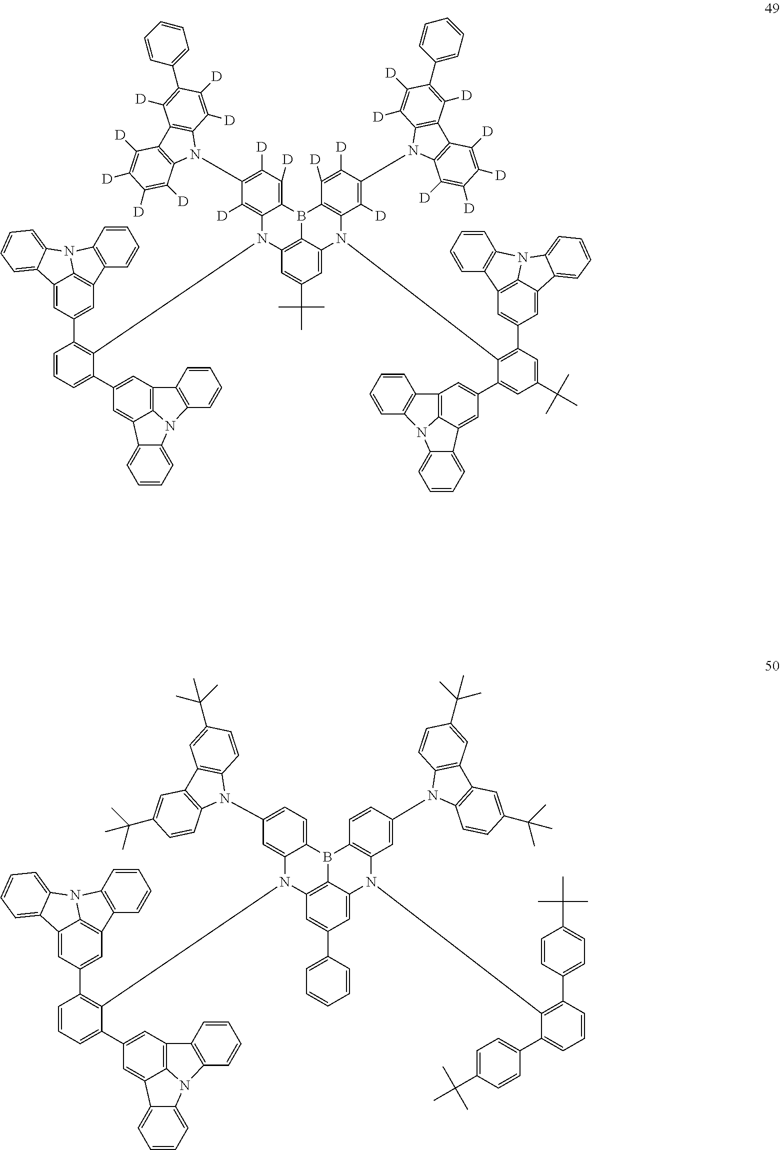

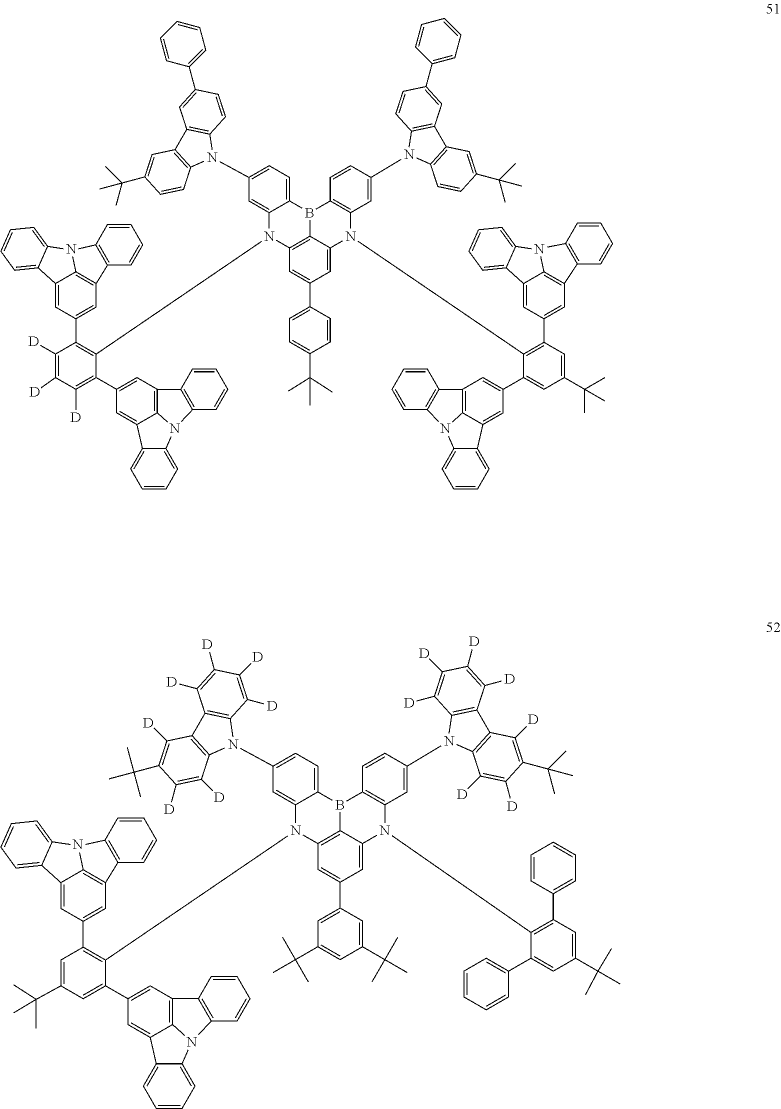

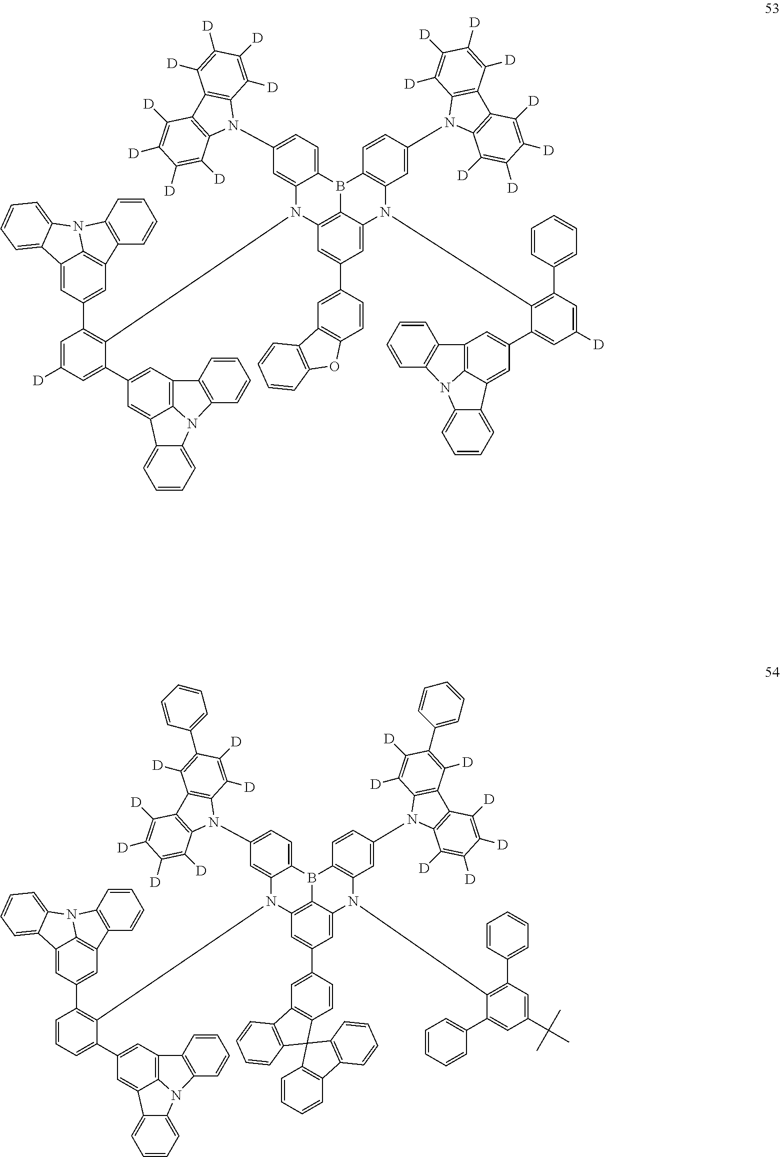

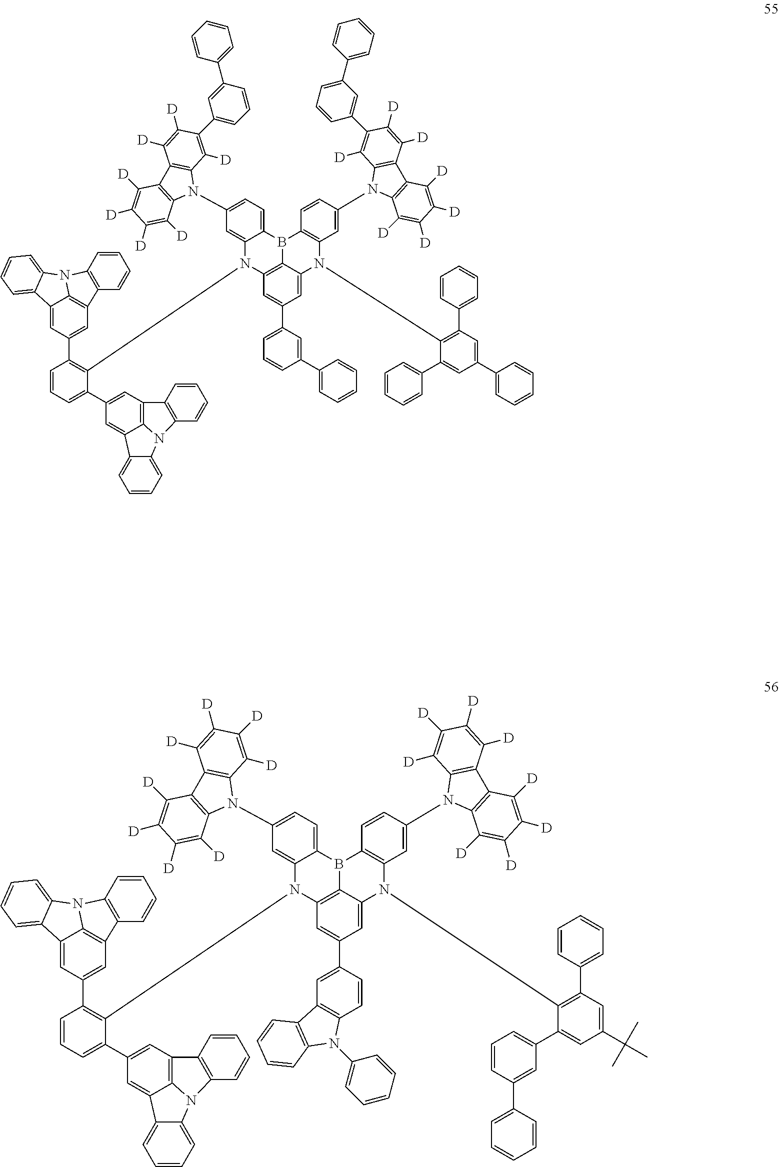

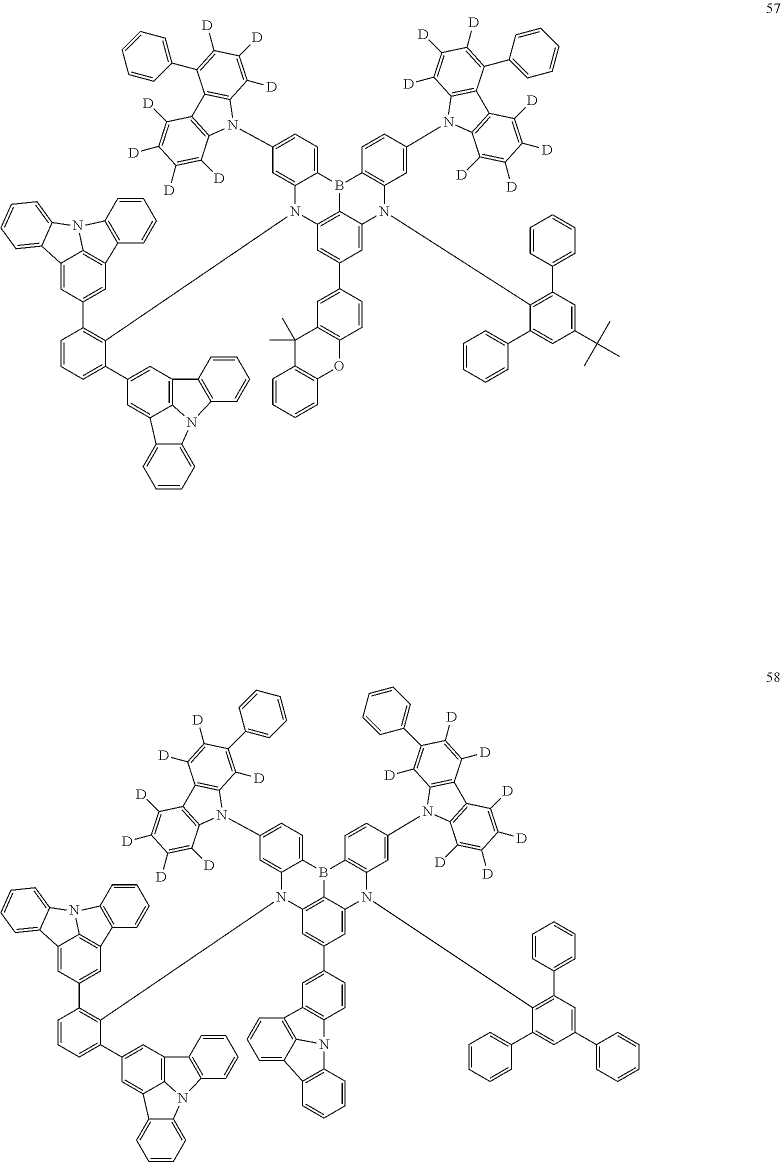

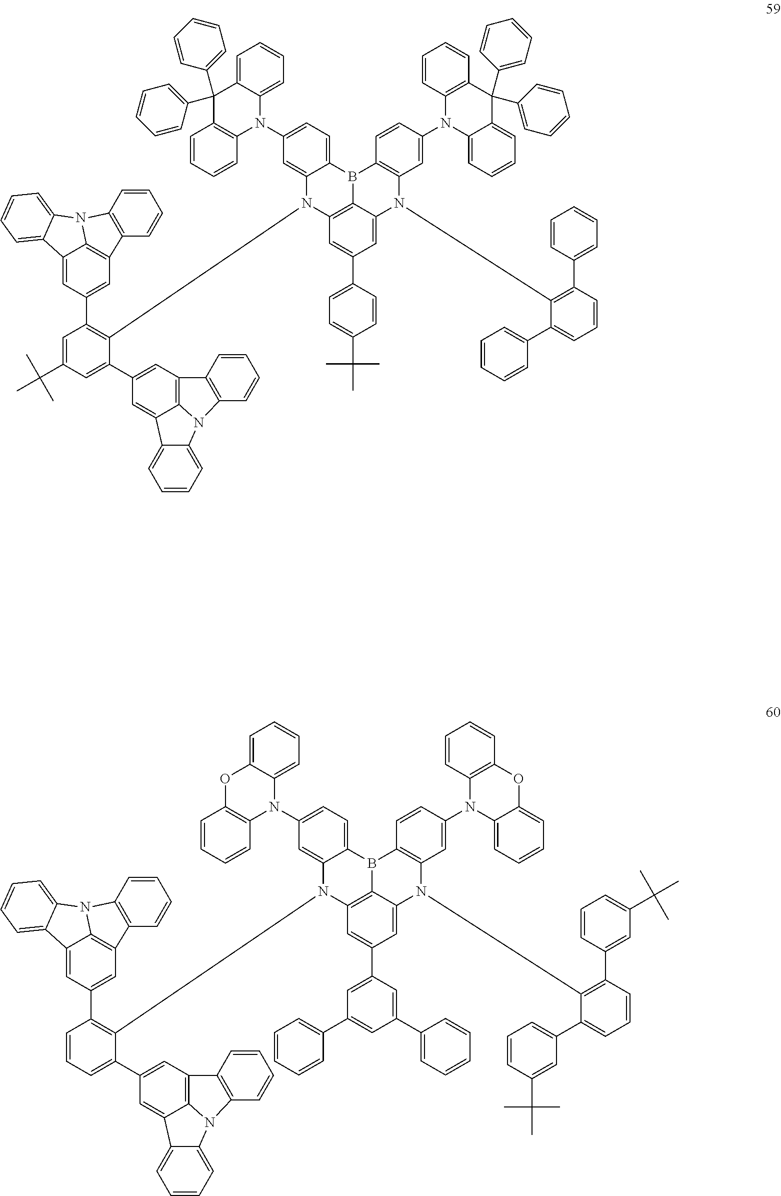 [SMILES: CC(C)(C)c1ccc(-c2cc3c4c(c2)N(c2c(-c5cc6c7ccccc7n7c8ccccc8c(c5)c67)cc(C(C)(C)C)cc2-c2cc5c6ccccc6n6c7ccccc7c(c2)c56)c2cc(N5c6ccccc6C(c6ccccc6)(c6ccccc6)c6ccccc65)ccc2B4c2ccc(N4c5ccccc5C(c5ccccc5)(c5ccccc5)c5ccccc54)cc2N3c2c(-c3ccccc3)cccc2-c2ccccc2)cc1 ; CC(C)(C)c1cccc(-c2cccc(-c3cccc(C(C)(C)C)c3)c2N2c3cc(N4c5ccccc5Oc5ccccc54)ccc3B3c4ccc(N5c6ccccc6Oc6ccccc65)cc4N(c4c(-c5cc6c7ccccc7n7c8ccccc8c(c5)c67)cccc4-c4cc5c6ccccc6n6c7ccccc7c(c4)c56)c4cc(-c5cc(-c6ccccc6)cc(-c6ccccc6)c5)cc2c43)c1]

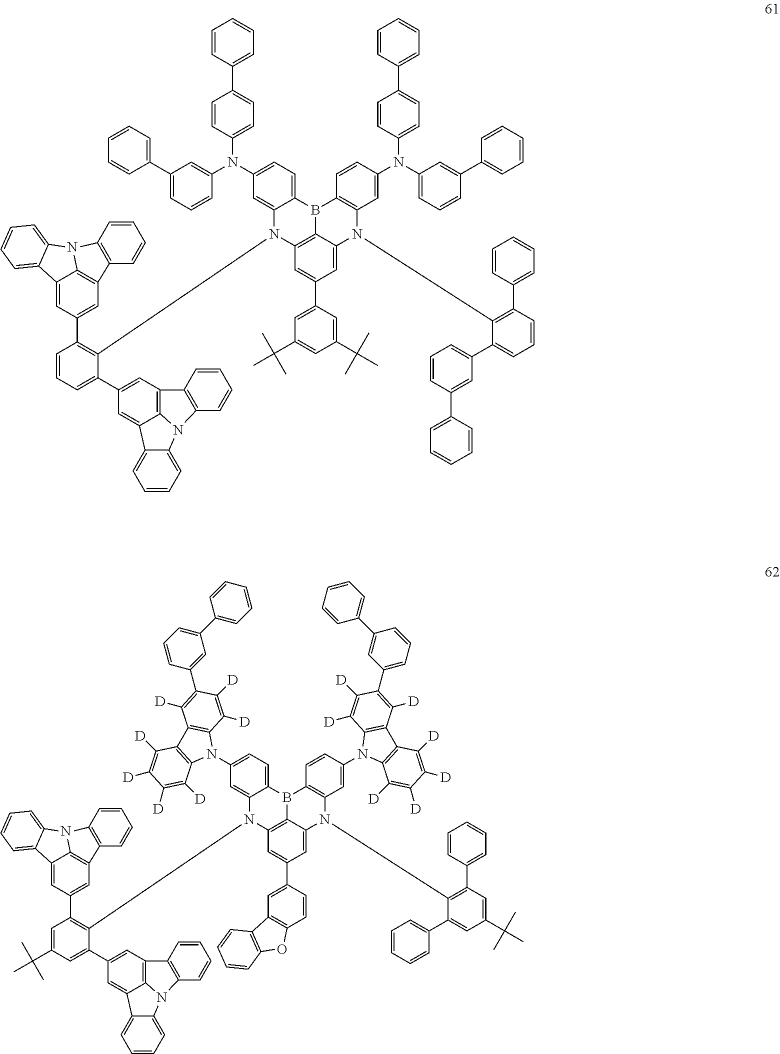

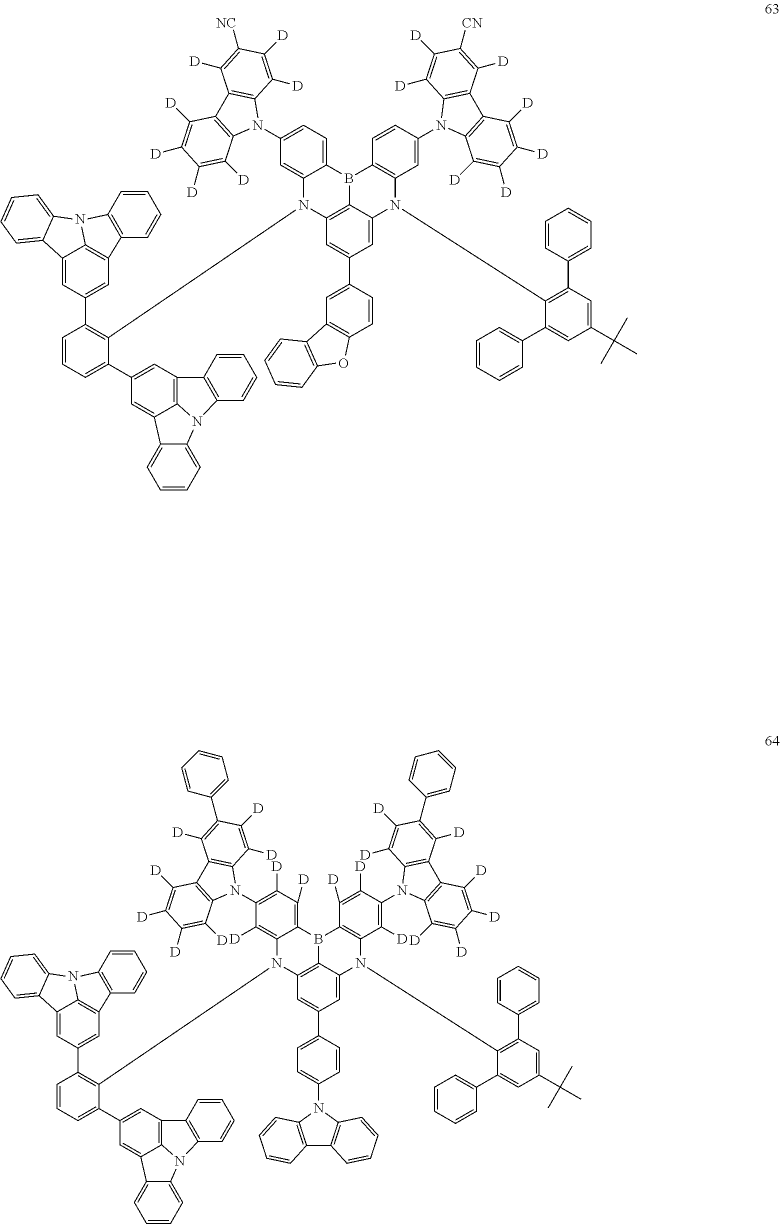

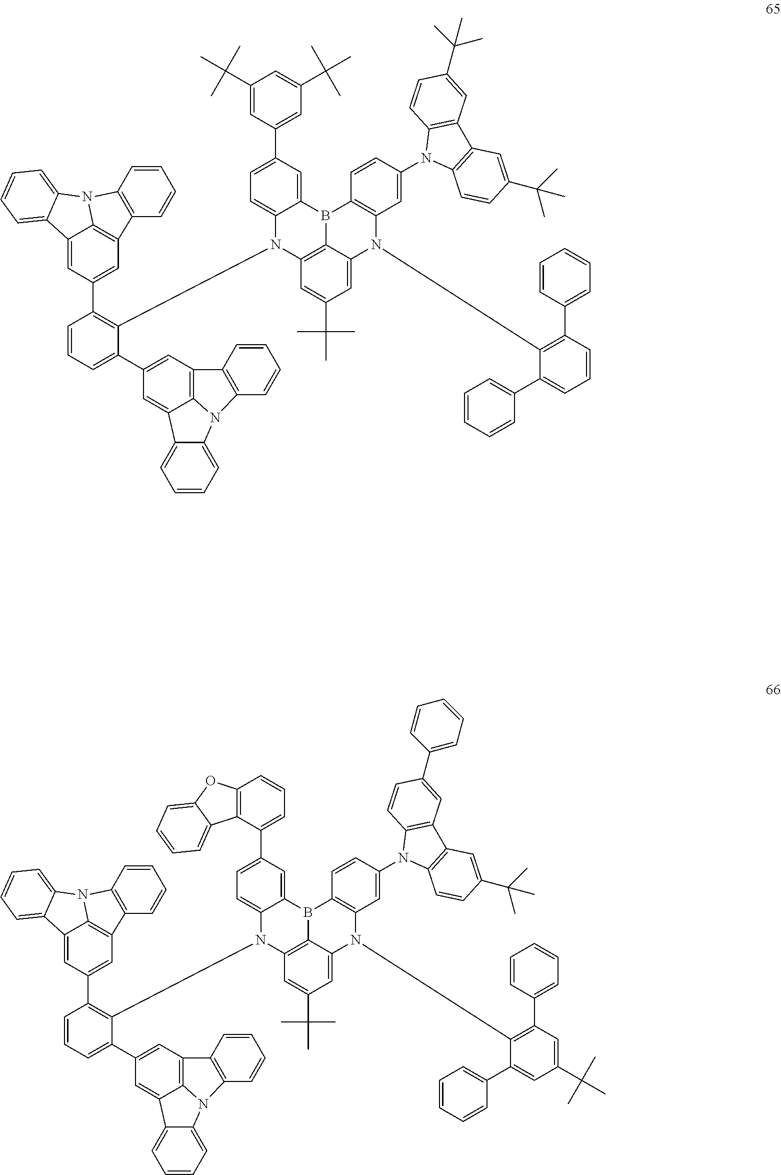 [SMILES: CC(C)(C)c1cc(-c2ccc3c(c2)B2c4ccc(-n5c6ccc(C(C)(C)C)cc6c6cc(C(C)(C)C)ccc65)cc4N(c4c(-c5ccccc5)cccc4-c4ccccc4)c4cc(C(C)(C)C)cc(c42)N3c2c(-c3cc4c5ccccc5n5c6ccccc6c(c3)c45)cccc2-c2cc3c4ccccc4n4c5ccccc5c(c2)c34)cc(C(C)(C)C)c1 ; CC(C)(C)c1cc(-c2ccccc2)c(N2c3cc(-n4c5ccc(-c6ccccc6)cc5c5cc(C(C)(C)C)ccc54)ccc3B3c4cc(-c5cccc6oc7ccccc7c56)ccc4N(c4c(-c5cc6c7ccccc7n7c8ccccc8c(c5)c67)cccc4-c4cc5c6ccccc6n6c7ccccc7c(c4)c56)c4cc(C(C)(C)C)cc2c43)c(-c2ccccc2)c1]

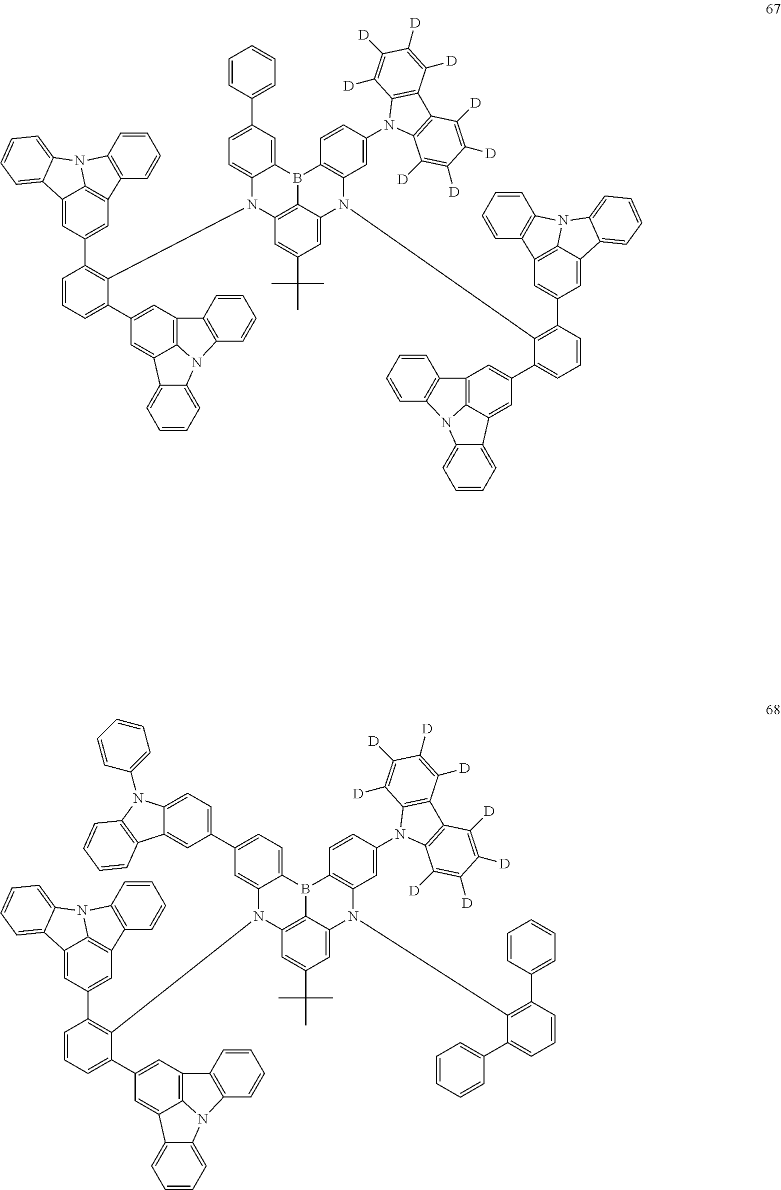

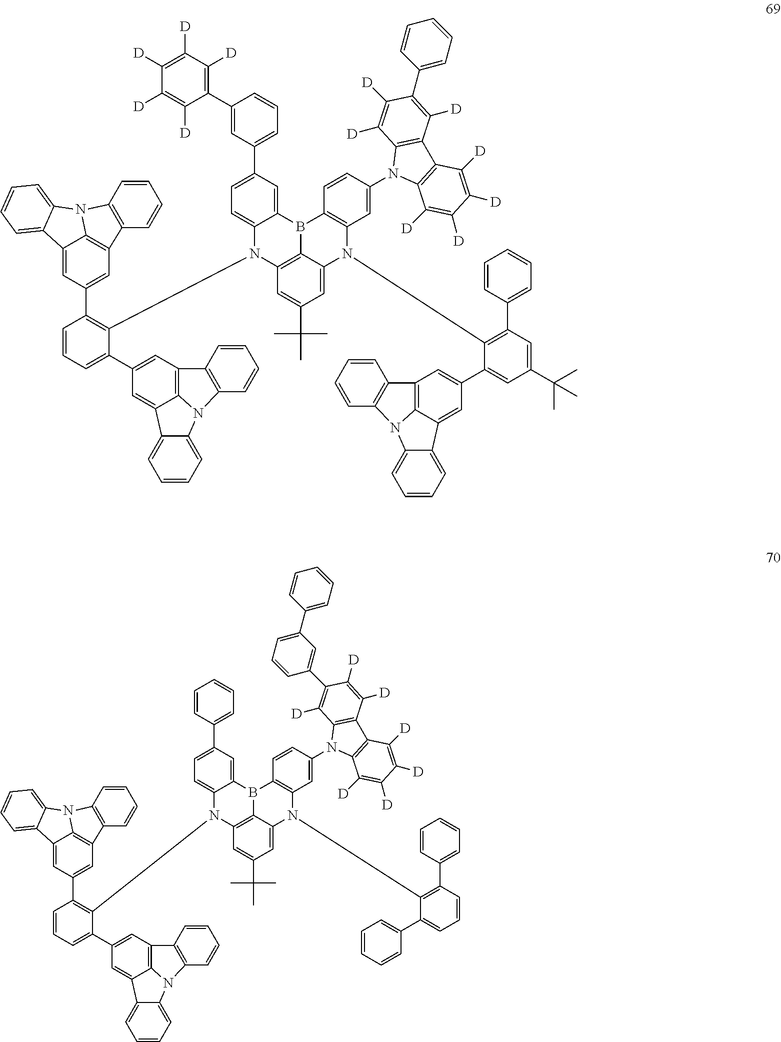

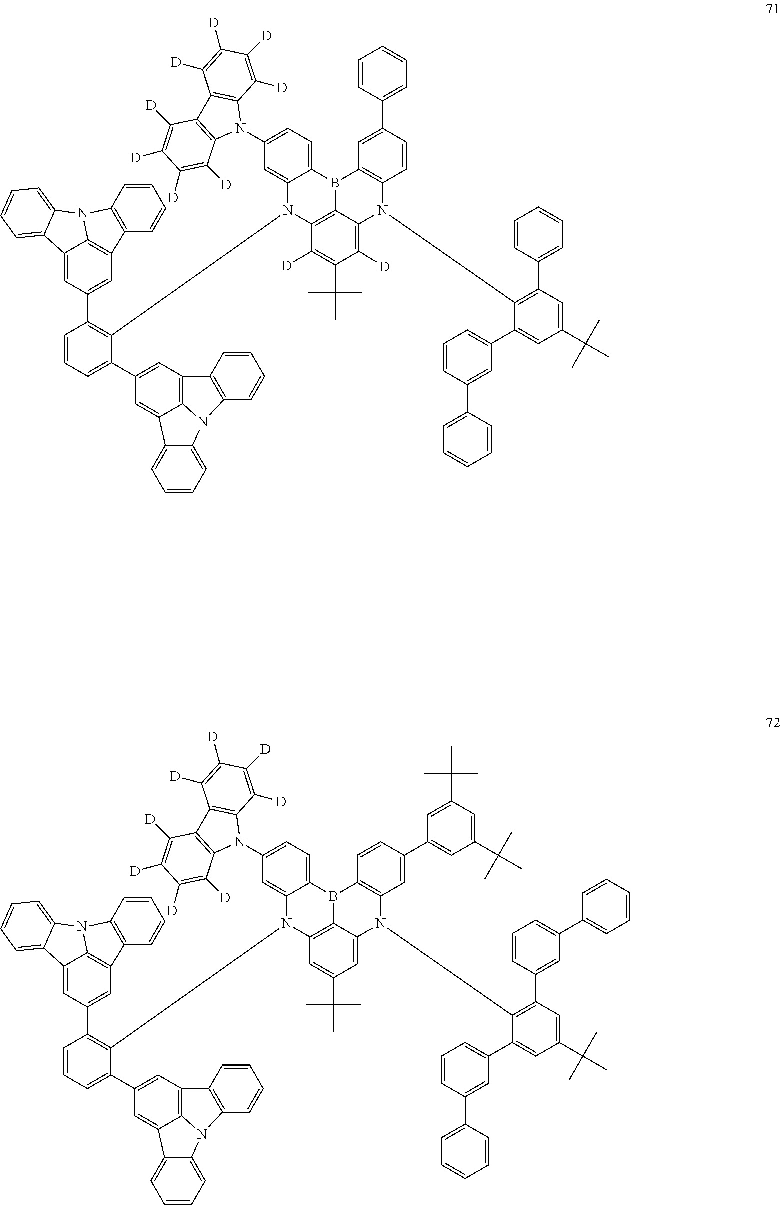

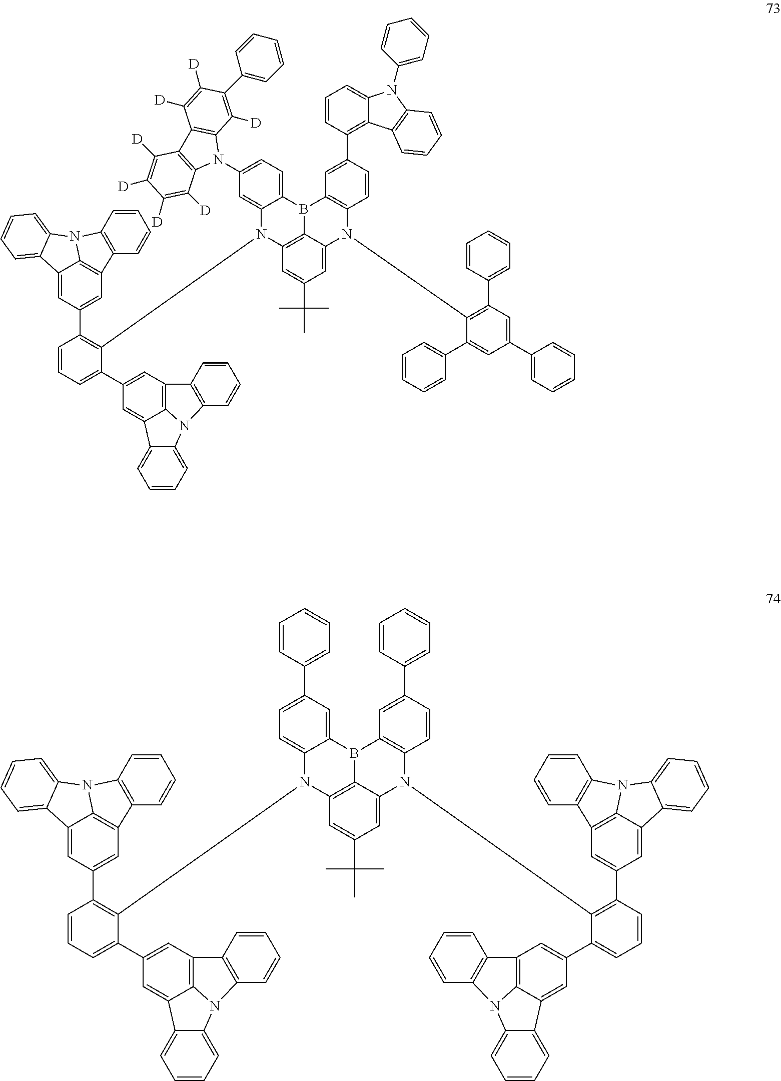 [SMILES: [2H]c1c([2H])c([2H])c2c(c1[2H])c1c([2H])c([2H])c(-c3ccccc3)c([2H])c1n2-c1ccc2c(c1)N(c1c(-c3cc4c5ccccc5n5c6ccccc6c(c3)c45)cccc1-c1cc3c4ccccc4n4c5ccccc5c(c1)c34)c1cc(C(C)(C)C)cc3c1B2c1cc(-c2cccc4c2c2ccccc2n4-c2ccccc2)ccc1N3c1c(-c2ccccc2)cc(-c2ccccc2)cc1-c1ccccc1 ; CC(C)(C)c1cc2c3c(c1)N(c1c(-c4cc5c6ccccc6n6c7ccccc7c(c4)c56)cccc1-c1cc4c5ccccc5n5c6ccccc6c(c1)c45)c1ccc(-c4ccccc4)cc1B3c1cc(-c3ccccc3)ccc1N2c1c(-c2cc3c4ccccc4n4c5ccccc5c(c2)c34)cccc1-c1cc2c3ccccc3n3c4ccccc4c(c1)c23]

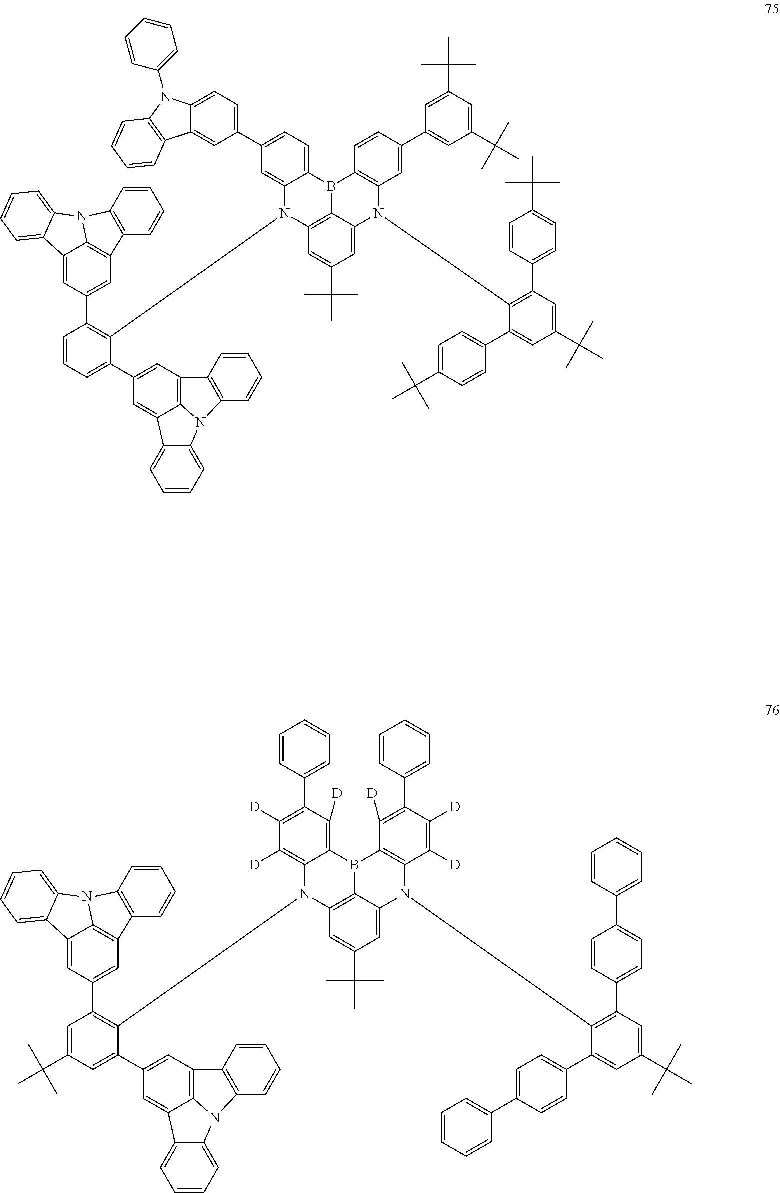 [SMILES: CC(C)(C)c1ccc(-c2cc(C(C)(C)C)cc(-c3ccc(C(C)(C)C)cc3)c2N2c3cc(-c4cc(C(C)(C)C)cc(C(C)(C)C)c4)ccc3B3c4ccc(-c5ccc6c(c5)c5ccccc5n6-c5ccccc5)cc4N(c4c(-c5cc6c7ccccc7n7c8ccccc8c(c5)c67)cccc4-c4cc5c6ccccc6n6c7ccccc7c(c4)c56)c4cc(C(C)(C)C)cc2c43)cc1 ; [2H]c1c([2H])c2c(c([2H])c1-c1ccccc1)B1c3c(cc(C(C)(C)C)cc3N(c3c(-c4cc5c6ccccc6n6c7ccccc7c(c4)c56)cc(C(C)(C)C)cc3-c3cc4c5ccccc5n5c6ccccc6c(c3)c45)c3c([2H])c([2H])c(-c4ccccc4)c([2H])c31)N2c1c(-c2ccc(-c3ccccc3)cc2)cc(C(C)(C)C)cc1-c1ccc(-c2ccccc2)cc1]

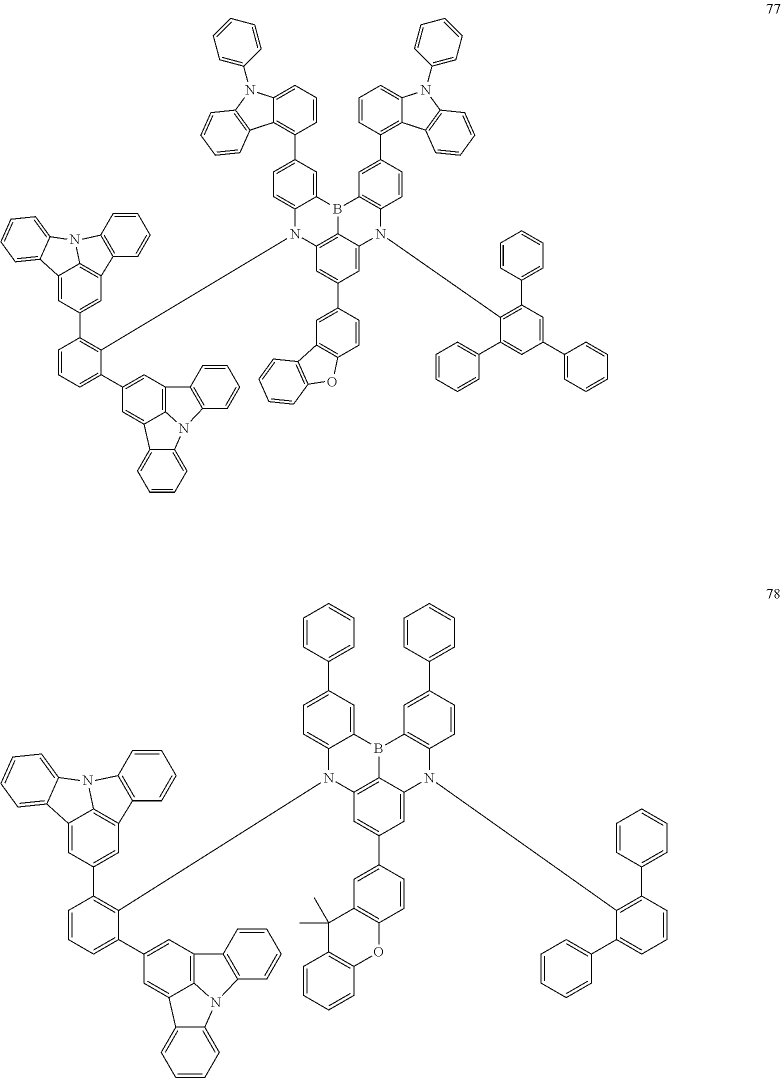 [SMILES: c1ccc(-c2cc(-c3ccccc3)c(N3c4ccc(-c5cccc6c5c5ccccc5n6-c5ccccc5)cc4B4c5cc(-c6cccc7c6c6ccccc6n7-c6ccccc6)ccc5N(c5c(-c6cc7c8ccccc8n8c9ccccc9c(c6)c78)cccc5-c5cc6c7ccccc7n7c8ccccc8c(c5)c67)c5cc(-c6ccc7oc8ccccc8c7c6)cc3c54)c(-c3ccccc3)c2)cc1 ; CC1(C)c2ccccc2Oc2ccc(-c3cc4c5c(c3)N(c3c(-c6cc7c8ccccc8n8c9ccccc9c(c6)c78)cccc3-c3cc6c7ccccc7n7c8ccccc8c(c3)c67)c3ccc(-c6ccccc6)cc3B5c3cc(-c5ccccc5)ccc3N4c3c(-c4ccccc4)cccc3-c3ccccc3)cc21]

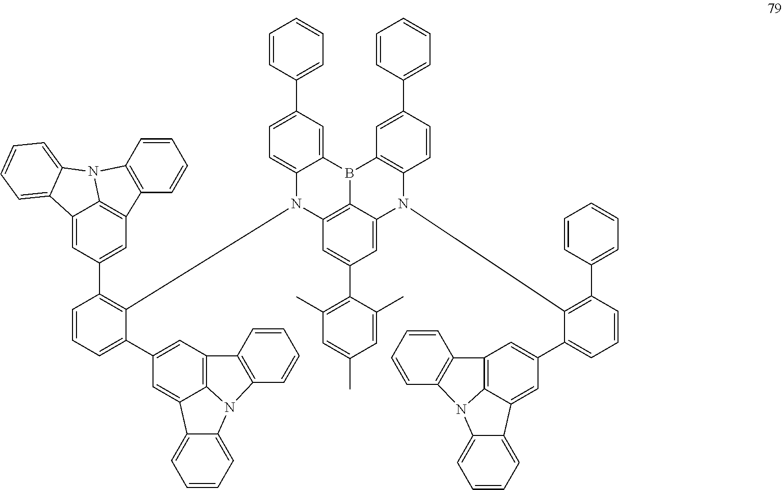 [SMILES: Cc1cc(C)c(-c2cc3c4c(c2)N(c2c(-c5cc6c7ccccc7n7c8ccccc8c(c5)c67)cccc2-c2cc5c6ccccc6n6c7ccccc7c(c2)c56)c2ccc(-c5ccccc5)cc2B4c2cc(-c4ccccc4)ccc2N3c2c(-c3ccccc3)cccc2-c2cc3c4ccccc4n4c5ccccc5c(c2)c34)c(C)c1]

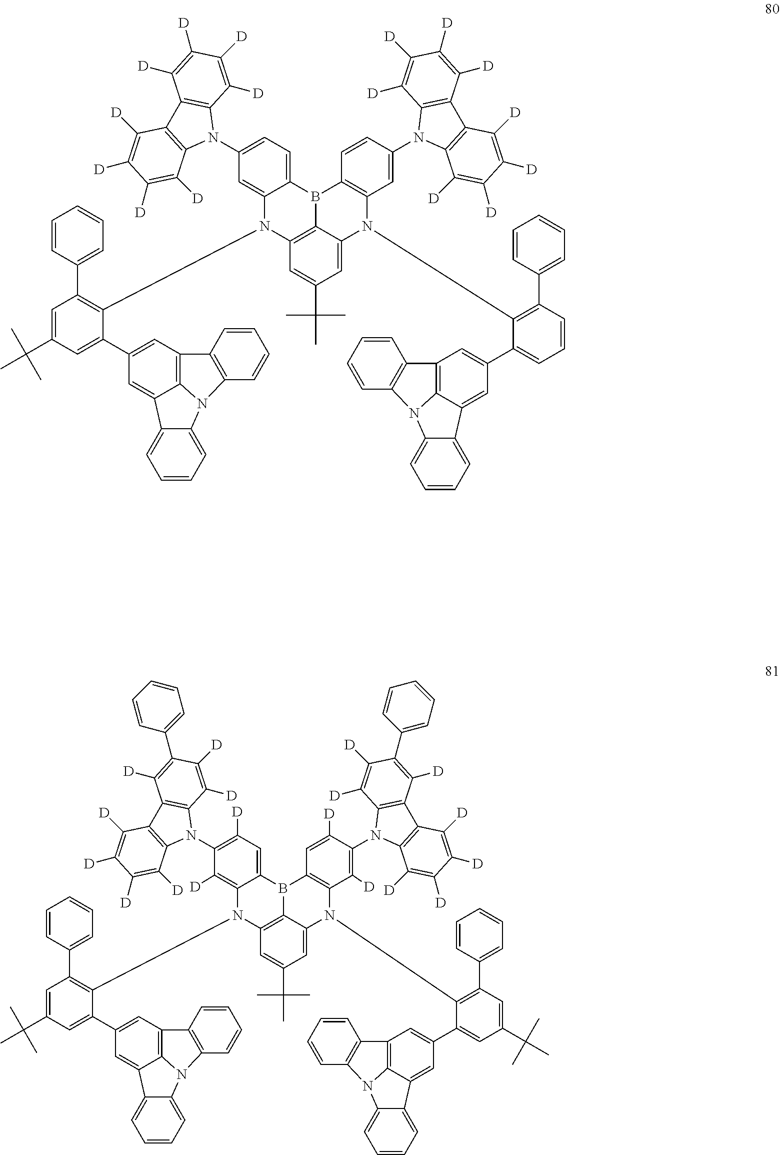

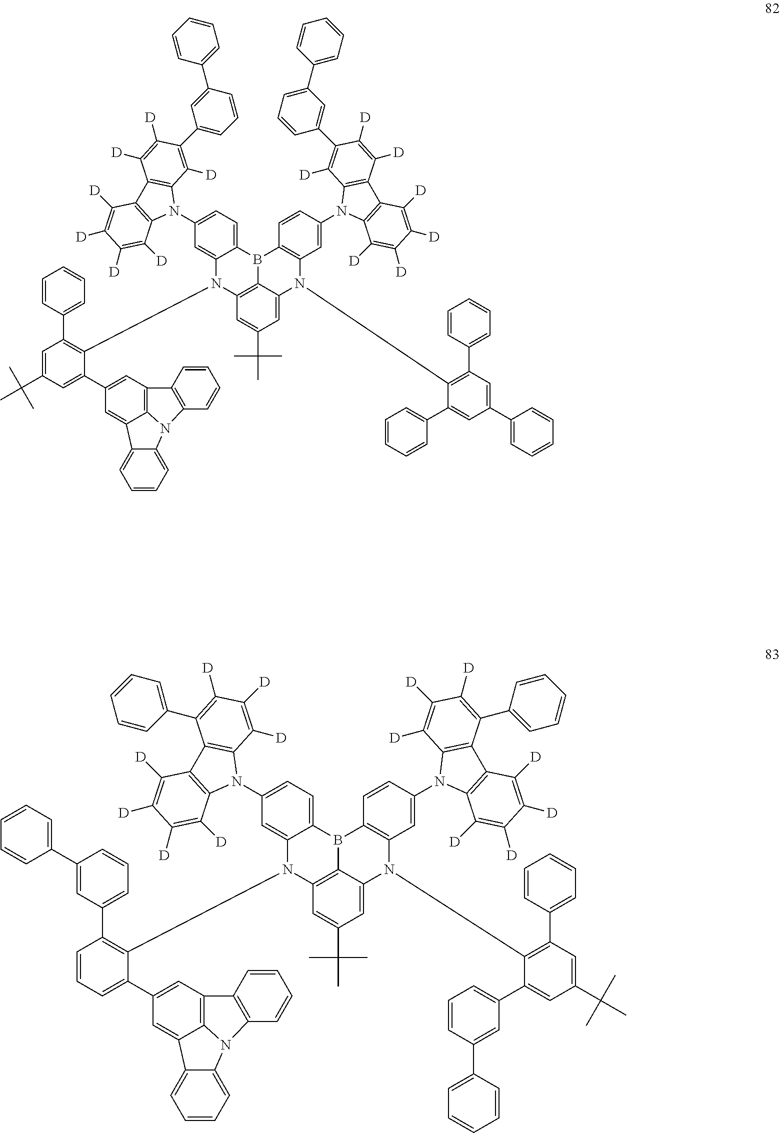

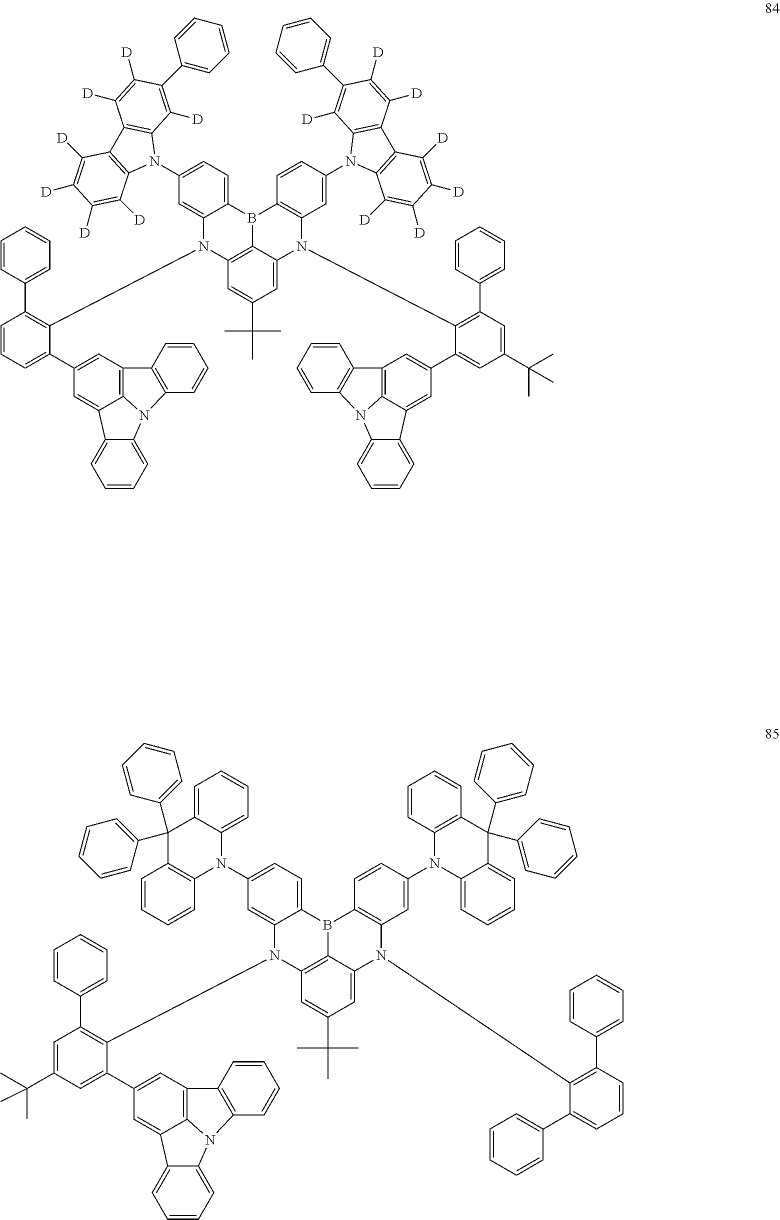

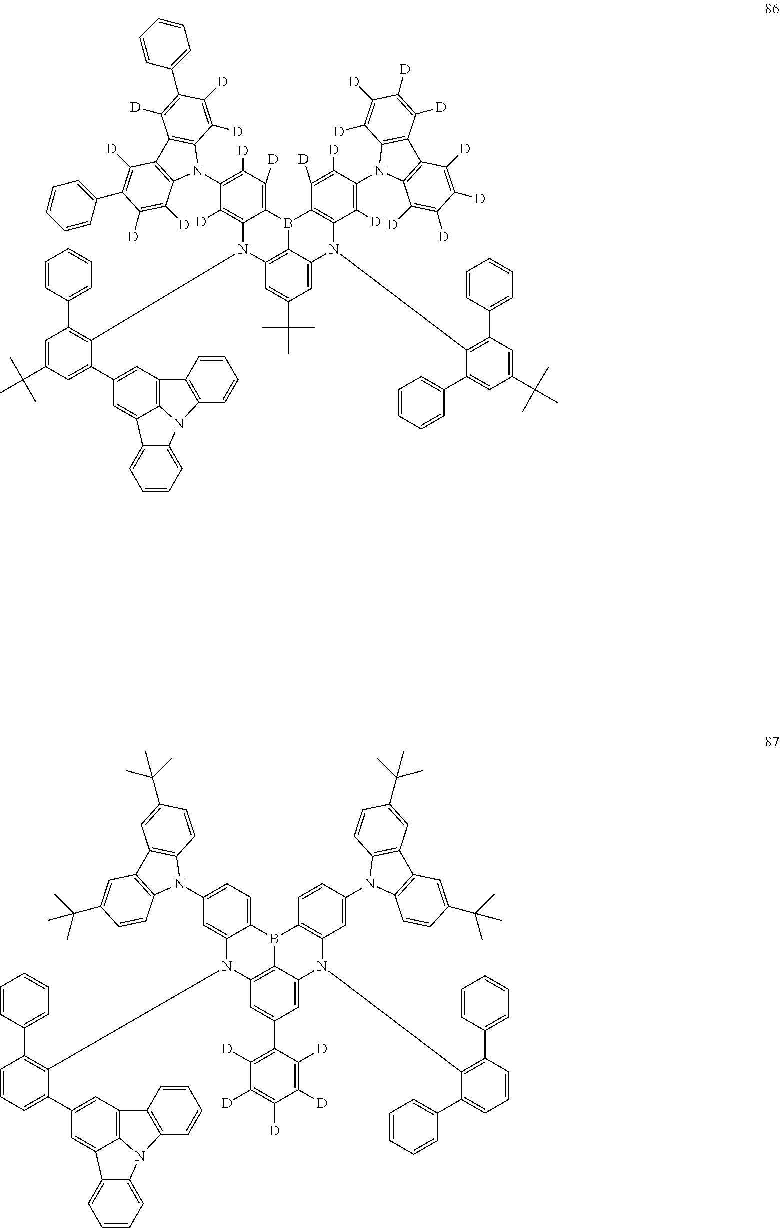

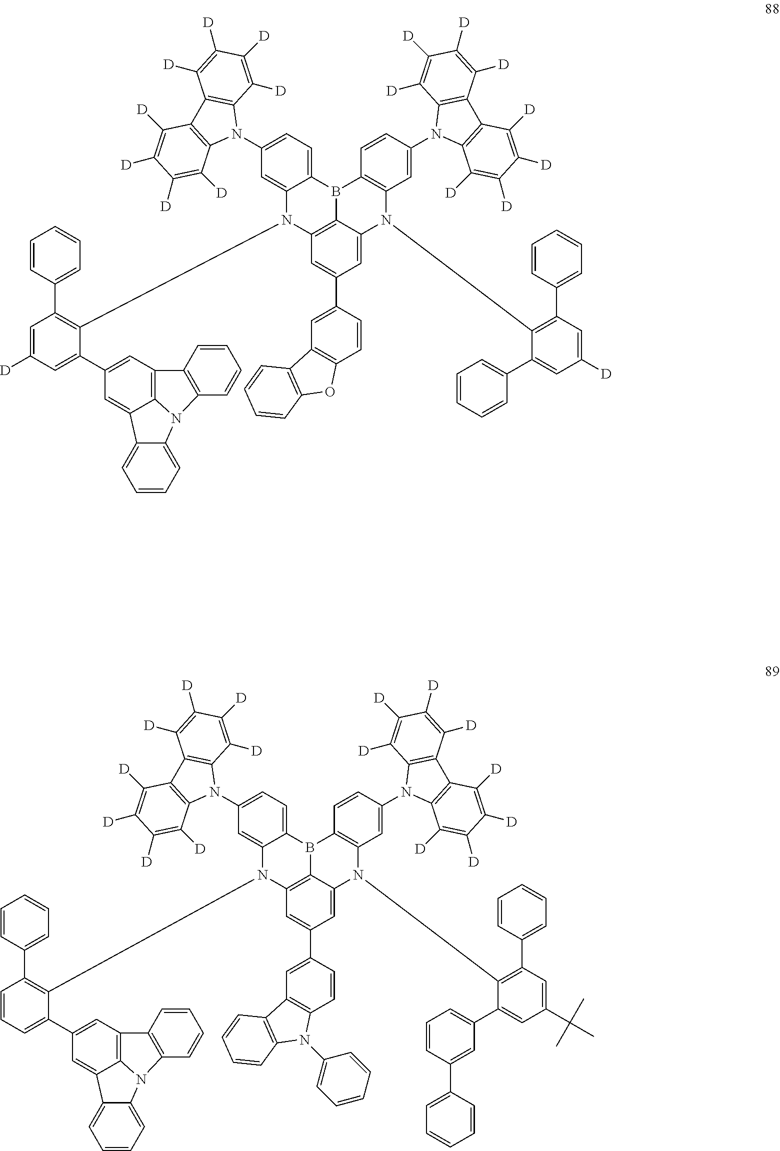

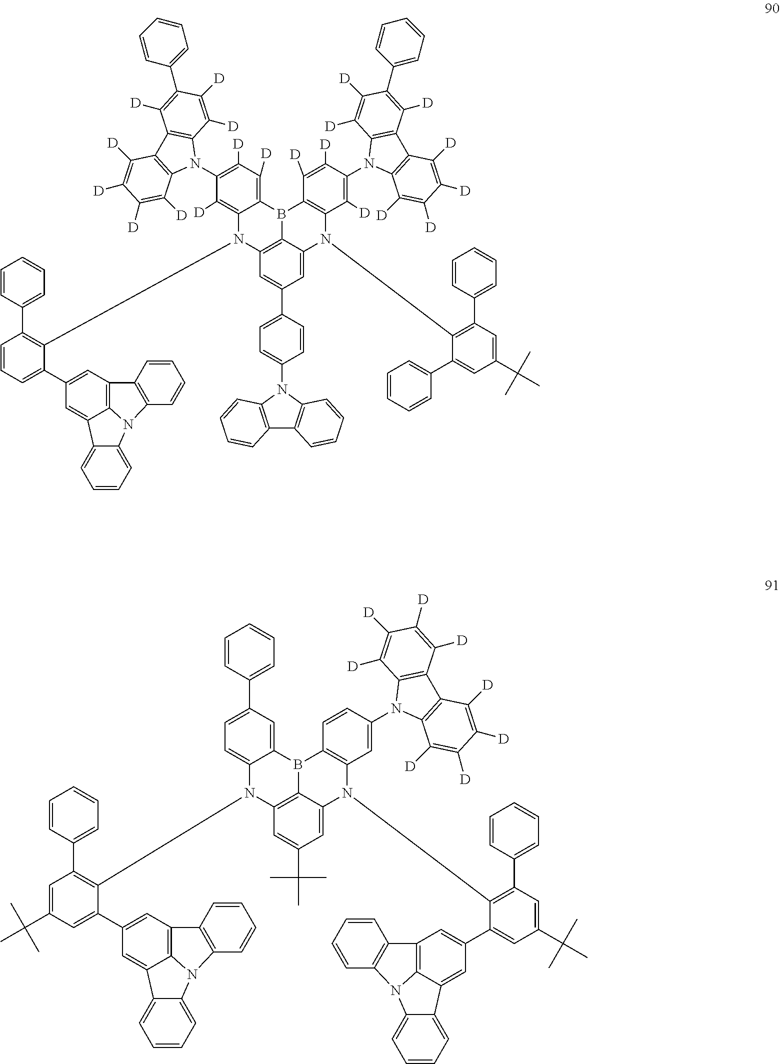

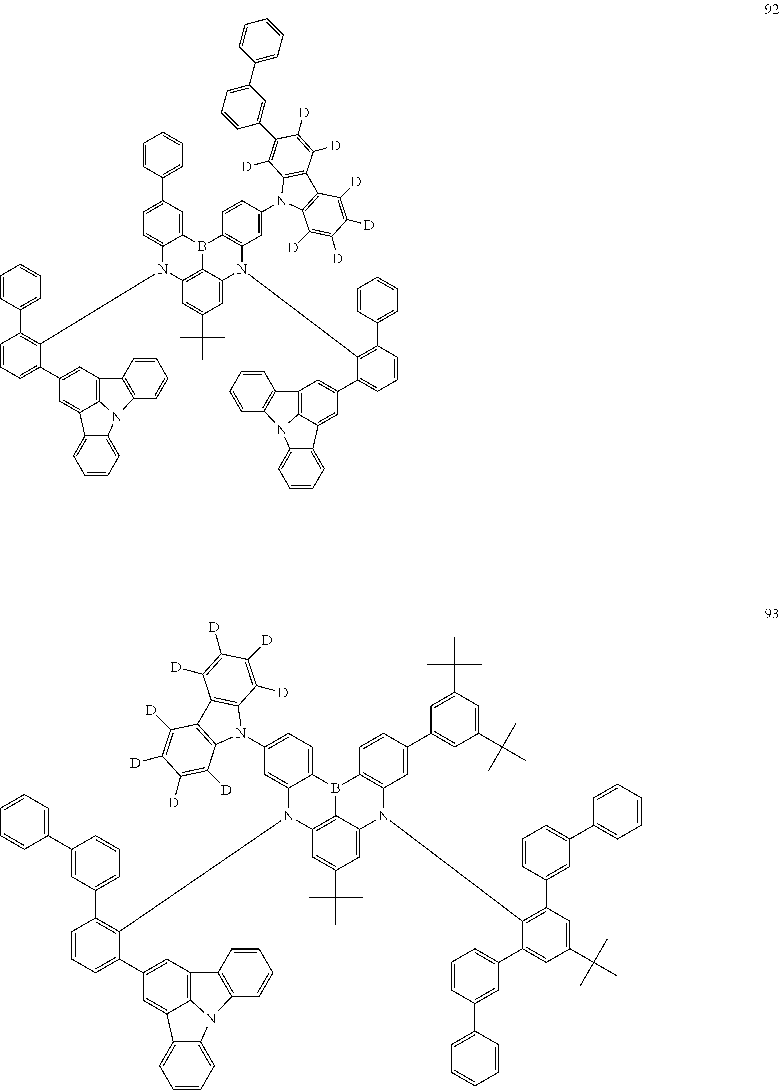

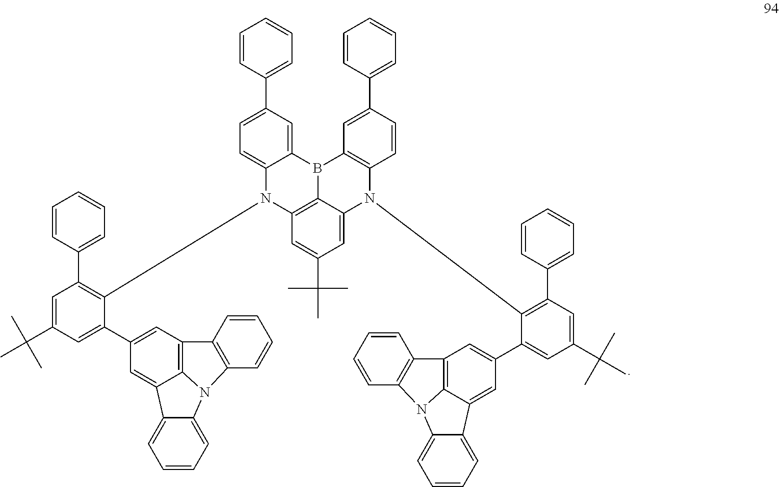 [SMILES: CC(C)(C)c1cc(-c2ccccc2)c(N2c3ccc(-c4ccccc4)cc3B3c4cc(-c5ccccc5)ccc4N(c4c(-c5ccccc5)cc(C(C)(C)C)cc4-c4cc5c6ccccc6n6c7ccccc7c(c4)c56)c4cc(C(C)(C)C)cc2c43)c(-c2cc3c4ccccc4n4c5ccccc5c(c2)c34)c1]

In Compound Group 1, D represents a deuterium atom.

The fused polycyclic compound represented by Formula 1 has a structure of a fused ring core that includes a first substituent, and may contribute to high emission efficiency and long lifetime in a light emitting element.

The fused polycyclic compound represented by Formula 1 has a structure in which multiple aromatic rings are fused together via a boron atom, a first nitrogen atom, and a first heteroatom, and further includes a first substituent that is bonded to the first nitrogen atom. The first substituent may include an indolocarbazole moiety and may be bonded to the fused ring core via a first linker.

The fused polycyclic compound may effectively maintain a trigonal planar structure of a boron atom through the steric hindrance effects of the first substituent. In the case of a boron atom, electron-deficient properties are shown due to a vacant p-orbital, and a bond may be formed with a nucleophile to transform the trigonal planar structure into a tetrahedral structure, which may contribute to the deterioration of a light emitting element. According to embodiments, since the fused polycyclic compound includes the first substituent that is bonded to the fused ring core, a vacant p-orbital of the boron atom may be effectively protected, thereby preventing the structural deterioration of the trigonal planar structure.

The steric hindrance effects of the first substituent may also suppress intermolecular interactions, so that the fused polycyclic compound may prevent or control the formation of aggregates, excimers, or exciplexes, and thereby contributing to increased emission efficiency. Since the fused polycyclic compound represented by Formula 1 has a bulky structure, intermolecular distance may be increased, and Dexter energy transfer may be suppressed. Accordingly, increased concentration of triplet excitons in the fused polycyclic compound may be prevented. A high concentration of triplet excitons may remain in an excited state for an extended period of time, which may lead to decomposition of the fused polycyclic compound, to the production of excitons having high energy produced through triplet-triplet annihilation (TTA), and to the structural decomposition of neighboring compounds. The phenomenon of the triplet-triplet annihilation corresponds to a bimolecular reaction that rapidly exhausts triplet excitons used for light emission, and a reduction of emission efficiency may be induced through non-radiative transition. By the inclusion of the first substituent in the fused polycyclic compound, intermolecular distance may increase by the suppression of Dexter energy transfer, and the deterioration of lifetime due to increased triplet exciton concentration may be prevented. Accordingly, when the fused polycyclic compound is applied to an emission layer EML of the light emitting element ED, emission efficiency may be increased, and element lifetime may also be improved.

By the inclusion of the first substituent, the through-space charge transfer (TSCT) of the fused polycyclic compound may be increased in addition to through-bond charge transfer (TBCT), reverse intersystem crossing (RISC) may be promoted, and emission efficiency may be improved. Since the fused polycyclic compound has a structure in which a fused ring core and an indolocarbazole moiety are connected via the first linker at an ortho position to each other, the fused ring core and the indolocarbazole moiety may have a co-facial configuration. Accordingly, π-π interaction between the indolocarbazole moiety and the fused ring core may become possible, and radiative decay may be increased. For example, as shown in Formula A, since the fused polycyclic compound represented by Formula 1 has a structure in which the fused ring core and the indolocarbazole moiety are connected via a phenylene linker, the indolocarbazole moiety and the fused ring core may have co-facial configuration so that they are positioned adjacently to each other in a three-dimensional space. Accordingly, the fused polycyclic compound may show effects of promoting RISC through 71-71 interaction between the nitrogen atom of the indolocarbazole moiety and the boron atom of the fused ring core, in addition to protecting the vacant p-orbitals of the boron atom by the indolocarbazole moiety.

In the specification, through-bond charge transfer (TBCT) may refer to a charge transfer phenomenon of an electron donor and an electron acceptor in a molecule through a conjugation bond structure, and through-space charge transfer (TSCT) may refer to a charge transfer phenomenon of an electron donor and an electron acceptor, if positioned adjacently in a three-dimensional space, even though they are not connected via a covalent bond. The fused polycyclic compound may induce through-space charge transfer (TSCT) by the inclusion of the first substituent, in addition to through-bond charge transfer (TBCT) produced in the fused ring core with the boron atom as a center, and the charge transfer mode of the molecule may be increased. Accordingly, the fused polycyclic compound may have high reverse intersystem crossing (RISC) efficiency and may show improved thermally activated delayed fluorescence (TADF) properties.

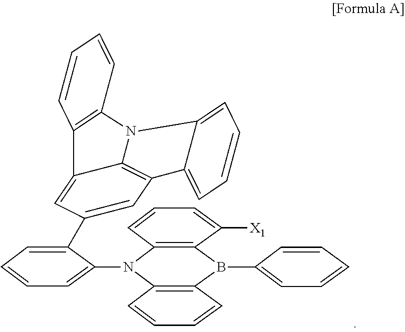

Since a rigid indolocarbazole moiety and the fused ring core are bonded via a phenylene linker at an ortho position to each other, a molecule of the fused polycyclic compound may have increased rigidity as a whole, structural change in an excited state and a ground state may be minimized, Stokes shift may be largely reduced, and emission of blue light with high color purity may be achieved. Accordingly, if the fused polycyclic compound is included as a delayed fluorescence dopant, emission efficiency and color purity may be improved.

Since the fused polycyclic compound has synergistically increasing effects of steric hindrance effects, intramolecular charge transfer properties, and intramolecular rigidity properties, when it is included as a material for an emission layer of a light emitting element, high efficiency and long lifetime may be achieved.

A full width at half maximum (FWHM) of an emission spectrum of the fused polycyclic compound may be in a range of about 10 nm to about 50 nm. For example, the FWHM of an emission spectrum of the fused polycyclic compound may be in a range of about 20 nm to about 40 nm. Since a FWHM of an emission spectrum of the fused polycyclic compound is within the above-described range, when the fused polycyclic compound is included as a material in a light emitting element, emission efficiency may be improved. When the fused polycyclic compound is included as a material of a blue light emitting element, element lifetime may be improved.

The fused polycyclic compound may be a material for emitting thermally activated delayed fluorescence (TADF). For example, the fused polycyclic compound may be a thermally activated delayed fluorescence dopant having a difference (expressed as ΔE_{ST}) between a lowest triplet excitation energy level (T1 level) and a lowest singlet excitation energy level (Si level) equal to or less than about 0.6 eV. For example, the fused polycyclic compound may be a thermally activated delayed fluorescence dopant having a difference (ΔE_{ST}) between a lowest triplet excitation energy level (T1 level) and a lowest singlet excitation energy level (Si level) equal to or less than about 0.2 eV.

The fused polycyclic compound may be a light-emitting material having a central wavelength in a range of about 430 nm to about 490 nm. For example, the fused polycyclic compound may be a blue thermally activated delayed fluorescence (TADF) dopant. However, embodiments are not limited thereto, and if the fused polycyclic compound is used as a light-emitting material, the fused polycyclic compound may be used as a dopant material emitting light in various wavelength regions, such as a red emitting dopant or a green emitting dopant.

In the light emitting element ED, the emission layer EML may emit delayed fluorescence. For example, the emission layer EML may emit thermally activated delayed fluorescence (TADF).

The emission layer EML of the light emitting element ED may emit blue light. The emission layer EML of the light emitting element ED may emit blue light having a central wavelength equal to or less than about 490 nm. However, embodiments are not limited thereto, and the emission layer EML may emit green light or red light.

The fused polycyclic compound may be included in an emission layer EML. The fused polycyclic compound may be included in an emission layer EML as a dopant material. The fused polycyclic compound may be a thermally activated delayed fluorescence material. The fused polycyclic compound may be used as a thermally activated delayed fluorescence dopant. For example, in the light emitting element ED, the emission layer EML may include at least one fused polycyclic compound selected from Compound Group 1 as a thermally delayed fluorescence dopant. However, the use of the fused polycyclic compound is not limited thereto.

In an embodiment, the emission layer EML may include multiple compounds. The emission layer EML may include the fused polycyclic compound represented by Formula 1 as a first compound, and at least one of a second compound represented by Formula HT-1, a third compound represented by Formula ET-1 and a fourth compound represented by Formula D-1.

In an embodiment, the emission layer EML may include the first compound represented by Formula 1, and may further include at least one of a second compound represented by Formula HT-1 and a third compound represented by Formula ET-1.

In an embodiment, the emission layer EML may further include a second compound represented by Formula HT-1. In an embodiment, the second compound may be used as a hole transport host material in the emission layer EML.

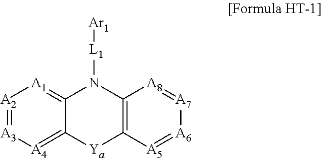

In Formula HT-1, A₁ to A₈ may each independently be N or C(R₄₁). For example, all A₁ to A₈ may each independently be C(R₅₁). As another example, one of A₁ to A₈ may be N, and the remainder of A₁ to A₈ may each independently be C(R₅₁).

In Formula HT-1, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, or the like, but embodiments are not limited thereto.

In Formula HT-1, Yₐ may be a direct linkage, C(R₅₂)(R₅₃), or Si(R₅₄)(R₅₅). For example, the two benzene rings that are bonded to the nitrogen atom of Formula HT-1 may be bonded to each other via a direct linkage,

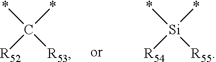

In Formula HT-1, if Yₐ is a direct linkage, the second compound represented by Formula HT-1 may include a carbazole moiety.

In Formula HT-1, Ar₁ may be a substituted or unsubstituted aryl group of 6 to 30 ring-forming carbon atoms or a substituted or unsubstituted heteroaryl group of 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, or the like, but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, the second compound represented by Formula HT-1 may be selected from Compound Group 2. In an embodiment, in the light emitting element ED, the second compound may include at least one compound selected from Compound Group 2:

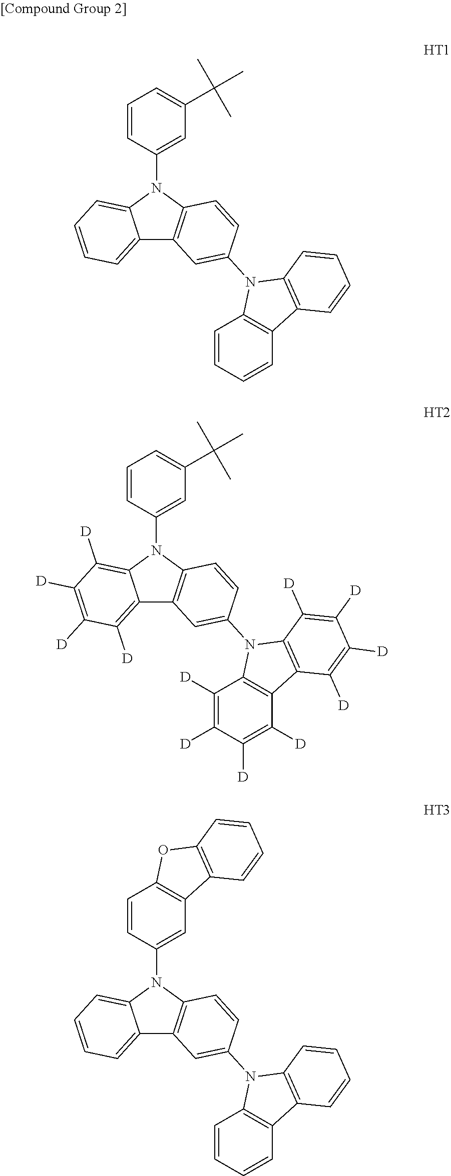

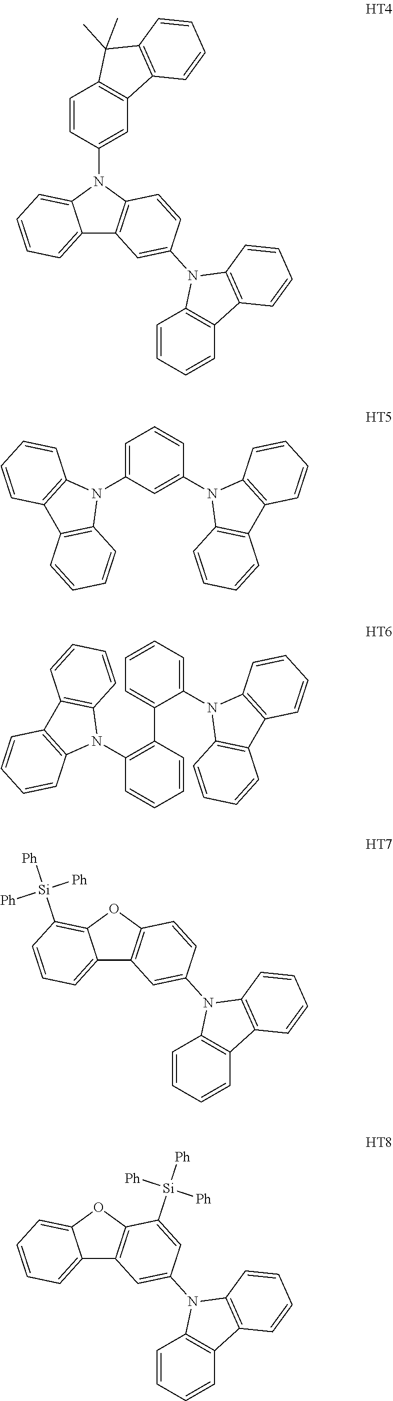 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

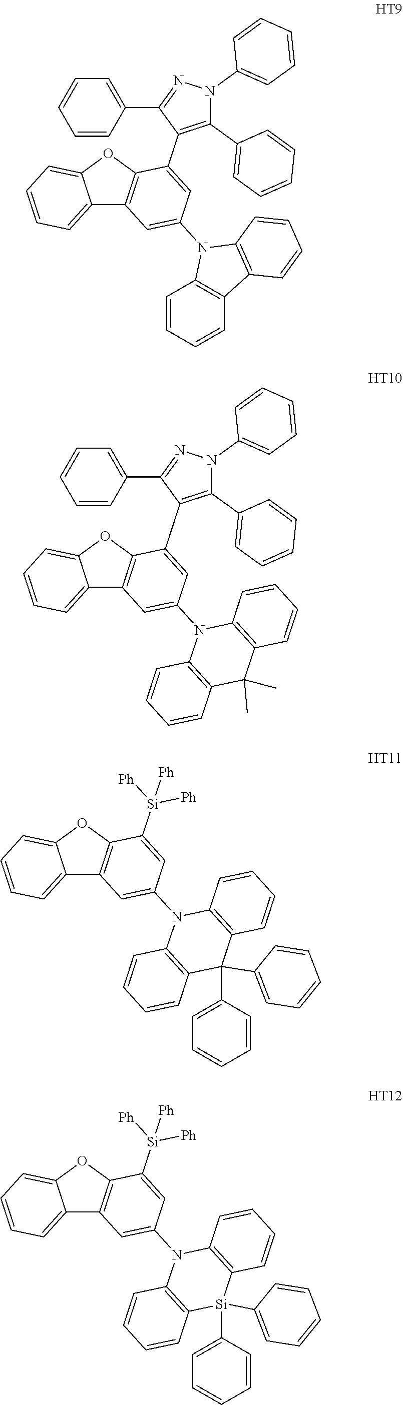 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

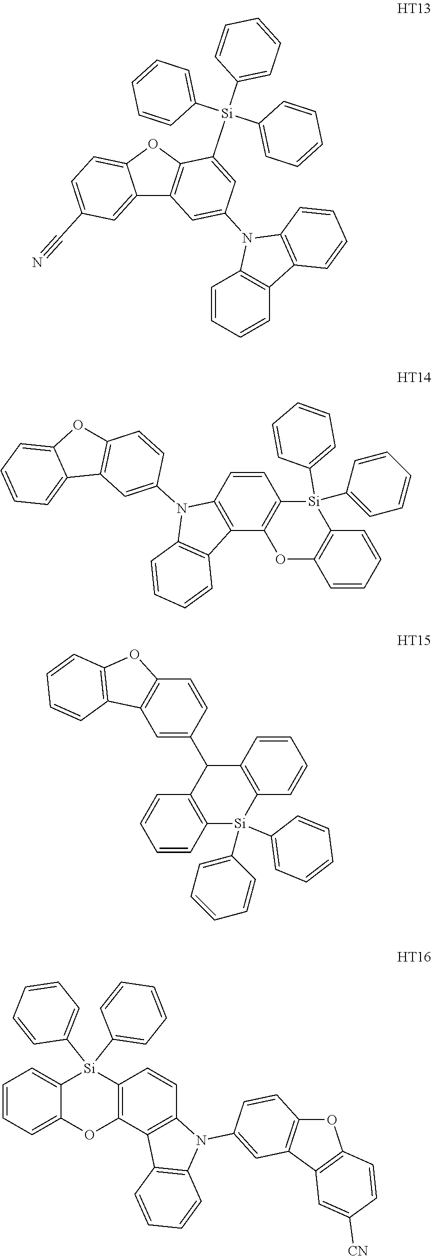 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3C(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

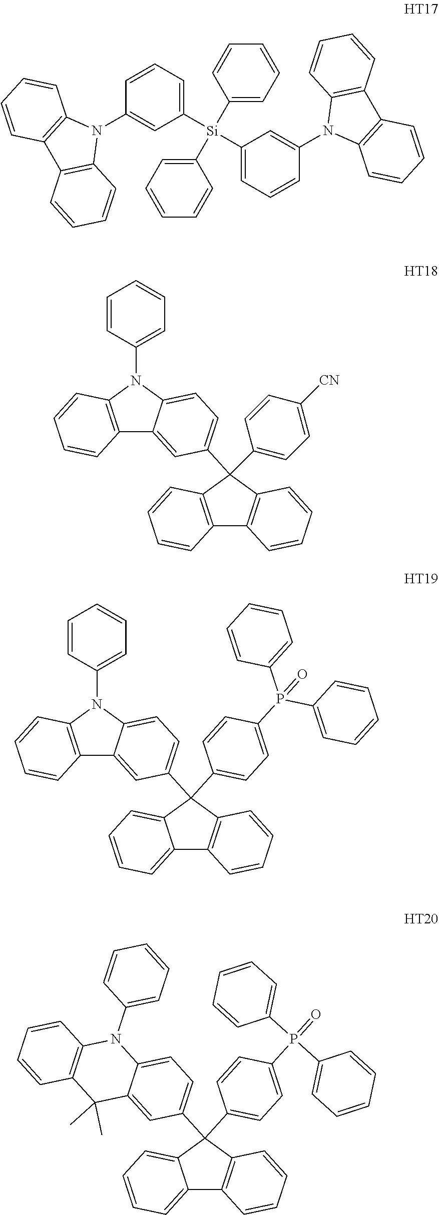 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

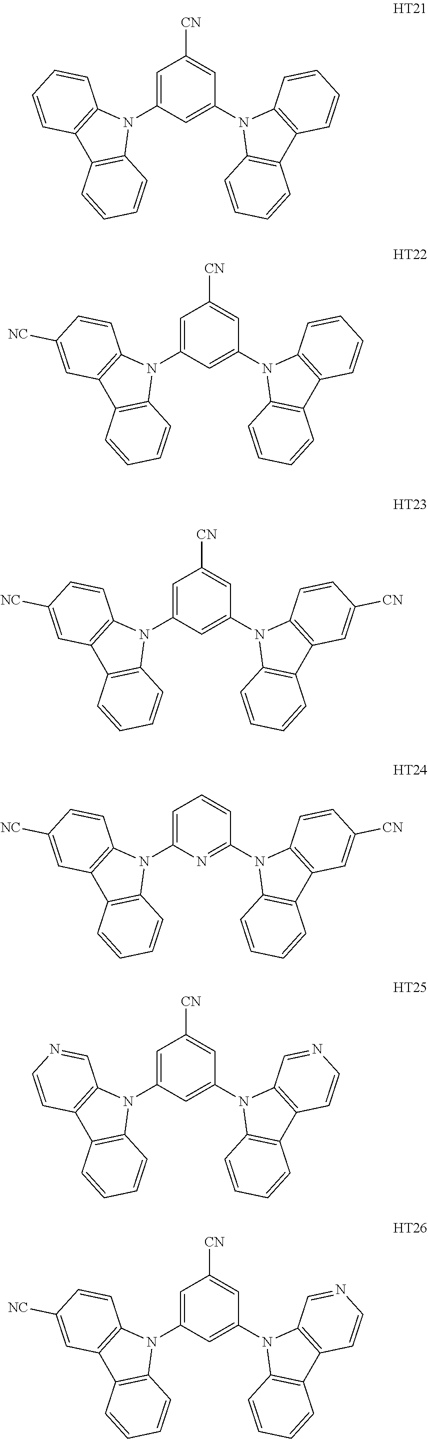 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

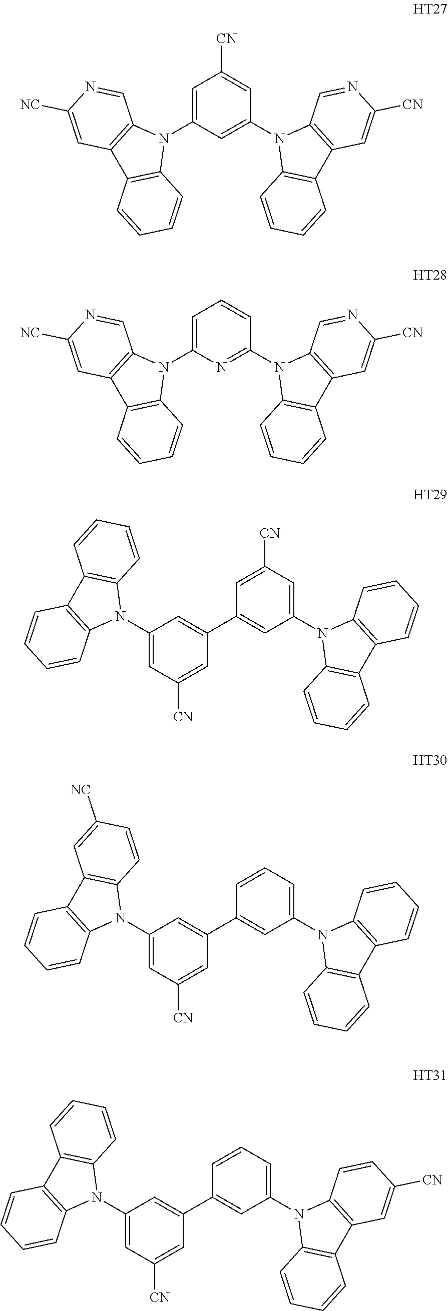 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

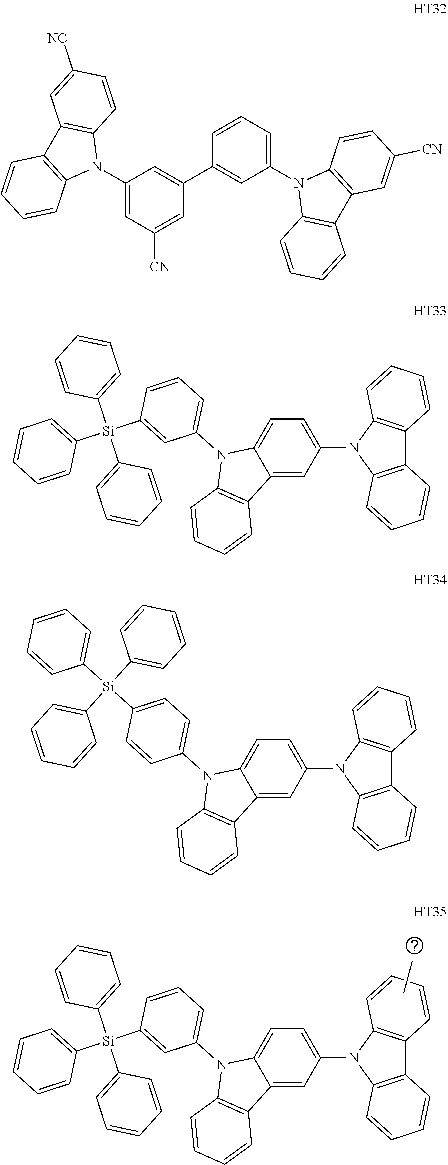

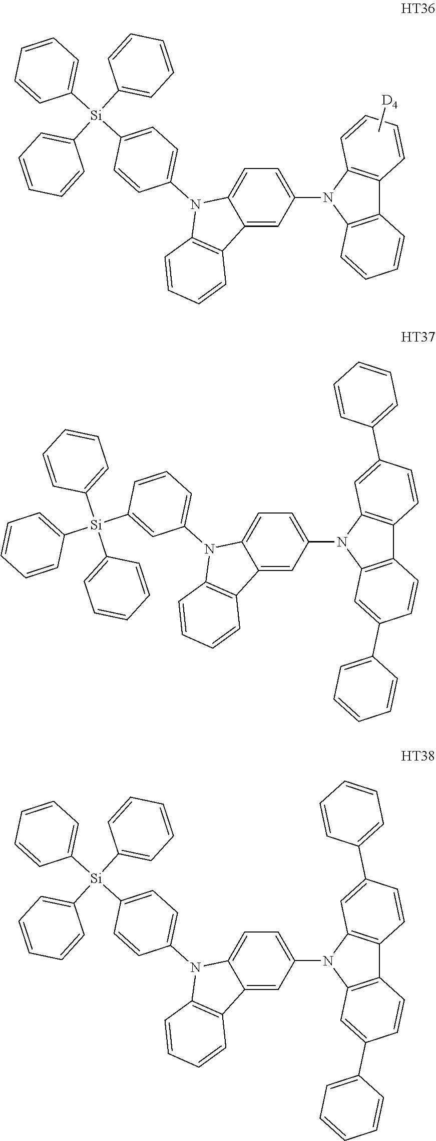

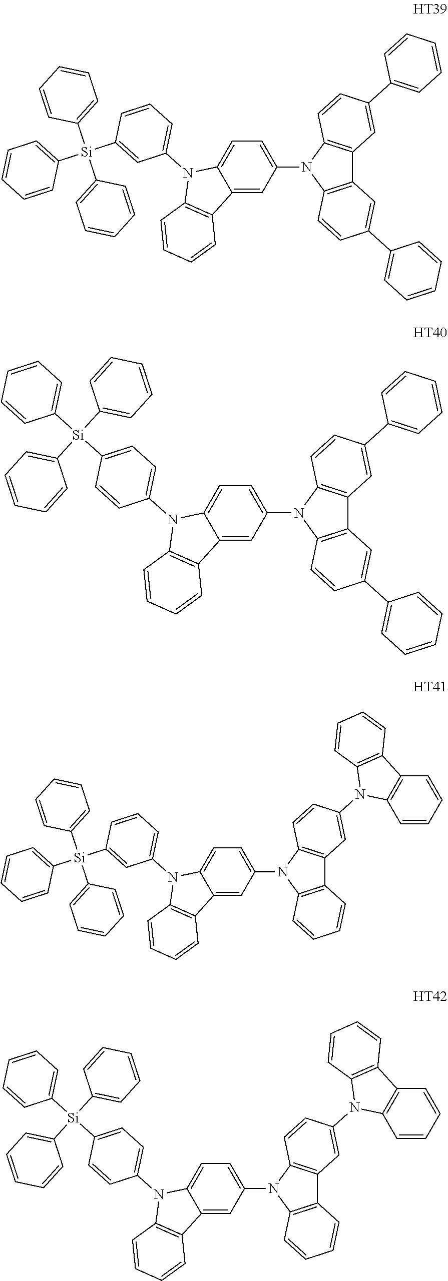 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

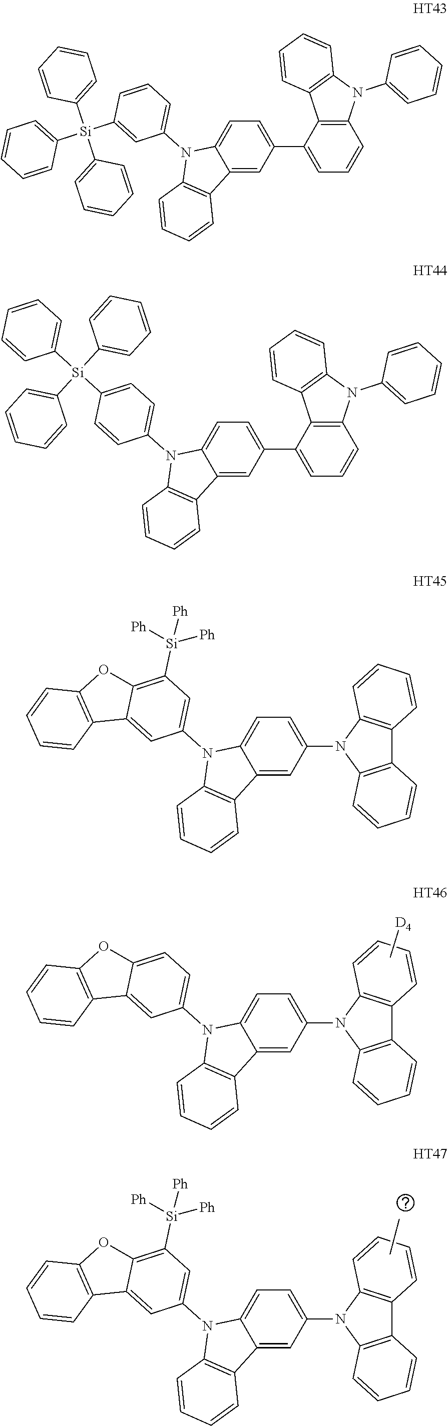

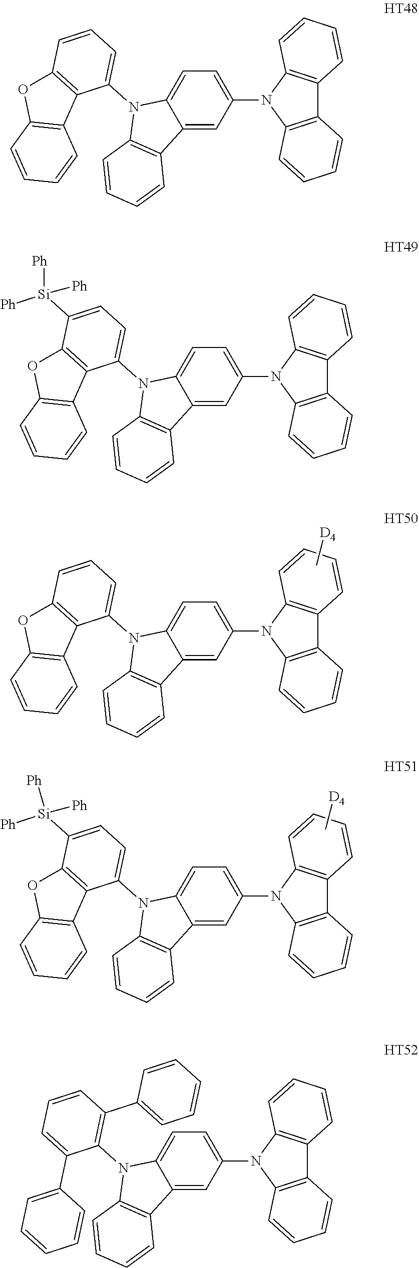

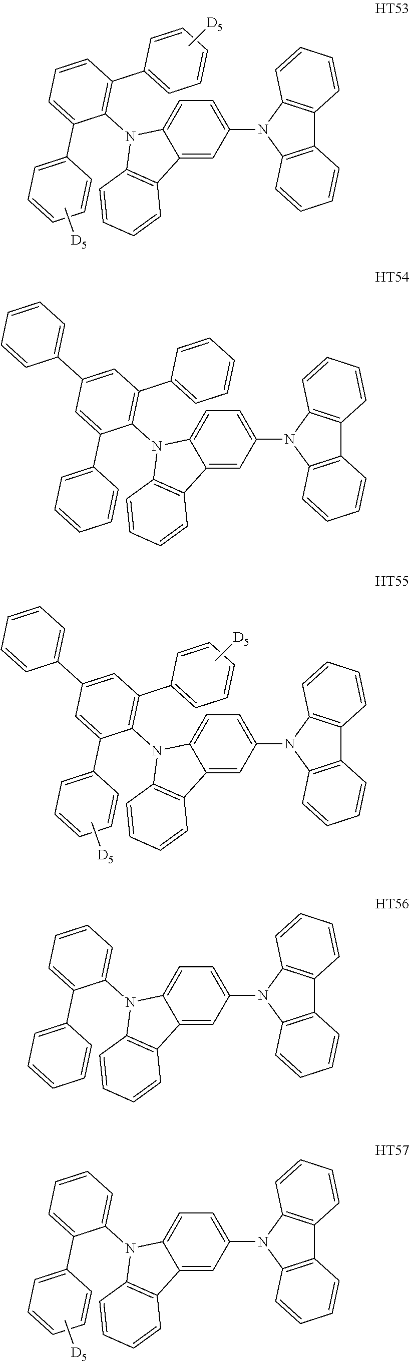

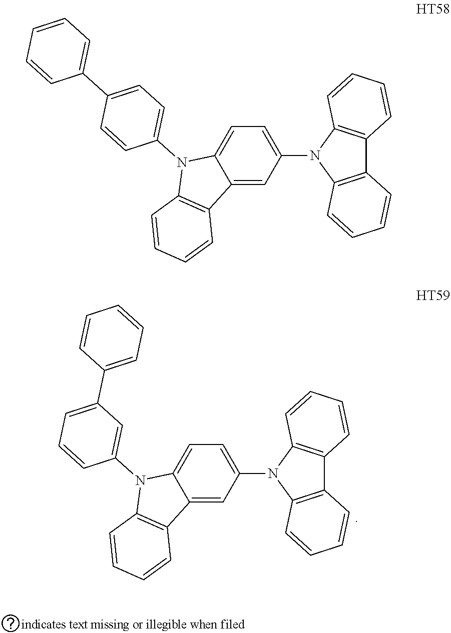 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In Compound Group 2, D represents a deuterium atom, and Ph represents a substituted or unsubstituted phenyl group. For example, in Compound Group 2, Ph may represent an unsubstituted phenyl group.

In an embodiment, the emission layer EML may further include a third compound represented by Formula ET-1. In an embodiment, the third compound may be used as an electron transport host material in the emission layer EML.

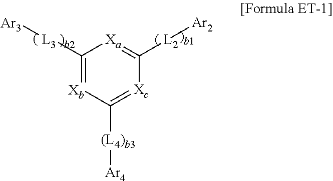

In Formula ET-1, at least one of Xₐ to X_{c} may each be N, and the remainder of Xₐ to X_{c} may each independently be C(R₅₆). For example, one of Xₐ to X_{c} may be N, and the remainder of Xₐ to X_{c} may each independently be C(R₅₆). Thus, the third compound represented by Formula ET-1 may include a pyridine moiety. As another example two of Xₐ to X_{c} may each be N, and the remainder of Xₐ to X_{c} may be C(R₅₆). Thus, the third compound represented by Formula ET-1 may include a pyrimidine moiety. As yet another example, Xₐ to X_{c} may each be N. Thus, the third compound represented by Formula ET-1 may include a triazine moiety.

In Formula ET-1, R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer from 0 to 10.

In Formula ET-1, Ar₂ to Ar₄ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms. If b1 to b3 are each 2 or more, multiple groups of each of L₂ to L₄ may each independently be a substituted or unsubstituted arylene group of 6 to 30 ring-forming carbon atoms or a substituted or unsubstituted heteroarylene group of 2 to 30 ring-forming carbon atoms.

In an embodiment, the third compound represented by Formula ET-1 may be selected from Compound Group 3. In an embodiment, in the light emitting element ED, the third compound may include at least one compound selected from Compound Group 3:

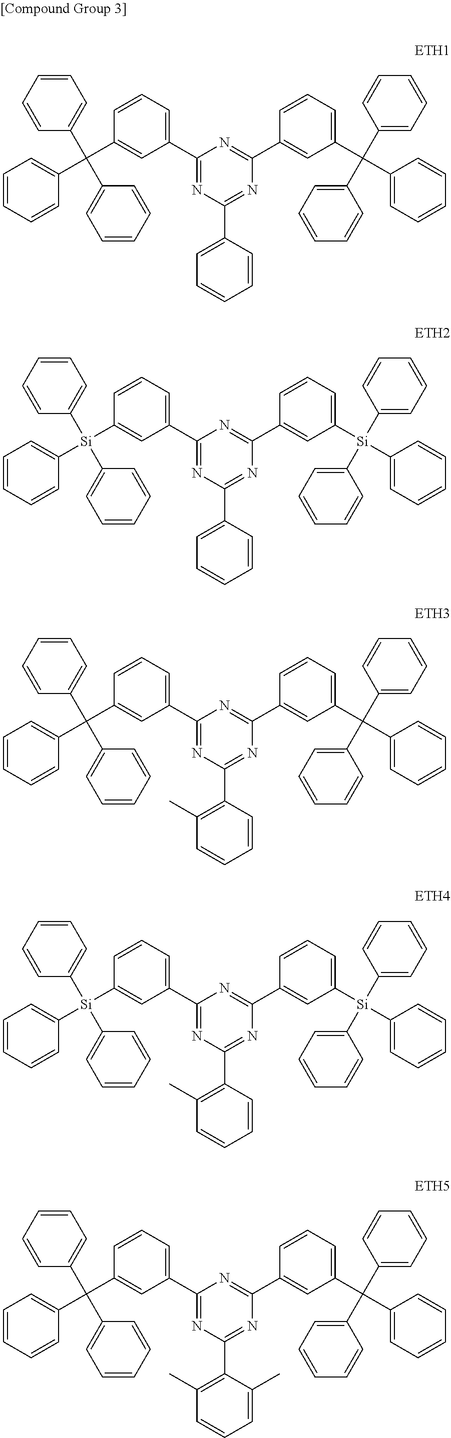

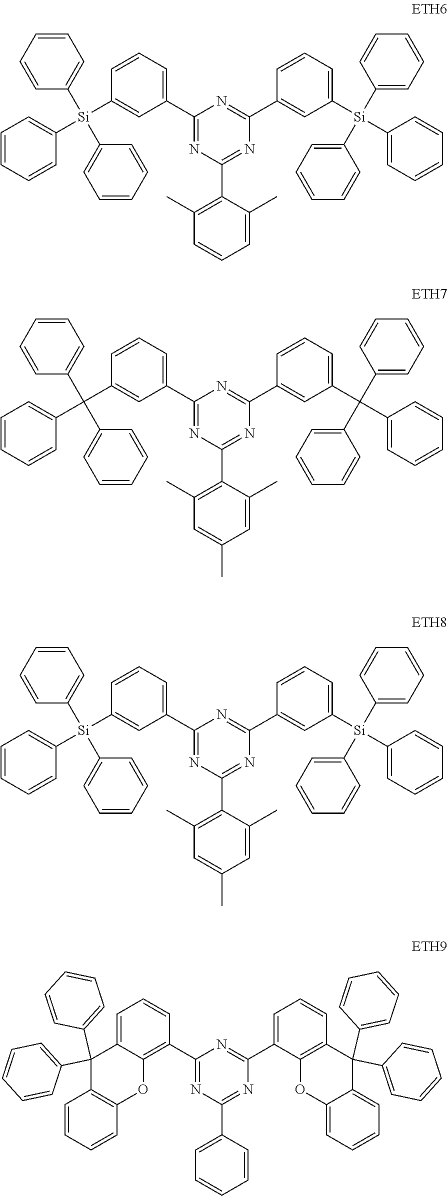 [SMILES: Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1 ; c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1]

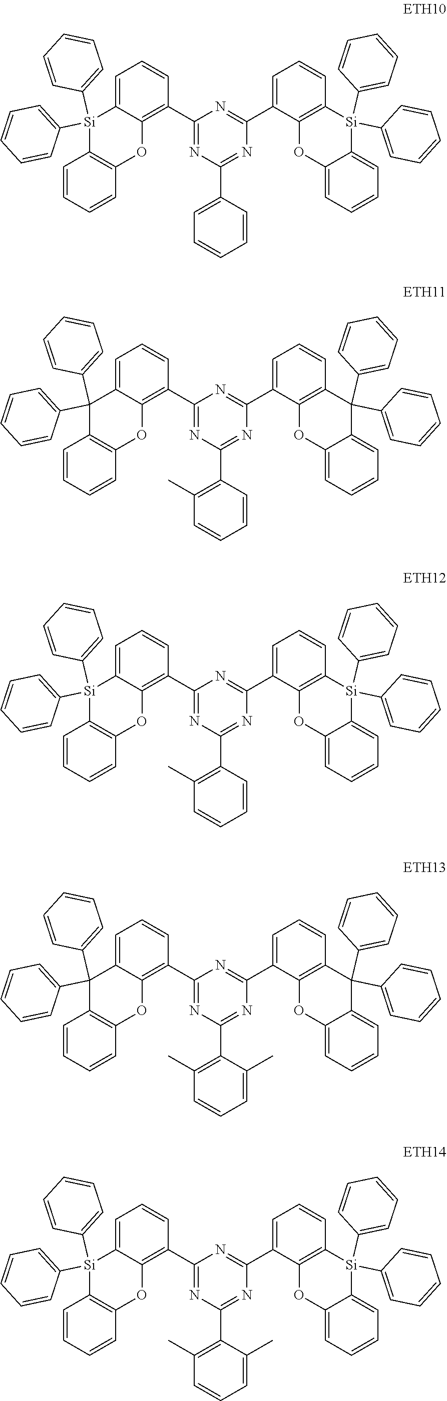

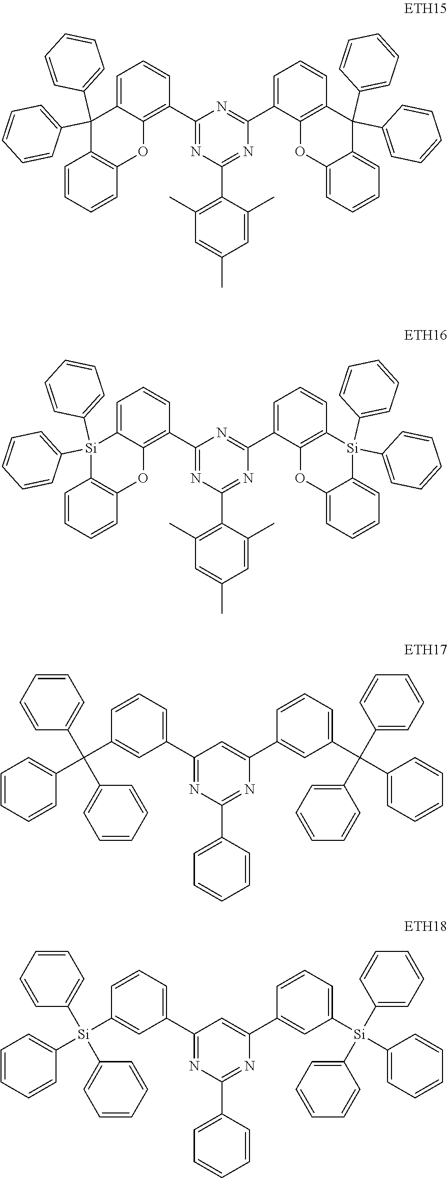 [SMILES: Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1 ; c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1]

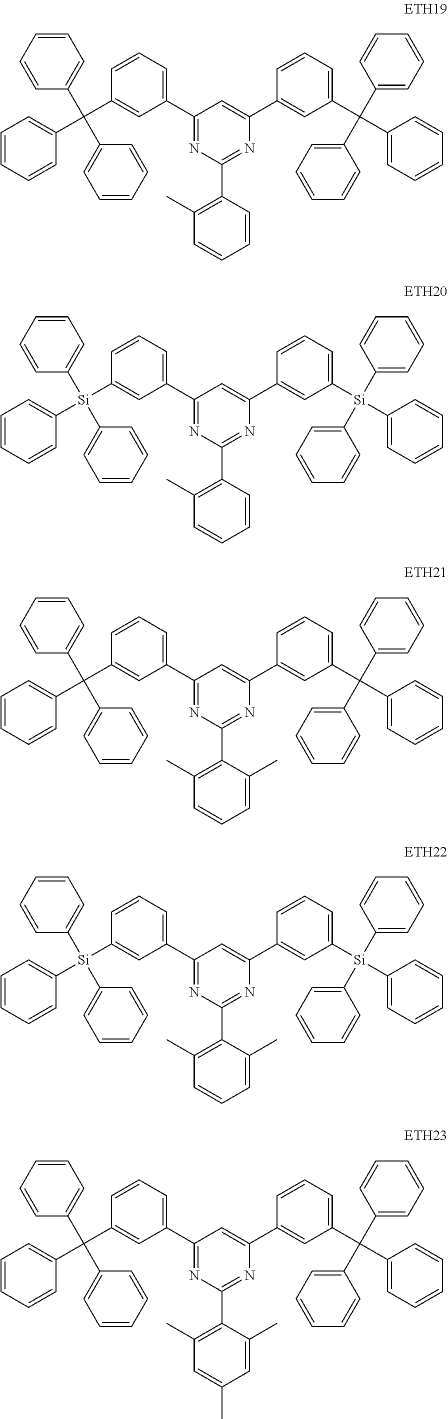

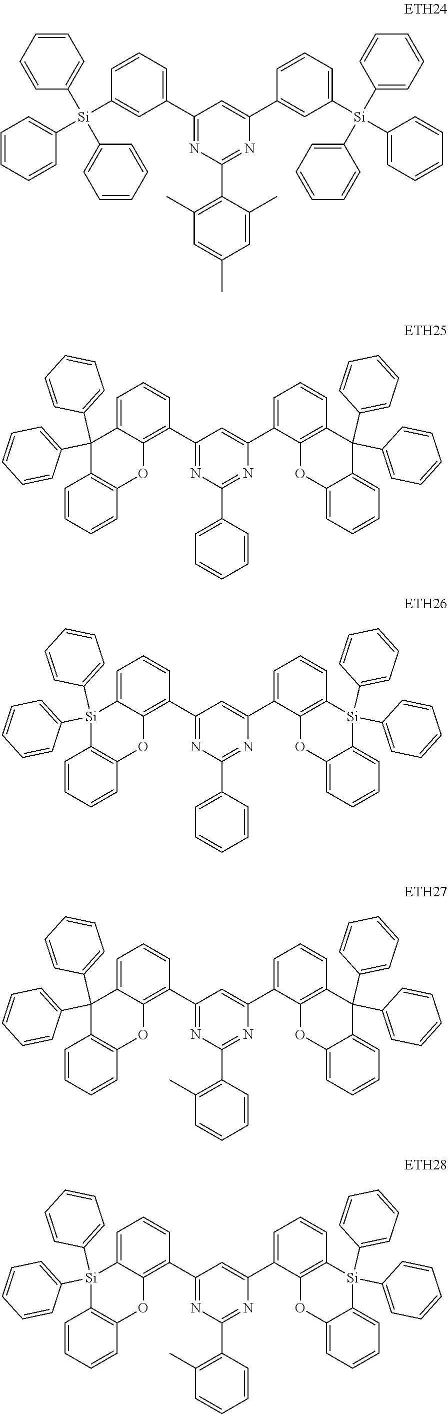

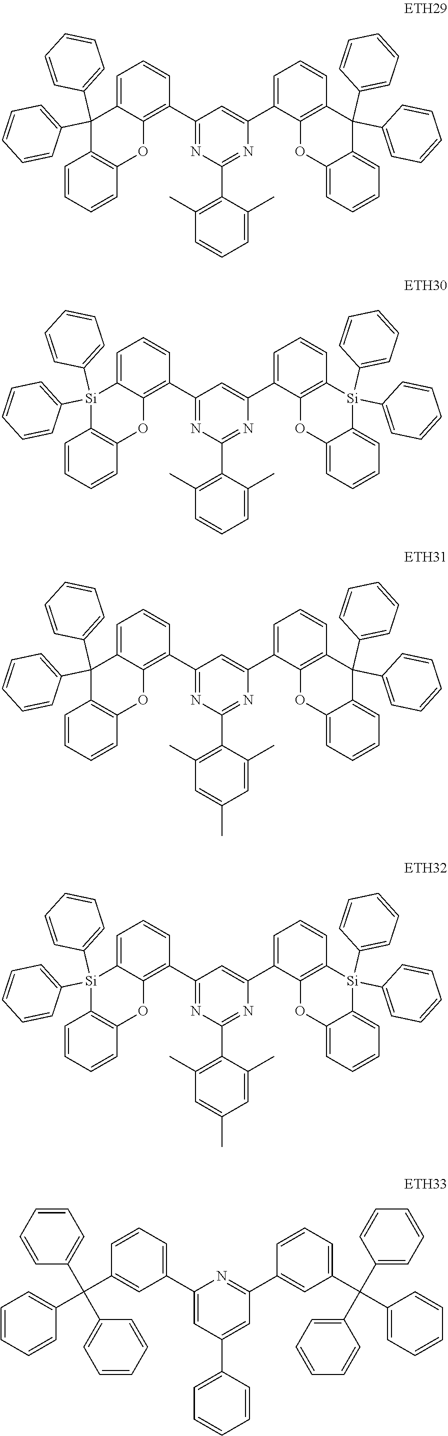

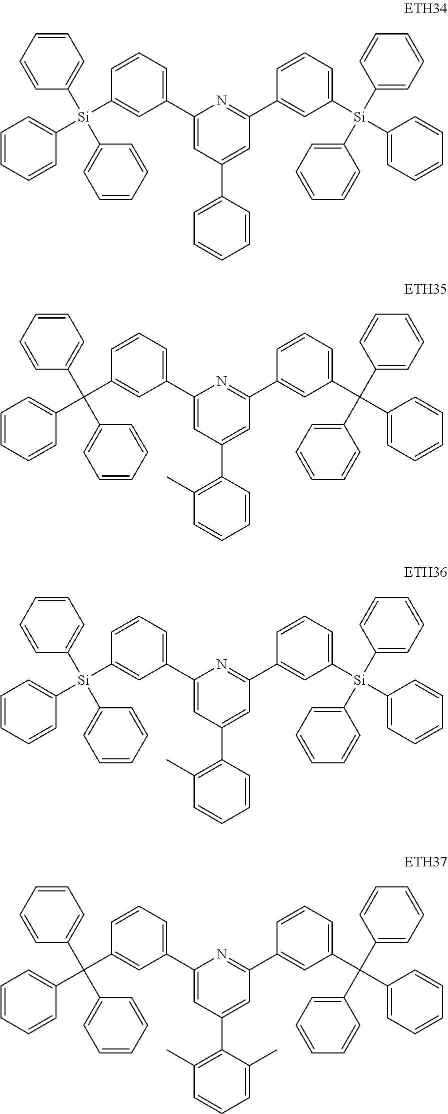 [SMILES: c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1]

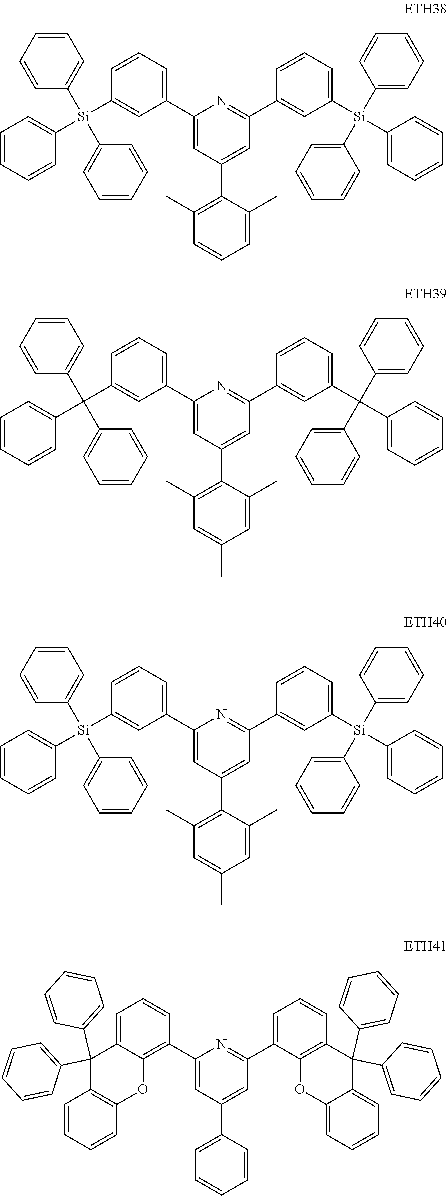 [SMILES: Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1 ; c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1]

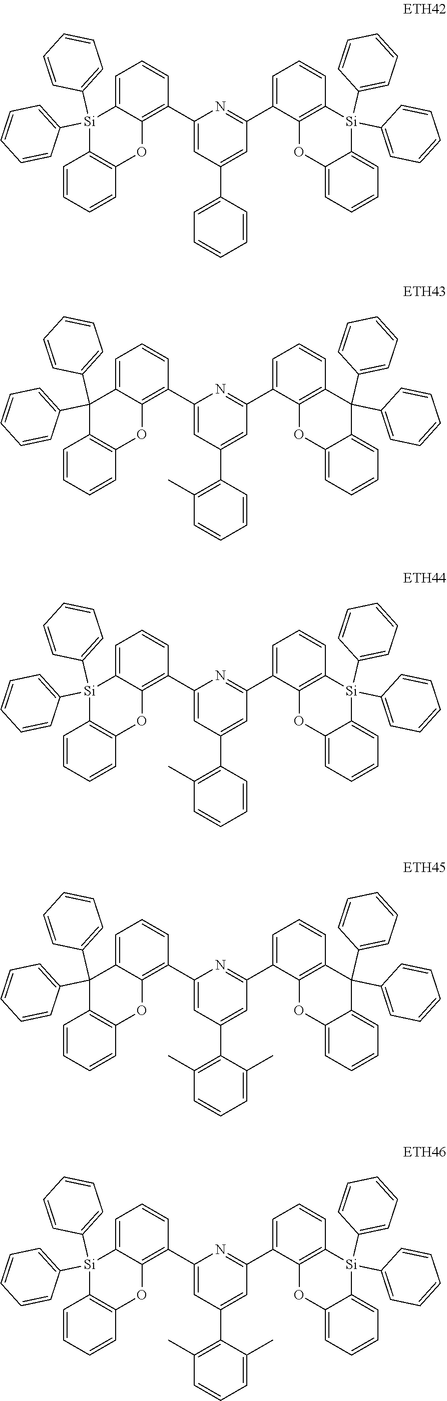

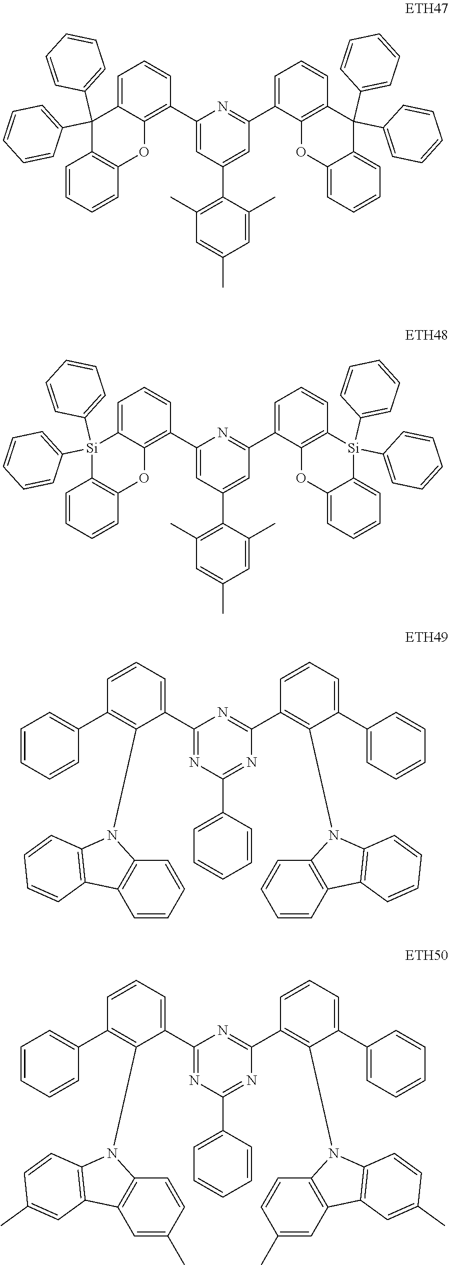

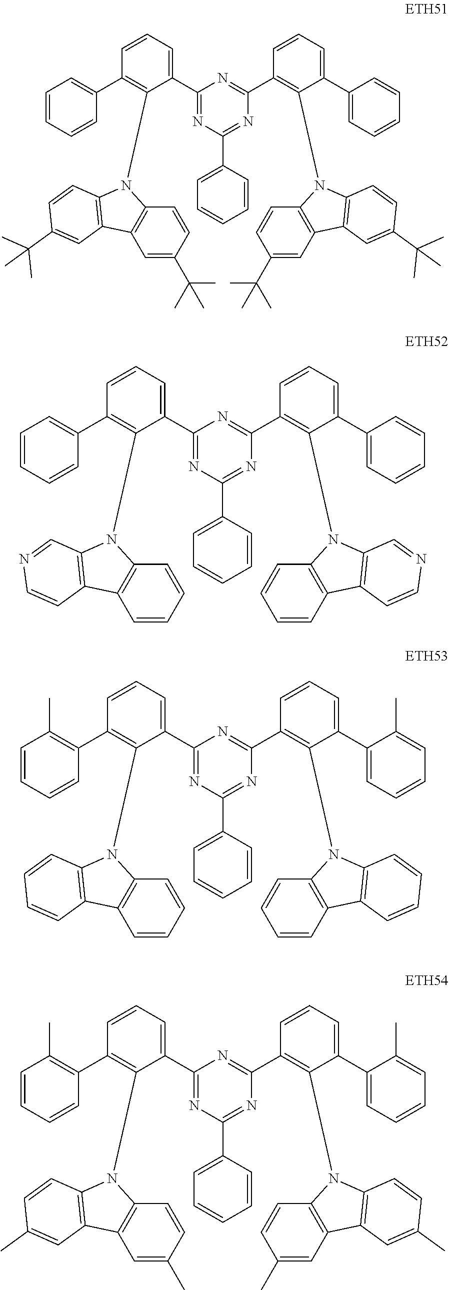

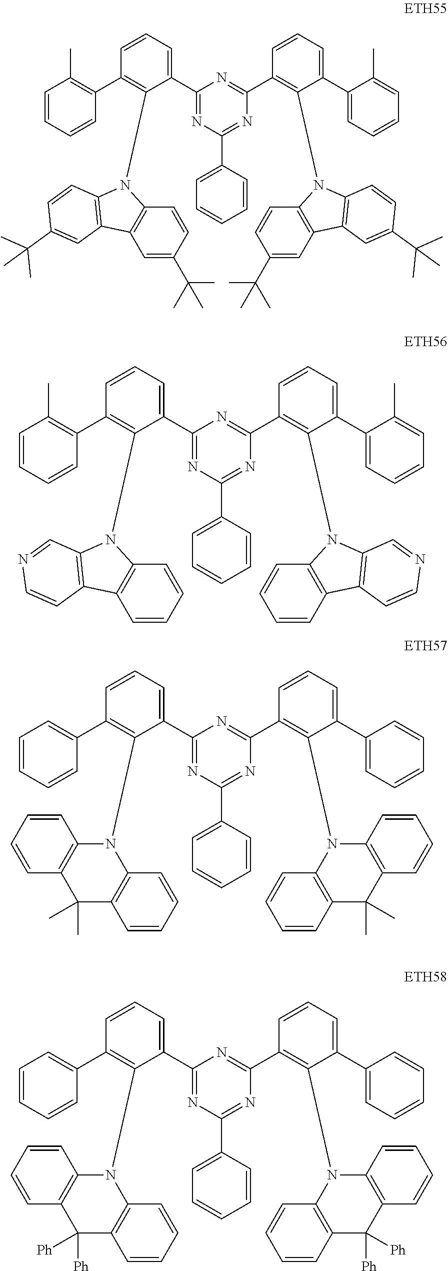

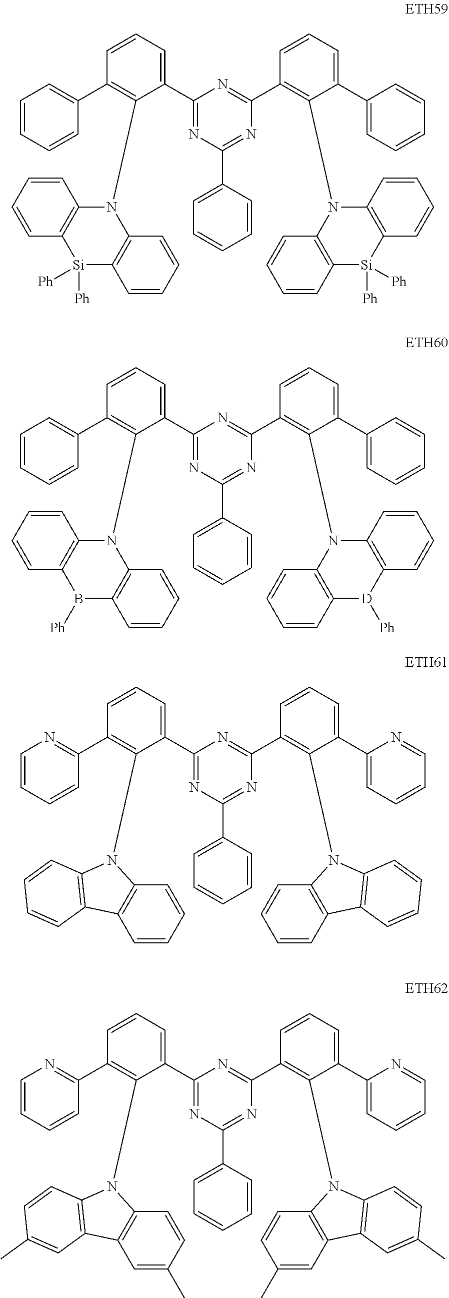

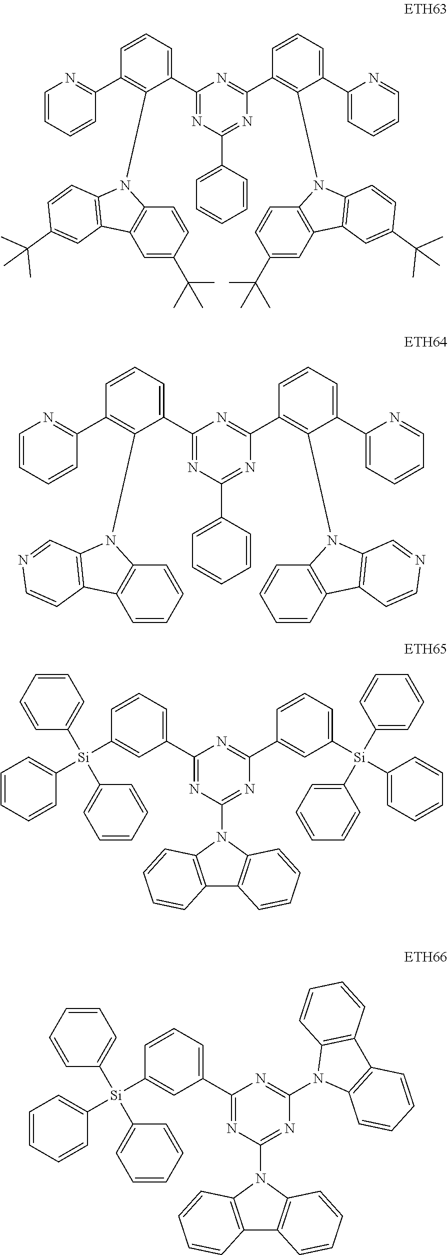 [SMILES: CC(C)(C)c1ccc2c(c1)c1cc(C(C)(C)C)ccc1n2-c1c(-c2ccccn2)cccc1-c1nc(-c2ccccc2)nc(-c2cccc(-c3ccccn3)c2-n2c3ccc(C(C)(C)C)cc3c3cc(C(C)(C)C)ccc32)n1 ; c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

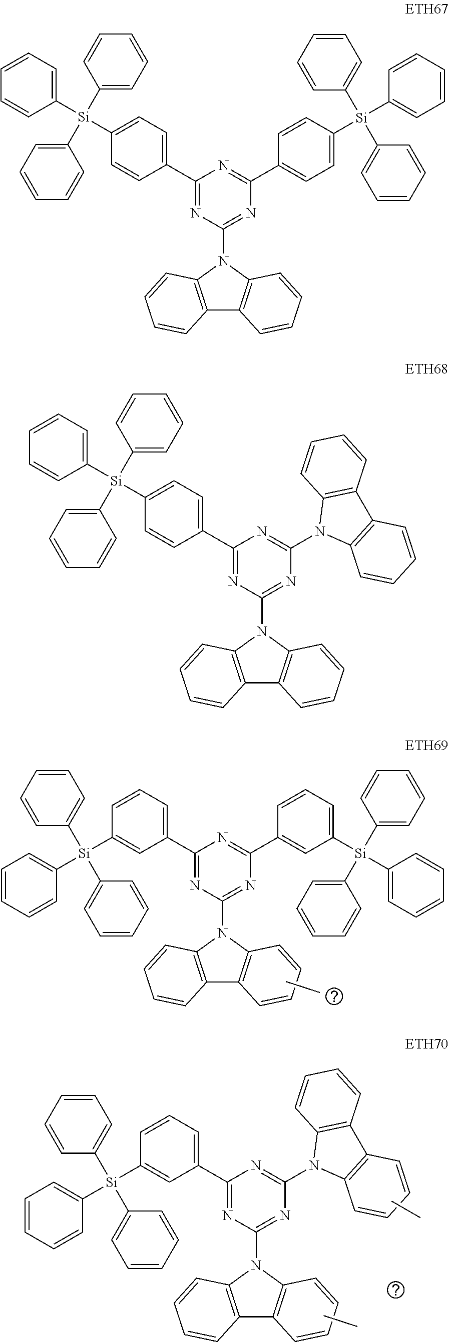

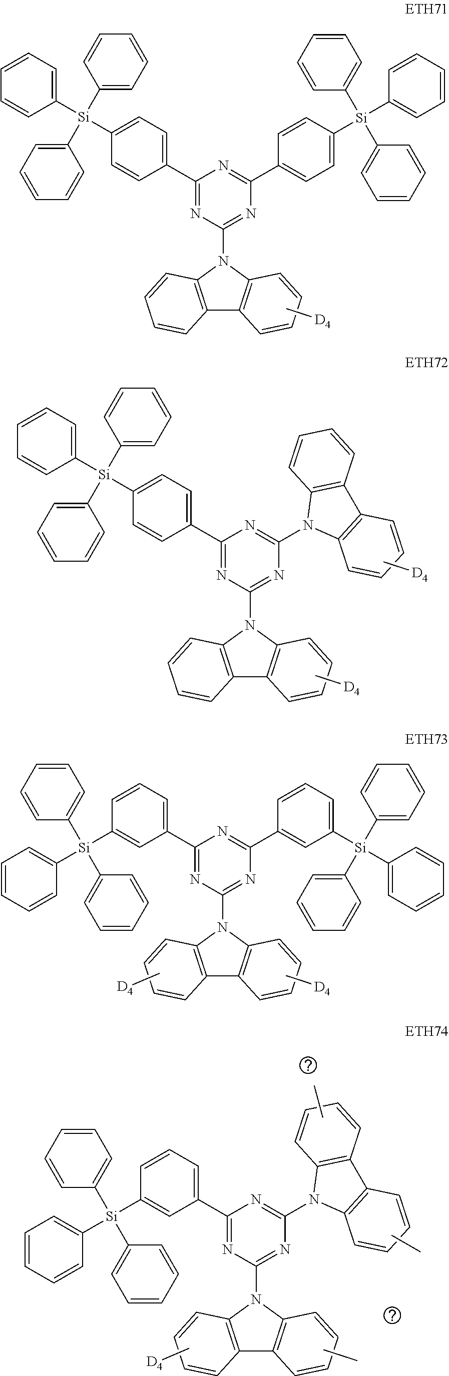

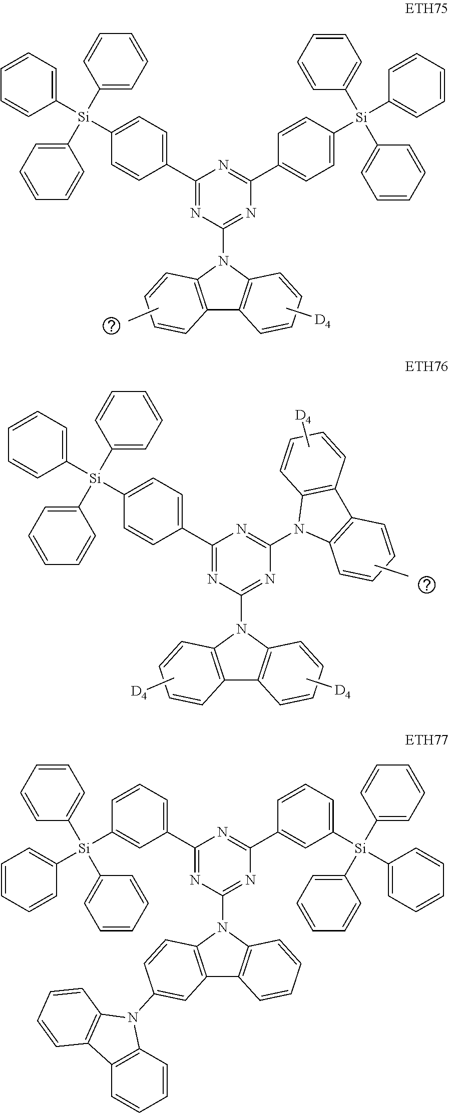

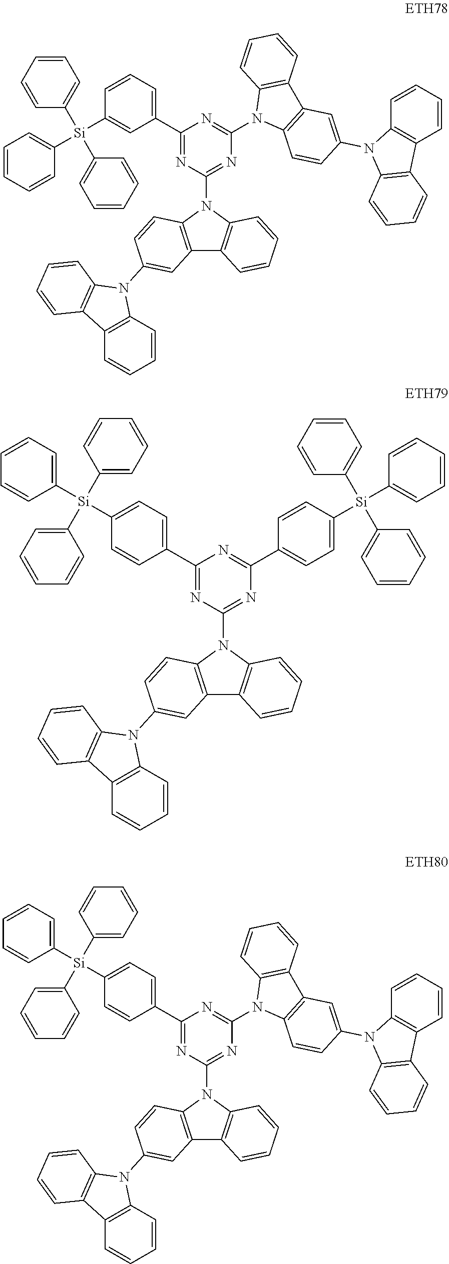 [SMILES: c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1 ; c1ccc([Si](c2ccccc2)(c2ccccc2)c2ccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)cc2)cc1]

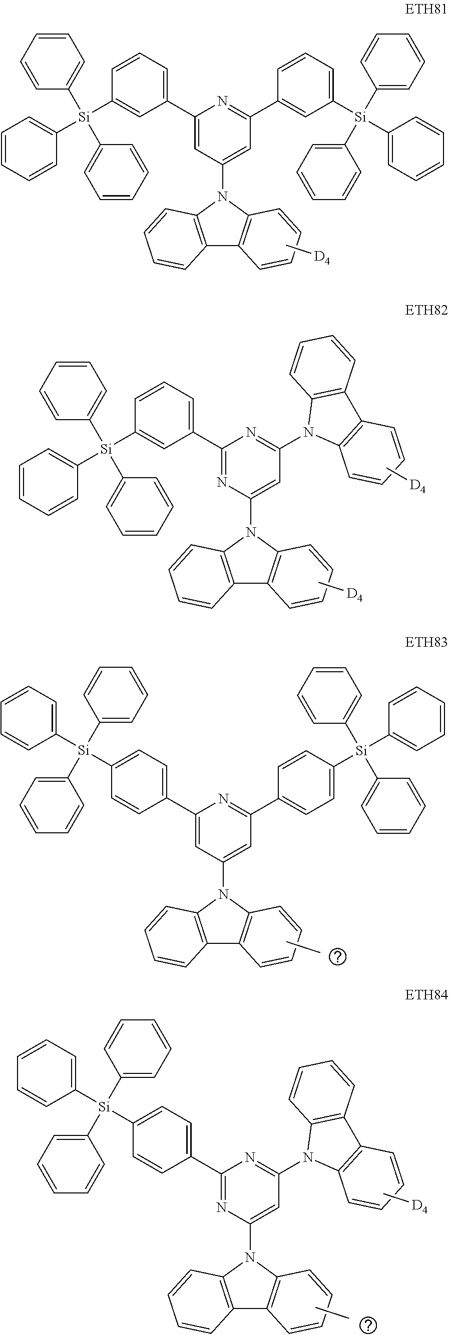

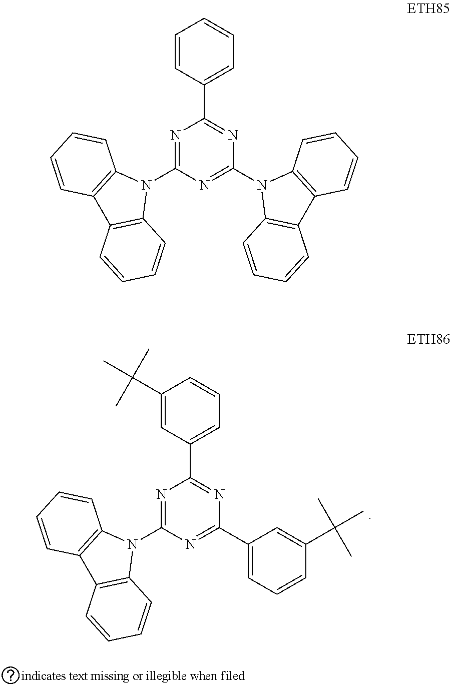 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy level of the exciplex formed by a hole transport host and an electron transport host may correspond to a difference between a lowest unoccupied molecular orbital (LUMO) energy level of the electron transport host and a highest occupied molecular orbital (HOMO) energy level of the hole transport host.

For example, an absolute value of a triplet energy level (Ti) of the exciplex formed by the hole transport host and the electron transport host may be in a range of about 2.4 eV to about 3.0 eV. The triplet energy level of the exciplex may have a value that is smaller than an energy gap of each host material. The exciplex may have a triplet energy level equal to or less than about 3.0 eV, which is an energy gap between the hole transport host and the electron transport host.

In an embodiment, the emission layer EML may include a fourth compound, in addition to the first compound, the second compound, and the third compound. The fourth compound may be used as a phosphorescence sensitizer in an emission layer EML. Energy may be transferred from the fourth compound to the first compound, thereby emitting light.

The emission layer EML may include, as a fourth compound, an organometallic complex that includes platinum (Pt) as a central metal atom and ligands bonded to the central metal atom. In an embodiment, the emission layer EML may further include a fourth compound represented by Formula D-1:

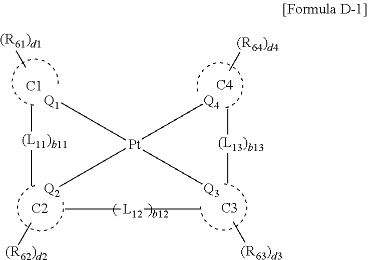

In Formula D-1, Q₁ to Q₄ may each independently be C or N.

In Formula D-1, C1 to C4 may each independently be a substituted or unsubstituted hydrocarbon ring of 5 to 30 ring-forming carbon atoms or a substituted or unsubstituted heterocycle of 2 to 30 ring-forming carbon atoms.

In Formula D-1, L₁₁ to L₁₃ may each independently be a direct linkage,

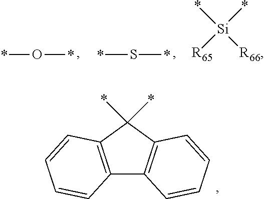

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃,

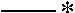 [SMILES: *C]

represents a bond to one of C1 to C4.

In Formula D-1, b11 to b13 may each independently be 0 or 1. If b11 is 0, C1 and C2 may not be directly bonded to each other. If b12 is 0, C2 and C3 may not be directly bonded to each other. If b3 is 0, C3 and C4 may not be directly bonded to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring. For example, R₆₁ to R₆₆ may each independently be a substituted or unsubstituted methyl group or a substituted or unsubstituted t-butyl group.

In Formula D-1, d1 to d4 may each independently be an integer from 0 to 4. In Formula D-1, if d1 to d4 are each 0, the fourth compound may not be substituted with R₆₁ to R₆₄, respectively. A case where d1 to d4 are each 4 and all groups of each of R₆₁ to R₆₄ are hydrogen atoms may be the same as a case where d1 to d4 are each 0. If d1 to d4 are each 2 or more, multiple groups of each of R₆₁ to R₆₄ may be all the same, or at least one group thereof may be different from the remainder.

In an embodiment, in Formula D-1, C1 to C4 may each independently be a substituted or unsubstituted hydrocarbon ring or a substituted or unsubstituted heterocycle that is represented by one of Formula C-1 to Formula C-4:

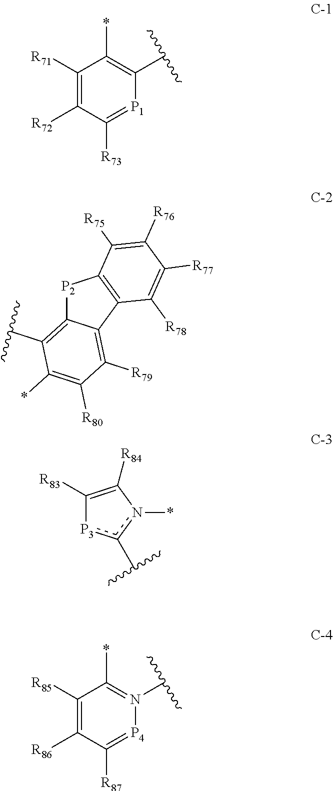

In Formula C-1 to Formula C-4, P₁ may be

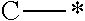 [SMILES: *C]

or C(R₇₄), P₂ may be

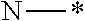 [SMILES: *N]

or N(R₈₁), P₃ may be

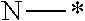 [SMILES: *N]

or N(R₈₂), and P₄ may be

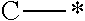 [SMILES: *C]

### or C(R₈₈).

In Formula C-1 to Formula C-4, R₇₁ to R₈₈ may each independently be a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring.

In Formula C-1 to Formula C-4,

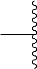

represents a bond to Pt, and

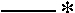 [SMILES: *C]

represents a bond to an adjacent ring group (C1 to C4) or to a linker (L₁₁ to L₁₃).

In an embodiment, the emission layer EML may include the first compound represented by Formula 1, and at least one of the second compound, the third compound, and the fourth compound. In an embodiment, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. In an embodiment, the fourth compound may be a sensitizer. In the light emitting element ED, the fourth compound included in the emission layer EML may serve as a sensitizer to transfer energy from a host to the first compound, which is a light-emitting dopant. For example, the fourth compound, which serves as an auxiliary dopant, may accelerate energy transfer to the first compound, which serves as a light emitting dopant, thereby increasing an emission ratio of the first compound. Accordingly, efficiency of the emission layer EML may be improved. If energy transfer to the first compound increases, excitons formed in the emission layer EML may not accumulate and may rapidly emit light, so that deterioration of the light emitting element ED may be reduced. Accordingly, the lifetime of the light emitting element ED may increase.

The light emitting element ED may include the first compound, the second compound, the third compound, and the fourth compound, and the emission layer EML may include the combination of two host materials and two dopant materials. In the light emitting element ED, the emission layer EML may include the second compound and the third compound, which are two different hosts, the first compound which emits delayed fluorescence, and the fourth compound which includes an organometallic complex, and thus the light emitting element ED may exhibit excellent emission efficiency properties.

In an embodiment, the fourth compound represented by Formula D-1 may be selected from Compound Group 4. In an embodiment, in the light emitting element ED, the fourth compound may include at least one compound selected from Compound Group 4:

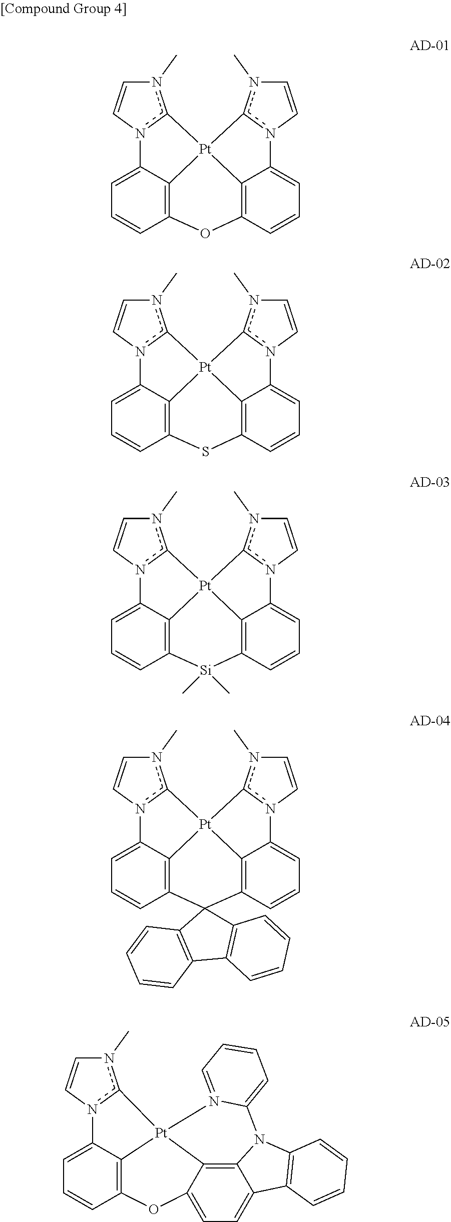

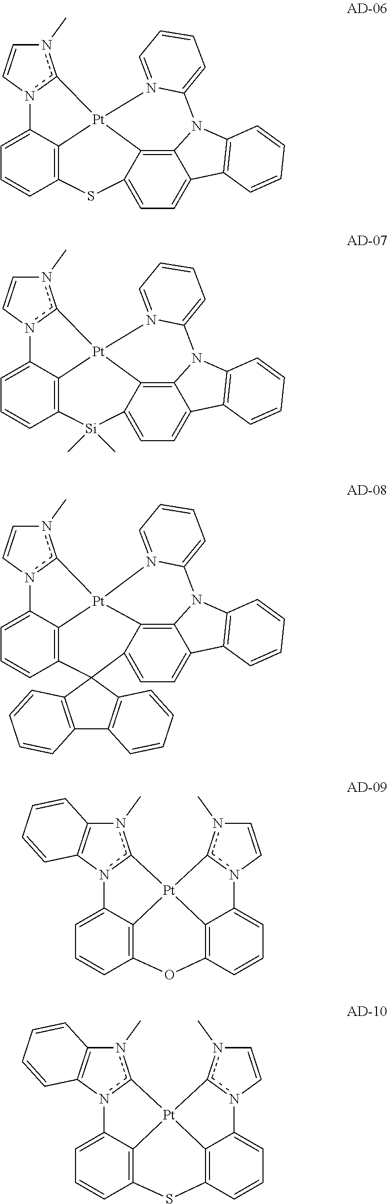

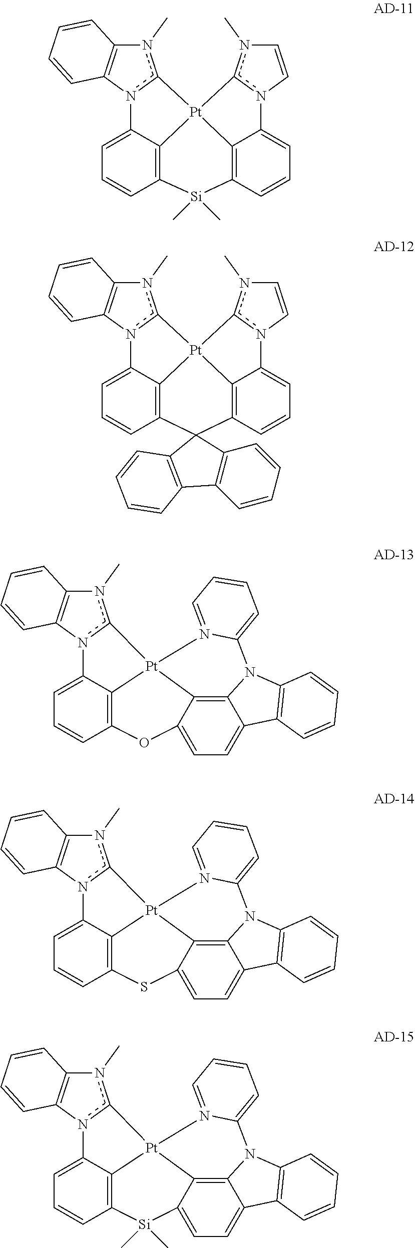

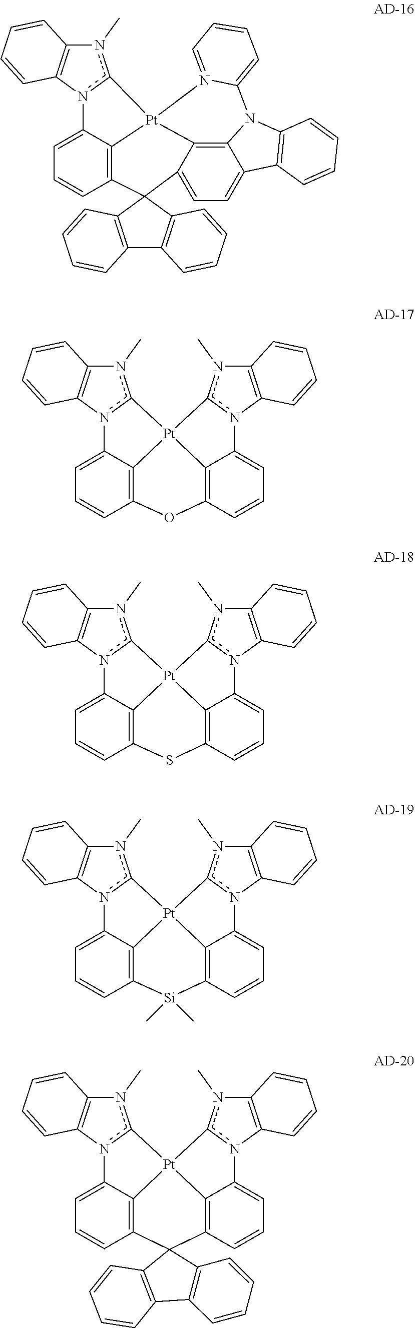

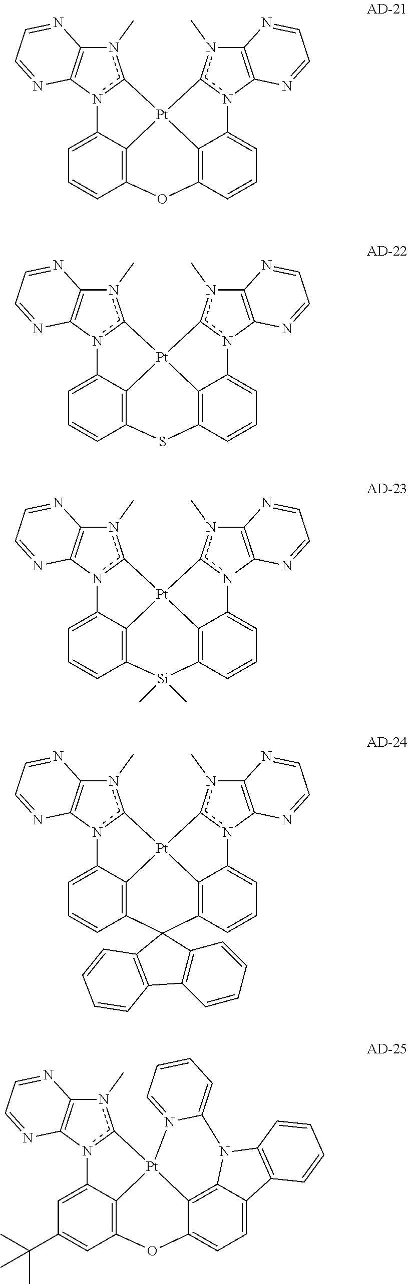

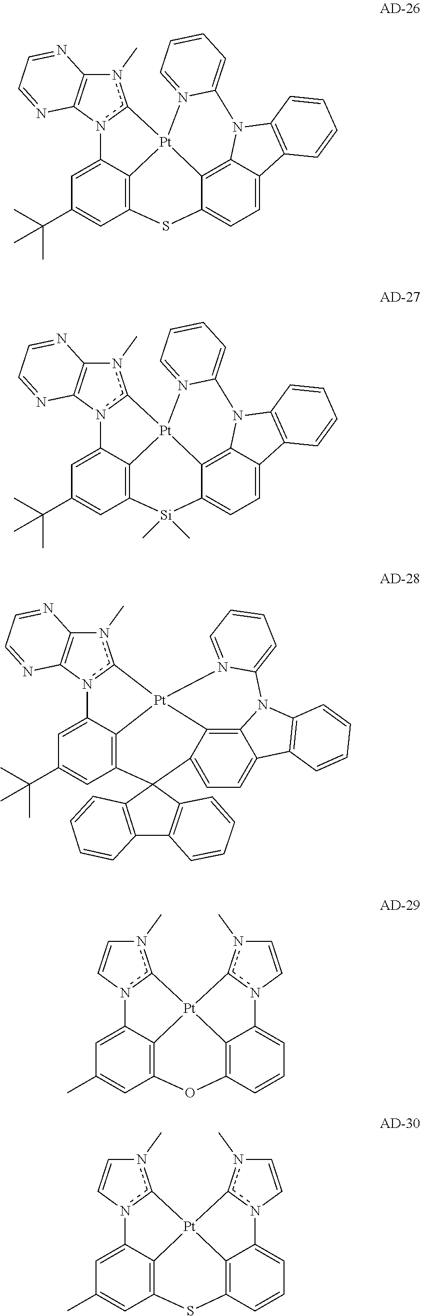

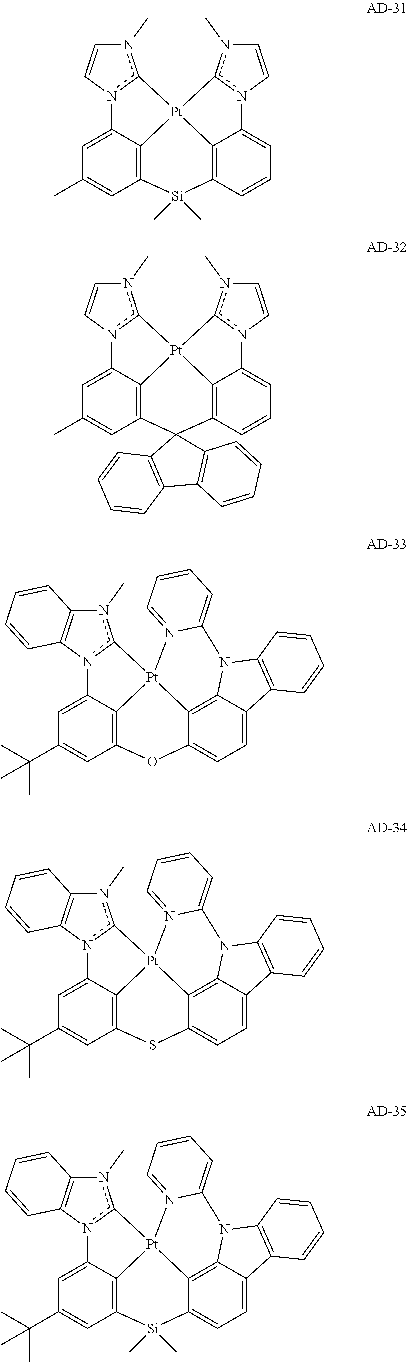

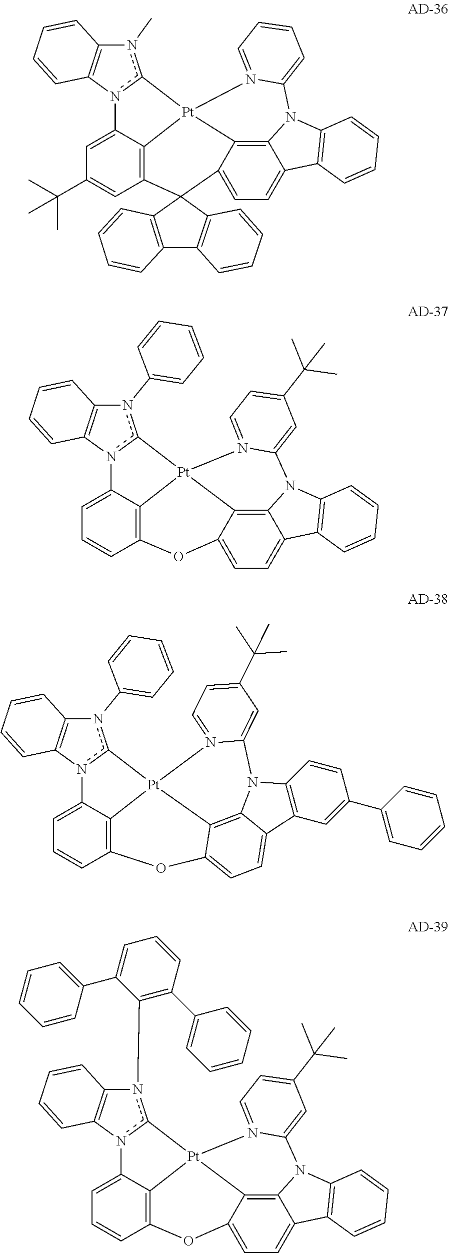

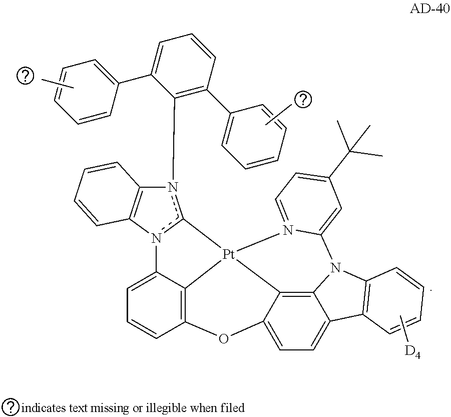

In Compound Group 4, D represents a deuterium atom.

In an embodiment, the light emitting element ED may include multiple emission layers. Multiple emission layers may be provided as a stack, so that a light emitting element ED including multiple emission layers may emit white light. The light emitting element ED including multiple emission layers may be a light emitting element having a tandem structure. If the light emitting element ED includes multiple emission layers, at least one emission layer EML may include the first compound represented by Formula 1. For example, if the light emitting element ED includes multiple emission layers, at least one emission layer EML may include the first compound, the second compound, the third compound, and the fourth compound.

In the light emitting element ED, if the emission layer EML includes the first compound, the second compound, and the third compound, an amount of the first compound may be in a range of about 0.1 wt % to about 5 wt %, based on a total weight of the first compound, the second compound, and the third compound. However, embodiments are not limited thereto. If an amount of the first compound satisfies the above-described range, energy transfer from the second compound and the third compound to the first compound may increase, and accordingly, emission efficiency and device lifetime may increase.

In the emission layer EML, a total amount of the second compound and the third compound may be the remainder of the total weight of the first compound, the second compound, and the third compound, excluding the amount of the first compound. For example, a combined amount of the second compound and the third compound may be in a range of about 65 wt % to about 95 wt %, based on a total weight of the first compound, the second compound and the third compound.

Within the combined amount of the second compound and the third compound in the emission layer EML, a weight ratio of the second compound to the third compound may be in a range of about 3:7 to about 7:3.

If the amounts of the second compound and the third compound satisfy the above-described ranges and ratios, charge balance properties in the emission layer EML may be improved, and emission efficiency and device lifetime may be improved. If the amounts of the second compound and the third compound deviate from the above-described ranges and ratios, charge balance in the emission layer EML may not be achieved, so that emission efficiency may be reduced, and the device may readily deteriorate.

If the emission layer EML includes the fourth compound, an amount of the fourth compound in the emission layer EML may be in a range of about 4 wt % to about 30 wt %, based on a total weight of the first compound, the second compound, the third compound, and the fourth compound. However, embodiments are not limited thereto. If an amount of the fourth compound satisfies the above-described range, energy transfer from a host to the first compound, which is a light emitting dopant, may increase, so that an emission ratio may be improved. Accordingly, the emission efficiency of the emission layer EML may be improved. If the amounts of the first compound, the second compound, the third compound, and the fourth compound included in the emission layer EML satisfy the above-described ranges and ratios, excellent emission efficiency and long lifetime may be achieved.

In the light emitting element ED, the emission layer EML may further include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting element ED according to embodiments as shown in each of FIG. 3 to FIG. 6, the emission layer EML may further include hosts and dopants of the related art, in addition to the above-described host and dopant.

In an embodiment, the emission layer EML may include a compound represented by Formula E-1. The compound represented by Formula E-1 may be used as a fluorescence host material.

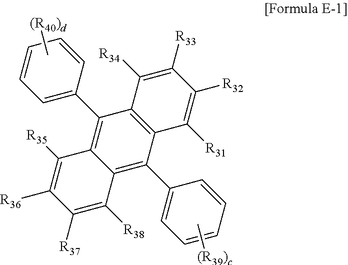

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring. For example, in Formula E-1, R₃₁ to R₄₀ may be combined with an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19:

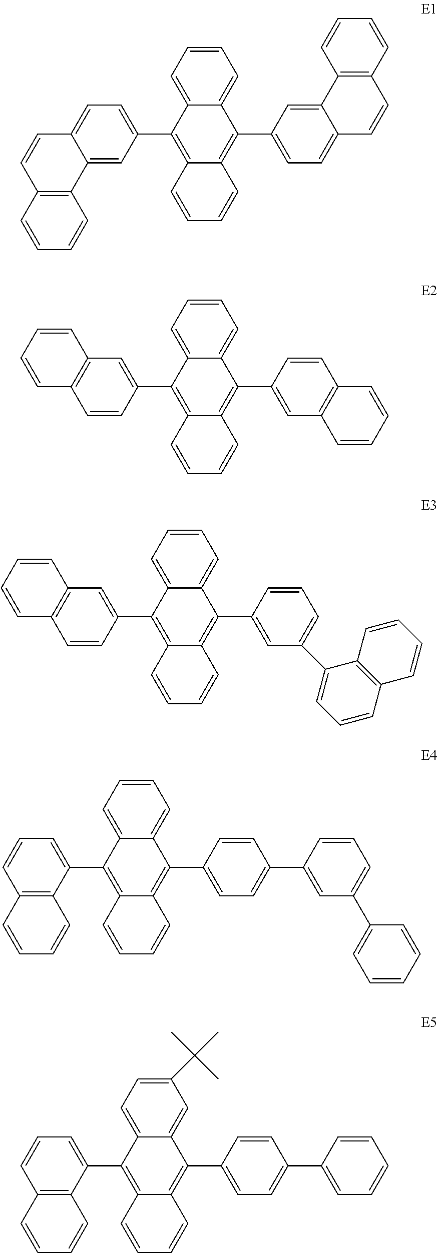

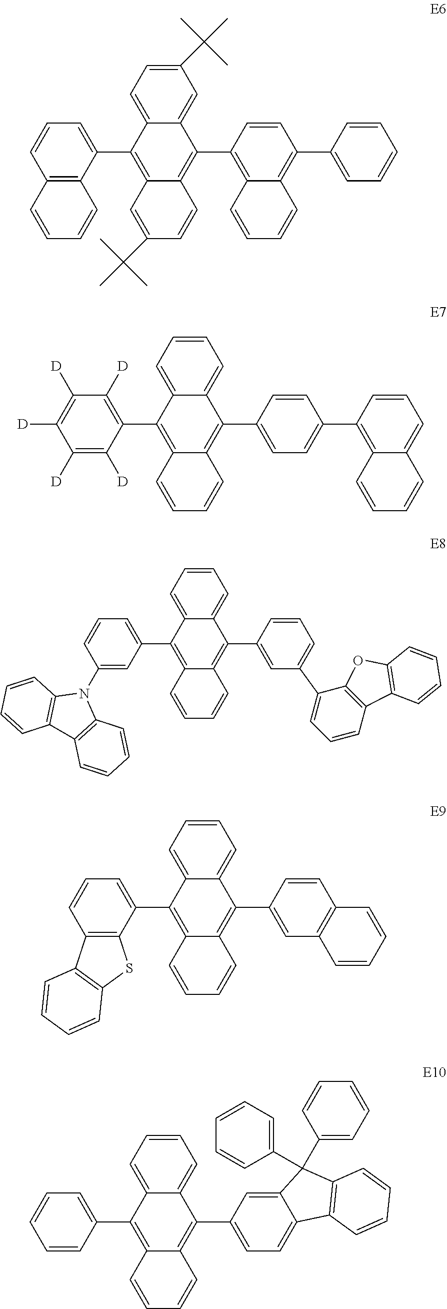

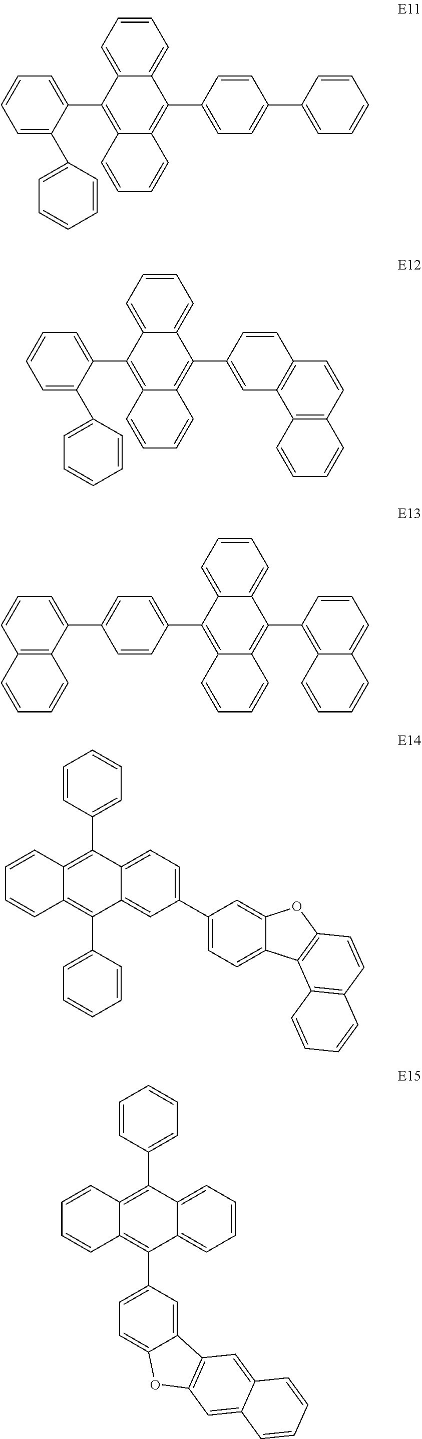

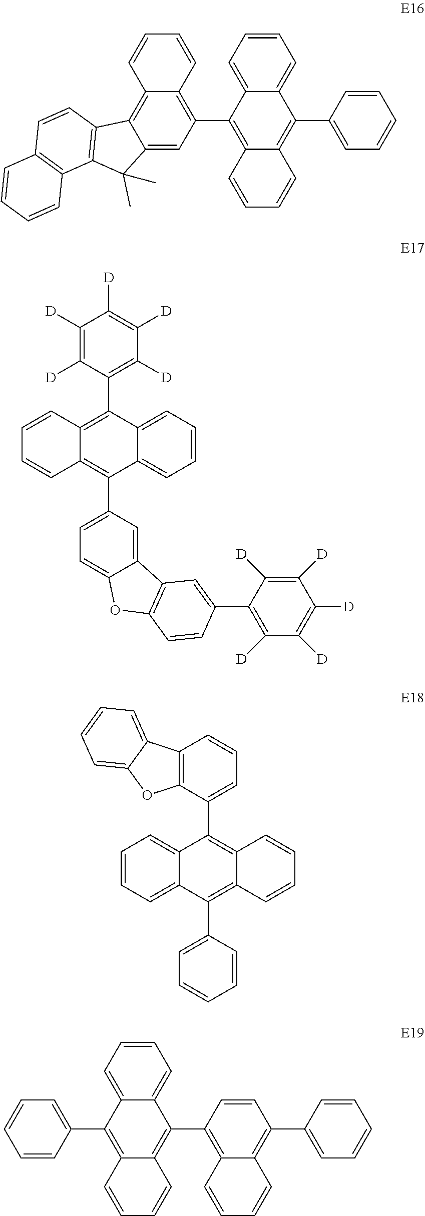

In an embodiment, the emission layer EML may include a compound represented by Formula E-2a or Formula E-2b. The compound represented by Formula E-2a or Formula E-2b may be used as a phosphorescence host material.

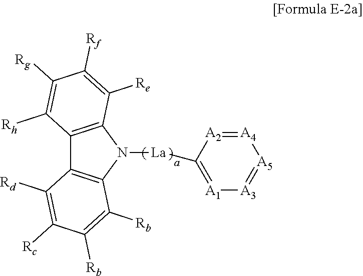

In Formula E-2a, a may be an integer from 0 to 10; and Lₐ may be a direct linkage, a substituted or unsubstituted arylene group of 6 to 30 ring-forming carbon atoms, or a substituted or unsubstituted heteroarylene group of 2 to 30 ring-forming carbon atoms. If a is 2 or more, multiple Lₐ groups may each independently be a substituted or unsubstituted arylene group of 6 to 30 ring-forming carbon atoms or a substituted or unsubstituted heteroarylene group of 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring. For example, Rₐ to Rᵢ may be combined with an adjacent group to form a hydrocarbon ring or a heterocycle including N, O, S, etc. as a ring-forming atom.

In Formula E-2a, two or three of A₁ to A₅ may each be N, and the remainder of A₁ to A₅ may each independently be C(Rᵢ).

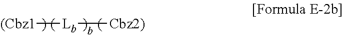

In Formula E-2b, Cbz1 and Cbz2 may each independently be an unsubstituted carbazole group, or a carbazole group substituted with an aryl group of 6 to 30 ring-forming carbon atoms. In Formula E-2b, L_{b} may be a direct linkage, a substituted or unsubstituted arylene group of 6 to 30 ring-forming carbon atoms, or a substituted or unsubstituted heteroarylene group of 2 to 30 ring-forming carbon atoms. In Formula E-2b, b may be an integer from 0 to 10, and if b is 2 or more, multiple L_{b} groups may each independently be a substituted or unsubstituted arylene group of 6 to 30 ring-forming carbon atoms or a substituted or unsubstituted heteroarylene group of 2 to 30 ring-forming carbon atoms.

The compound represented by Formula E-2a or Formula E-2b may be any compound selected from Compound Group E-2. However, the compounds shown in Compound Group E-2 are only examples, and the compound represented by Formula E-2a or Formula E-2b is not limited to the Compound Group E-2:

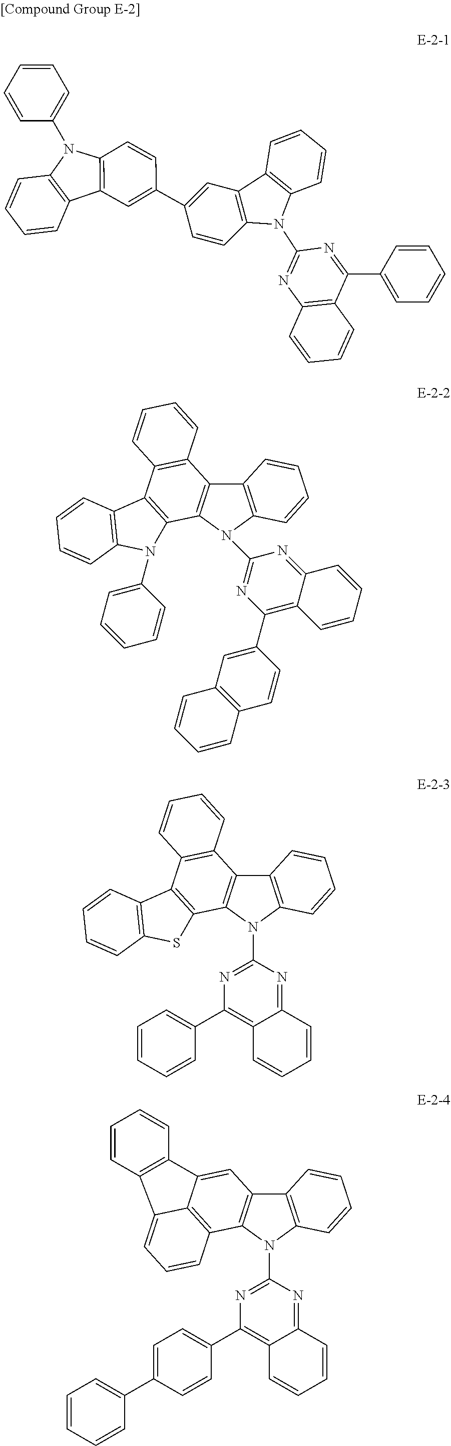

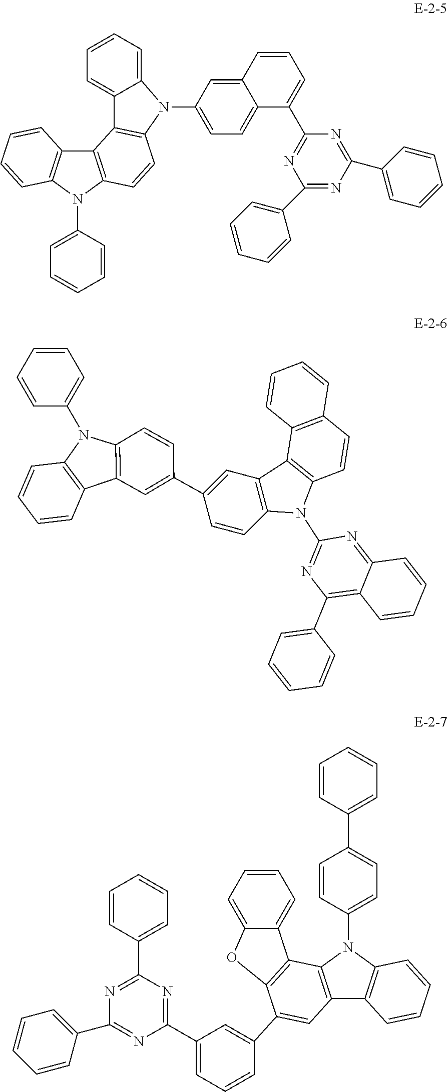 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1]

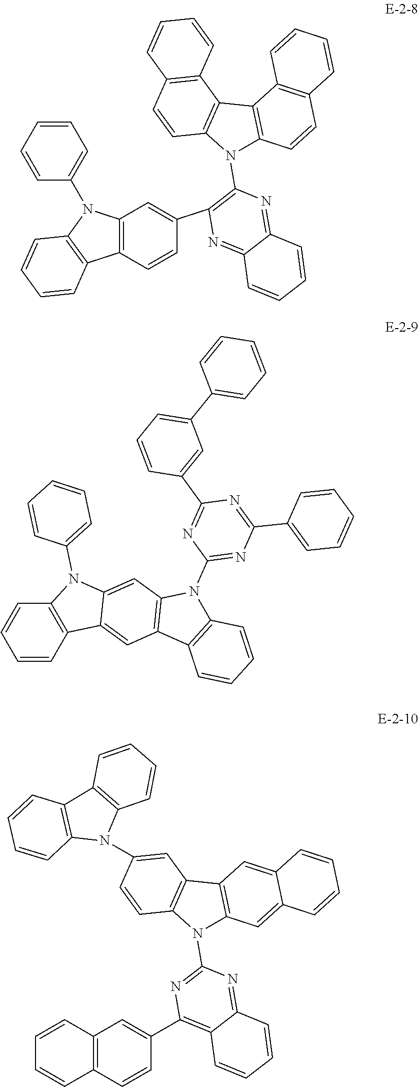 [SMILES: c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1]

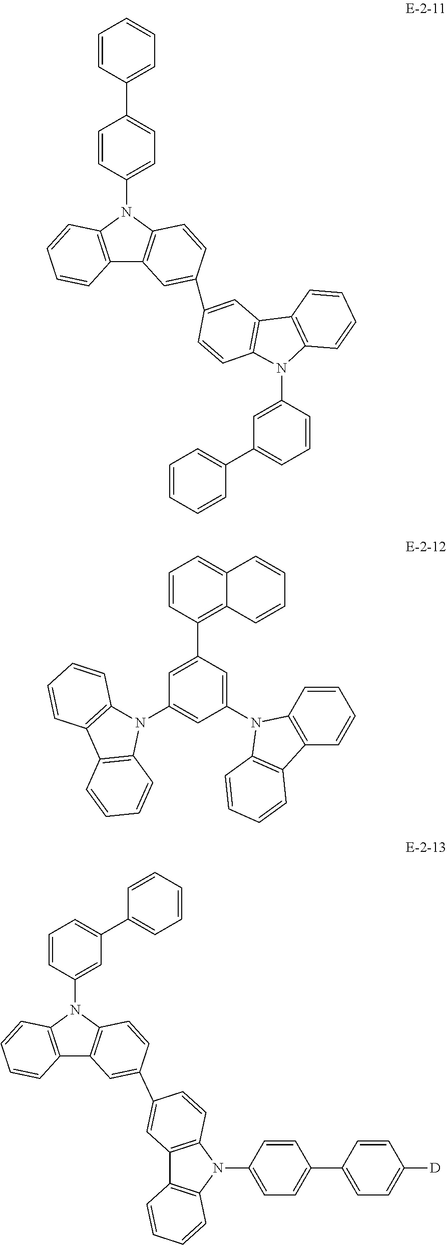

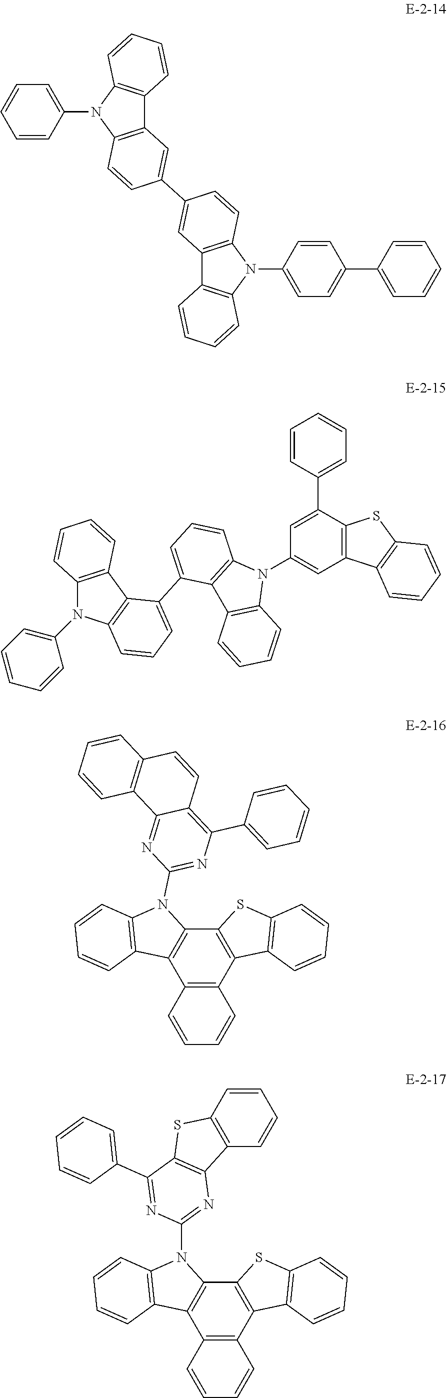 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1]

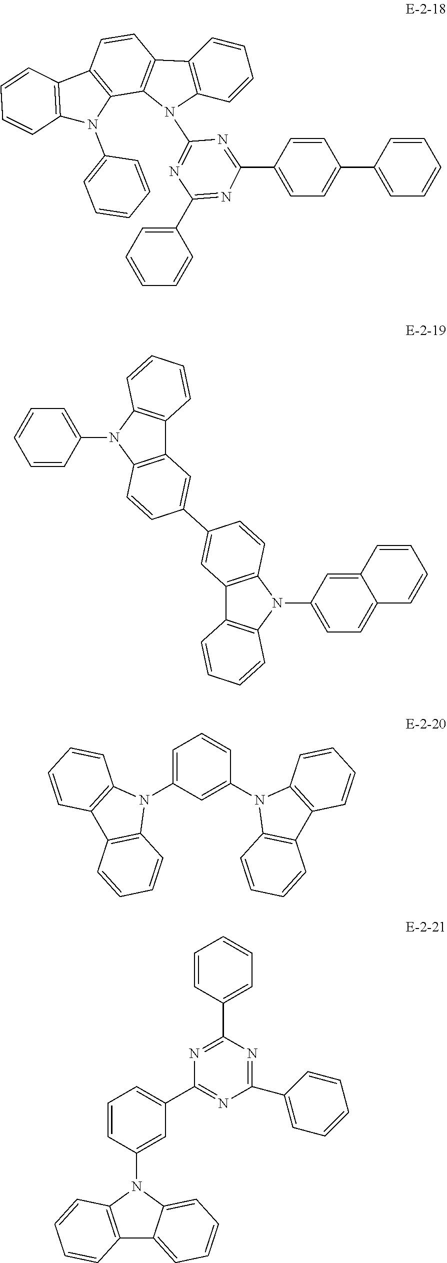 [SMILES: c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

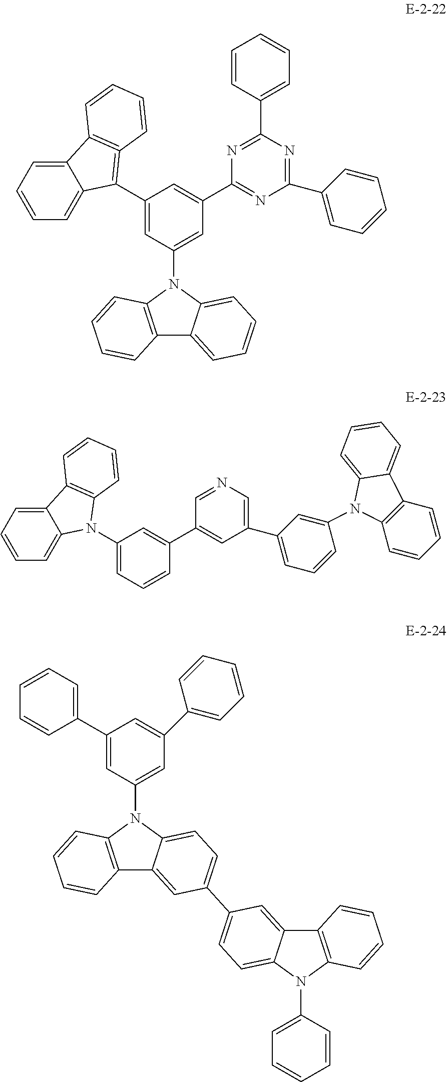

The emission layer EML may further include a material of the related art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolinato)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

In an embodiment, the emission layer EML may include a compound represented by Formula M-a. The compound represented by Formula M-a may be used as a phosphorescence dopant material.

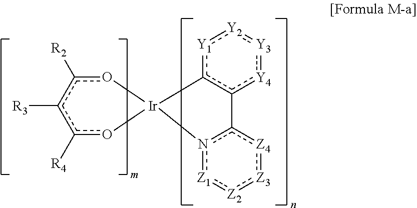

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring. In Formula M-a, m may be 0 or 1, and n may be 2 or 3. In Formula M-a, if m is 0, n may be 3, and if m is 1, n may be 2.

The compound represented by Formula M-a may be any compound selected from Compounds M-a1 to M-a25. However, Compounds M-a1 to M-a25 are only examples, and the compound represented by Formula M-a is not limited to Compounds M-a1 to M-a25:

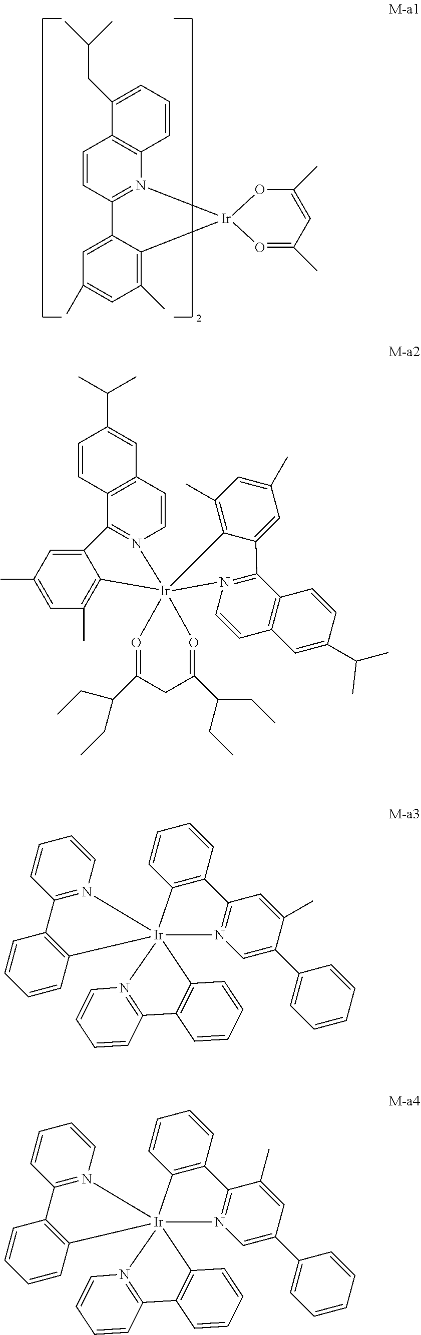

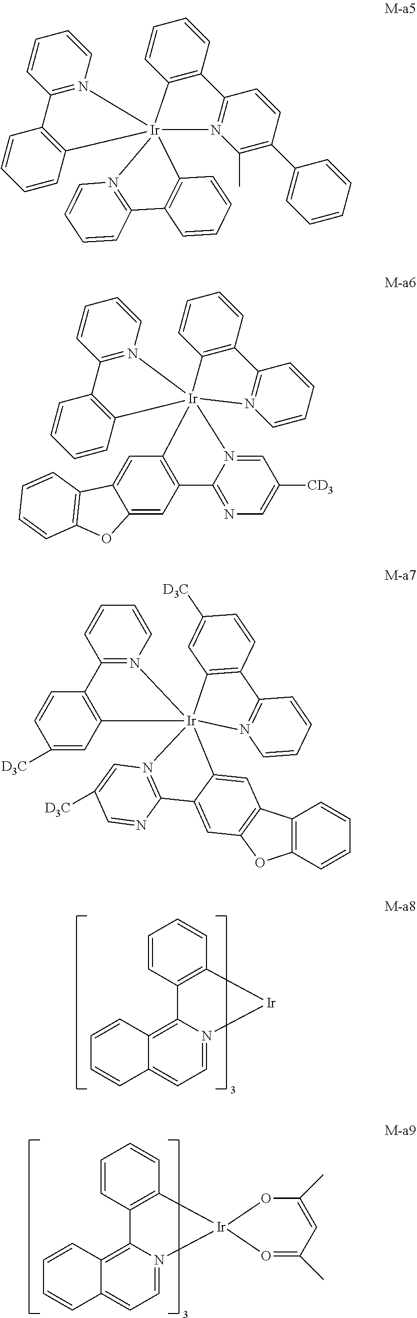

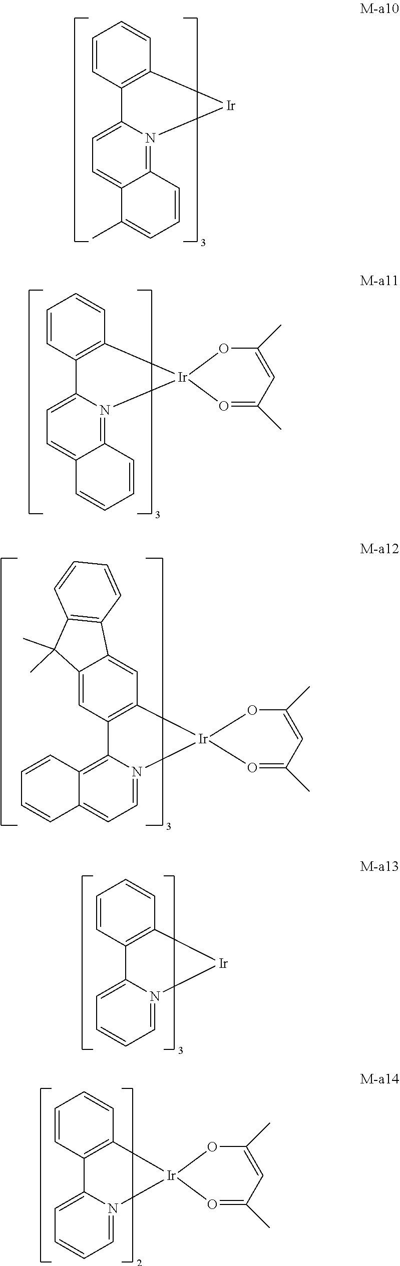

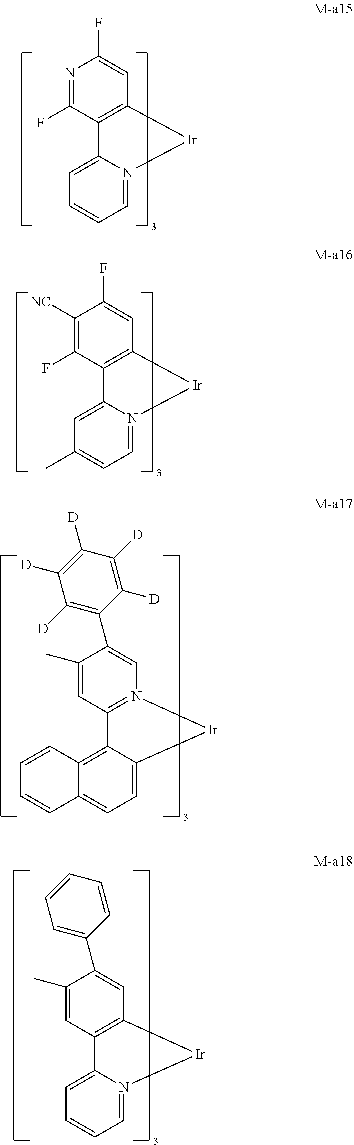

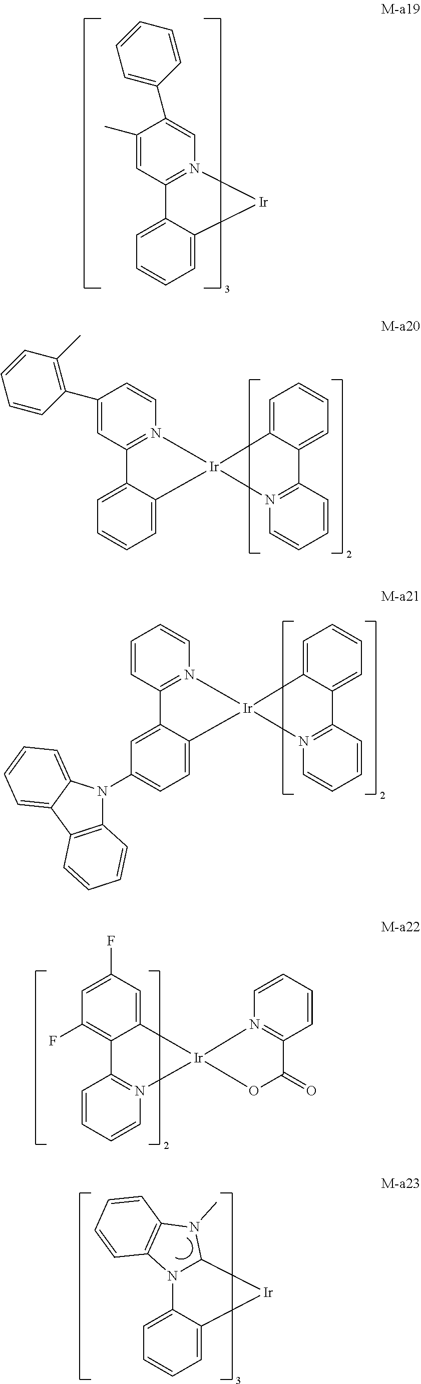

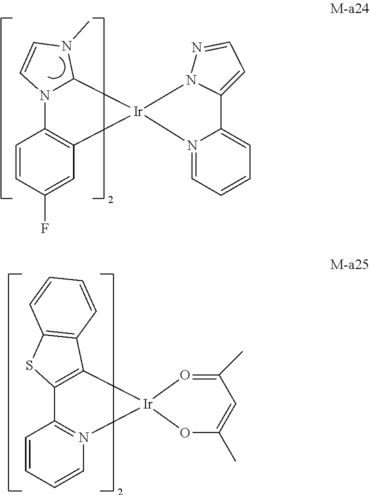

In an embodiment, the emission layer EML may include a compound represented by one of Formula F-a to Formula F-c. The compound represented by one of Formula F-a to Formula F-c may be used as a fluorescence dopant material.

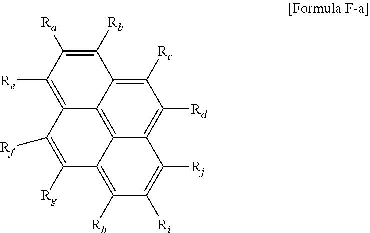

In Formula F-a, two of Rₐ to Rⱼ may each independently be substituted with a group represented by

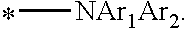

The remainder of Rₐ to Rⱼ which are not substituted with the group represented by

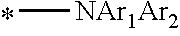

may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In the group represented by

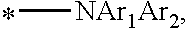

Ar₁ and Ar₂ may each independently be a substituted or unsubstituted aryl group of 6 to 30 ring-forming carbon atoms or a substituted or unsubstituted heteroaryl group of 2 to 30 ring-forming carbon atoms. For example, at least one of Ar₁ and Ar₂ may each independently be a heteroaryl group including O or S as a ring-forming atom.

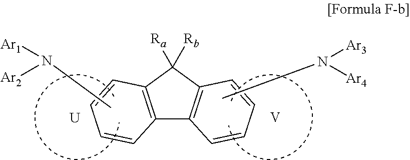

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring. In Formula F-b, Ar₁ to Ar₄ may each independently be a substituted or unsubstituted aryl group of 6 to 30 ring-forming carbon atoms or a substituted or unsubstituted heteroaryl group of 2 to 30 ring-forming carbon atoms. For example, at least one of Ar₁ to Ar₄ may each independently be a heteroaryl group including O or S as a ring-forming atom.

In Formula F-b, U and V may each independently be a substituted or unsubstituted hydrocarbon ring of 5 to 30 ring-forming carbon atoms or a substituted or unsubstituted heterocycle of 2 to 30 ring-forming carbon atoms.

In Formula F-b, the number of rings represented by U and V may each independently be 0 or 1. If the number of U or V is 1, a fused ring may be present at the portion indicated by U or V, and if the number of U or V is 0, a fused ring may not be present at the portion indicated by U or V. If the number of U is 0 and the number of V is 1, or if the number of U is 1 and the number of V is 0, a fused ring having the fluorene core of Formula F-b may be a cyclic compound with four rings. If the number of U and V is each 0, a fused ring having the fluorene core of Formula F-b may be a cyclic compound with three rings. If the number of U and V is each 1, a fused ring having the fluorene core of Formula F-b may be a cyclic compound with five rings.

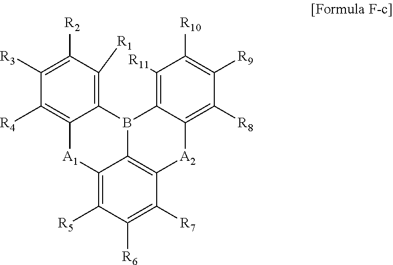

In Formula F-c, A₁ and A₂ may each independently be O, S, Se, or N(Rₘ); and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula F-c, R₁ to Rₙ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring.

In Formula F-c, A₁ and A₂ may each independently be combined with a substituent of an adjacent ring to form a fused ring. For example, if A₁ and A₂ are each independently N(Rₘ), A₁ may be combined with R₄ or R₅ to form a ring. For example, A₂ may be combined with R₇ or R₈ to form a ring.

In an embodiment, the emission layer EML may include as a dopant material of the related art, a styryl derivative (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene or a derivative thereof (for example, 2,5,8,11-tetra-t-butylperylene (TBP)), pyrene or a derivative thereof (for example, 1,1-dipyrene, 1,4-dipyrenylbenzene, and 1,4-bis(N,N-diphenylamino)pyrene), etc.

The emission layer EML may include a phosphorescence dopant material of the related art. For example, the phosphorescence dopant may include a metal complex including iridium (Ir), platinum (Pt), osmium (Os), gold (Au), titanium (Ti), zirconium (Zr), hafnium (Hf), europium (Eu), terbium (Tb) or thulium (Tm). For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescence dopant. However, embodiments are not limited thereto.

In an embodiment, the emission layer may include a quantum dot.

In the specification, a quantum dot may be a crystal of a semiconductor compound. The quantum dot may emit light in various emission wavelengths according to a size of the crystal. The quantum dot may emit light in various emission wavelengths by adjusting an elemental ratio of a quantum dot compound.

A diameter of the quantum dot may be, for example, in a range of about 1 nm to about 10 nm.

The quantum dot may be synthesized by a chemical bath deposition, a metal organic chemical vapor deposition, a molecular beam epitaxy, or a similar process therewith.

A chemical bath deposition is a method of mixing an organic solvent and a precursor material and growing a quantum dot particle crystal. While growing the crystal, the organic solvent may serve as a dispersant that is coordinated on a surface of the quantum dot crystal and may control the growth of the crystal. Accordingly, the chemical bath deposition may be more advantageous when compared to a vapor deposition method such as metal organic chemical vapor deposition (MOCVD) or molecular beam epitaxy (MBE), and the growth of the quantum dot particle may be controlled through a low-cost process.

In an embodiment, the emission layer EML may include a quantum dot material. The quantum dot may be a Group II-VI compound, a Group III-VI compound, a Group 1-II-VI compound, a Group III-V compound, a Group III-II-V compound, a Group IV-VI group compound, a Group II-IV-V compound, a Group IV element, a Group IV compound, or a combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof; or any combination thereof. In an embodiment, a Group II-VI compound may further include a Group I metal and/or a Group IV element. Examples of a Group 1-II-VI compound may include CuSnS and CuZnS; and examples of a Group II-IV-VI compound may include ZnSnS and the like. Examples of a Group I-II-IV-VI compound may include a quaternary compound selected from the group consisting of Cu₂ZnSnS₂, Cu₂ZnSnS₄, Cu₂ZnSnSe₄, Ag₂ZnSnS₂, and a mixture thereof.

Examples of a Group III-VI compound may include: a binary compound such as In₂S₃ and In₂Se₃; a ternary compound such as InGaS₃ and InGaSe₃; or any combination thereof.

Examples of a Group 1-III-VI compound may include: a ternary compound selected from the group consisting of AgInS, AgInS₂, CuInS, CuInS₂, AgGaS₂, CuGaS₂, CuGaO₂, AgGaO₂, AgAlO₂, and mixtures thereof; a quaternary compound such as AgInGaS₂ and CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof; or any combination thereof. In an embodiment, a Group III-V compound may further include a Group II metal. For example, InZnP, etc. may be selected as a Group III-II-V compound.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof.

Examples of a Group II-IV-V compound may include a ternary compound selected from the group consisting of ZnSnP, ZnSnP₂, ZnSnAs₂, ZnGeP₂, ZnGeAs₂, CdSnP₂, CdGeP₂, or any combination thereof.

Examples of a Group IV element may include Si, Ge, and a mixture thereof. Examples of a Group IV compound may include a binary compound selected from the group consisting of SiC, SiGe, and a mixture thereof.

Each element included in a multi-element compound, such as a binary compound, a ternary compound, or a quaternary compound, may be present in a particle at a uniform concentration or at a non-uniform concentration. For example, a formula may indicate the elements included in a compound, but an elemental ratio in the compound may be different. For example, AgInGaS₂ may indicate AgInₓGa₁₋ₓS₂ (where x is a real number between 0 and 1).

A binary compound, a ternary compound, or a quaternary compound may be present in a particle at a uniform concentration or may be present in a particle at a partially different concentration distribution state. In an embodiment, a quantum dot may have a core/shell structure in which one quantum dot surrounds another quantum dot. An interface between the core and the shell may have a concentration gradient in which the concentration of an element that is present in the shell decreases toward the core.

In embodiments, the quantum dot may have the above-described core-shell structure including a core that includes a nanocrystal and a shell surrounding the core. The shell of a quantum dot may serve as a protection layer for preventing the chemical deformation of the core to maintain semiconductor properties and/or may serve as a charging layer for imparting the quantum dot with electrophoretic properties. The shell may be a single layer or a multilayer. Examples of a shell of a quantum dot may include a metal oxide, a non-metal oxide, a semiconductor compound, or any combination thereof.

Examples of a metal oxide or a non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO; or a ternary compound such as MgAl₂O₄, CoFe₂O₄, NiFe₂O₄ and CoMn₂O₄. However, embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Within any of the above ranges, color purity or color reproducibility may be improved. Light emitted through a quantum dot may be emitted in all directions, so that light viewing angle properties may be improved.

The shape of a quantum dot may be any shape that is used in the related art. For example, a quantum dot may have a spherical shape, a pyramidal shape, a multi-arm shape, or a cubic shape, or the quantum dot may be in the form of a nanoparticle, a nanotube, a nanowire, a nanofiber, a nanoplate particle, etc.

As the size of the quantum dot or an elemental ratio of the quantum dot compound is adjusted, the energy band gap may be accordingly controlled to obtain light of various wavelengths from a quantum dot emission layer. Therefore, by using quantum dots as described above (for example, using quantum dots of different sizes or having different elemental ratios in the quantum dot compound), a light emitting element that emits light of various wavelengths may be achieved. For example, the size of the quantum dots or the elemental ratio of a quantum dot compound may be adjusted to emit red light, green light, and/or blue light. For example, quantum dots may be configured to emit white light by combining light of various colors.

In the light emitting element ED according to an embodiment as shown in each of FIG. 3 to FIG. 6, the electron transport region ETR may be provided on the emission layer EML. The electron transport region ETR may include at least one of a hole blocking layer HBL, an electron transport layer ETL, and an electron injection layer EIL. However, embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure formed of different materials, or may have a structure in which an electron transport layer ETL/electron injection layer EIL, or a hole blocking layer HBL/electron transport layer ETL/electron injection layer EIL, are stacked in its respective stated order from the emission layer EML, but embodiments are not limited thereto. A thickness of the electron transport region ETR may be, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-2:

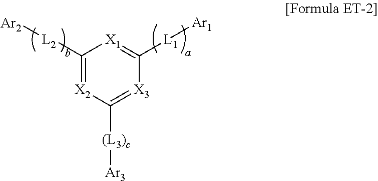

In Formula ET-2, at least one of X₁ to X₃ may each be N; and the remainder of X₁ to X₃ may each independently be C(Rₐ). In Formula ET-2, Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula ET-2, Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. If a to c are each 2 or more, multiple groups of each of L₁ to L₃ may each independently be a substituted or unsubstituted arylene group of 6 to 30 ring-forming carbon atoms or a substituted or unsubstituted heteroarylene group of 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate (Bebg₂), 9,10-di(naphthalene-2-yl)anthracene (ADN), 1,3-bis[3,5-di(pyridin-3-yl)phenyl]benzene (BmPyPhB), or a mixture thereof, without limitation.

In an embodiment, the electron transport region ETR may include at least one compound selected from Compound Group 3.

In an embodiment, the electron transport region ETR may include at least one compound selected from Compounds ET1 to ET36:

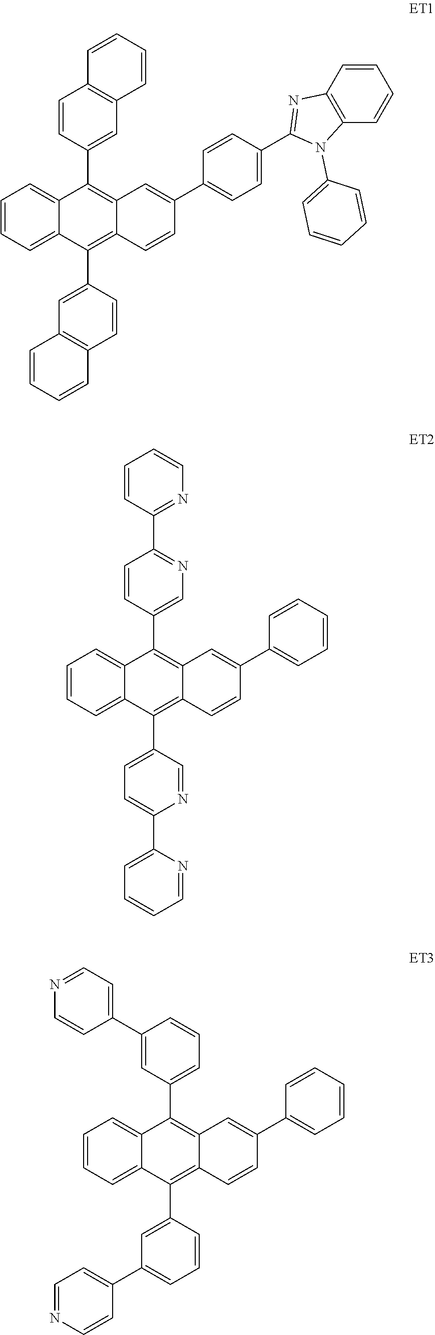 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

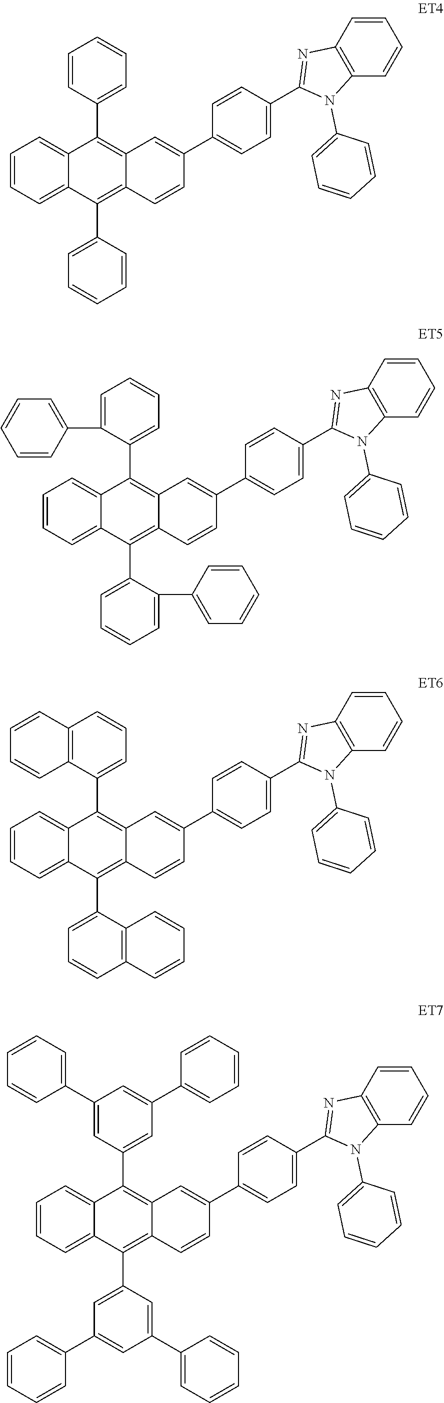 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

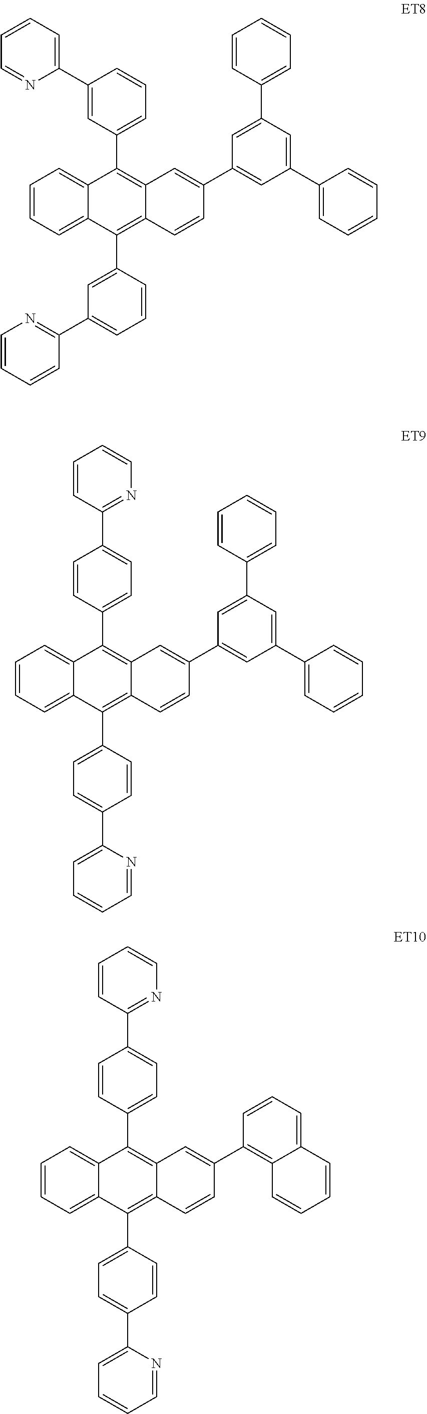

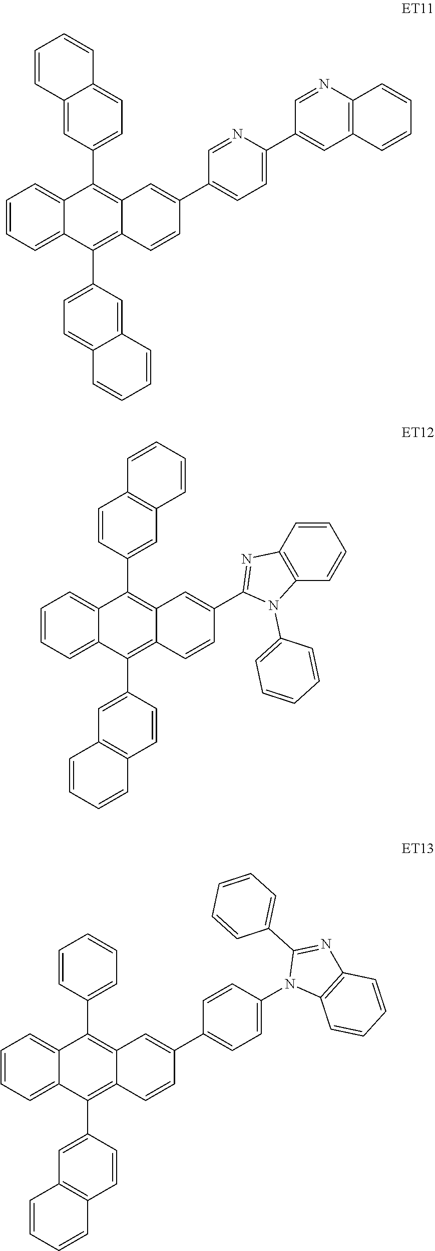 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

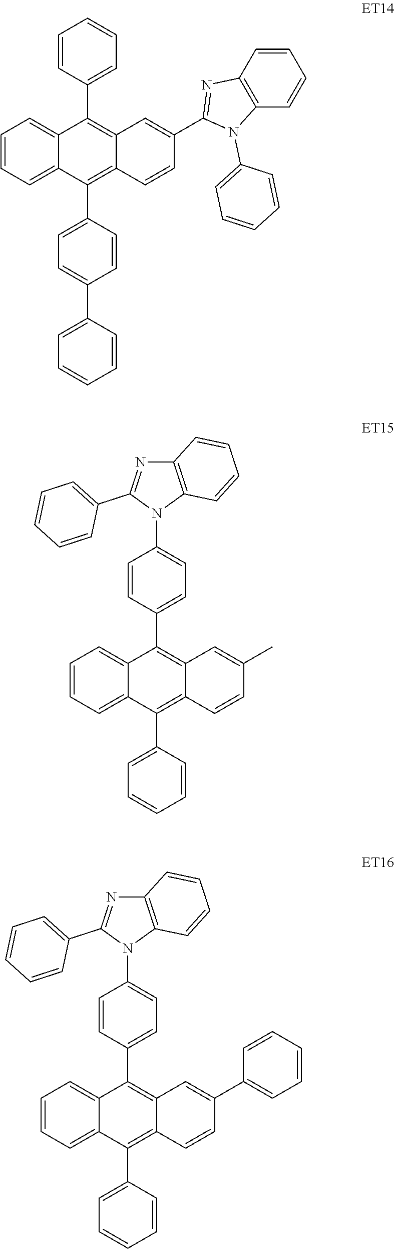 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

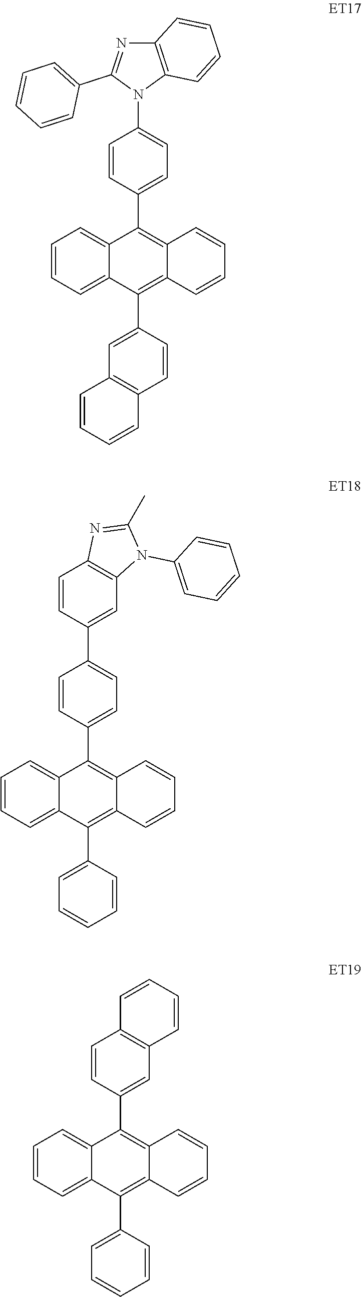

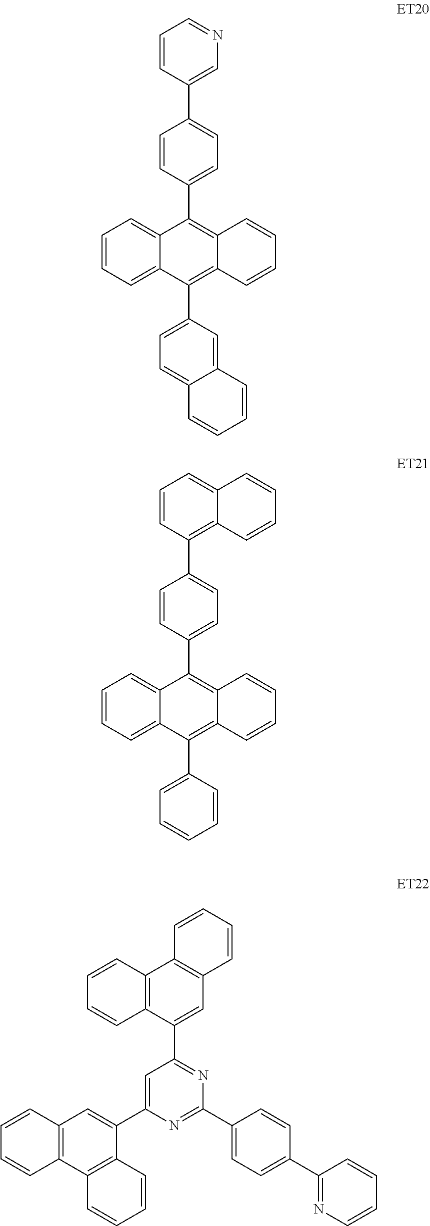

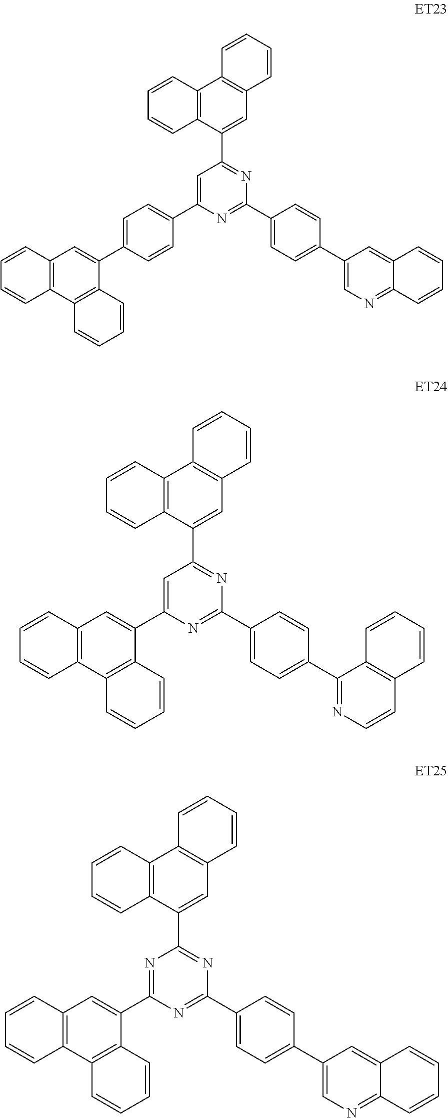 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

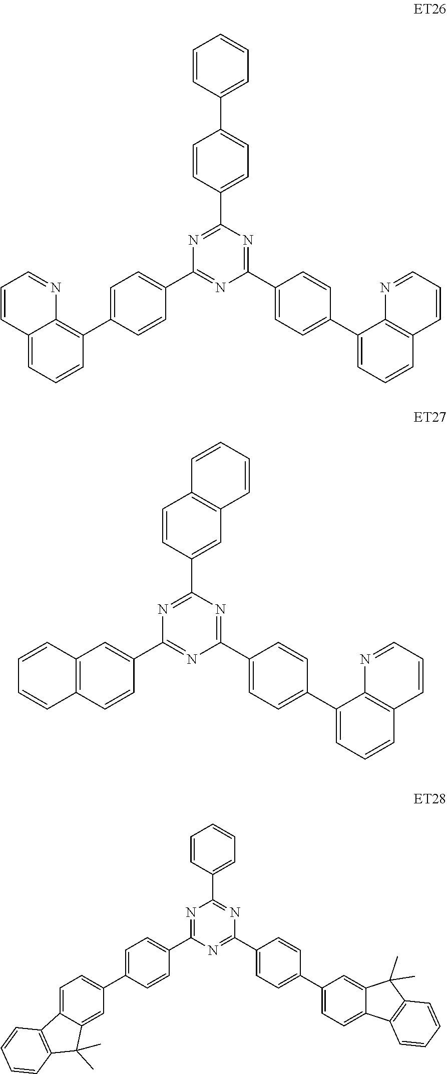 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

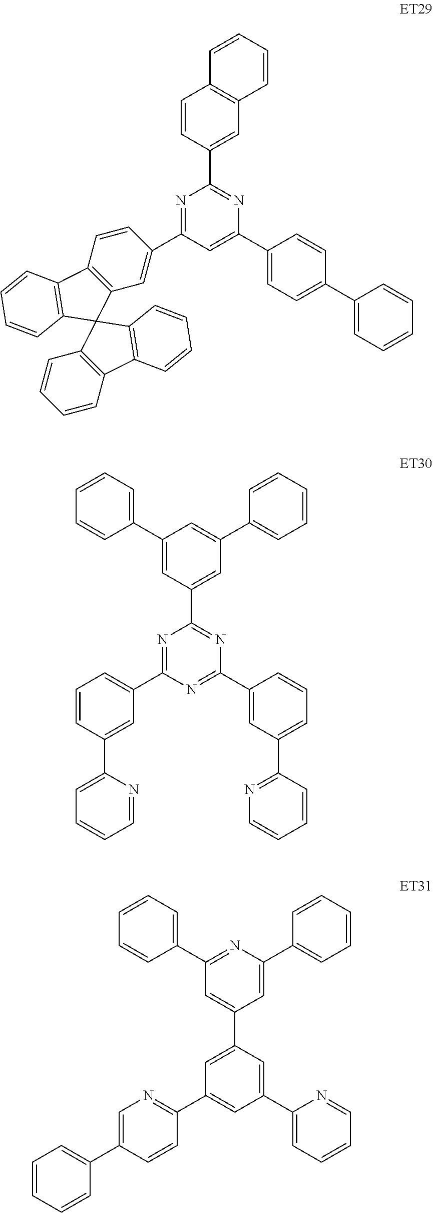 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

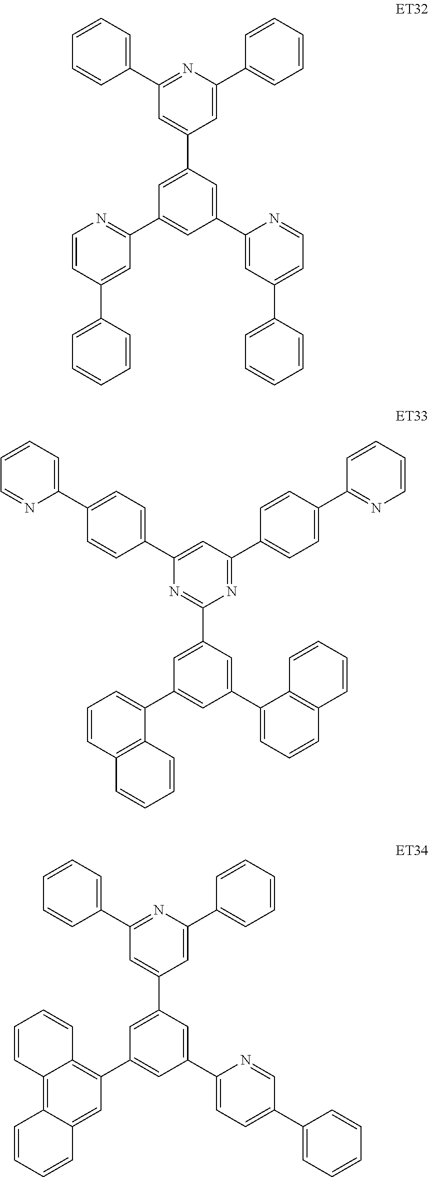 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

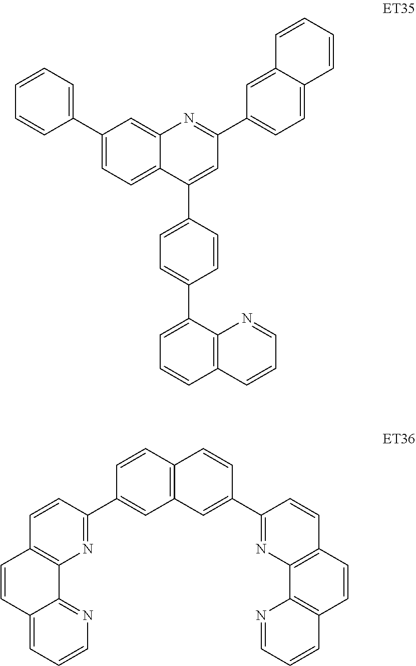 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include a metal halide such as LiF, NaCl, CsF, RbCl, RbI, CuI, and KI; a lanthanide metal such as Yb; or a co-deposited material of a metal halide and a lanthanide metal. For example, the electron transport region ETR may include KI:Yb, RbI:Yb, LiF:Yb, etc., as a co-deposited material. The electron transport region ETR may include a metal oxide such as Li₂O and BaO, or 8-hydroxy-lithium quinolate (Liq). However, embodiments are not limited thereto. The electron transport region ETR also may be formed of a mixture material of an electron transport material and an insulating organometallic salt. The insulating organometallic salt may be a material having an energy band gap equal to or greater than about 4 eV. For example, the insulating organometallic salt may include a metal acetate, a metal benzoate, a metal acetoacetate, a metal acetylacetonate, or a metal stearate.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) and 4,7-diphenyl-1,10-phenanthroline (Bphen), in addition to the aforementioned materials. However, embodiments are not limited thereto.

The electron transport region ETR may include the compounds of the electron transport region in at least one of an electron injection layer EIL, an electron transport layer ETL, and a hole blocking layer HBL.

If the electron transport region ETR includes an electron transport layer ETL, a thickness of the electron transport layer ETL may be in a range of about 100 Å to about 1,000 Å. For example, the thickness of the electron transport layer ETL may be in a range of about 150 Å to about 500 Å. If the thickness of the electron transport layer ETL satisfies any of the above-described ranges, satisfactory electron transport properties may be obtained without a substantial increase of driving voltage. If the electron transport region ETR includes an electron injection layer EIL, a thickness of the electron injection layer EIL may be in a range of about 1 Å to about 100 Å. For example, the thickness of the electron injection layer EIL may be in a range of about 3 Å to about 90 Å. If the thickness of the electron injection layer EIL satisfies any of the above described ranges, satisfactory electron injection properties may be obtained without inducing a substantial increase of driving voltage.

The second electrode EL2 may be provided on the electron transport region ETR. The second electrode EL2 may be a common electrode. The second electrode EL2 may be a cathode or an anode, but embodiments are not limited thereto. For example, if the first electrode EL1 is an anode, the second cathode EL2 may be a cathode, and if the first electrode EL1 is a cathode, the second electrode EL2 may be an anode.

The second electrode EL2 may be a transmissive electrode, a transflective electrode, or a reflective electrode. If the second electrode EL2 is a transmissive electrode, the second electrode EL2 may include a transparent metal oxide, for example, ITO, IZO, ZnO, ITZO, etc.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (for example, AgMg, AgYb, or MgYb). In an embodiment, the second electrode EL2 may have a multilayered structure including a reflective layer or a transflective layer formed of the above-described materials and a transparent conductive layer formed of ITO, IZO, ZnO, ITZO, etc. For example, the second electrode EL2 may include the aforementioned metal materials, combinations of two or more metal materials selected from the aforementioned metal materials, or oxides of the aforementioned metal materials.

Although not shown in the drawings, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, if the capping layer CPL includes an inorganic material, the inorganic material may include an alkali metal compound such as LiF, an alkaline earth metal compound such as MgF₂, SiON, SiNₓ, SiO_{y}, etc.

For example, if the capping layer CPL includes an organic material, the organic material may include 2,2′-dimethyl-N,N′-di-[(1-naphthyl)-N,N′-diphenyl]-1,1′-biphenyl-4,4′-diamine(α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), etc., or may include an epoxy resin, or an acrylate such as methacrylate. In an embodiment, the capping layer CPL may include at least one of Compounds P1 to P5, but embodiments are not limited thereto.

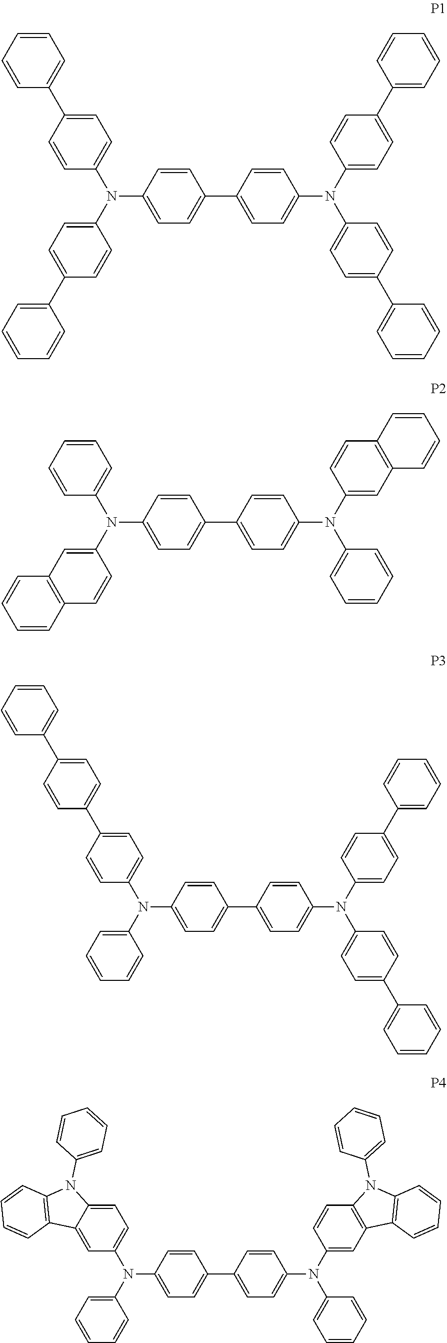 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

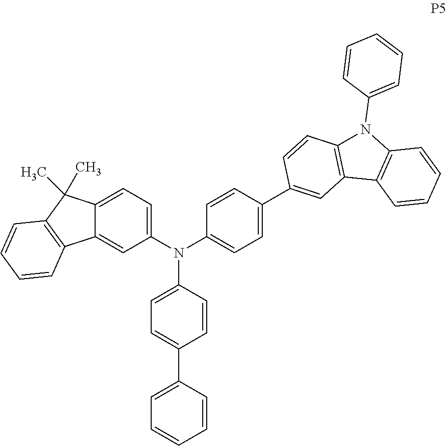 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL equal to or greater than about 1.6, with respect to light in a wavelength range of about 550 nm to about 660 nm.

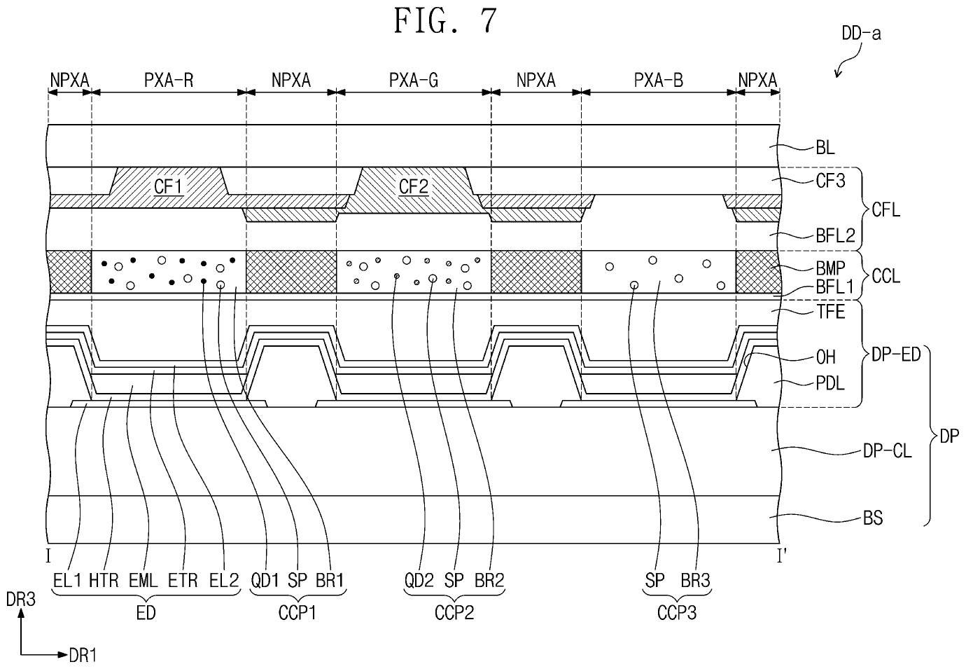

FIG. 7 to FIG. 10 are each a schematic cross-sectional view of a display apparatus according to an embodiment. In the descriptions of the display apparatuses according to embodiments as shown in FIG. 7 to FIG. 10, the features which have been described above with respect to FIG. 1 to FIG. 6 will not be explained again, and the differing features will be explained.

Referring to FIG. 7, the display apparatus DD-a according to an embodiment may include a display panel DP including a display device layer DP-ED, a light controlling layer CCL disposed on the display panel DP, and a color filter layer CFL.

In an embodiment shown in FIG. 7, the display panel DP includes a base layer BS, a circuit layer DP-CL provided on the base layer BS, and a display device layer DP-ED, and the display device layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 7 may be the same as a structure of a light emitting element ED according to one of FIG. 3 to FIG. 6 as described above.

The emission layer EML of the light emitting element ED included in a display apparatus DD-a according to an embodiment may include the fused polycyclic compound according to an embodiment described above.

Referring to FIG. 7, the emission layer EML may be disposed in an opening OH defined in a pixel defining film PDL. For example, the emission layer EML, which is separated by the pixel defining film PDL and correspondingly provided to each of the light emitting regions PXA-R, PXA-G, and PXA-B, may emit light in a same wavelength region. In the display apparatus DD-a, the emission layer EML may emit blue light. Although not shown in the drawings, in an embodiment, the emission layer EML may be provided as a common layer for each of the light emitting regions PXA-R, PXA-G, and PXA-B.

The light controlling layer CCL may be disposed on the display panel DP. The light controlling layer CCL may include a light converter. The light converter may be a quantum dot or a phosphor. The light converter may convert the wavelength of a provided light and emit the resulting light. For example, the light controlling layer CCL may be a layer including a quantum dot or a layer including a phosphor.

The light controlling layer CCL may include light controlling parts CCP1, CCP2, and CCP3. The light controlling parts CCP1, CCP2, and CCP3 may be spaced apart from each other.

Referring to FIG. 7, a partition pattern BMP may be disposed between the light controlling parts CCP1, CCP2, and CCP3, which are spaced apart from each other, but embodiments are not limited thereto. In FIG. 7, it is shown that the partition pattern BMP does not overlap the light controlling parts CCP1, CCP2, and CCP3, but the edges of the light controlling parts CCP1, CCP2, and CCP3 may overlap at least a portion of the partition pattern BMP.

The light controlling layer CCL may include a first light controlling part CCP1 including a first quantum dot QD1 that converts first color light provided from the light emitting element ED into second color light, a second light controlling part CCP2 including a second quantum dot QD2 that converts first color light into third color light, and a third light controlling part CCP3 that transmits first color light.

In an embodiment, the first light controlling part CCP1 may provide red light, which is the second color light, and the second light controlling part CCP2 may provide green light, which is the third color light. The third color controlling part CCP3 may transmit and provide blue light, which is the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but may include the scatterer SP.

The scatterer SP may be an inorganic particle. For example, the scatterer SP may include at least one of TiO₂, ZnO, Al₂O₃, SiO₂, and hollow silica. The scatterer SP may include at least one of TiO₂, ZnO, Al₂O₃, SiO₂, and hollow silica, or may be a mixture of two or more materials selected from TiO₂, ZnO, Al₂O₃, SiO₂, and hollow silica.

The first light controlling part CCP1, the second light controlling part CCP2, and the third light controlling part CCP3 may each include base resins BR1, BR2, and BR3, in which the quantum dots QD1 and QD2 and the scatterer SP are dispersed. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer SP dispersed in the third base resin BR3.

The base resins BR1, BR2, and BR3 are mediums in which the quantum dots QD1 and QD2 and the scatterer SP are dispersed, and may be composed of various resin compositions which may be generally referred to as a binder. For example, the base resins BR1, BR2, and BR3 may be acrylic resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light controlling layer CCL may include a barrier layer BFL1. The barrier layer BFL1 may block the penetration of moisture and/or oxygen (hereinafter, will be referred to as “humidity/oxygen”). The barrier layer BFL1 may block the light controlling parts CCP1, CCP2, and CCP3 from exposure to humidity/oxygen. The barrier layer BFL1 may cover the light controlling parts CCP1, CCP2, and CCP3. A color filter layer CFL, which will be explained later, may include a barrier layer BFL2 disposed on the light controlling parts CCP1, CCP2, and CCP3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film securing light transmittance. The barrier layers BFL1 and BFL2 may each independently further include an organic layer. The barrier layers BFL1 and BFL2 may each be formed of a single layer or of multiple layers.

In the display apparatus DD-a, the color filter layer CFL may be disposed on the light controlling layer CCL. In an embodiment, the color filter layer CFL may be disposed directly on the light controlling layer CCL. For example, the barrier layer BFL2 may be omitted.

The color filter layer CFL may include filters CF1, CF2, and CF3. The first to third filters CF1, CF2, and CF3 may be disposed to respectively correspond to a red light emitting region PXA-R, a green light emitting region PXA-G, and a blue light emitting region PXA-B.

The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymer photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymer photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may be provided in one body, without distinction.

Although not shown in the drawings, the color filter layer CFL may further include a light blocking part (not shown). The light blocking part (not shown) may be a black matrix. The light blocking part (not shown) may include an organic light blocking material or an inorganic light blocking material, each including a black pigment or a black dye. The light blocking part (not shown) may prevent light leakage, and may separate the boundaries between adjacent filters CF1, CF2, and CF3.

A base substrate BL may be disposed on the color filter layer CFL. The base substrate BL may provide a base surface on which the color filter layer CFL, the light controlling layer CCL, etc. are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

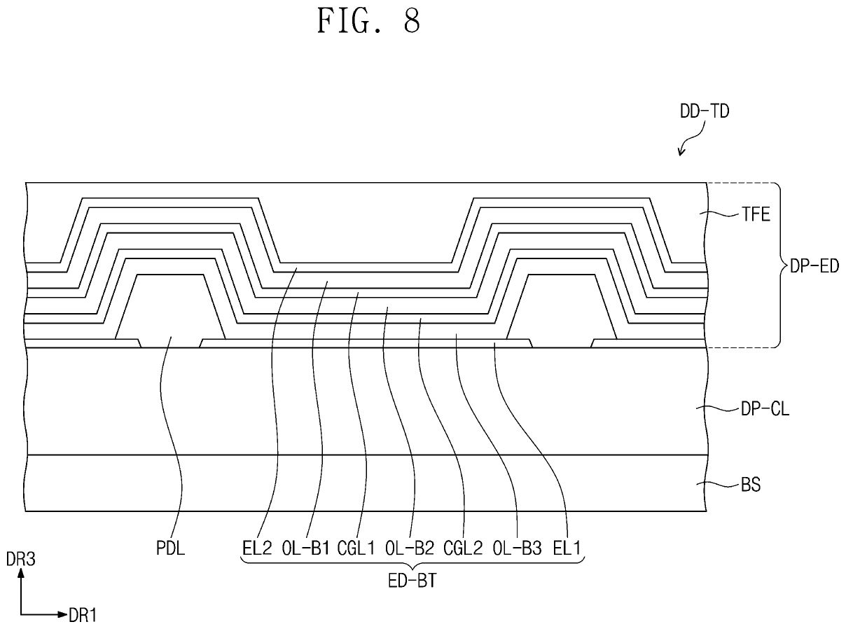

FIG. 8 is a schematic cross-sectional view of a portion of a display apparatus according to an embodiment. In a display apparatus DD-TD according to an embodiment, the light emitting element ED-BT may include light emitting structures OL-B1, OL-B2, and OL-B3.

The light emitting element ED-BT may include first electrode EL1 and second electrode EL2 which face each other, and the light emitting structures OL-B1, OL-B2, and OL-B3 stacked in a thickness direction between the first electrode EL1 and the second electrode EL2. The light emitting structures OL-B1, OL-B2, and OL-B3 may each include an emission layer EML (see FIG. 7), and a hole transport region HTR and an electron transport region ETR disposed with the emission layer EML (see FIG. 7) therebetween.

For example, the light emitting element ED-BT included in the display apparatus DD-TD may be a light emitting element having a tandem structure and including multiple emission layers.

In an embodiment shown in FIG. 8, light emitted from each of the light emitting structures OL-B1, OL-B2, and OL-B3 may be blue light. However, embodiments are not limited thereto, and the light emitted from each of the light emitting structures OL-B1, OL-B2, and OL-B3 may have wavelength regions that are different from each other. For example, the light emitting element ED-BT that includes the light emitting structures OL-B1, OL-B2, and OL-B3, which emit light having wavelength regions that are different from each other, may emit white light.

Charge generating layers CGL1 and CGL2 may each be disposed neighboring light emitting structures among the light emitting structures OL-B1, OL-B2, and OL-B3. Charge generating layers CGL1 and CGL2 may each independently include a p-type charge generating layer and/or an n-type charge generating layer.

At least one of the light emitting structures OL-B1, OL-B2, and OL-B3 in the display apparatus DD-TD may include the fused polycyclic compound according to an embodiment. For example, at least one of the emission layers included in the light emitting element ED-BT may include the fused polycyclic compound.

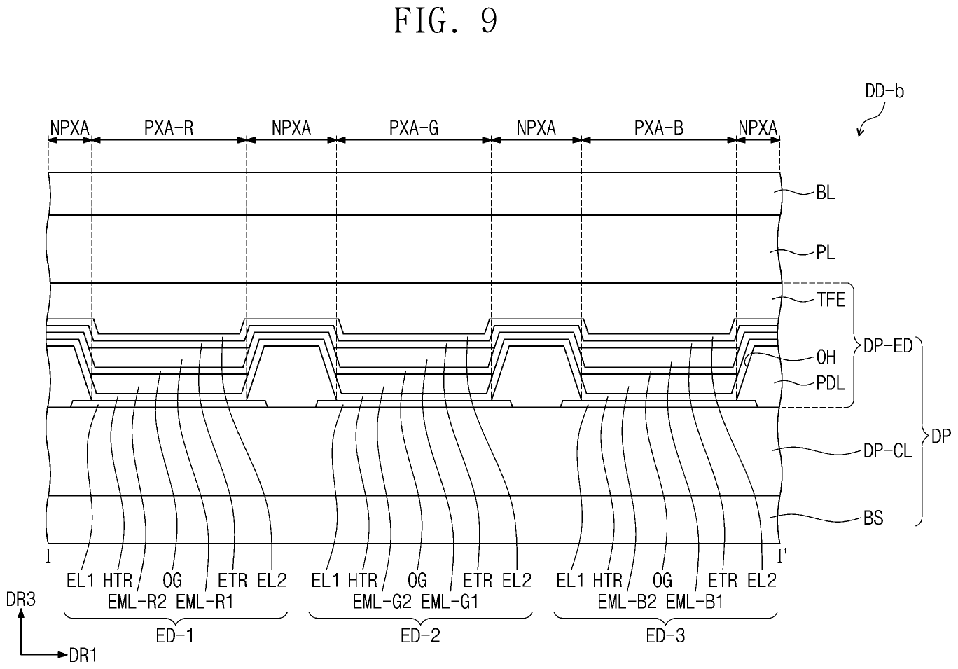

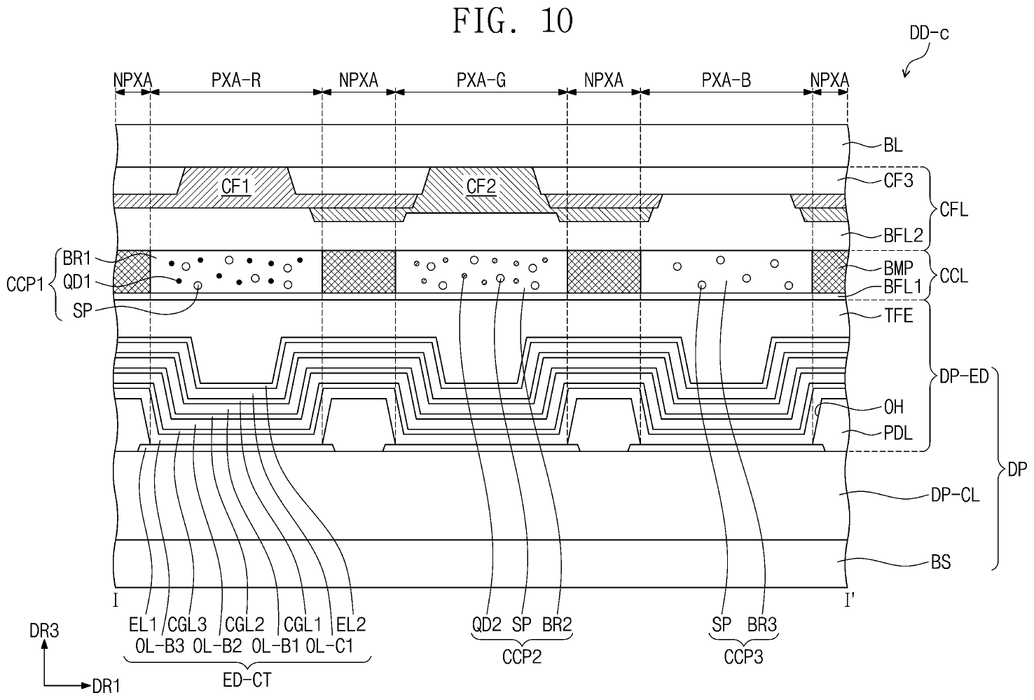

FIG. 9 is a schematic cross-sectional view of a display apparatus according to an embodiment. FIG. 10 is a schematic cross-sectional view of a display apparatus according to an embodiment.

Referring to FIG. 9, a display apparatus DD-b according to an embodiment may include light emitting elements ED-1, ED-2, and ED-3, in which two emission layers are stacked. In comparison to the display apparatus DD shown in FIG. 2, the embodiment shown in FIG. 9 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generating layer. For example, the emission auxiliary part OG may include an electron transport region, a charge generating layer, and a hole transport region, which may be stacked in that order. The emission auxiliary part OG may be provided as a common layer for each of the first to third light emitting elements ED-1, ED-2, and ED-3. However, embodiments are not limited thereto, and the emission auxiliary part OG may be provided by being patterned in the openings OH defined in the pixel defining film PDL.

The first red emission layer EML-R1, the first green emission layer EML-G1 and the first blue emission layer EML-B1 may each be disposed between the electron transport region ETR and the emission auxiliary part OG. The second red emission layer EML-R2, the second green emission layer EML-G2, and the second blue emission layer EML-B2 may each be disposed between the emission auxiliary part OG and the hole transport region HTR.

For example, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2, which are stacked in that order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, which are stacked in that order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, which are stacked in that order.

An optical auxiliary layer PL may be disposed on the display device layer DP-ED. The optical auxiliary layer PL may include a polarization layer. The optical auxiliary layer PL may be disposed on the display panel DP and may control light that is reflected at the display panel DP from an external light. Although not shown the drawings, in an embodiment, the optical auxiliary layer PL may be omitted from the display apparatus DD-b.

At least one emission layer included in the display apparatus DD-b shown in FIG. 9 may include the fused polycyclic compound according to an embodiment. For example, in an embodiment, at least one of the first blue emission layer EML-B1 and the second blue emission layer EML-B2 may include the fused polycyclic compound.

In contrast to FIG. 8 and FIG. 9, FIG. 10 shows a display apparatus DD-c that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. In an embodiment, the third light emitting structure OL-B3, the second light emitting structure OL-B2, the first light emitting structure OL-B1, and the fourth light emitting structure OL-C1 may be stacked in the stated order in a thickness direction.

Charge generating layers CGL1, CGL2, and CGL3 may each be disposed between adjacent light emitting structures among the first to fourth light emitting structures OL-B1, OL-B2, OL-B3, and OL-C1. For example, a first charge generating layer CGL1 may be disposed between the first light emitting structure OL-B1 and the fourth light emitting structure OL-C1. For example, a second charge generating layer CGL2 may be disposed between the first light emitting structure OL-B1 and the second light emitting structure OL-B2. For example, a third charge generating layer CGL3 may be disposed between the second light emitting structure OL-B2 and the third light emitting structure OL-B3.

Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3 and OL-C1 may emit light having different wavelengths from each other.

The charge generating layers CGL1, CGL2, and CGL3 that are disposed between neighboring light emitting structures among the first to fourth light emitting structures OL-B1, OL-B2, OL-B3, and OL-C1 may each independently include a p-type charge generating layer and/or an n-type charge generating layer.

In the display apparatus DD-c, at least one of the light emitting structures OL-B1, OL-B2, OL-B3, and OL-C1 may each independently include the fused polycyclic compound according to an embodiment as described above. For example, in an embodiment, at least one of the first to third light emitting structures OL-B1, OL-B2, and OL-B3 may each independently include the fused polycyclic compound.

The light emitting element ED according to an embodiment may include the fused polycyclic compound represented by Formula 1 in at least one functional layer disposed between the first electrode EL1 and the second electrode EL2, thereby exhibiting excellent emission efficiency and improved lifespan. For example, the emission layer EML of the light emitting element ED may include the fused polycyclic compound, and the light emitting element ED may exhibit a long lifespan.

In an embodiment, an electronic apparatus may include a display apparatus that includes multiple light emitting elements and a control part which controls the display apparatus. The electronic apparatus may be a device that is activated according to electrical signals. The electronic apparatus may include display apparatuses according to various embodiments. Examples of an electronic apparatus may include a television, a monitor, large display apparatuses such as a billboard, a personal computer, a laptop computer, a personal digital terminal, a vehicle display device, a game console, a portable electronic device, and a medium-sizes or small apparatuses such as a camera.

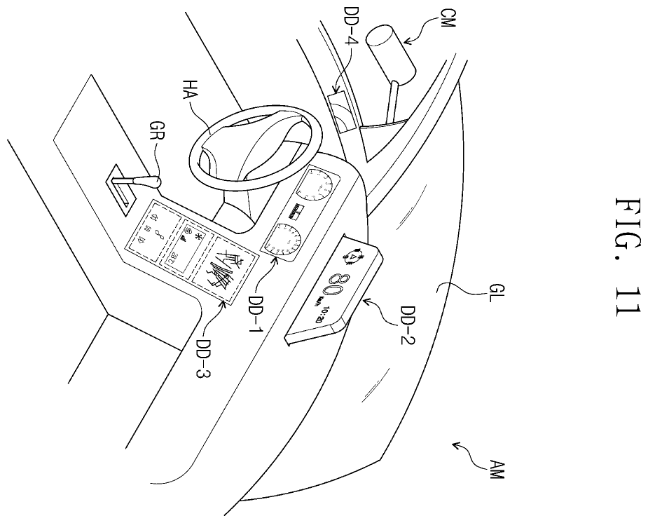

FIG. 11 is a schematic perspective view of a vehicle AM in which first to fourth display apparatuses DD-1, DD-2, DD-3, and DD-4 are disposed. At least one of the first to fourth display apparatuses DD-1, DD-2, DD-3, and DD-4 may have a structure according to one of display apparatuses DD, DD-TD, DD-a, DD-b, and DD-c, as described above with reference to FIGS. 1, 2, and 7 to 10.

In FIG. 11, a vehicle AM is shown as an automobile, but this is only an example, and the first to fourth display apparatuses DD-1, DD-2, DD-3, and DD-4 may be disposed in various transportation means such as bicycles, motorcycles, trains, ships, and airplanes. In an embodiment, at least one of the first to fourth display apparatuses DD-1, DD-2, DD-3, and DD-4 having a structure according to one of display apparatuses DD, DD-TD, DD-a, DD-b, and DD-c may be included in a personal computer, a laptop computer, a personal digital terminal, a game console, a portable electronic device, a television, a monitor, a billboard, or the like. However, these are merely suggested as examples, and the display apparatus may be included in other electronic devices.

At least one of the first to fourth display apparatuses DD-1, DD-2, DD-3, and DD-4 may each independently include a light emitting element ED according to an embodiment as described with reference to any of FIG. 3 to FIG. 6. The light emitting element ED may include the fused polycyclic compound according to an embodiment. At least one of the first to fourth display apparatuses DD-1, DD-2, DD-3, and DD-4 may include a light emitting element ED that includes the fused polycyclic compound according to an embodiment and may thus show improved display lifetime.

Referring to FIG. 11, a vehicle AM may include a steering wheel HA for the operation of the vehicle AM and a gearshift GR. The vehicle AM may include a front window GL that is disposed so as to face a driver.

A first display apparatus DD-1 may be disposed in a first region that overlaps the steering wheel HA. For example, the first display apparatus DD-1 may be a digital cluster that displays first information of the automobile AM. The first information may include a first scale which indicates a driving speed of the automobile AM, a second scale which indicates an engine speed (i.e., as revolutions per minute (RPM)), a fuel gauge, and the like. The first scale and the second scale may each be represented by a digital image.

A second display apparatus DD-2 may be disposed in a second region facing a driver's seat and overlapping the front window GL. The driver's seat may be a seat where the steering wheel HA is disposed. For example, the second display apparatus DD-2 may be a head up display (HUD) that displays second information of the vehicle AM. The second display apparatus DD-2 may be optically transparent. The second information may include digital numbers that indicate a driving speed of the vehicle AM and may further include information such as the current time. Although not shown in the drawings, in an embodiment, the second information of the second display apparatus DD-2 may be displayed by being projected on the front window GL.

A third display apparatus DD-3 may be disposed in a third region adjacent to the gearshift GR. For example, the third display apparatus DD-3 may be a center information display (CID) for a vehicle that is disposed between a driver's seat and a passenger seat that displays third information. The passenger seat may be a seat that is spaced apart from the driver's seat with the gearshift GR disposed therebetween. The third information may include information on traffic or road conditions (for example, navigation information), playing music or radio, displaying an image or a video, the temperature in the vehicle AM, or the like.

A fourth display apparatus DD-4 may be disposed in a fourth region that is spaced apart from the steering wheel HA and the gearshift GR and adjacent to a side of the vehicle AM. For example, the fourth display apparatus DD-4 may be a digital side-view mirror that displays fourth information. The fourth display apparatus DD-4 may display an image external to the vehicle AM that is taken by a camera module CM disposed outside the vehicle AM. The fourth information may include an image of the exterior of the vehicle AM.

The first to fourth information as described above are only presented as examples, and the first to fourth display apparatuses DD-1, DD-2, DD-3, and DD-4 may further display information about the interior and exterior of the vehicle AM. The first to fourth information may include information that is different from each other. However, embodiments are not limited thereto, and a portion of the first to fourth information may include the same information.

Hereinafter, a fused polycyclic compound according to an embodiment and a light emitting element according to an embodiment will be explained with reference to the Examples and the Comparative Examples. The Examples described below are only provided as illustrations to assist in understanding the disclosure, and the scope thereof is not limited thereto.

### EXAMPLES

### 1. Synthesis of Fused Polycyclic Compound

A synthesis method of the fused polycyclic compound according to embodiments will be explained by describing synthesis methods for Compounds 1, 6, 7, 20, 35, and 81 as examples. The synthesis methods of the fused polycyclic compounds as explained hereinafter are provided only as examples, and synthesis methods of fused polycyclic compounds according to embodiments are not limited to the Examples below.

### (1) Synthesis of Compound 1

### (Synthesis of Intermediate 1-1)

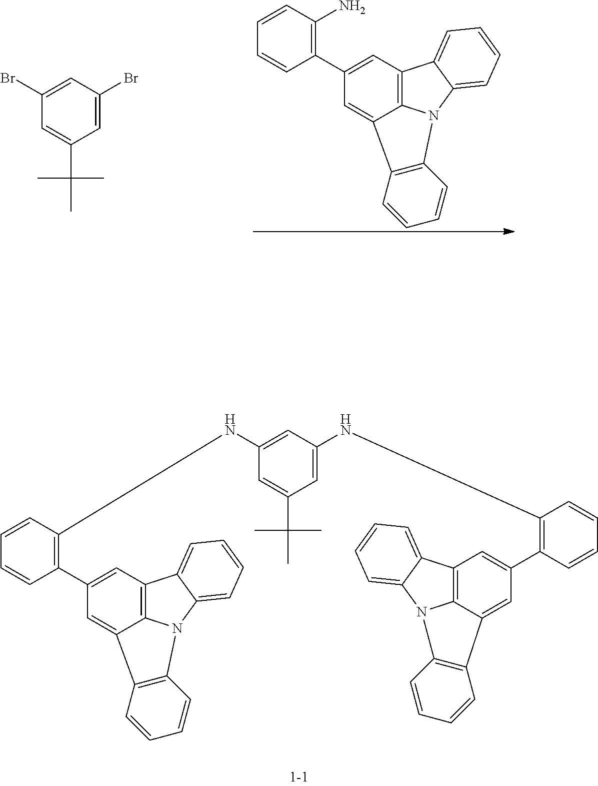 [SMILES: CC(C)(C)c1cc(Br)cc(Br)c1 ; Nc1ccccc1-c1cc2c3ccccc3n3c4ccccc4c(c1)c23 ; CC(C)(C)c1cc(Nc2ccccc2-c2cc3c4ccccc4n4c5ccccc5c(c2)c34)cc(Nc2ccccc2-c2cc3c4ccccc4n4c5ccccc5c(c2)c34)c1]

1,3-Dibromo-5-(tert-butyl)benzene (1 eq), 2-(indolo[3,2,1-jk]carbazol-2-yl)aniline (2 eq), tris(dibenzylideneacetone)dipalladium(0) (0.05 eq), tri-tert-butylphosphine (0.1 eq), and sodium tert-butoxide (3 eq) were dissolved in toluene and stirred at about 110 degrees centigrade for about 12 hours. After cooling, the resultant was washed with ethyl acetate and water three times, layers were separated, and an organic layer obtained was dried over MgSO₄ and dried under a reduced pressure. The crude product was purified by column chromatography using methylene chloride (MC) and n-hexane to obtain Intermediate 1-1 (yield: 68%).

### (Synthesis of Intermediate 1-2)

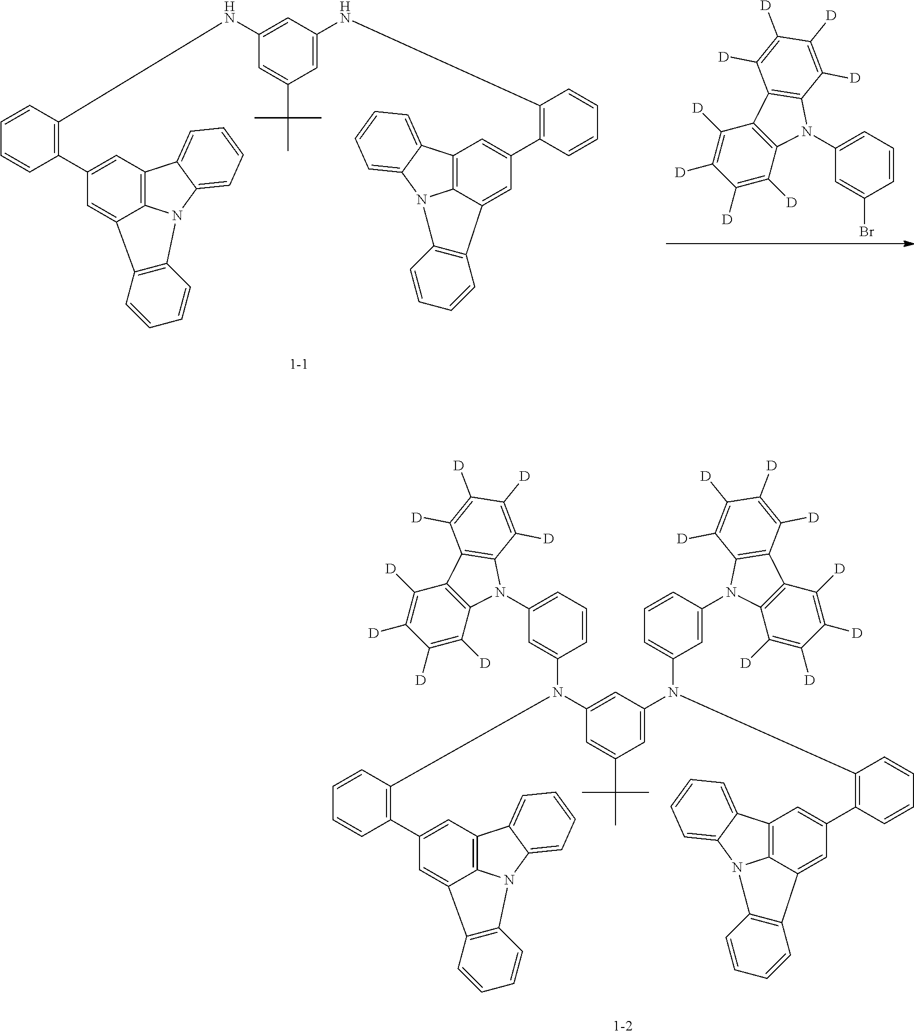 [SMILES: CC(C)(C)c1cc(Nc2ccccc2-c2cc3c4ccccc4n4c5ccccc5c(c2)c34)cc(Nc2ccccc2-c2cc3c4ccccc4n4c5ccccc5c(c2)c34)c1 ; [2H]c1c([2H])c([2H])c2c(c1[2H])c1c([2H])c([2H])c([2H])c([2H])c1n2-c1cccc(Br)c1 ; [2H]c1c([2H])c([2H])c2c(c1[2H])c1c([2H])c([2H])c([2H])c([2H])c1n2-c1cccc(N(c2cc(N(c3cccc(-n4c5c([2H])c([2H])c([2H])c([2H])c5c5c([2H])c([2H])c([2H])c([2H])c54)c3)c3ccccc3-c3cc4c5ccccc5n5c6ccccc6c(c3)c45)cc(C(C)(C)C)c2)c2ccccc2-c2cc3c4ccccc4n4c5ccccc5c(c2)c34)c1]

Intermediate 1-1 (1 eq), 9-(3-bromophenyl)-9H-carbazole-1,2,3,4,5,6,7,8-d8 (2 eq), tris(dibenzylideneacetone)dipalladium(0) (0.1 eq), tri-tert-butylphosphine (0.2 eq), and sodium tert-butoxide (3 eq) were dissolved in o-xylene and stirred at about 140 degrees centigrade for about 12 hours. After cooling, the resultant was washed with ethyl acetate and water three times, layers were separated, and an organic layer obtained was dried over MgSO₄ and dried under a reduced pressure. The crude product was purified by column chromatography using MC and n-hexane to obtain Intermediate 1-2 (yield: 74%).

### (Synthesis of Compound 1)

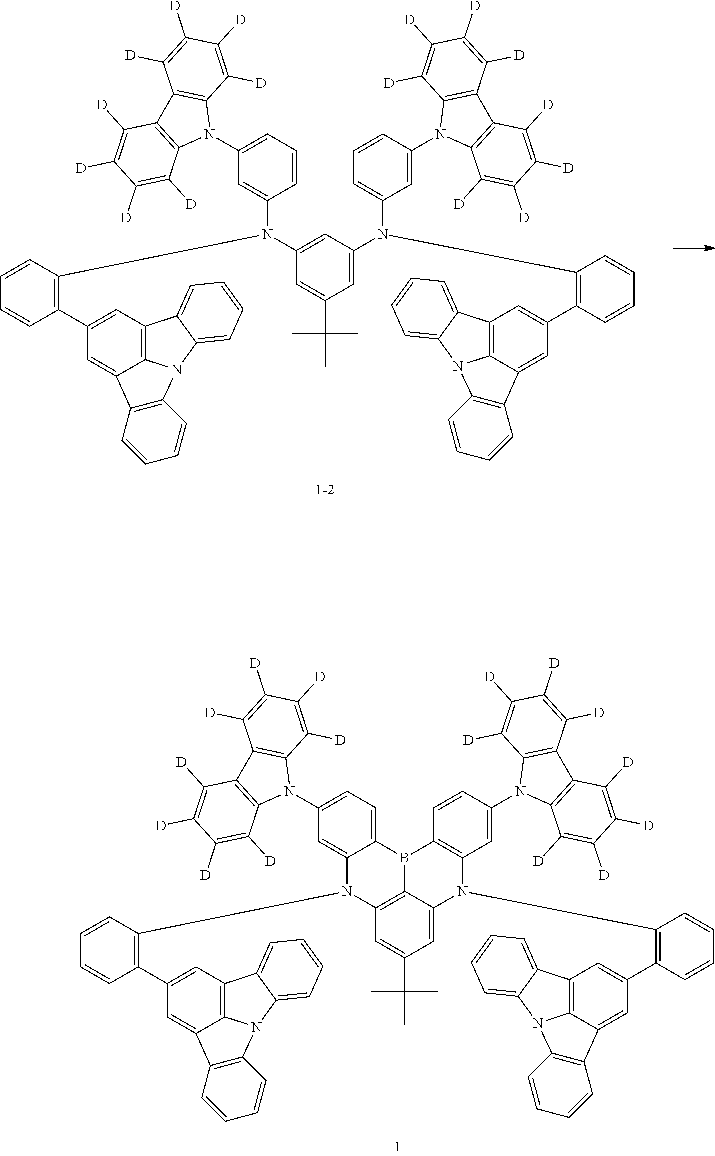

Intermediate 1-2 (1 eq) was dissolved in o-dichlorobenzene and cooled to about 0 degrees centigrade, and BBr₃ (4 eq) was slowly injected under a nitrogen atmosphere. After finishing the dropwise addition, the temperature was raised to about 180 degrees centigrade, followed by stirring for about 48 hours. After cooling, triethylamine was slowly added dropwise to a flask containing the reaction product to terminate the reaction, and ethyl alcohol was added to precipitate. The precipitate was filtered, and the solid thus obtained was purified by column chromatography using MC and n-hexane and recrystallized using toluene and acetone to obtain Compound 1 (yield: 9%).

### (2) Synthesis of Compound 6

### (Synthesis of Intermediate 6-1)

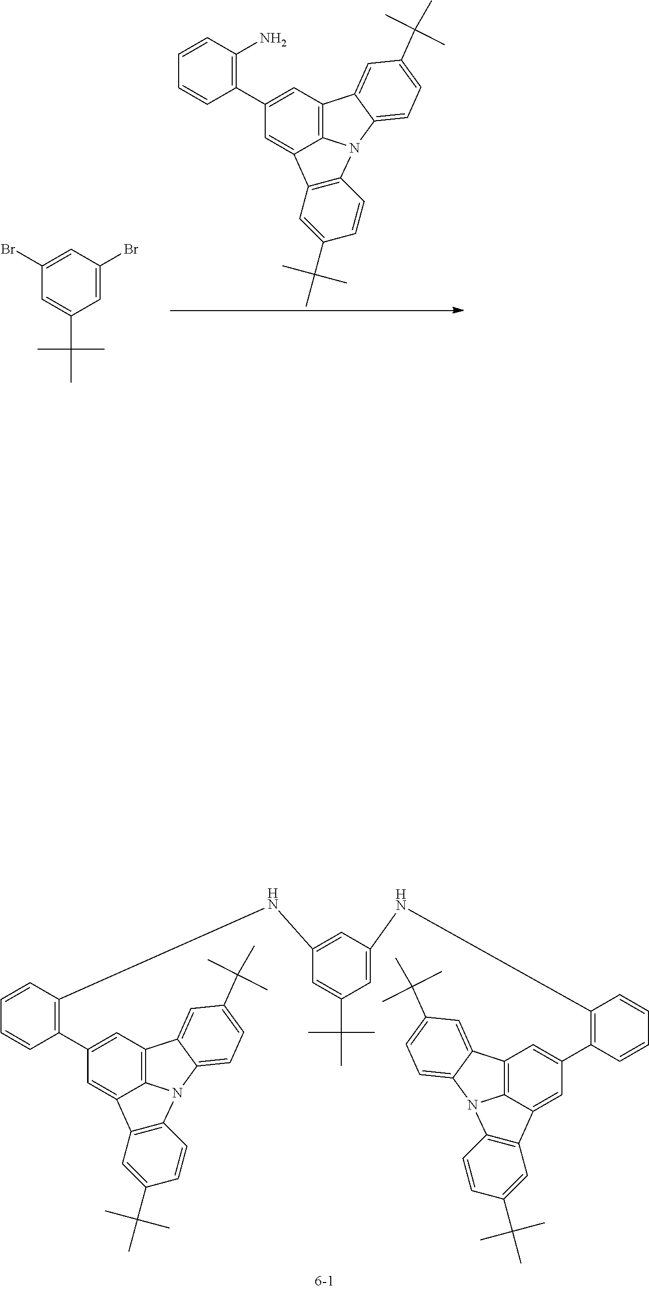 [SMILES: CC(C)(C)c1cc(Br)cc(Br)c1 ; CC(C)(C)c1ccc2c(c1)c1cc(-c3ccccc3N)cc3c4cc(C(C)(C)C)ccc4n2c13 ; CC(C)(C)c1cc(Nc2ccccc2-c2cc3c4cc(C(C)(C)C)ccc4n4c5ccc(C(C)(C)C)cc5c(c2)c34)cc(Nc2ccccc2-c2cc3c4cc(C(C)(C)C)ccc4n4c5ccc(C(C)(C)C)cc5c(c2)c34)c1]

1,3-Dibromo-5-(tert-butyl)benzene (1 eq), 2-(5,11-di-tert-butylindolo[3,2,1-jk]carbazol-2-yl)aniline (2 eq), tris(dibenzylideneacetone)dipalladium(0) (0.05 eq), tri-tert-butylphosphine (0.1 eq), and sodium tert-butoxide (3 eq) were dissolved in toluene and stirred at about 110 degrees centigrade for about 12 hours. After cooling, the resultant was washed with ethyl acetate and water three times, layers were separated, and an organic layer obtained was dried over MgSO₄ and dried under a reduced pressure. The crude product was purified by column chromatography using methylene chloride (MC) and n-hexane to obtain Intermediate 6-1 (yield: 59%).

### (Synthesis of Intermediate 6-2)

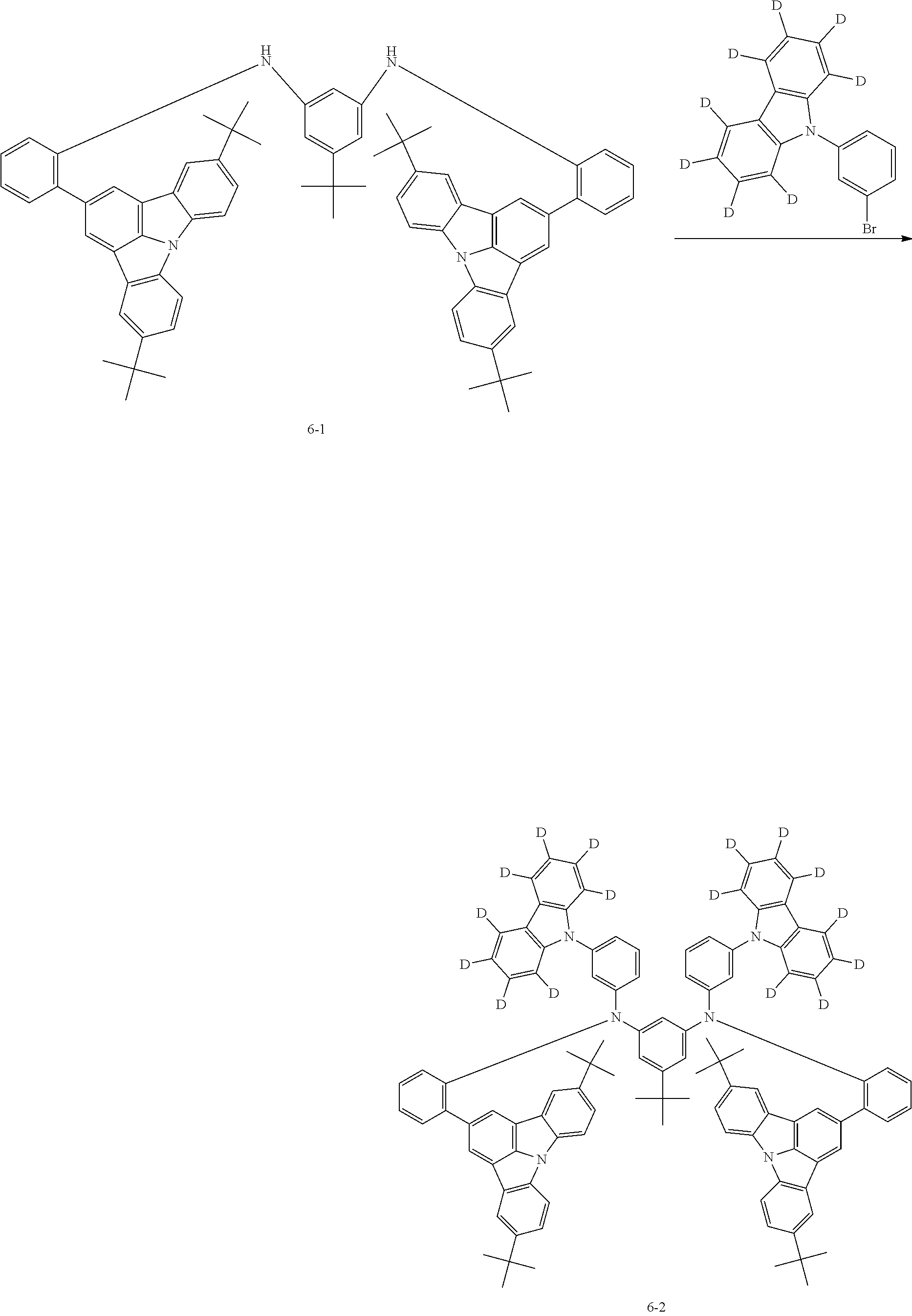

Intermediate 6-1 (1 eq), 9-(3-bromophenyl)-9H-carbazole-1,2,3,4,5,6,7,8-d8 (2 eq), tris(dibenzylideneacetone)dipalladium(0) (0.1 eq), tri-tert-butylphosphine (0.2 eq), and sodium tert-butoxide (3 eq) were dissolved in o-xylene and stirred at about 140 degrees centigrade for about 12 hours. After cooling, the resultant was washed with ethyl acetate and water three times, layers were separated, and an organic layer obtained was dried over MgSO₄ and dried under a reduced pressure. The crude product was purified by column chromatography using MC and n-hexane to obtain Intermediate 6-2 (yield: 66%).

### (Synthesis of Compound 6)

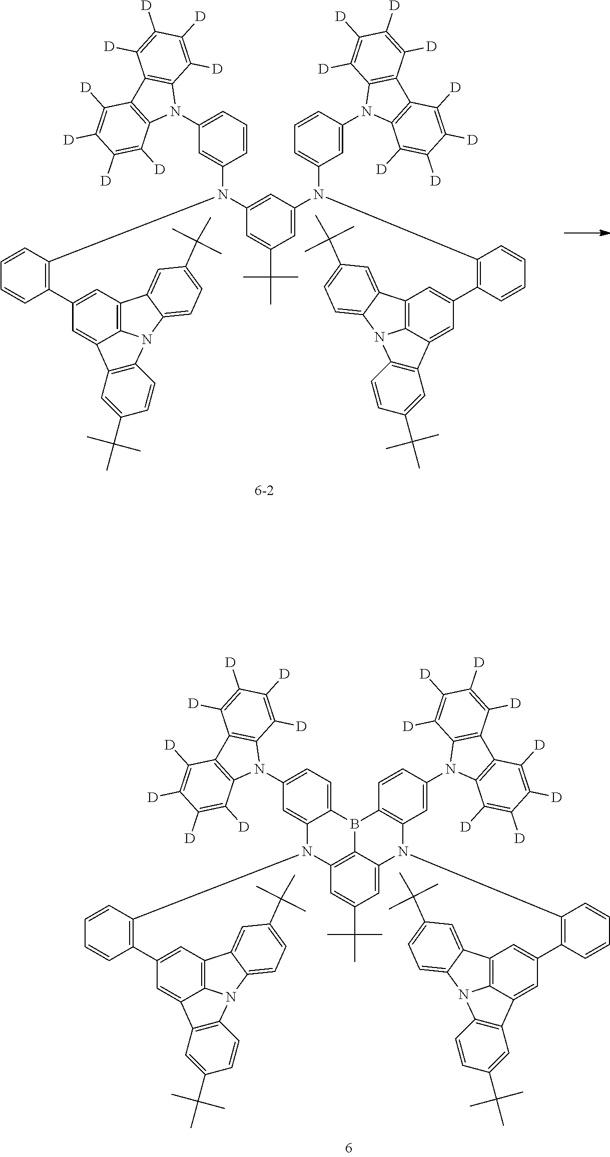

Intermediate 6-2 (1 eq) was dissolved in o-dichlorobenzene and cooled to about 0 degrees centigrade, and BBr₃ (4 eq) was slowly injected under a nitrogen atmosphere. After finishing the dropwise addition, the temperature was raised to about 180 degrees centigrade, followed by stirring for about 48 hours. After cooling, triethylamine was slowly added dropwise to a flask containing the reaction product to terminate the reaction, and ethyl alcohol was added to precipitate. The precipitate was filtered, and the solid thus obtained was purified by column chromatography using MC and n-hexane and recrystallized using toluene and acetone to obtain Compound 6 (yield: 6%).

### (3) Synthesis of Compound 7

### (Synthesis of Intermediate 7-1)

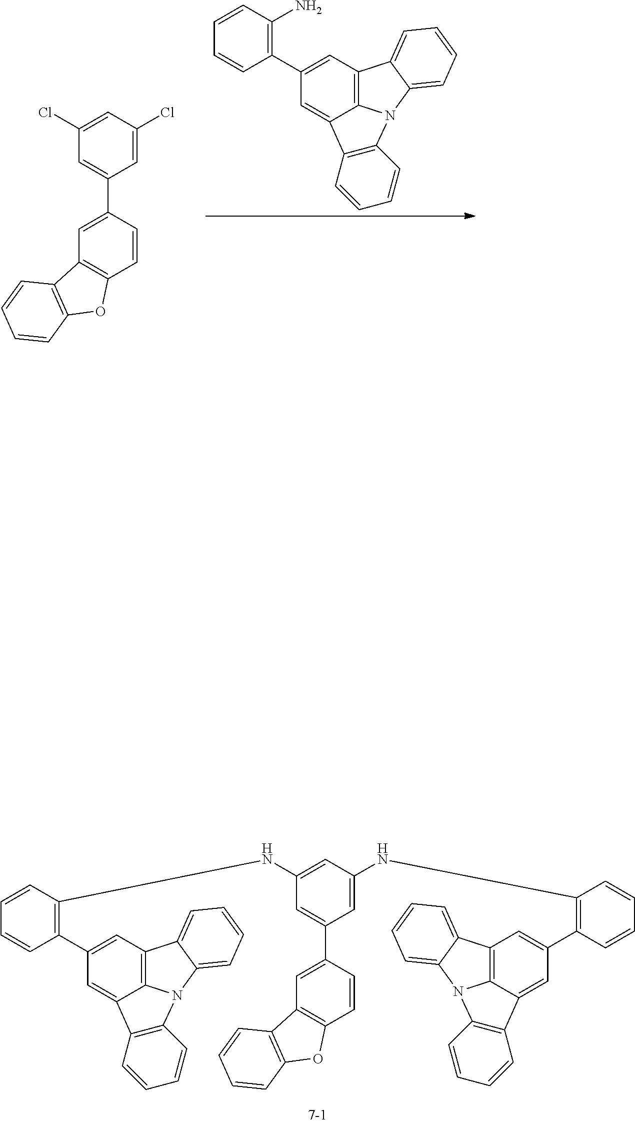

2-(3,5-Dichlorophenyl)dibenzo[b,d]furan (1 eq), 2-(indolo[3,2,1-jk]carbazol-2-yl)aniline (2 eq), tris(dibenzylideneacetone)dipalladium(0) (0.05 eq), tri-tert-butylphosphine (0.1 eq), and sodium tert-butoxide (3 eq) were dissolved in toluene and stirred at about 110 degrees centigrade for about 12 hours. After cooling, the resultant was washed with ethyl acetate and water three times, layers were separated, and an organic layer obtained was dried over MgSO₄ and dried under a reduced pressure. The crude product was purified by column chromatography using methylene chloride (MC) and n-hexane to obtain Intermediate 7-1 (yield: 74%).

### (Synthesis of Intermediate 7-2)

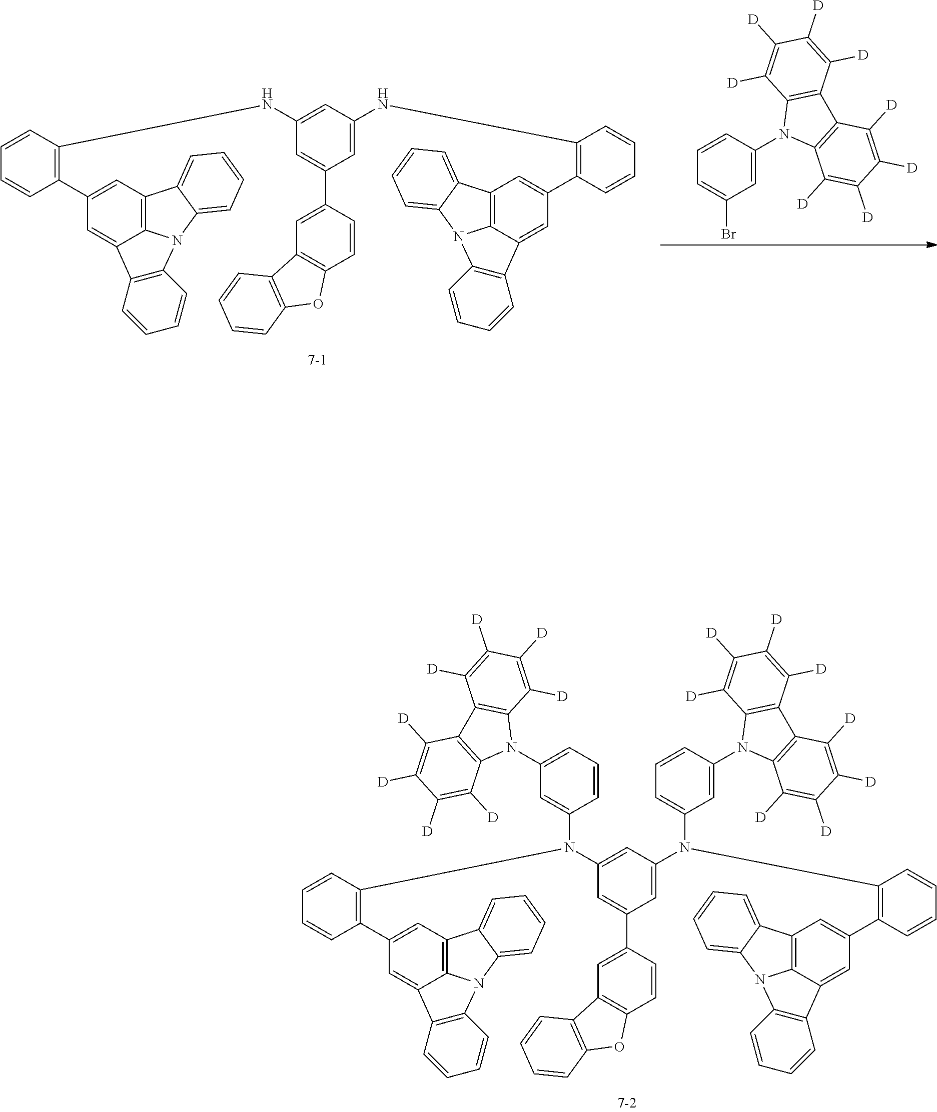

Intermediate 7-1 (1 eq), 9-(3-bromophenyl)-9H-carbazole-1,2,3,4,5,6,7,8-d8 (2 eq), tris(dibenzylideneacetone)dipalladium(0) (0.1 eq), tri-tert-butylphosphine (0.2 eq), and sodium tert-butoxide (3 eq) were dissolved in o-xylene and stirred at about 140 degrees centigrade for about 12 hours. After cooling, the resultant was washed with ethyl acetate and water three times, layers were separated, and an organic layer obtained was dried over MgSO₄ and dried under a reduced pressure. The crude product was purified by column chromatography using MC and n-hexane to obtain Intermediate 7-2 (yield: 73%).

### (Synthesis of Compound 7)

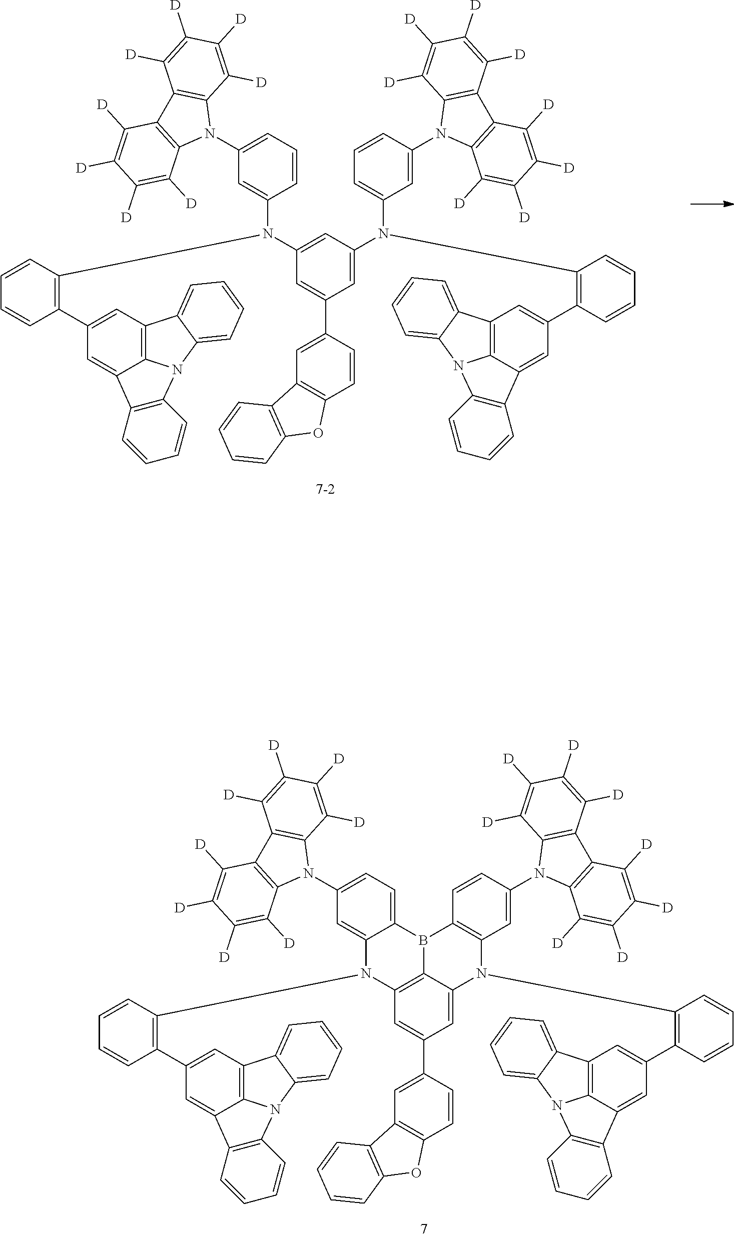

Intermediate 7-2 (1 eq) was dissolved in o-dichlorobenzene and cooled to about 0 degrees centigrade, and BBr₃ (4 eq) was slowly injected under a nitrogen atmosphere. After finishing the dropwise addition, the temperature was raised to about 180 degrees centigrade, and stirring was performed for about 48 hours. After cooling, triethylamine was slowly added dropwise to a flask containing the reaction product to terminate the reaction, and ethyl alcohol was added to precipitate. The precipitate was filtered, and the solid thus obtained was purified by column chromatography using MC and n-hexane and recrystallized using toluene and acetone to obtain Compound 7 (yield: 5%).

### (4) Synthesis of Compound 20

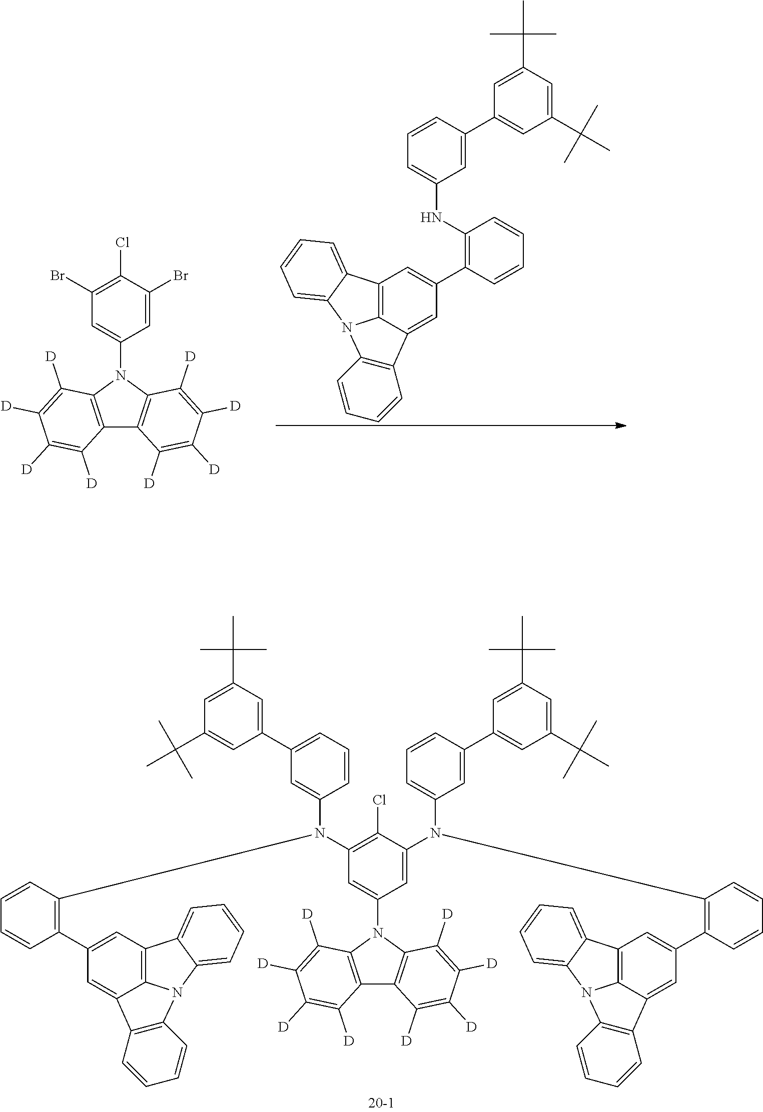 [SMILES: [2H]c1c([2H])c([2H])c2c(c1[2H])c1c([2H])c([2H])c([2H])c([2H])c1n2-c1cc(Br)c(Cl)c(Br)c1 ; CC(C)(C)c1cc(-c2cccc(Nc3ccccc3-c3cc4c5ccccc5n5c6ccccc6c(c3)c45)c2)cc(C(C)(C)C)c1 ; [2H]c1c([2H])c([2H])c2c(c1[2H])c1c([2H])c([2H])c([2H])c([2H])c1n2-c1cc(N(c2cccc(-c3cc(C(C)(C)C)cc(C(C)(C)C)c3)c2)c2ccccc2-c2cc3c4ccccc4n4c5ccccc5c(c2)c34)c(Cl)c(N(c2cccc(-c3cc(C(C)(C)C)cc(C(C)(C)C)c3)c2)c2ccccc2-c2cc3c4ccccc4n4c5ccccc5c(c2)c34)c1]

9-(3,5-Dibromo-4-chlorophenyl)-9H-carbazole-1,2,3,4,5,6,7,8-d8 (1 eq), 3′,5′-di-tert-butyl-N-(2-(indolo[3,2,1-jk]carbazol-2-yl)phenyl)-[1,1′-biphenyl]-3-amine (2 eq), tris(dibenzylideneacetone)dipalladium(0) (0.05 eq), tri-tert-butylphosphine (0.1 eq), and sodium tert-butoxide (3 eq) were dissolved in toluene and stirred at about 100 degrees centigrade for about 5 hours. After cooling, the resultant was washed with ethyl acetate and water three times, layers were separated, and an organic layer obtained was dried over MgSO₄ and dried under a reduced pressure. The crude product was purified by column chromatography using methylene chloride (MC) and n-hexane to obtain Intermediate 20-1 (yield: 56%).

### (Synthesis of Compound 20)

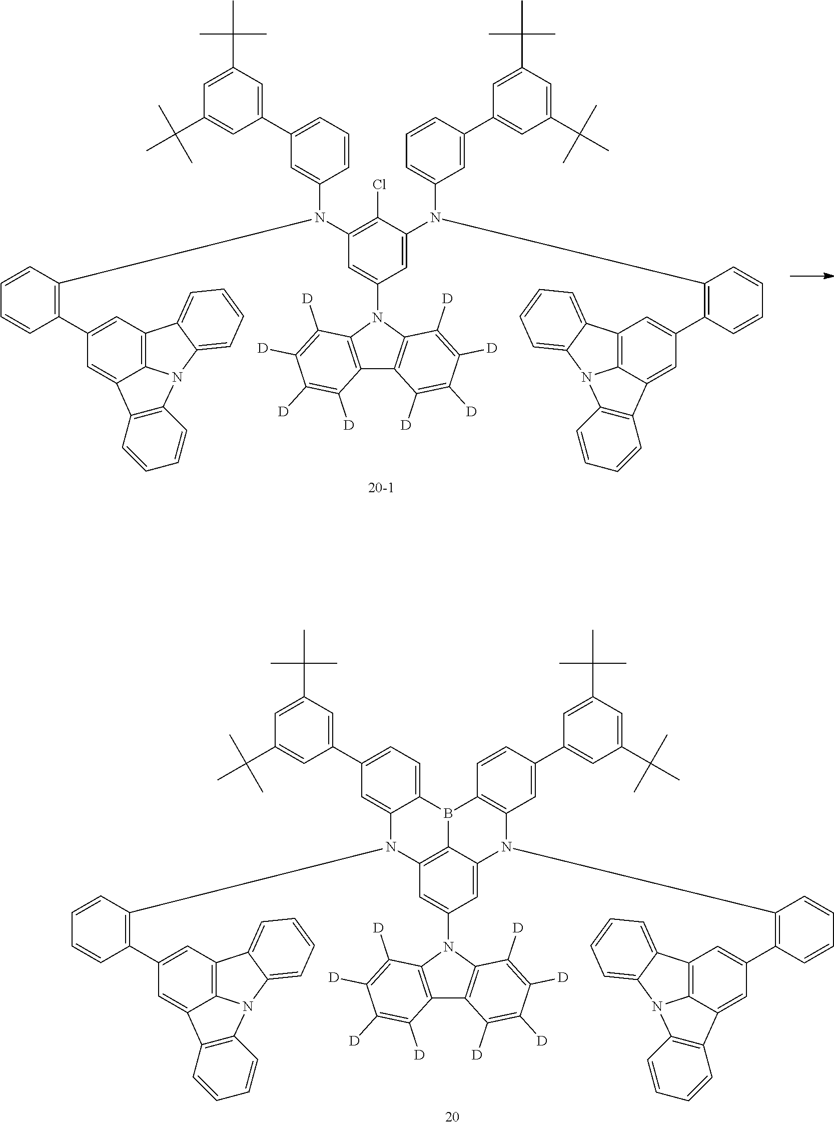 [SMILES: [2H]c1c([2H])c([2H])c2c(c1[2H])c1c([2H])c([2H])c([2H])c([2H])c1n2-c1cc(N(c2cccc(-c3cc(C(C)(C)C)cc(C(C)(C)C)c3)c2)c2ccccc2-c2cc3c4ccccc4n4c5ccccc5c(c2)c34)c(Cl)c(N(c2cccc(-c3cc(C(C)(C)C)cc(C(C)(C)C)c3)c2)c2ccccc2-c2cc3c4ccccc4n4c5ccccc5c(c2)c34)c1 ; [2H]c1c([2H])c([2H])c2c(c1[2H])c1c([2H])c([2H])c([2H])c([2H])c1n2-c1cc2c3c(c1)N(c1ccccc1-c1cc4c5ccccc5n5c6ccccc6c(c1)c45)c1cc(-c4cc(C(C)(C)C)cc(C(C)(C)C)c4)ccc1B3c1ccc(-c3cc(C(C)(C)C)cc(C(C)(C)C)c3)cc1N2c1ccccc1-c1cc2c3ccccc3n3c4ccccc4c(c1)c23]

Intermediate 20-1 (1 eq) was dissolved in 1-butylbenzene and cooled to about −78 degrees centigrade under a nitrogen atmosphere. t-BuLi (2 eq) was slowly injected thereto, and the temperature was raised to room temperature, and stirring was performed for about 30 minutes, followed by stirring at about 90 degrees for about 2 hours. The temperature of the reactor was cooled to about −78 degrees centigrade, and BBr₃ (2 eq) was slowly injected. After finishing the dropwise addition, stirring was performed at room temperature for about 1 hour. After cooling to about 0 degrees centigrade, triethylamine (6 eq) was injected, and the temperature was raised to about 140 degrees, followed by stirring for about 12 hours. After cooling, triethylamine was slowly added dropwise to a flask containing the reaction product to terminate the reaction, and ethyl alcohol was added to precipitate. The precipitate was filtered, and the solid thus obtained was purified by column chromatography to obtain Compound 20 (yield: 31%).

### (5) Synthesis of Compound 35

### (Synthesis of Intermediate 35-1)

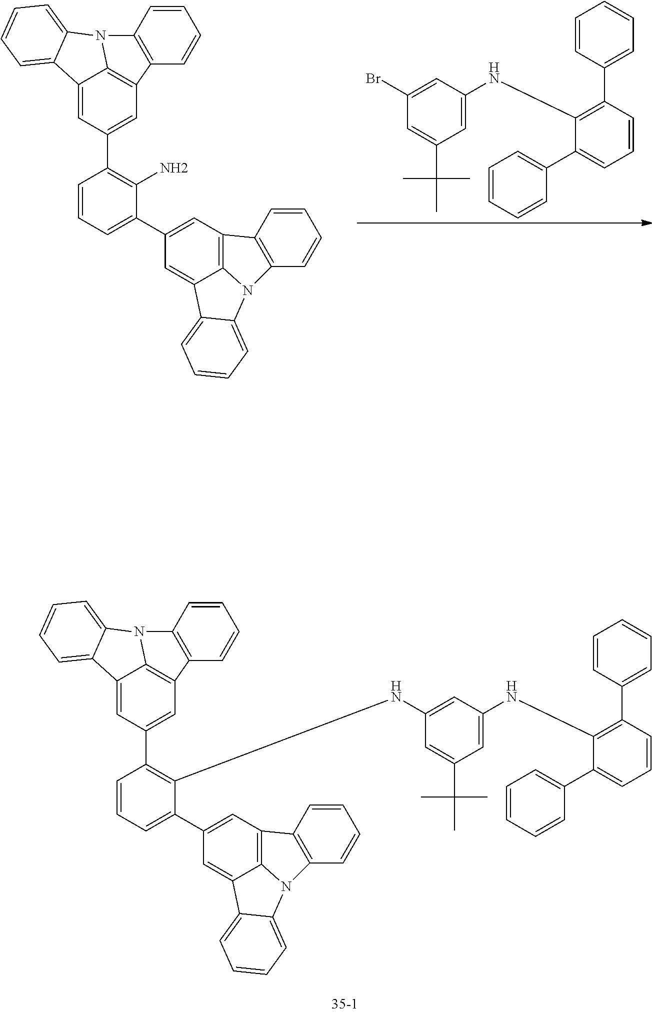 [SMILES: Nc1c(-c2cc3c4ccccc4n4c5ccccc5c(c2)c34)cccc1-c1cc2c3ccccc3n3c4ccccc4c(c1)c23 ; CC(C)(C)c1cc(Br)cc(Nc2c(-c3ccccc3)cccc2-c2ccccc2)c1 ; CC(C)(C)c1cc(Nc2c(-c3ccccc3)cccc2-c2ccccc2)cc(Nc2c(-c3cc4c5ccccc5n5c6ccccc6c(c3)c45)cccc2-c2cc3c4ccccc4n4c5ccccc5c(c2)c34)c1]

2,6-Bis(indolo[3,2,1-jk]carbazol-2-yl)aniline (1 eq), N-(3-bromo-5-(tert-butyl)phenyl)-[1,1′:3′,1″-terphenyl]-2′-amine (1 eq), tris(dibenzylideneacetone)dipalladium(0) (0.05 eq), tri-tert-butylphosphine (0.1 eq), and sodium tert-butoxide (3 eq) were dissolved in toluene and stirred at about 110 degrees centigrade for about 12 hours. After cooling, the resultant was washed with ethyl acetate and water three times, layers were separated, and an organic layer obtained was dried over MgSO₄ and dried under a reduced pressure. The crude product was purified by column chromatography using methylene chloride (MC) and n-hexane to obtain Intermediate 35-1 (yield: 82%).

### (Synthesis of Intermediate 35-2)

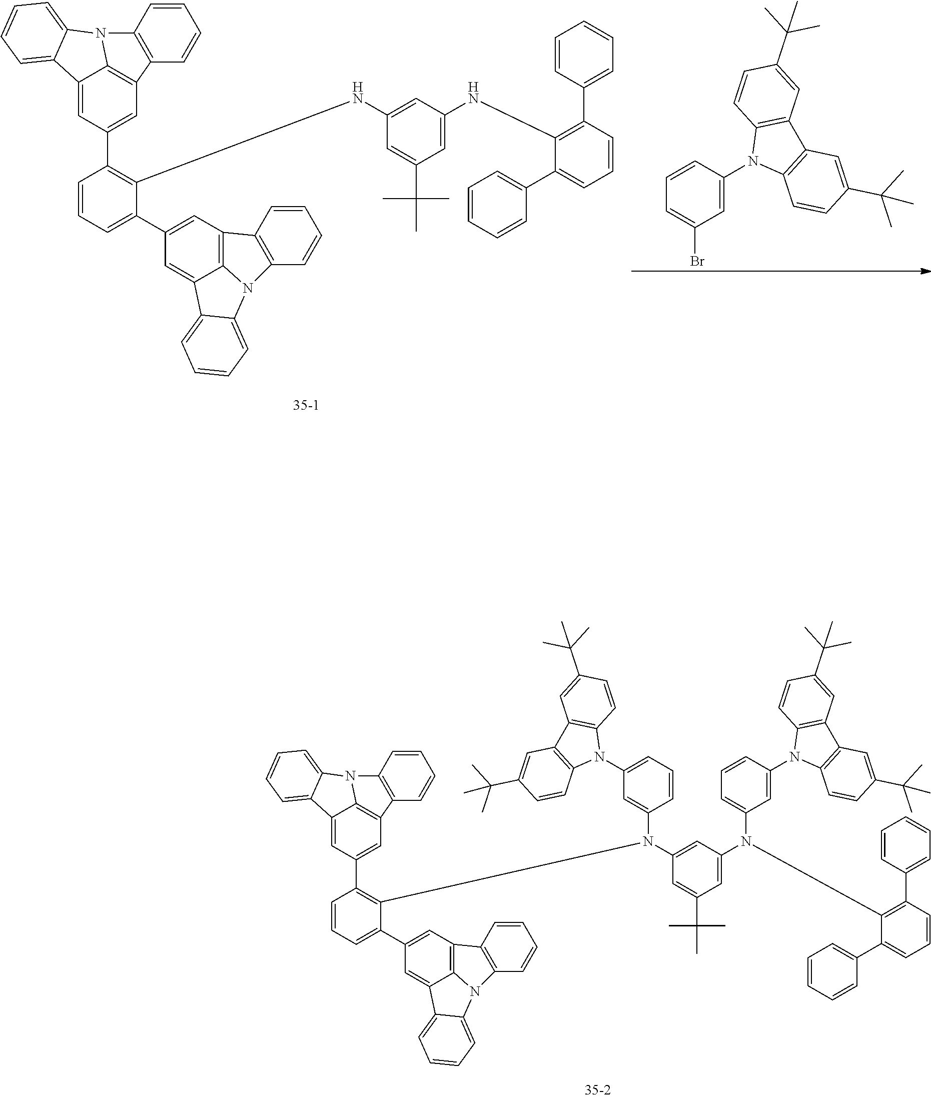

Intermediate 35-1 (1 eq), 9-(3-bromophenyl)-3,6-di-tert-butyl-9H-carbazole (4 eq), tris(dibenzylideneacetone)dipalladium(0) (0.2 eq), tri-tert-butylphosphine (0.4 eq), and sodium tert-butoxide (5 eq) were dissolved in o-xylene and stirred at about 140 degrees centigrade for about 48 hours. After cooling, the resultant was washed with ethyl acetate and water three times, layers were separated, and an organic layer obtained was dried over MgSO₄ and dried under a reduced pressure. The crude product was purified by column chromatography using MC and n-hexane to obtain Intermediate 35-2 (yield: 29%).

### (Synthesis of Compound 35)

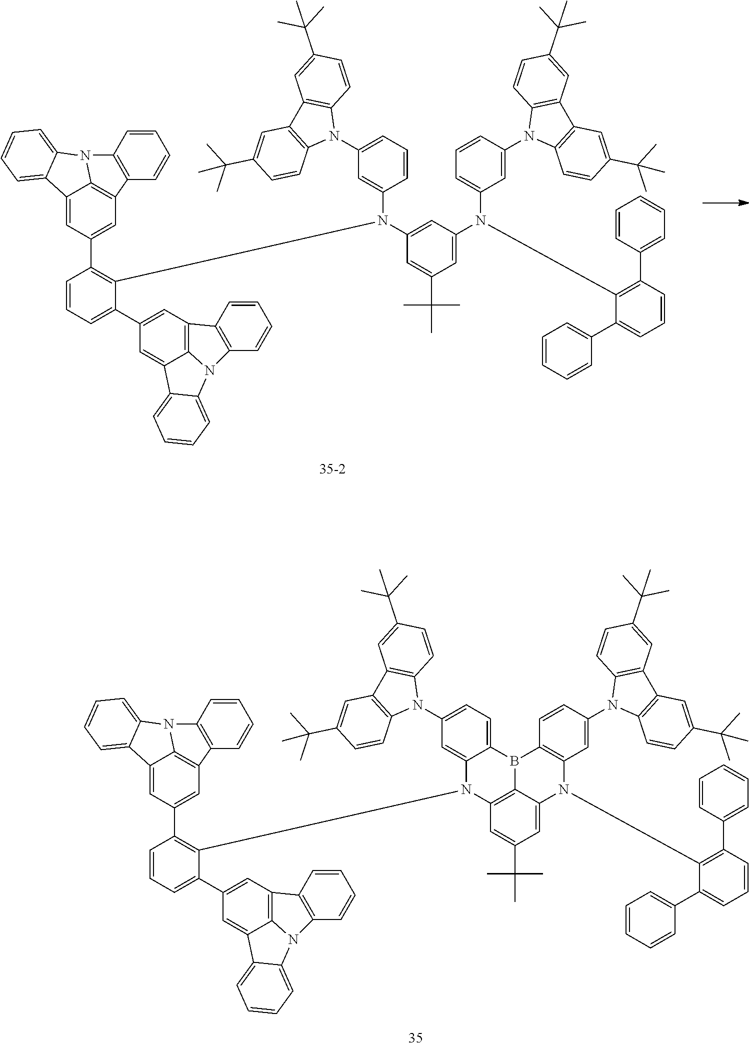

Intermediate 35-2 (1 eq) was dissolved in o-dichlorobenzene and cooled to about 0 degrees centigrade, and BBr₃ (4 eq) was slowly injected under a nitrogen atmosphere. After finishing the dropwise addition, the temperature was raised to about 180 degrees centigrade, followed by stirring for about 48 hours. After cooling, triethylamine was slowly added dropwise to a flask containing the reaction product to terminate the reaction, and ethyl alcohol was added to precipitate. The precipitate was filtered, and the solid thus obtained was purified by column chromatography using MC and n-hexane and recrystallized using toluene and acetone to obtain Compound 35 (yield: 4%).

### (6) Synthesis of Compound 81

### (Synthesis of Intermediate 81-1)

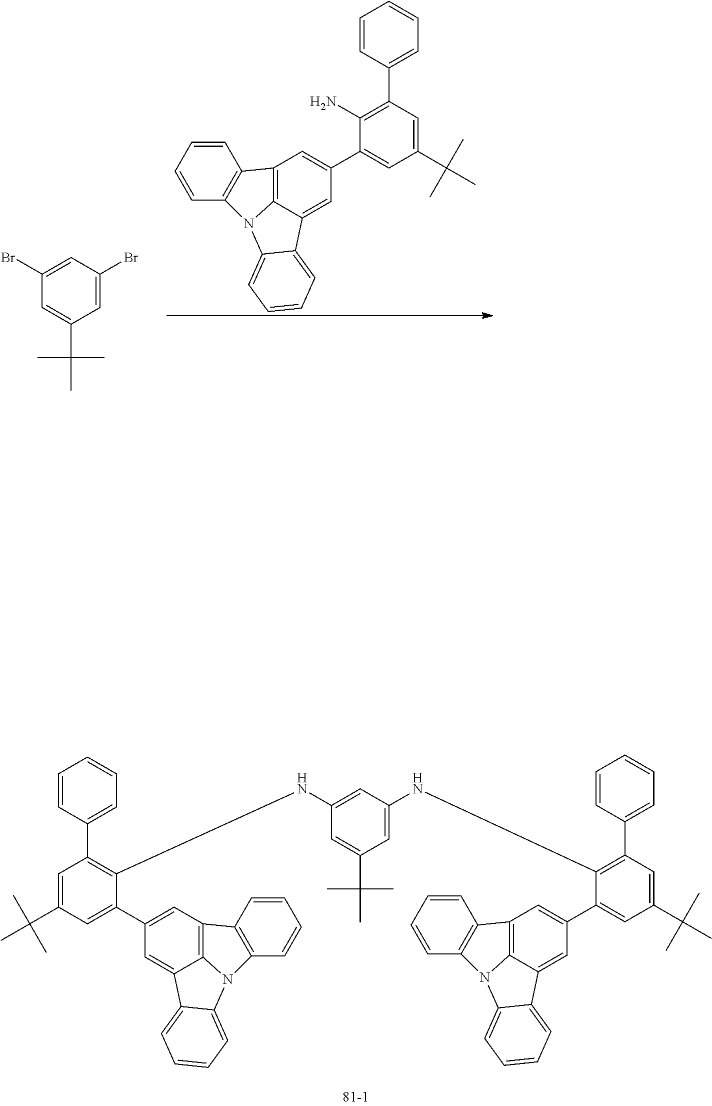 [SMILES: CC(C)(C)c1cc(Br)cc(Br)c1 ; CC(C)(C)c1cc(-c2ccccc2)c(N)c(-c2cc3c4ccccc4n4c5ccccc5c(c2)c34)c1 ; CC(C)(C)c1cc(Nc2c(-c3ccccc3)cc(C(C)(C)C)cc2-c2cc3c4ccccc4n4c5ccccc5c(c2)c34)cc(Nc2c(-c3ccccc3)cc(C(C)(C)C)cc2-c2cc3c4ccccc4n4c5ccccc5c(c2)c34)c1]

1,3-Dibromo-5-(tert-butyl)benzene (1 eq), 5-(tert-butyl)-3-(indolo[3,2,1-jk]carbazol-2-yl)-[1,1′-biphenyl]-2-amine (2 eq), tris(dibenzylideneacetone)dipalladium(0) (0.05 eq), tri-tert-butylphosphine (0.1 eq), and sodium tert-butoxide (3 eq) were dissolved in toluene and stirred at about 110 degrees centigrade for about 12 hours. After cooling, the resultant was washed with ethyl acetate and water three times, layers were separated, and an organic layer obtained was dried over MgSO₄ and dried under a reduced pressure. The crude product was purified by column chromatography using methylene chloride (MC) and n-hexane to obtain Intermediate 81-1 (yield: 77%).

### (Synthesis of Intermediate 81-2)

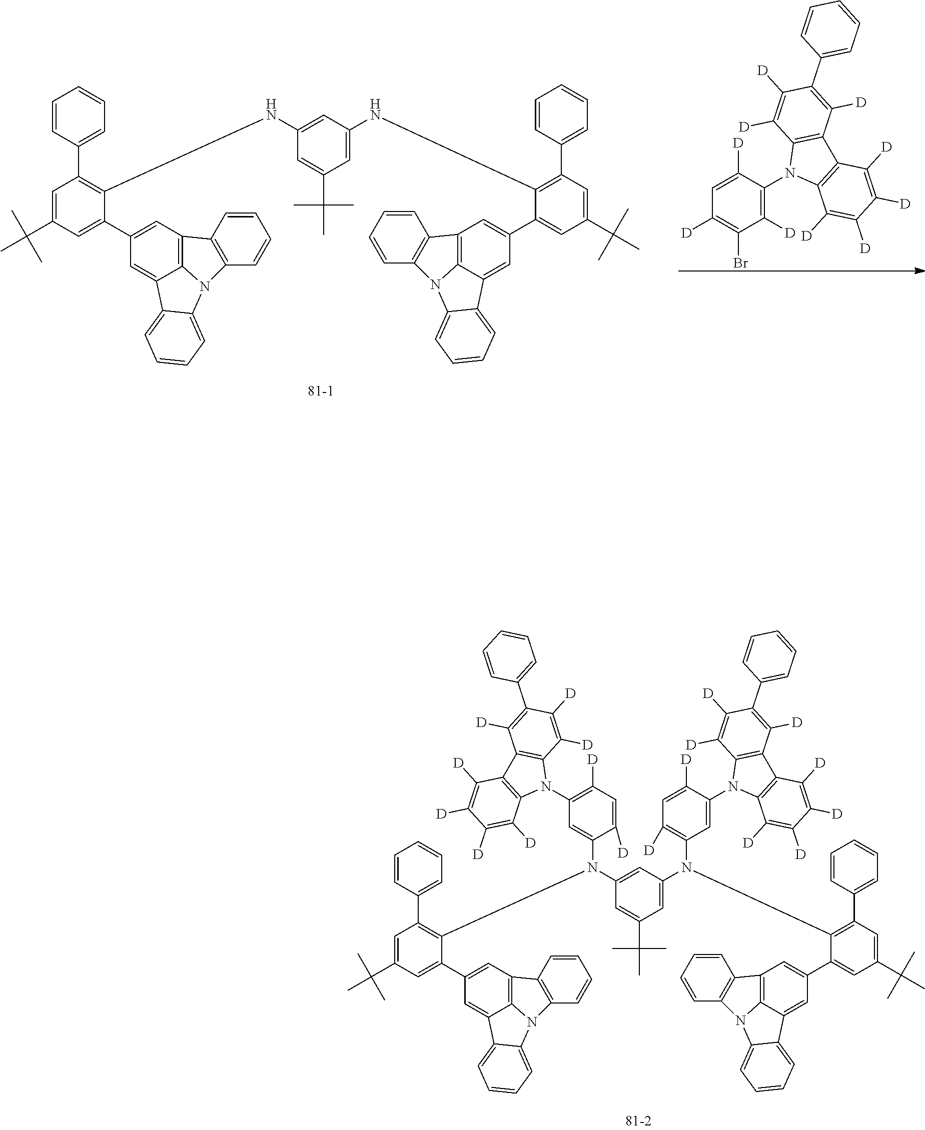

Intermediate 81-1 (1 eq), 9-(3-bromophenyl-2,4,6-d3)-3-phenyl-9H-carbazole-1,2,4,5,6,7,8-d7 (4 eq), tris(dibenzylideneacetone)dipalladium(0) (0.2 eq), tri-tert-butylphosphine (0.4 eq), and sodium tert-butoxide (5 eq) were dissolved in o-xylene and stirred at about 140 degrees centigrade for about 48 hours. After cooling, the resultant was washed with ethyl acetate and water three times, layers were separated, and an organic layer obtained was dried over MgSO₄ and dried under a reduced pressure. The crude product was purified by column chromatography using MC and n-hexane to obtain Intermediate 81-2 (yield: 34%).

### (Synthesis of Compound 81)

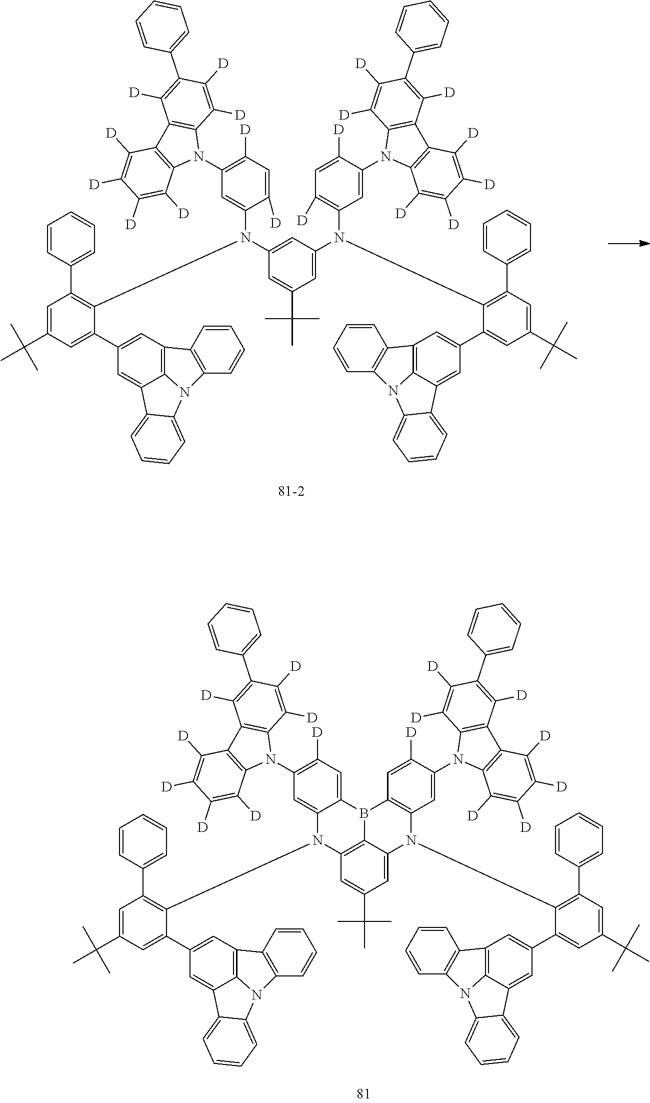

Intermediate 81-2 (1 eq) was dissolved in o-dichlorobenzene and cooled to about 0 degrees centigrade, and BBr₃ (4 eq) was slowly injected under a nitrogen atmosphere. After finishing the dropwise addition, the temperature was raised to about 180 degrees centigrade, and stirring was performed for about 48 hours. After cooling, triethylamine was slowly added dropwise to a flask containing the reaction product to terminate the reaction, and ethyl alcohol was added to precipitate. The precipitate was filtered, and the solid thus obtained was purified by column chromatography using MC and n-hexane and recrystallized using toluene and acetone to obtain Compound 81 (yield: 6%).

### 2. Manufacture and Evaluation of Light Emitting Element

The light emitting element of an embodiment, including the fused polycyclic compound of an embodiment in an emission layer was manufactured by a method below. Light emitting elements of Example 1 to Example 6 were manufactured using the fused polycyclic compounds of Example Compounds 1, 6, 7, 20, 35, and 81 as the dopant materials of an emission layer. Comparative Example 1 to Comparative Example 4 correspond to light emitting elements manufactured using Comparative Compound X-1 to Comparative Compound X-4 as the dopant materials of an emission layer.

### Example Compounds

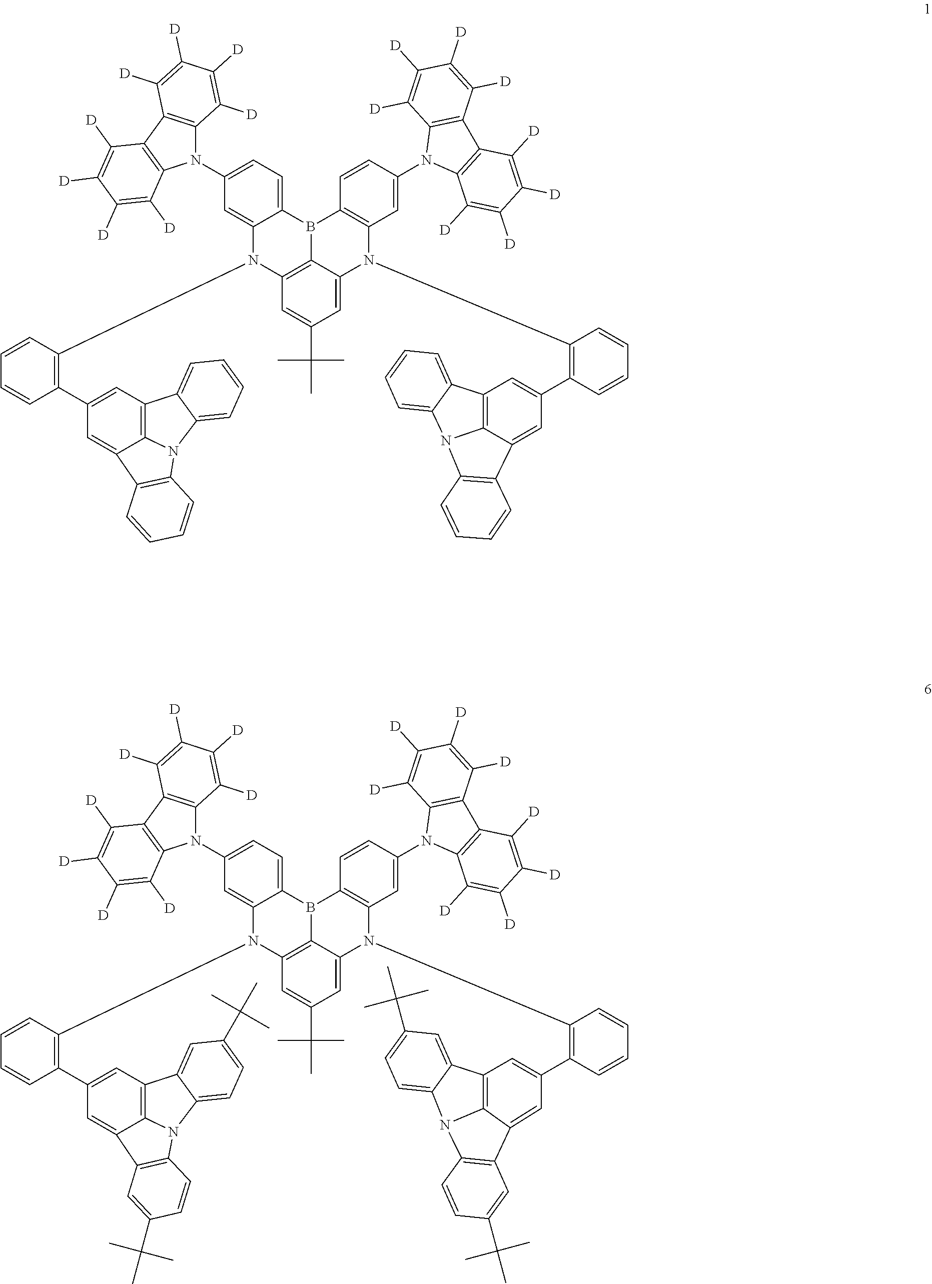

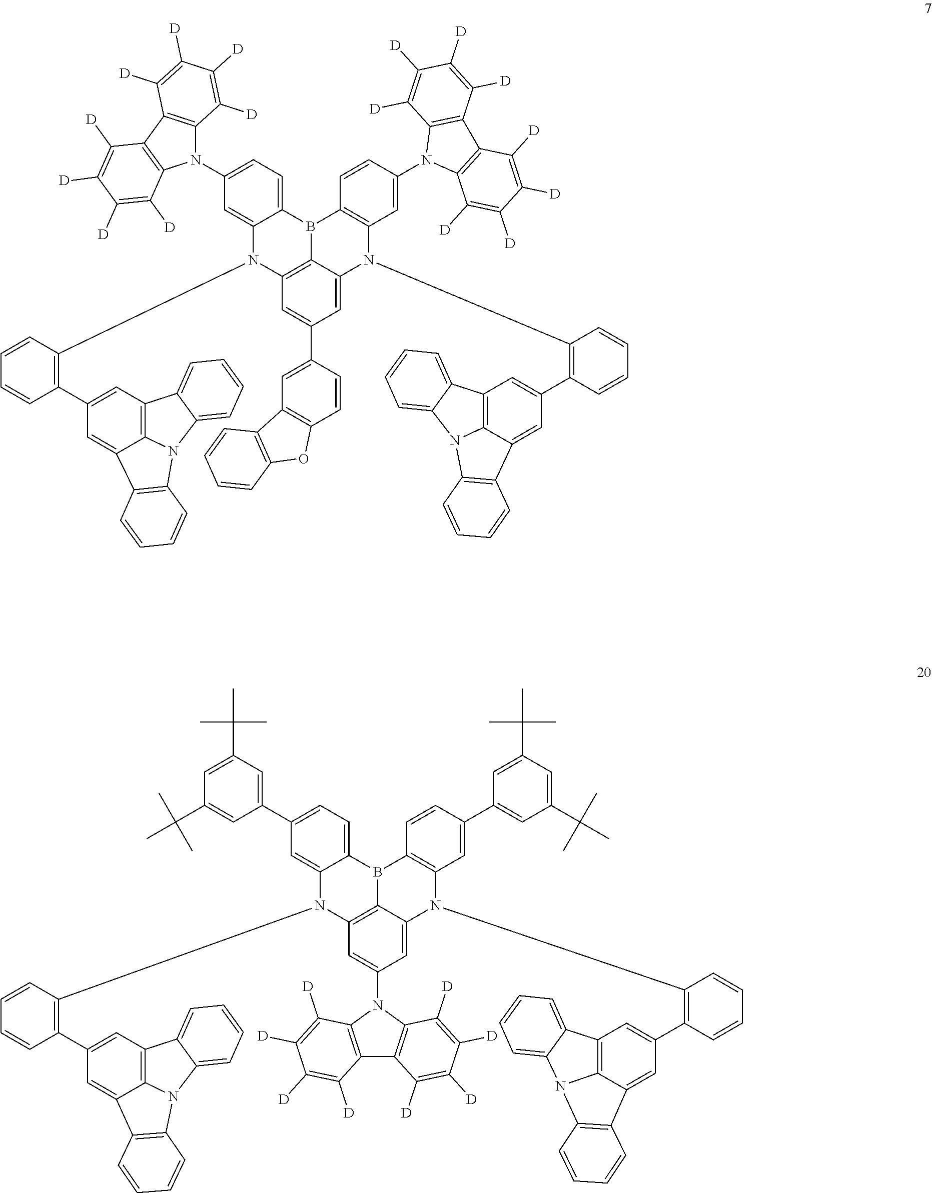

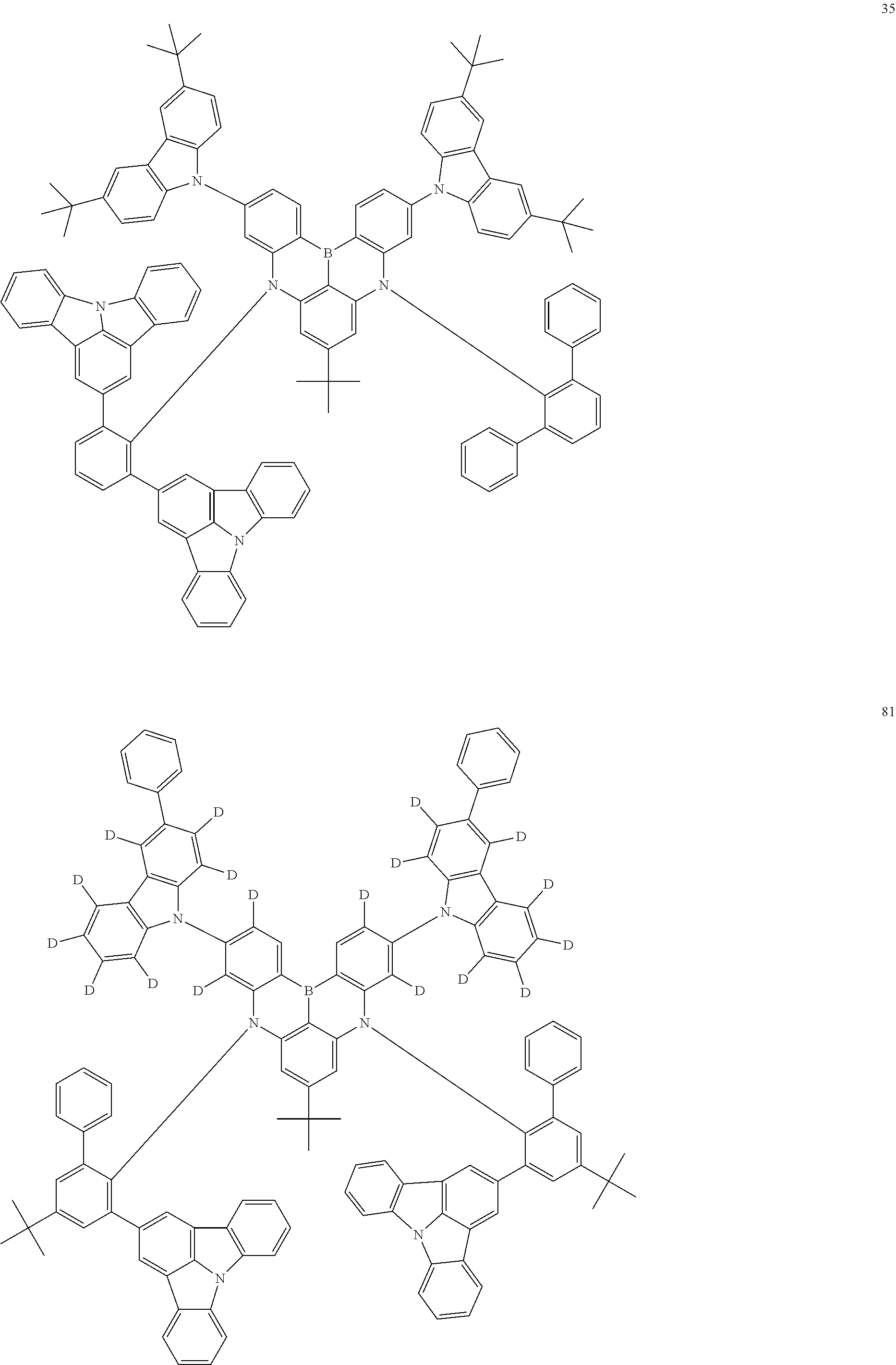

### [Comparative Compounds]

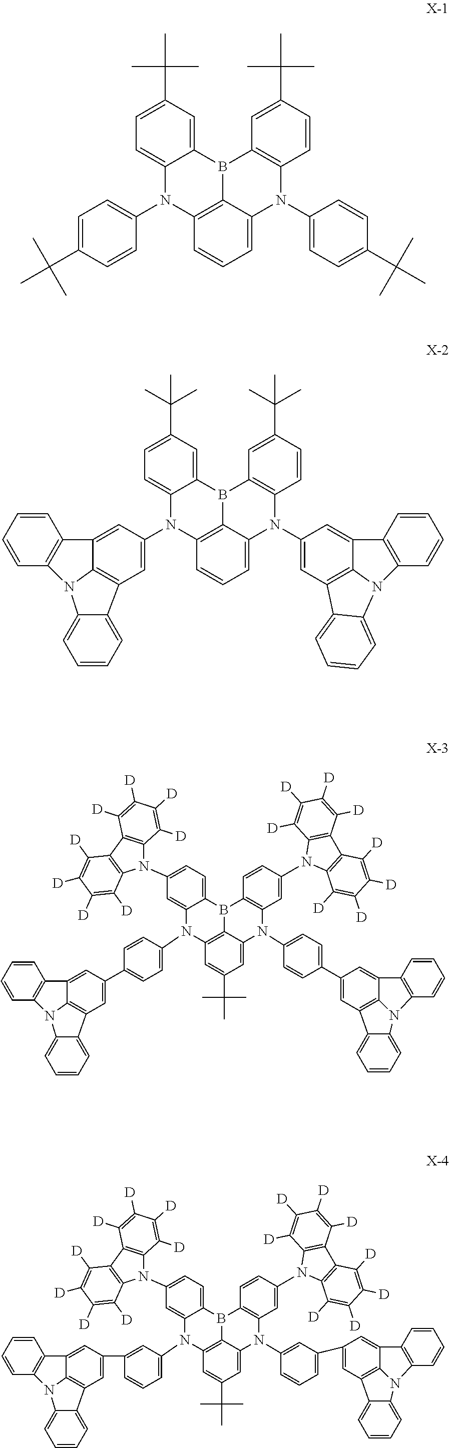

### (Manufacture of Light Emitting Element)

For the manufacture of the light emitting elements of the Examples and Comparative Examples, a glass substrate on which an ITO electrode of about 15 Ω/cm² (1,200 Å) was formed (a product of Corning Co.) was cut to a size of about 50 mm×50 mm×0.7 mm, cleansed with ultrasonic waves using isopropyl alcohol and pure water for about 5 minutes each, exposed to ultraviolet for about 30 minutes, and cleansed by exposure to ozone to form an anode. The anode was installed in a vacuum evaporation apparatus.

On the anode, NPD was deposited to form a hole injection layer with a thickness of about 300 Å. On the hole injection layer, Compound H-1-1 was deposited to form a hole transport layer with a thickness of about 200 Å. On the hole transport layer, CzSi was deposited to form an emission auxiliary layer with a thickness of about 100 Å.

A host mixture that was obtained by mixing a second compound and a third compound according to an embodiment at a ratio of about 1:1, a fourth compound, and an Example Compound or a Comparative Compound were co-deposited at a weight ratio of about 85:14:1 to form an emission layer with a thickness of about 350 Å. On the emission layer, Compound ETH2 was deposited to form a hole blocking layer with a thickness of about 50 Å. On the hole blocking layer, CNNPTRZ:Liq were co-deposited at a weight ratio of about 4.0:6.0 to form an electron transport layer with a thickness of about 310 Å. On the hole transport layer, Yb was deposited to form a hole injection layer with a thickness of about 15 Å. On the electron injection layer, Mg was deposited to form a cathode with a thickness of about 800 Å. On the cathode, Compound P4 was deposited to form a capping layer with a thickness of about 700 Å, thereby manufacturing a light emitting element.

All layers were formed by a vacuum deposition method. From among the compounds in Compound Group 2, Compound HT35 was used as the second compound. From among the compounds in Compound Group 3, Compound ETH66 was used as the third compound. From among the compounds in Compound Group 2, Compound AD-38 was used as the fourth compound.

The compounds used for the manufacture of the light emitting elements of the Examples and the Comparative Examples are shown below. The materials below were used after purchasing commercial products and performing sublimation purification.

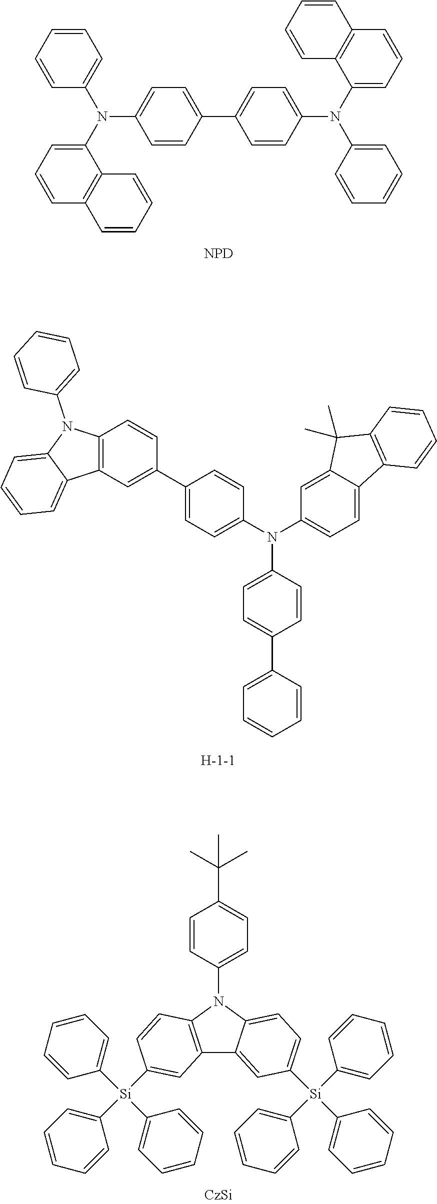 [SMILES: c1ccc(N(c2ccc(-c3ccc(N(c4ccccc4)c4cccc5ccccc45)cc3)cc2)c2cccc3ccccc23)cc1 ; "NPD" ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1]

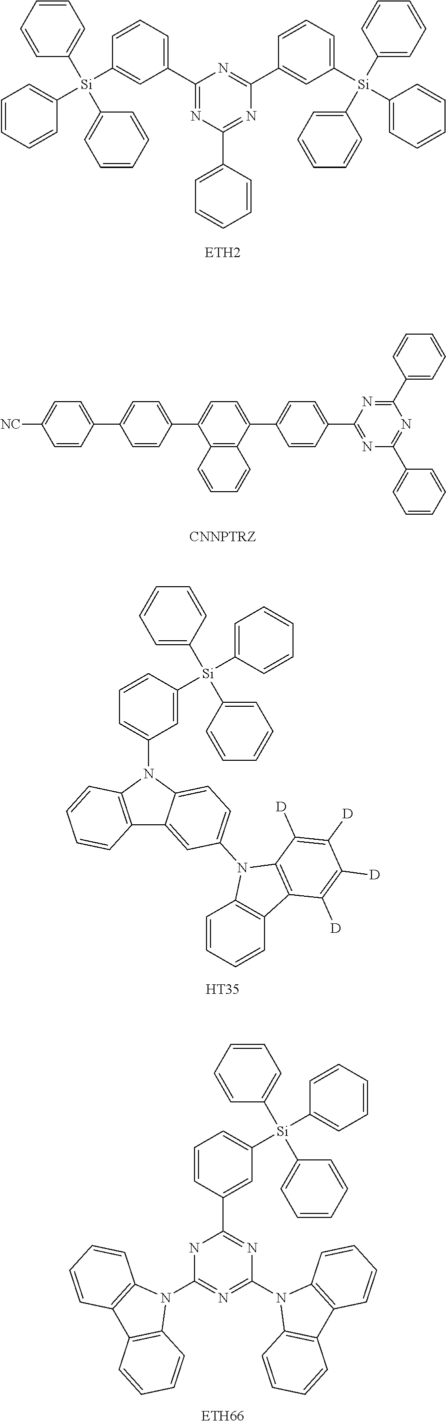

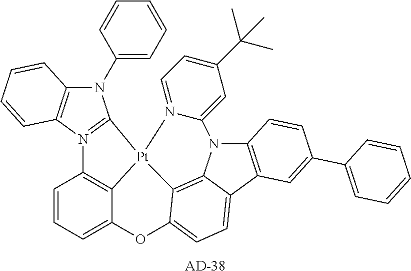

### (Evaluation of Properties of Light Emitting Elements)

Element efficiency and lifetime of the light emitting elements manufactured by using Compounds 1, 6, 7, 20, 35, and 81 and Comparative Compounds X-1 to X-4 were evaluated. In Table 1, the evaluation results on the light emitting elements of Examples 1 to 6, and Comparative Examples 1 to 4 are shown. For the evaluation of the properties of the light emitting elements manufactured in Examples 1 to 6 and Comparative Examples 1 to 4, driving voltages (V) at a current density of about 1000 cd/m², emission efficiency (Cd/A), and emission wavelengths were measured using Keithley MU 236 and a luminance meter PR650. A time taken to reach about 95% luminance in contrast to an initial luminance was measured as the lifetime (T95), relative lifetime was calculated based on the element of Comparative Example 1, and the results are shown in Table 1.

TABLE 1

| | Host (second | | | Driving | | Emission | Lifetime |
|---|---|---|---|---|---|---|---|
| | compound: third | Fourth | First | voltage | Efficiency | wavelength | ratio |
| | compound = 5: 5) | compound | compound | (V) | (cd/A) | (nm) | (T95) |
| Example 1 | HT35/ETH66 | AD-38 | Compound 1 | 4.4 | 26.1 | 462 | 4.6 |
| Example 2 | HT35/ETH66 | AD-38 | Compound 6 | 4.4 | 25.4 | 462 | 5.2 |
| Example 3 | HT35/ETH66 | AD-38 | Compound 7 | 4.5 | 25.3 | 463 | 5.0 |
| Example 4 | HT35/ETH66 | AD-38 | Compound 20 | 4.7 | 24.9 | 460 | 4.2 |
| Example 5 | HT35/ETH66 | AD-38 | Compound 35 | 4.3 | 26.7 | 460 | 6.5 |
| Example 6 | HT35/ETH66 | AD-38 | Compound 81 | 4.3 | 26.3 | 461 | 6.3 |
| Comparative | HT35/ETH66 | AD-38 | Comparative | 5.4 | 18.1 | 467 | 1.0 |
| Example 1 | | | Compound X-1 | | | | |
| Comparative | HT35/ETH66 | AD-38 | Comparative | 5.7 | 17.2 | 468 | 1.7 |
| Example 2 | | | Compound X-2 | | | | |
| Comparative | HT35/ETH66 | AD-38 | Comparative | 5.3 | 21.7 | 465 | 2.3 |
| Example 3 | | | Compound X-3 | | | | |
| Comparative | HT35/ETH66 | AD-38 | Comparative | 5.2 | 20.6 | 465 | 2.1 |
| Example 4 | | | Compound X-4 | | | | |

Referring to the results of Table 1, it could be confirmed that the light emitting elements of the Examples using the fused polycyclic compounds according to embodiments as light emitting materials showed improved emission efficiency and lifetime characteristics, in comparison to the Comparative Examples. It could be confirmed that the Example Compounds have a structure in which a fused ring core includes a first substituent and if applied to a light emitting element, show high emission efficiency and improved lifetime characteristics when compared to the Comparative Examples. The Example Compounds include a fused ring core in which first to third aromatic rings are fused via a boron atom, a first nitrogen atom, and a first heteroatom, and have a structure in which a first substituent is bonded to the first nitrogen atom via a first linker. Since the Example Compounds include the first substituent, the boron atom may be effectively protected, chemical stability may be improved, and intermolecular interaction may be suppressed, and accordingly, the formation of excimers or exciplexes may be effectively controlled, and emission efficiency may be increased. Intermolecular distance of the Example Compounds may increase due to a structure having large steric hindrance, and Dexter energy transfer may be suppressed, and thus, the deterioration of lifetime due to the increase of triplet concentration may be suppressed.

Since the fused polycyclic compound includes the first substituent, through-space charge transfer (TSCT) may be increased in addition to through-bond charge transfer (TBCT), and reverse intersystem crossing (RISC) may be promoted to improve emission efficiency. Since the fused polycyclic compound has a structure in which a fused ring core and an indolocarbazole moiety are each bonded to a first linker at an ortho position, the fused ring core and the indolocarbazole moiety may have a cofacial configuration. Accordingly, through-space charge transfer (TSCT) in a molecule may be induced, and the charge transfer (CT) mode of a whole molecule may be increased. Accordingly, the fused polycyclic compound of an embodiment may have high reverse intersystem crossing (RISC) efficiency and may show improved thermally activated delayed fluorescence (TADF) properties.

Referring to Comparative Example 1, Comparative Compound X-1 includes a fused ring core with a boron atom as a central atom, but does not include a first substituent according to an embodiment, and if applied to an element, it could be confirmed that emission efficiency and element lifetime were degraded when compared to the Examples. Comparative Compound X-1 has a structure in which a methyl group is substituted at a phenyl group which is connected to a ring-forming nitrogen atom of the fused ring core, but steric hindrance effects are insufficient with the methyl group, and it is thought that emission efficiency and lifetime were degraded when compared to the Example Compounds. By comparison, in the fused polycyclic compound according to an embodiment, the first substituent connected with the fused ring core is included, and high emission efficiency and long lifetime may be achieved in a blue light wavelength region.

Referring to Comparative Example 2, Comparative Compound X-2 includes a fused ring core with a boron atom as a central atom, and a first substituent is directly bonded to a ring-forming nitrogen atom of the fused ring core. However, it could be confirmed that emission efficiency and element lifetime were degraded when compared to the Example Compounds.

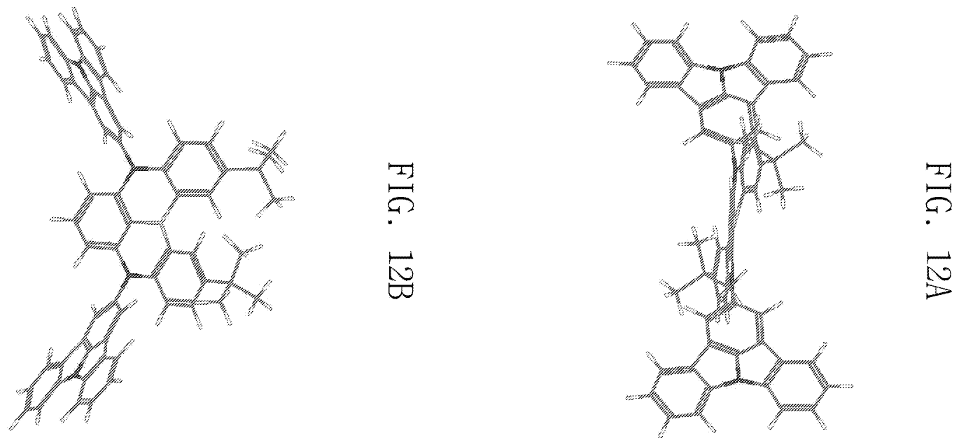

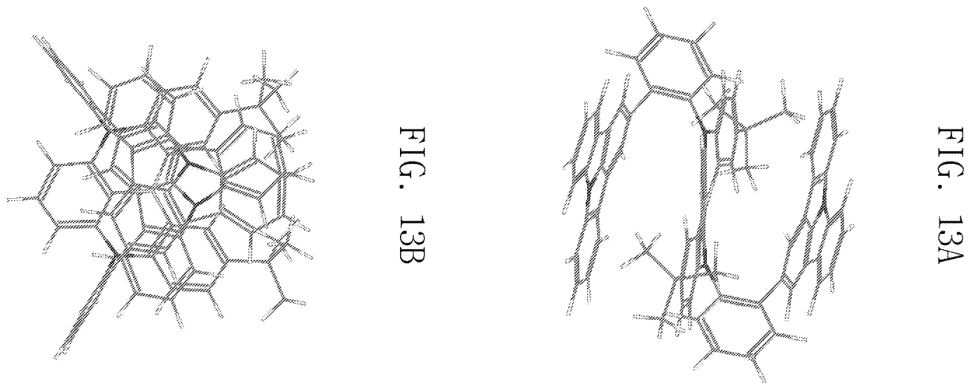

FIG. 12A and FIG. 12B are diagrams showing three-dimensional molecular models of a Comparative Compound. FIG. 13A and FIG. 13B are diagrams showing three-dimensional molecular models of the Example Compound. FIG. 12A and FIG. 12B are diagrams showing the three-dimensional molecular models of Comparative Compound X-2, and FIG. 13A and FIG. 13B are diagrams showing the three-dimensional molecular models of Example Compound 34. Comparative Compound X-2 is different from Example Compound 34 in having a structure in which an indolocarbazole moiety is directly bonded to a nitrogen atom without a first linker as described above.

Referring to FIG. 12A and FIG. 12B, in the structure of Comparative Compound X-2, an indolocarbazole moiety is oriented away from the boron atom of the fused ring core. When compared to the Example Compounds, the reducing effect of intermolecular interaction may decrease, or the reducing effects of triplet energy concentration by suppressing Dexter energy transfer may decrease. Rather, due to the indolocarbazole moiety having a plate-type fused structure, intermolecular aggregation tends to increase to reduce emission efficiency and lifetime characteristics. As shown in FIGS. 12A and 12B, since the indolocarbazole moiety is directly bonded to the nitrogen atom in Comparative Compound X-2, it is difficult to have a cofacial configuration of the fused ring core and the indolocarbazole moiety. Accordingly, through-space charge transfer (TSCT) effects in a molecule are difficult to predict when compared to the Example Compounds. By contrast, referring to FIG. 13A and FIG. 13B, the Example Compounds have a cofacial configuration of the indolocarbazole moiety and the fused ring core, and the boron atom may be completely covered, such that the approach of external nucleophiles, radicals, or decomposed materials in an element may be difficult. The Example Compounds may have steric hindrance effects which are sufficient to interfere with Dexter energy transfer, which is a short-distance transition process. Accordingly, increased lifetime and efficiency may be achieved. Since the Example Compounds have a structure in which a fused ring core and an indolocarbazole moiety are each connected to a phenylene linker at an ortho position, the indolocarbazole moiety and the fused ring core may have a cofacial configuration and may be present at sterically adjacent positions. Accordingly, through-space charge transfer (TSCT) between the fused ring core and the indolocarbazole moiety may be increased in addition to through-bond charge transfer (TBCT) in the fused ring core, and reverse intersystem crossing (RISC) may be improved to improve emission efficiency.

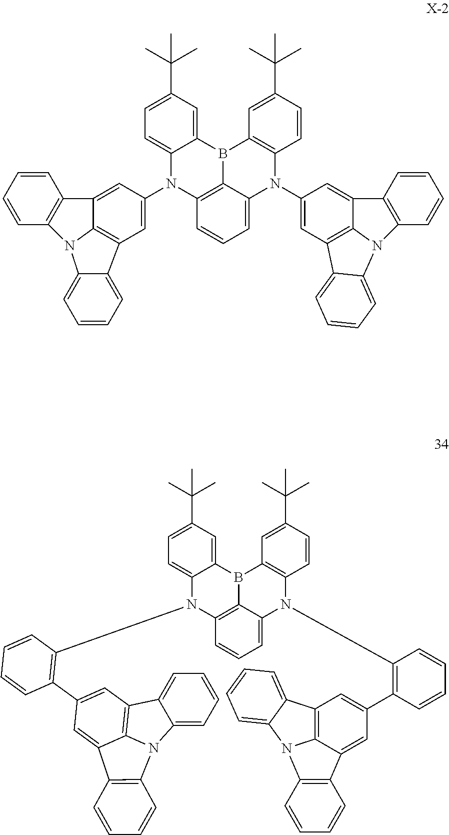 [SMILES: CC(C)(C)c1ccc2c(c1)B1c3cc(C(C)(C)C)ccc3N(c3cc4c5ccccc5n5c6ccccc6c(c3)c45)c3cccc(c31)N2c1cc2c3ccccc3n3c4ccccc4c(c1)c23 ; CC(C)(C)c1ccc2c(c1)B1c3cc(C(C)(C)C)ccc3N(c3ccccc3-c3cc4c5ccccc5n5c6ccccc6c(c3)c45)c3cccc(c31)N2c1ccccc1-c1cc2c3ccccc3n3c4ccccc4c(c1)c23]

It could be confirmed that Comparative Example 3 and Comparative Example 4 showed degraded emission efficiency and element lifetime when compared to Example 3. Comparative Compound X-3 and Comparative Compound X-4 respectively included in Comparative Example 3 and Comparative Example 4 each include a fused ring core with a boron atom as a central atom and have a structure in which a first substituent is connected to a ring-forming nitrogen atom of the fused ring core, similar to Compound 7 that is included in Example 3. However, the first substituent is not bonded to a phenylene linker at an ortho position to the nitrogen atom of the fused ring core, but at a para position or a meta position to the nitrogen atom. Thus, both emission efficiency and element lifetime were degraded when compared to Example 3. Comparative Compound X-3 and Comparative Compound X-4 are compounds having a different bonding position of the first substituent when compared to Example Compound 7, and have a very rigid and long anisotropic molecular model when compared to the fused polycyclic compound. Accordingly, strong molecular packing with other host molecules is induced, and due to the increase of intermolecular interaction, it is thought that Comparative Compound X-3 and Comparative Compound X-4 are exposed to Dexter energy transfer, or the like, and both emission efficiency and element lifetime were degraded when compared to the Examples.

The light emitting element according to an embodiment may show improved element properties of high efficiency and long lifetime.

The fused polycyclic compound according to an embodiment may be included in an emission layer of a light emitting element and may contribute to increased efficiency and lifetime of the light emitting element.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element, comprising:
a first electrode;
a second electrode disposed on the first electrode; and
an emission layer disposed between the first electrode and the second electrode, and comprising a first compound represented by Formula 1: 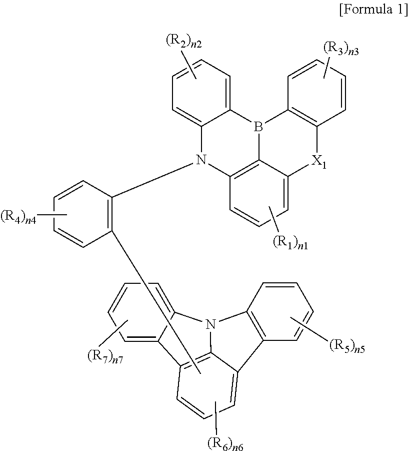
wherein in Formula 1,
X₁ is O, S, or N(Rₐ),
R₁ to R₇ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring,
Rₐ is a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n1 and n6 are each independently an integer from 0 to 3,
n2 to n5 and n7 are each independently an integer from 0 to 4, and
a sum of n6 and n7 is equal to or less than 6.

2. The light emitting element of claim 1, wherein the first compound is represented by Formula 2: 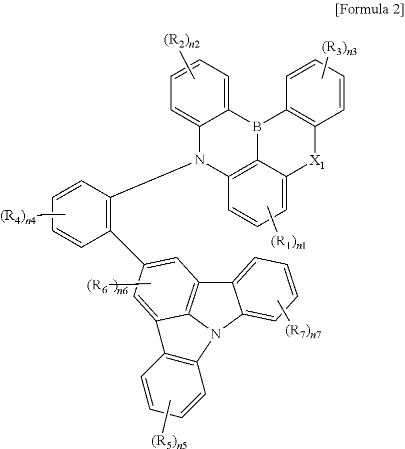
wherein in Formula 2,
X₁, R₁ to R₇, and n1 to n7 are the same as defined in Formula 1.

3. The light emitting element of claim 1, wherein the first compound is represented by Formula 3: 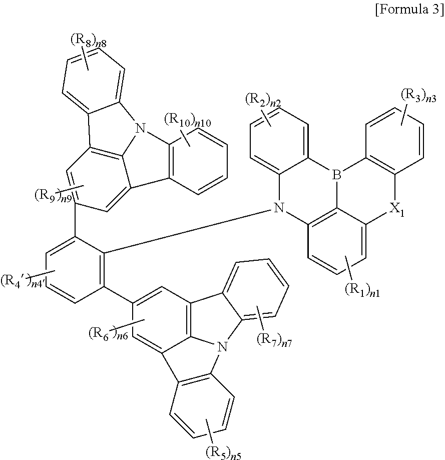
wherein in Formula 3,
R₄′ and R₈ to R₁₀ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n4′ is an integer from 0 to 3,
n8 and n10 are each independently an integer from 0 to 4,
n9 is an integer from 0 to 2, and
X₁, R₁ to R₃, R₅ to R₇, n1 to n3, and n5 to n7 are the same as defined in Formula 1.

4. The light emitting element of claim 1, wherein the first compound is represented by Formula 4: 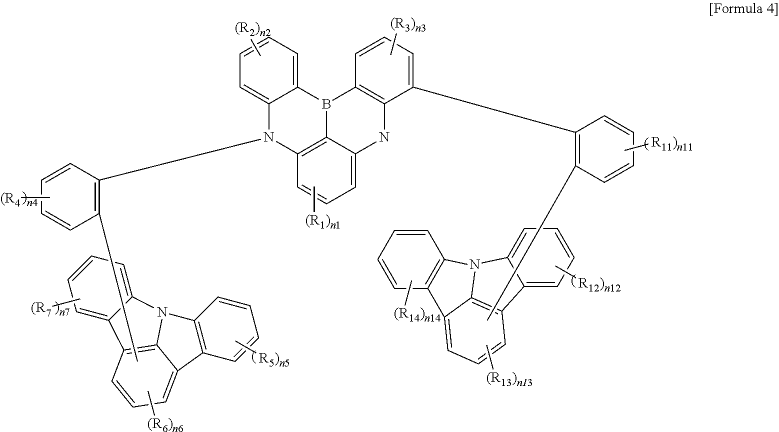
wherein in Formula 4,
R₁₁ to R₁₄ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring,
n11, n12, and n14 are each independently an integer from 0 to 4,
n13 is an integer from 0 to 3,
a sum of n12 and n13 is equal to or less than 6, and
R₁ to R₇ and n1 to n7 are the same as defined in Formula 1.

5. The light emitting element of claim 4, wherein the first compound is represented by Formula 5: 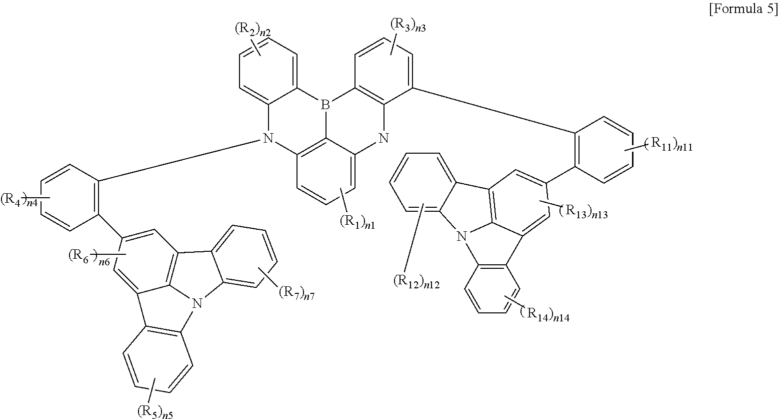
wherein in Formula 5,
R₁ to R₇ and n1 to n7 are the same as defined in Formula 1 and
R₁₁ to R₁₄ and n11 to n14 are the same as defined in Formula 4.

6. The light emitting element of claim 4, wherein the first compound is represented by one of Formula 6-1 to Formula 6-4: 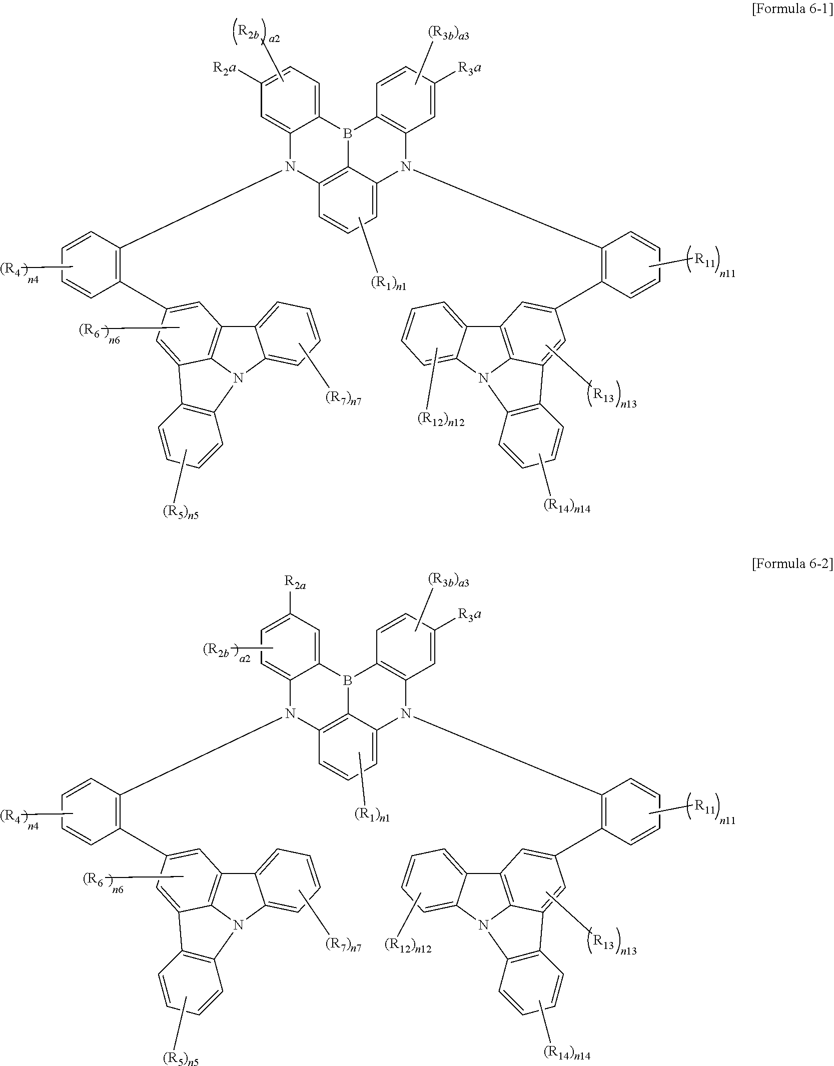 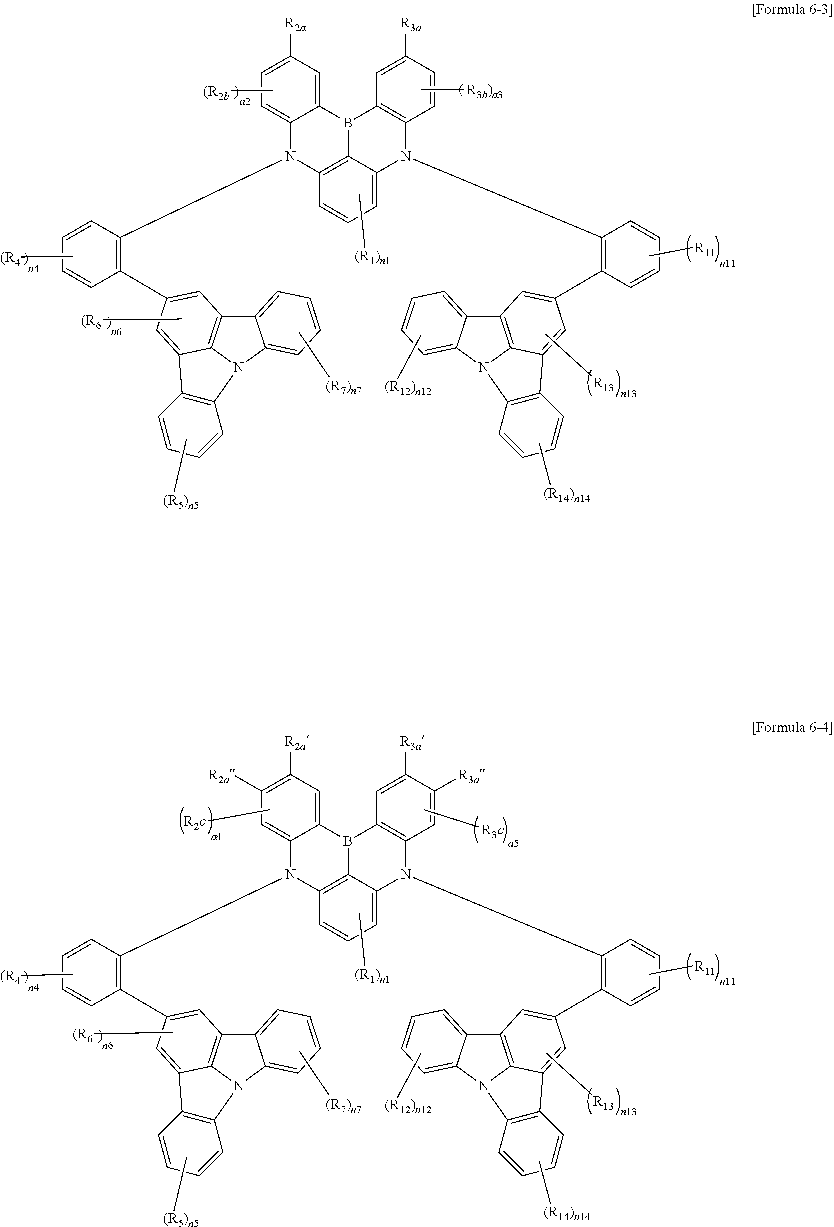
wherein in Formula 6-1 to Formula 6-4,
R₂ₐ, R₂ₐ′, R₂ₐ″, R₃ₐ, R₃ₐ′, and R₃ₐ″ are each independently a group represented by one of Formula A-1 to Formula A-5,
R_{2b}, R_{3b}, R_{2c}, and R_{3c} are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
a2 and a3 are each independently an integer from 0 to 3,
a4 and a5 are each independently an integer from 0 to 2,
R₁, R₄ to R₇, n1, and n4 to n7 are the same as defined in Formula 1, and
R₁₁ to R₁₄ and n11 to n14 are the same as defined in Formula 4: 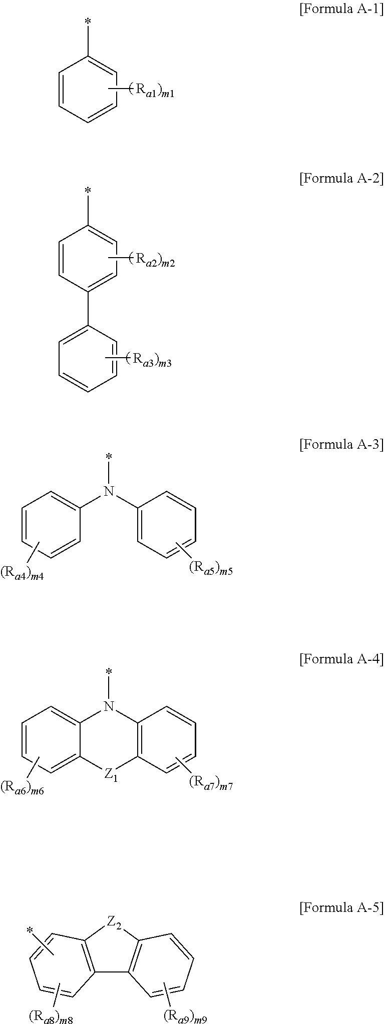
wherein in Formula A-1 to Formula A-5,
Z₁ is a direct linkage, O, or C(Rₐ₁₀)(Rₐ₁₁),
Z₂ is O, S, N(Rₐ₁₂), or C(Rₐ₁₃)(Rₐ₁₄),
Rₐ₁ to Rₐ₁₄ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m1, m3, m4, and m5 are each independently an integer from 0 to 5,
m2, m6, m7, and m9 are each independently an integer from 0 to 4, and
m8 is an integer from 0 to 3.

7. The light emitting element of claim 4, wherein the first compound is represented by Formula 7-1 or Formula 7-2: 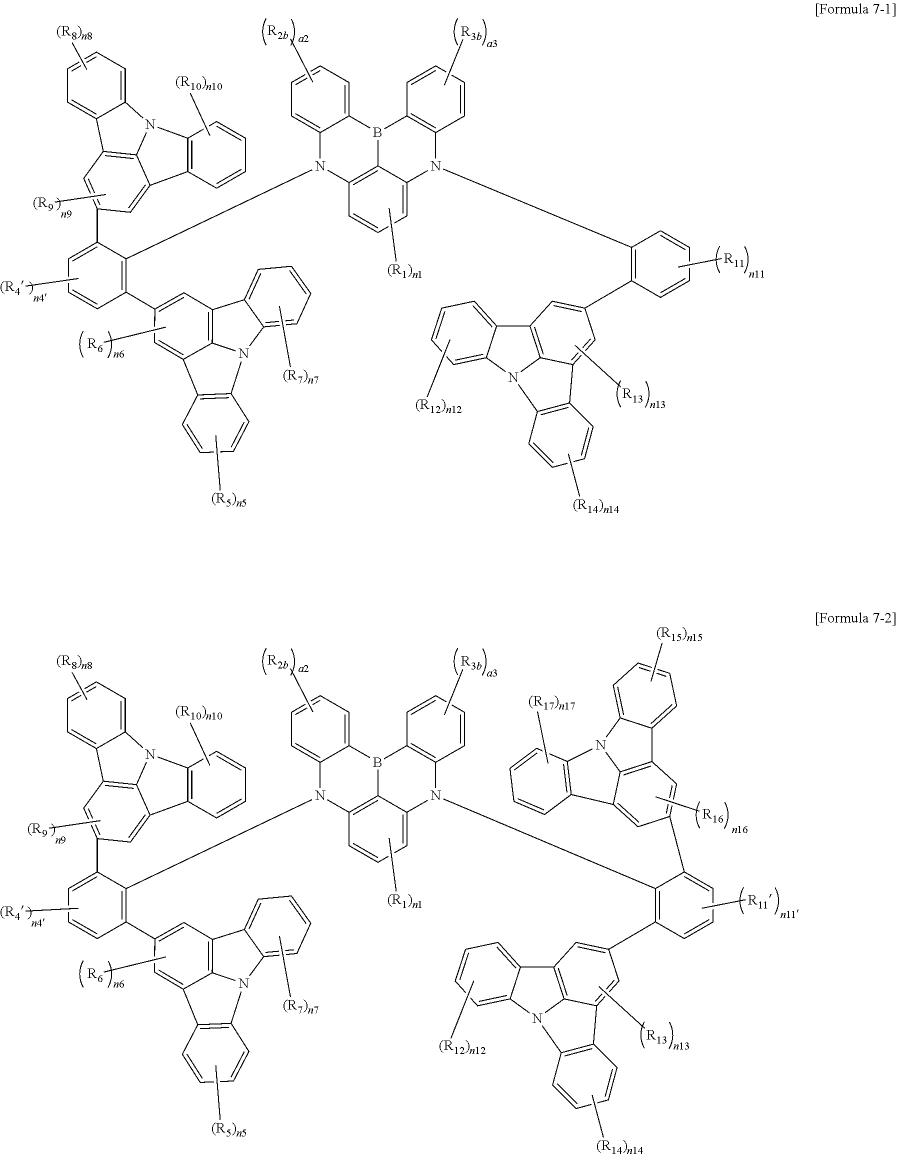
wherein in Formula 7-1 and Formula 7-2,
R₄′, R₈ to R₁₀, R₁₁′, and R₁₅ to R₁₇ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n4′ and n11′ are each independently an integer from 0 to 3,
n8, n10, n15, and n17 are each independently an integer from 0 to 4,
n9 and n16 are each independently an integer from 0 to 2,
R₁ to R₃, R₈ to R₇, n1 to n3, and n5 to n7 are the same as defined in Formula 1, and
R₁₁ to R₁₄ and n11 to n14 are the same as defined in Formula 4.

8. The light emitting element of claim 1, wherein the first compound is represented by Formula 8-1 or Formula 8-2: 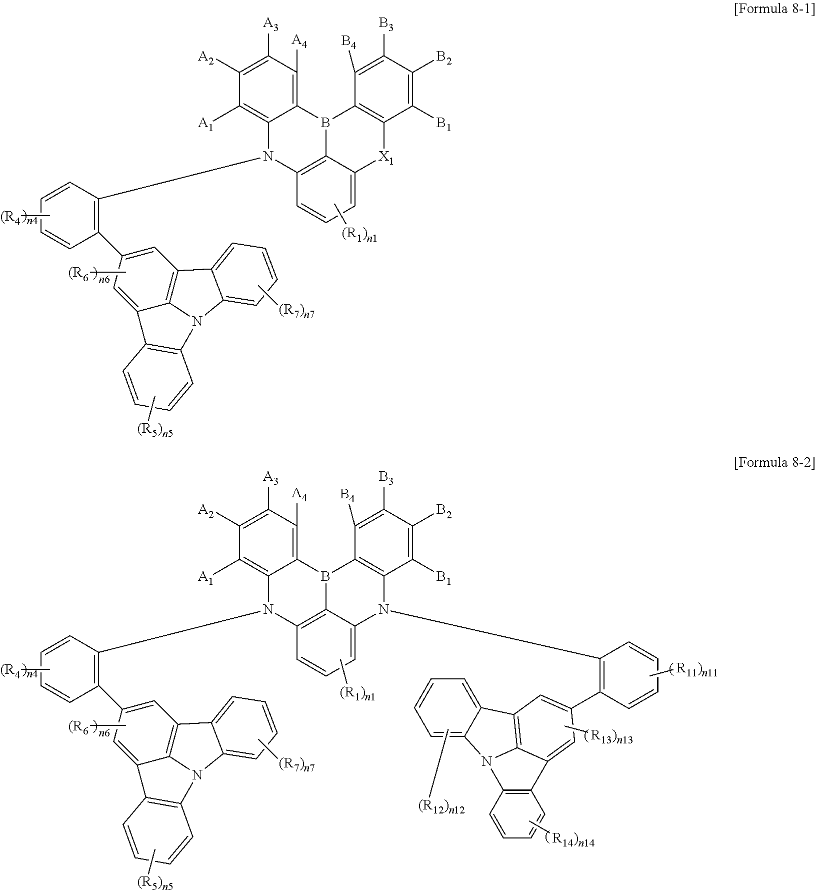
wherein in Formula 8-1 and Formula 8-2,
A₁ to A₄, B₁ to B₄, and R₁₁ to R₁₄ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring,
n11, n12, and n14 are each independently an integer from 0 to 4,
n13 is an integer from 0 to 2, and
at least one adjacent pair among A₁ to A₄ and at least one adjacent pair among B₁ to B₄ is each independently fused with a group represented by Formula B-1 or Formula B-2, and
X₁, R₁, R₄ to R₇, n1, and n4 to n7 are the same as defined in Formula 1: 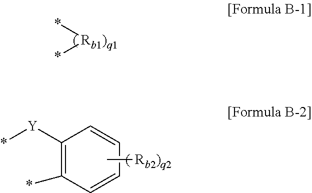
wherein in Formula B-1 and Formula B-2,
R_{b1} is C(R_{b3})(R_{b4}) or N(R_{b5}),
Y is O, S, N(R_{b6}), or C(R_{b7})(R_{b8}),
R_{b2} to Res are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring,
q1 is 3 or 4, and
q2 is an integer from 0 to 4.

9. The light emitting element of claim 1, wherein the first compound is represented by Formula 9-1 or Formula 9-2: 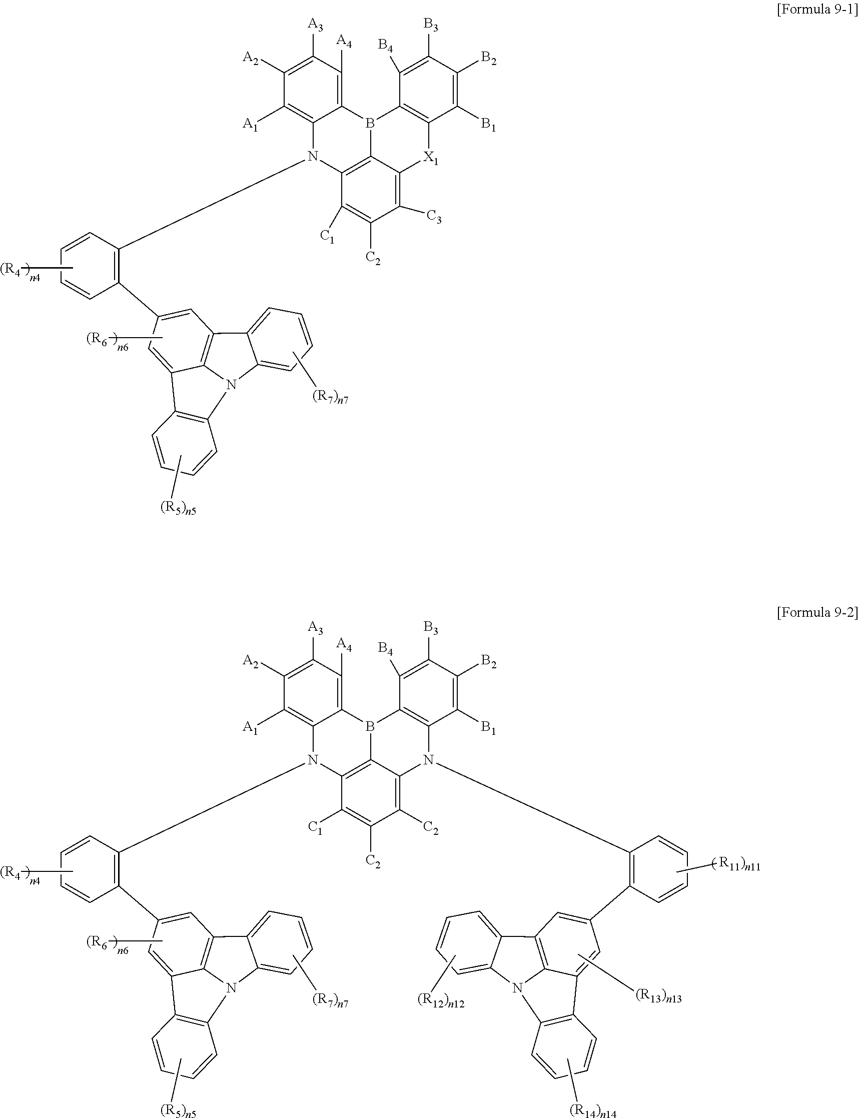
wherein in Formula 9-1 and Formula 9-2,
A₁ to A₄, B₁ to B₄, C₁ to C₃, and R₁₁ to R₁₄ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring,
n11, n12, and n14 are each independently an integer from 0 to 4,
n13 is an integer from 0 to 2,
at least one of A₁ to A₄, B₁ to B₄, and C₁ to C₃ is each independently a group selected from Substituent Group 1, and
X₁, R₄ to R₇, and n4 to n7 are the same as defined in Formula 1:

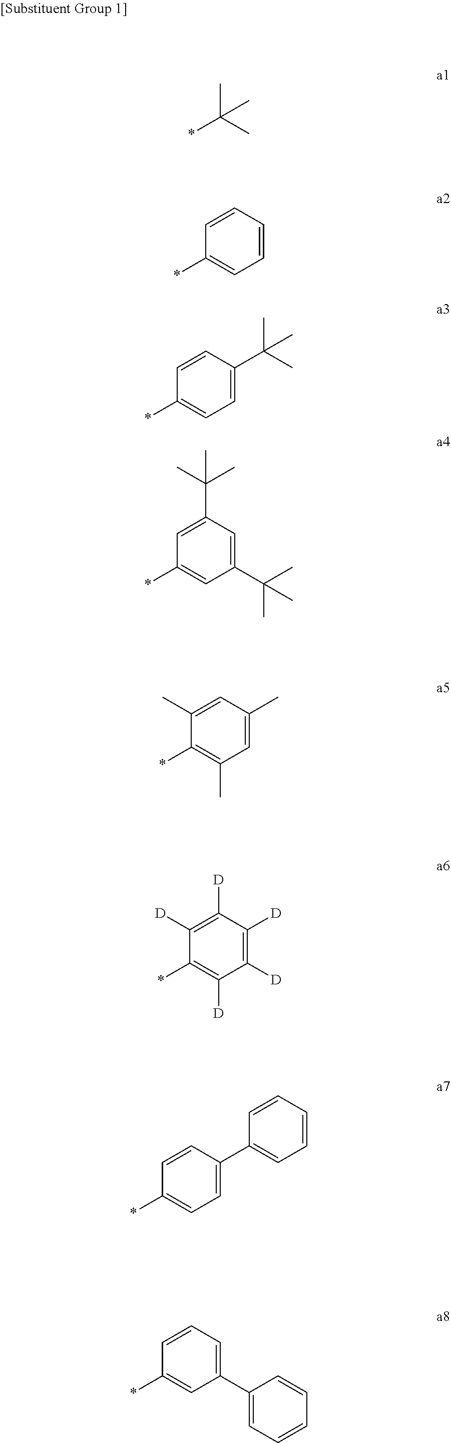

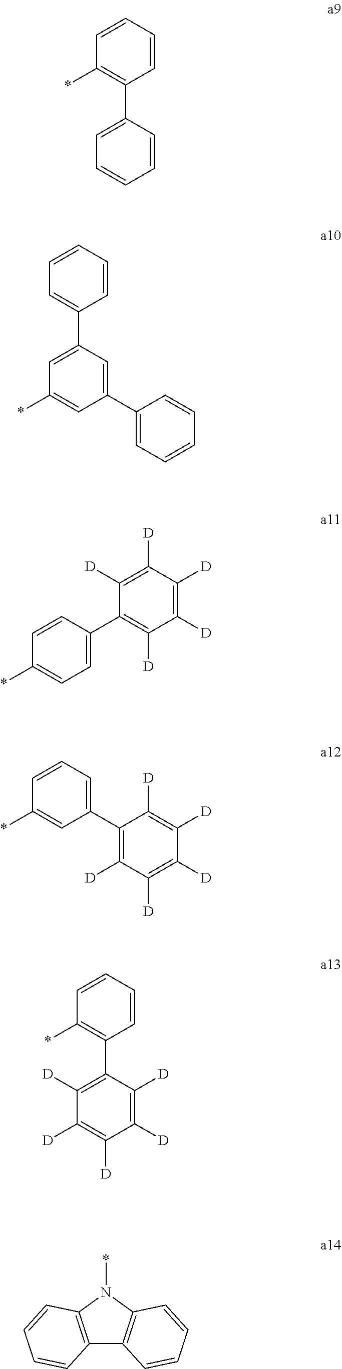 [SMILES: *c1ccccc1-c1ccccc1 ; *c1cc(-c2ccccc2)cc(-c2ccccc2)c1 ; *c1ccc(-c2c([2H])c([2H])c([2H])c([2H])c2[2H])cc1 ; *c1cccc(-c2c([2H])c([2H])c([2H])c([2H])c2[2H])c1 ; *c1ccccc1-c1c([2H])c([2H])c([2H])c([2H])c1[2H] ; *n1c2ccccc2c2ccccc21]

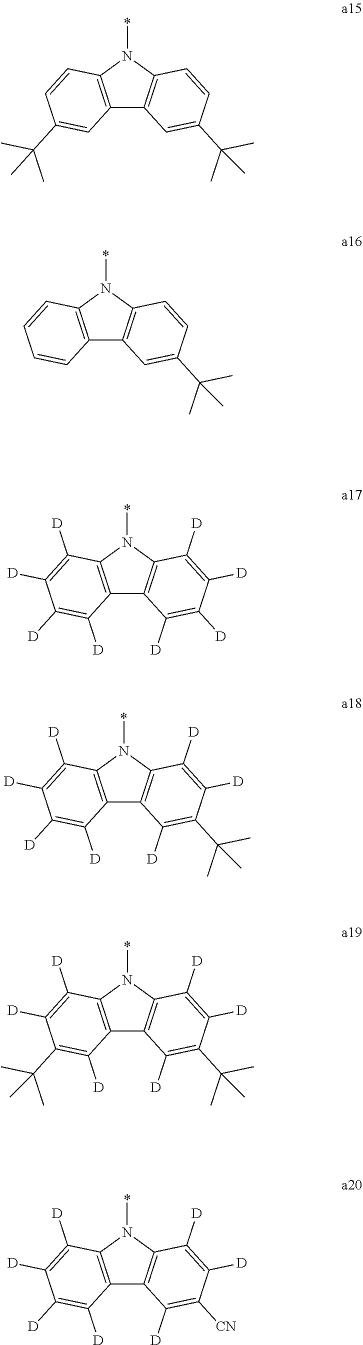

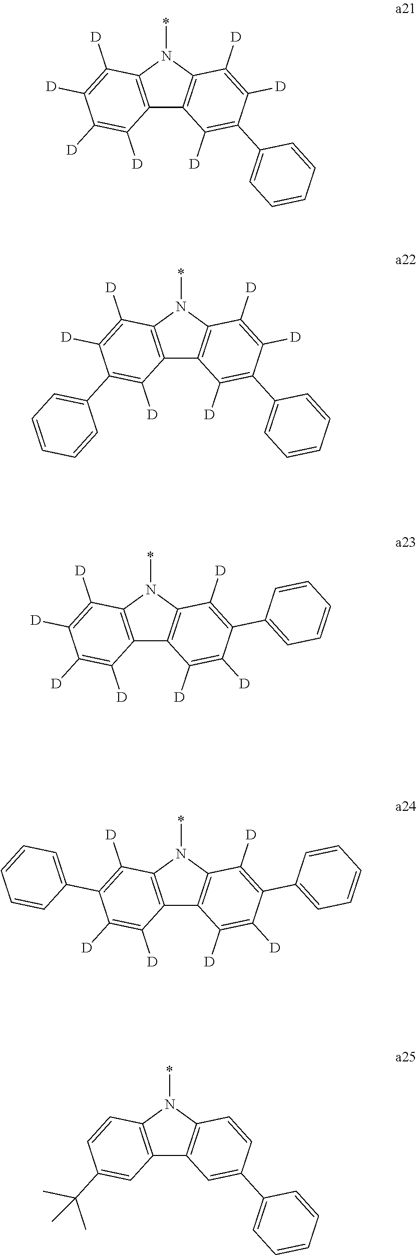 [SMILES: *n1c2c([2H])c([2H])c([2H])c([2H])c2c2c([2H])c(-c3ccccc3)c([2H])c([2H])c21 ; *n1c2c([2H])c([2H])c(-c3ccccc3)c([2H])c2c2c([2H])c(-c3ccccc3)c([2H])c([2H])c21 ; *n1c2c([2H])c([2H])c([2H])c([2H])c2c2c([2H])c([2H])c(-c3ccccc3)c([2H])c21 ; *n1c2c([2H])c(-c3ccccc3)c([2H])c([2H])c2c2c([2H])c([2H])c(-c3ccccc3)c([2H])c21 ; *n1c2ccc(-c3ccccc3)cc2c2cc(C(C)(C)C)ccc21]

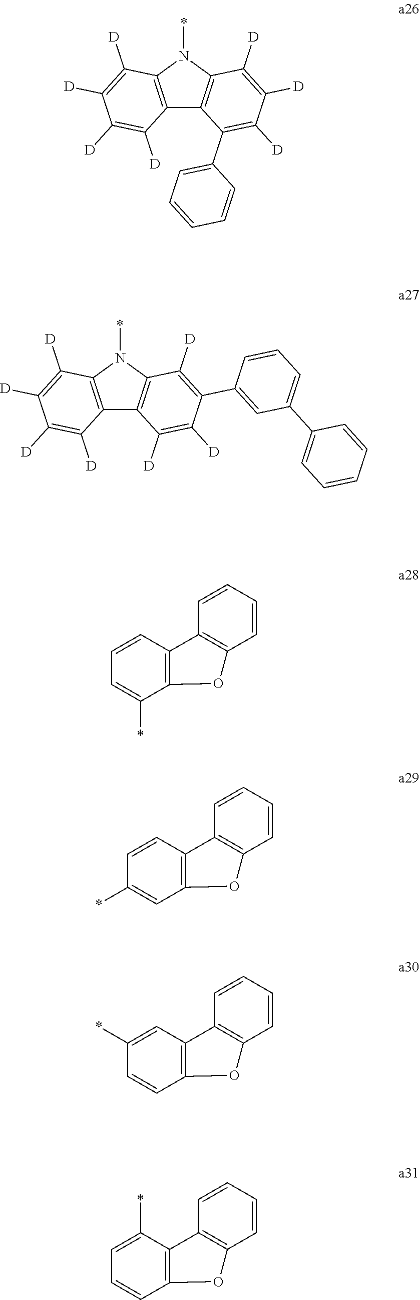 [SMILES: *n1c2c([2H])c([2H])c([2H])c([2H])c2c2c(-c3ccccc3)c([2H])c([2H])c([2H])c21 ; *n1c2c([2H])c([2H])c([2H])c([2H])c2c2c([2H])c([2H])c(-c3cccc(-c4ccccc4)c3)c([2H])c21 ; *c1cccc2c1oc1ccccc12 ; *c1ccc2c(c1)oc1ccccc12 ; *c1ccc2oc3ccccc3c2c1 ; *c1cccc2oc3ccccc3c12]

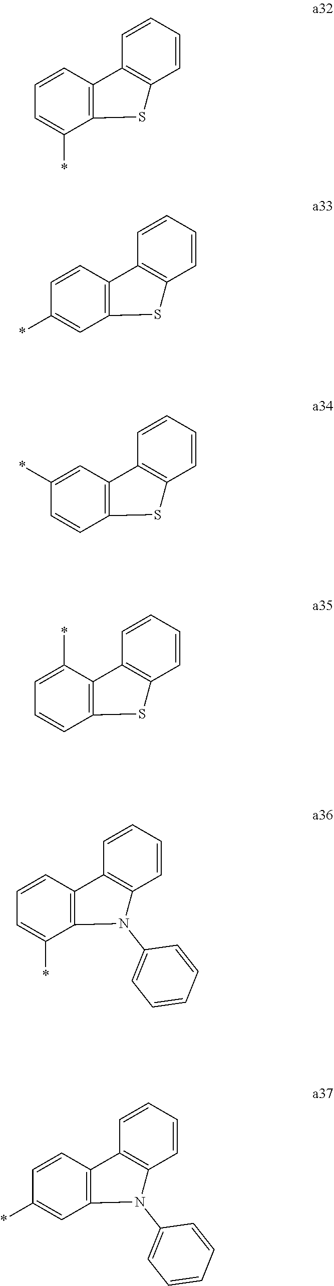 [SMILES: *c1cccc2c1sc1ccccc12 ; *c1ccc2c(c1)sc1ccccc12 ; *c1ccc2sc3ccccc3c2c1 ; *c1cccc2sc3ccccc3c12 ; *c1cccc2c3ccccc3n(-c3ccccc3)c12 ; *c1ccc2c3ccccc3n(-c3ccccc3)c2c1]

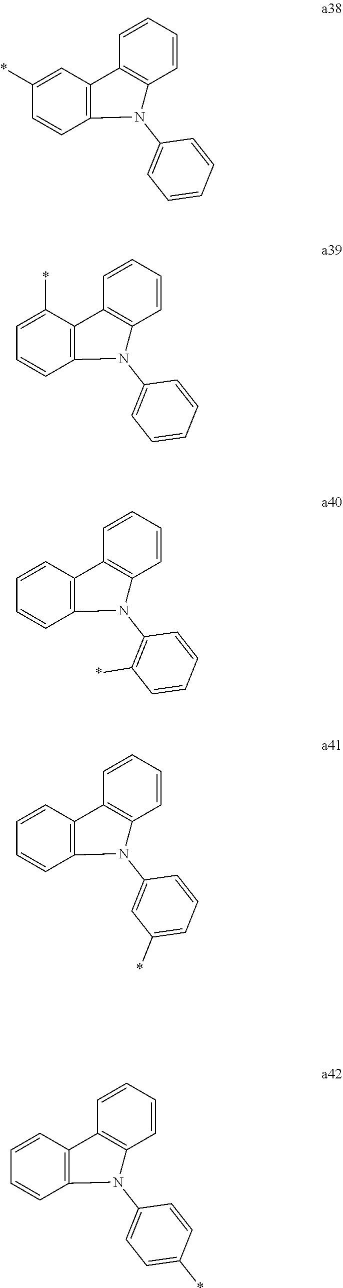 [SMILES: *c1ccc2c(c1)c1ccccc1n2-c1ccccc1 ; *c1cccc2c1c1ccccc1n2-c1ccccc1 ; *c1ccccc1-n1c2ccccc2c2ccccc21 ; *c1cccc(-n2c3ccccc3c3ccccc32)c1 ; *c1ccc(-n2c3ccccc3c3ccccc32)cc1]

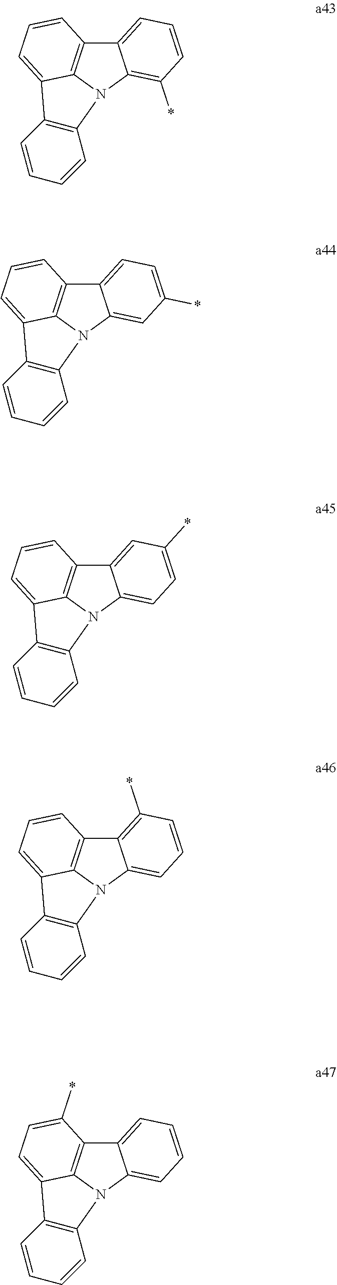 [SMILES: *c1cccc2c3cccc4c5ccccc5n(c12)c43 ; *c1ccc2c3cccc4c5ccccc5n(c2c1)c43 ; *c1ccc2c(c1)c1cccc3c4ccccc4n2c31 ; *c1cccc2c1c1cccc3c4ccccc4n2c31 ; *c1ccc2c3ccccc3n3c4ccccc4c1c23]

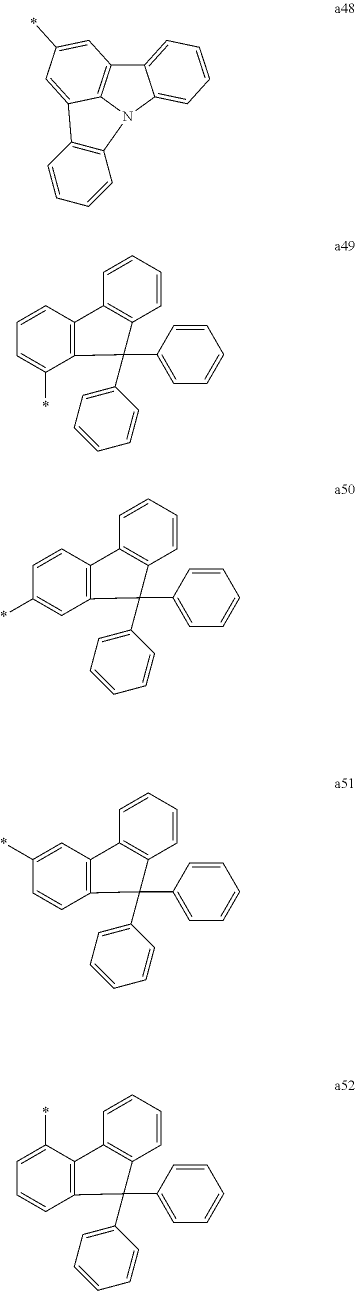 [SMILES: *c1cc2c3ccccc3n3c4ccccc4c(c1)c23 ; *c1cccc2c1C(c1ccccc1)(c1ccccc1)c1ccccc1-2 ; *c1ccc2c(c1)C(c1ccccc1)(c1ccccc1)c1ccccc1-2 ; *c1ccc2c(c1)-c1ccccc1C2(c1ccccc1)c1ccccc1 ; *c1cccc2c1-c1ccccc1C2(c1ccccc1)c1ccccc1]

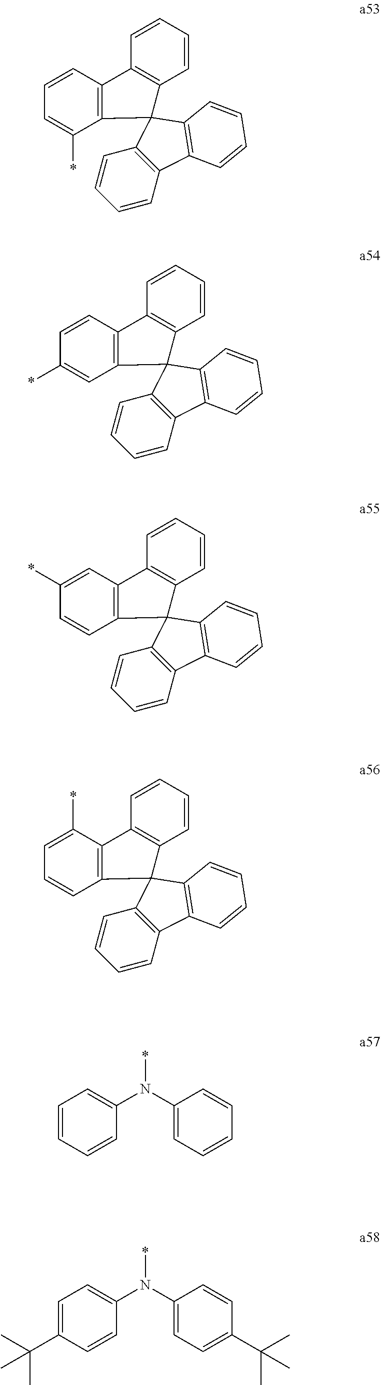 [SMILES: *c1cccc2c1C1(c3ccccc3-c3ccccc31)c1ccccc1-2 ; *c1ccc2c(c1)C1(c3ccccc3-c3ccccc31)c1ccccc1-2 ; *c1ccc2c(c1)-c1ccccc1C21c2ccccc2-c2ccccc21 ; *c1cccc2c1-c1ccccc1C21c2ccccc2-c2ccccc21 ; *N(c1ccccc1)c1ccccc1 ; *N(c1ccc(C(C)(C)C)cc1)c1ccc(C(C)(C)C)cc1]

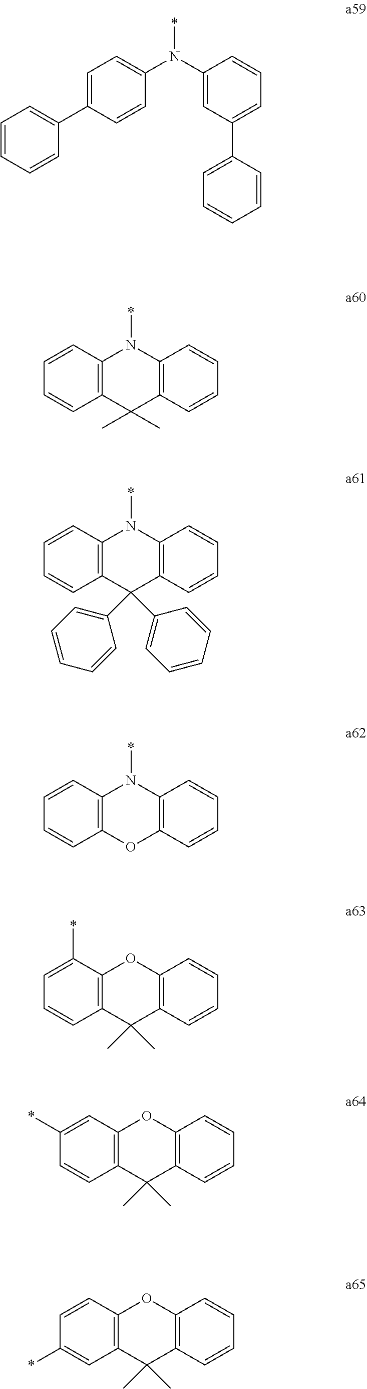

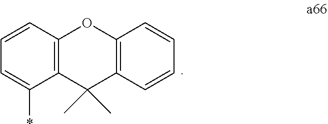 [SMILES: *c1cccc2c1C(C)(C)c1ccccc1O2]

10. The light emitting element of claim 1, wherein the first compound is represented by one of Formula 10-1 to Formula 10-4: 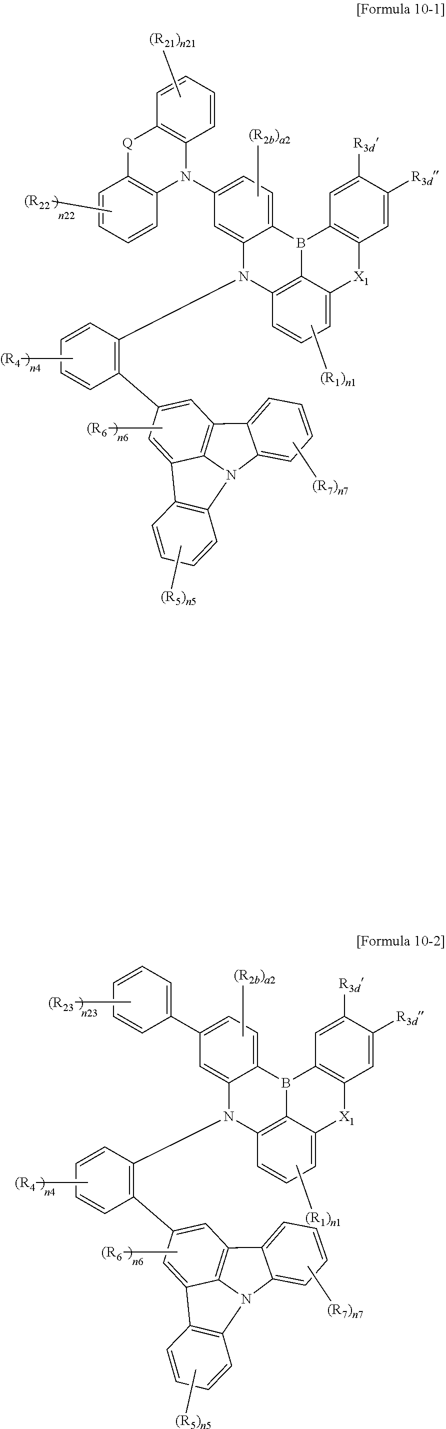 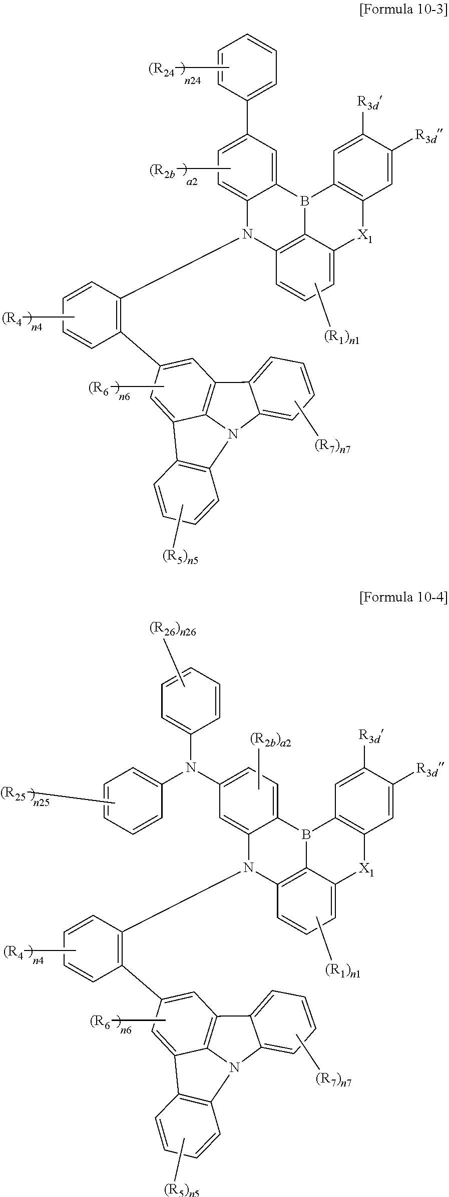
wherein in Formula 10-1 to Formula 10-4,
Q is a direct linkage, O, or C(R₂₇)(R₂₈),
R_{3d}′ and R_{3d}″ are each independently a hydrogen atom or a group represented by one of Formula A-1 to Formula A-5,
R₂₁ to R₂₈ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n21 and n22 are each independently an integer from 0 to 4,
n23 to n26 are each independently an integer from 0 to 5, and
X₁, R₁, R₄ to R₇, n1, and n4 to n7 are the same as defined in Formula 1: 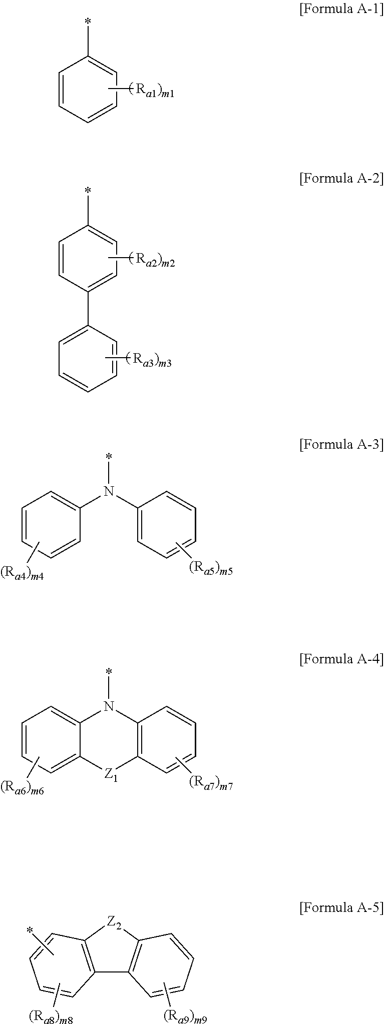
wherein in Formula A-1 to Formula A-5,
Z₁ is a direct linkage, O, or C(Rₐ₁₀)(Rₐ₁₁),
Z₂ is O, S, N(Rₐ₁₂), or C(Rₐ₁₃)(Rₐ₁₄),
Rₐ₁ to Rₐ₁₄ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m1, m3, m4, and m5 are each independently an integer from 0 to 5,
m2, m6, m7, and m9 are each independently an integer from 0 to 4, and
m8 is an integer from 0 to 3.

11. The light emitting element of claim 1, wherein the emission layer further comprises at least one of a second compound represented by Formula HT-1, a third compound represented by Formula ET-1, and a fourth compound represented by Formula D-1: 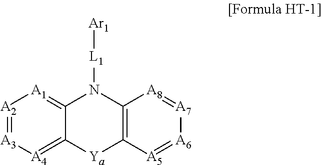
wherein in Formula HT-1,
A₁ to A₈ are each independently N or C(R₅₁),
L₁ is a direct linkage, a substituted or unsubstituted arylene group of 6 to 30 ring-forming carbon atoms, or a substituted or unsubstituted heteroarylene group of 2 to 30 ring-forming carbon atoms,
Yₐ is a direct linkage, C(R₅₂)(R₅₃), or Si(R₅₄)(R₅₅),
Ar₁ is a substituted or unsubstituted aryl group of 6 to 30 ring-forming carbon atoms or a substituted or unsubstituted heteroaryl group of 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring; 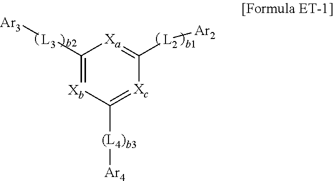
wherein in Formula ET-1,
at least one of Xₐ to X_{c} is each N,
the remainder of Xₐ to X_{c} are each independently C(R₅₆),
R₅₆ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
b1 to b3 are each independently an integer from 0 to 10,
Ar₂ to Ar₄ are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
L₂ to L₄ are each independently a direct linkage, a substituted or unsubstituted arylene group of 6 to 30 ring-forming carbon atoms, or a substituted or unsubstituted heteroarylene group of 2 to 30 ring-forming carbon atoms; 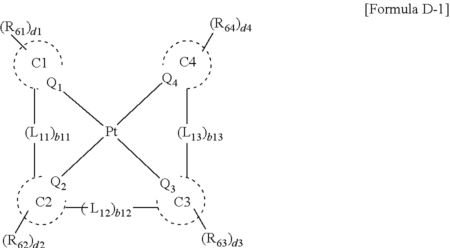
wherein in Formula D-1,
Q₁ to Q₄ are each independently C or N,
C1 to C4 are each independently a substituted or unsubstituted hydrocarbon ring of 5 to 30 ring-forming carbon atoms or a substituted or unsubstituted heterocycle of 2 to 30 ring-forming carbon atoms,
L₁₁ to L₁₃ are each independently a direct linkage, 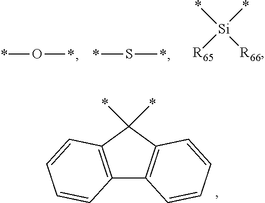
a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring, and
d1 to d4 are each independently an integer from 0 to 4.

12. An electronic device comprising at least one light emitting element, wherein
the electronic device is a television, a monitor, a billboard, a personal computer, a laptop computer, a personal digital terminal, a vehicle display device, a game console, or a camera, and
the light emitting element comprises a first compound represented by Formula 1: 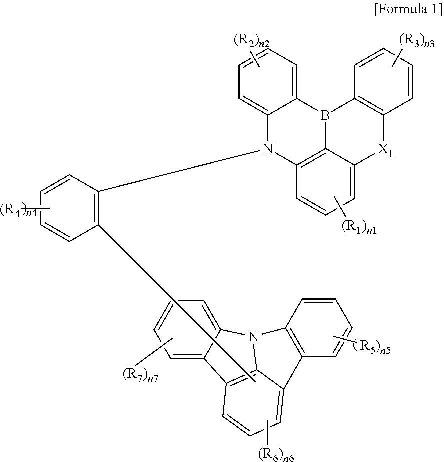
wherein in Formula 1,
X₁ is O, S, or N(Rₐ),
R₁ to R₇ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring,
Rₐ is a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n1 and n6 are each independently an integer from 0 to 3,
n2 to n5, and n7 are each independently an integer from 0 to 4, and
a sum of n6 and n7 is equal to or less than 6.

13. A fused polycyclic compound represented by Formula 1: 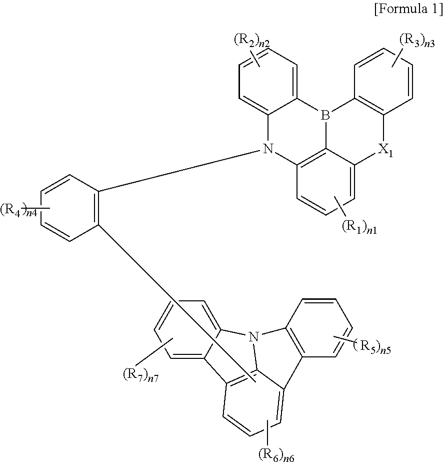
wherein in Formula 1,
X₁ is O, S, or N(Rₐ),
R₁ to R₇ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring,
Rₐ is a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n1 and n6 are each independently an integer from 0 to 3,
n2 to n5, and n7 are each independently an integer from 0 to 4, and
a sum of n6 and n7 is equal to or less than 6.

14. The fused polycyclic compound of claim 13, wherein the fused polycyclic compound represented by Formula 1 is represented by Formula 2: 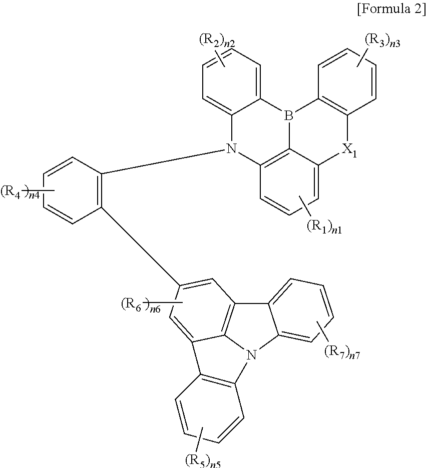
wherein in Formula 2,
X₁, R₁ to R₇, and n1 to n7 are the same as defined in Formula 1.

15. The fused polycyclic compound of claim 13, wherein the fused polycyclic compound represented by Formula 1 is represented Formula 3: 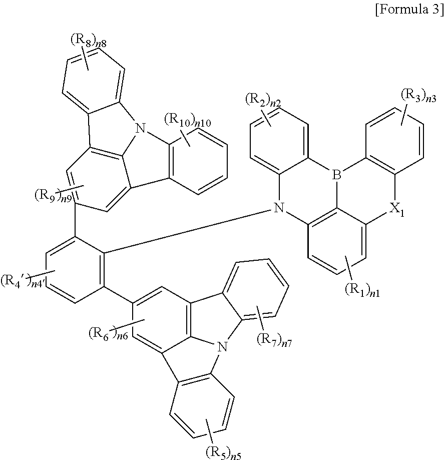
wherein in Formula 3,
R₄′, and R₈ to R₁₀ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n4′ is an integer from 0 to 3,
n8 and n10 are each independently an integer from 0 to 4,
n9 is an integer from 0 to 2, and
X₁, R₁ to R₃, R₅ to R₇, n1 to n3, and n5 to n7 are the same as defined in Formula 1.

16. The fused polycyclic compound of claim 13, wherein the fused polycyclic compound represented by Formula 1 is represented by Formula 4: 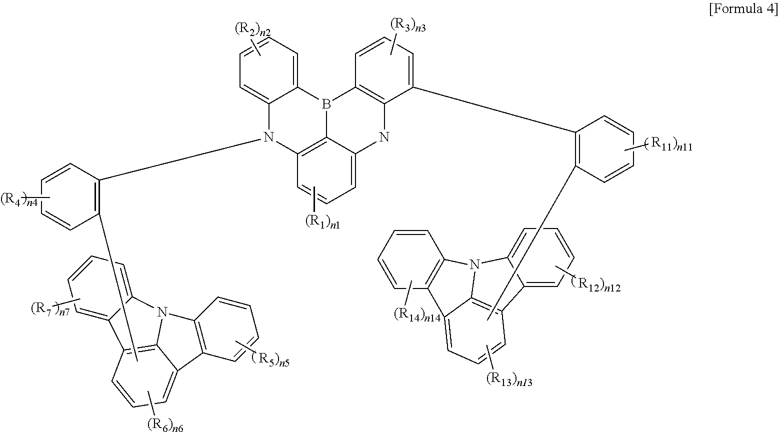
wherein in Formula 4,
R₁₁ to R₁₄ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring,
n11, n12, and n14 are each independently an integer from 0 to 4,
n13 is an integer from 0 to 3,
a sum of n12 and n13 is equal to or less than 6, and
R₁ to R₇ and n1 to n7 are the same as defined in Formula 1.

17. The fused polycyclic compound of claim 16, wherein the fused polycyclic compound represented by Formula 4 is represented by Formula 5: 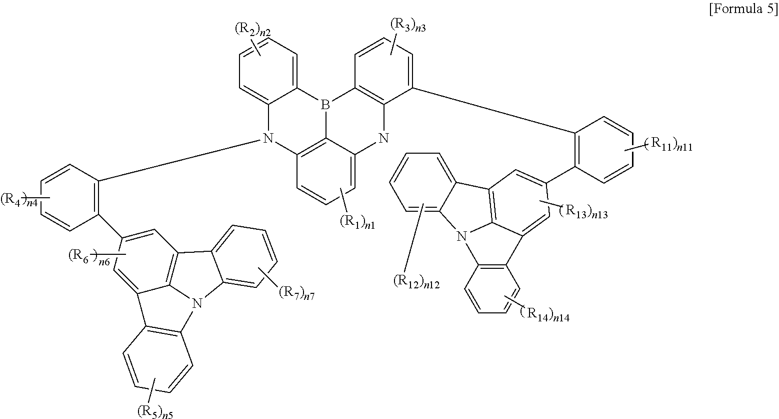
wherein in Formula 5,
R₁ to R₇ and n1 to n7 are the same as defined in Formula 1 and
R₁₁ to R₁₄ and n11 to n14 are the same as defined in Formula 4.

18. The fused polycyclic compound of claim 16, wherein the fused polycyclic compound represented by Formula 4 is represented by one of Formula 6-1 to Formula 6-4: 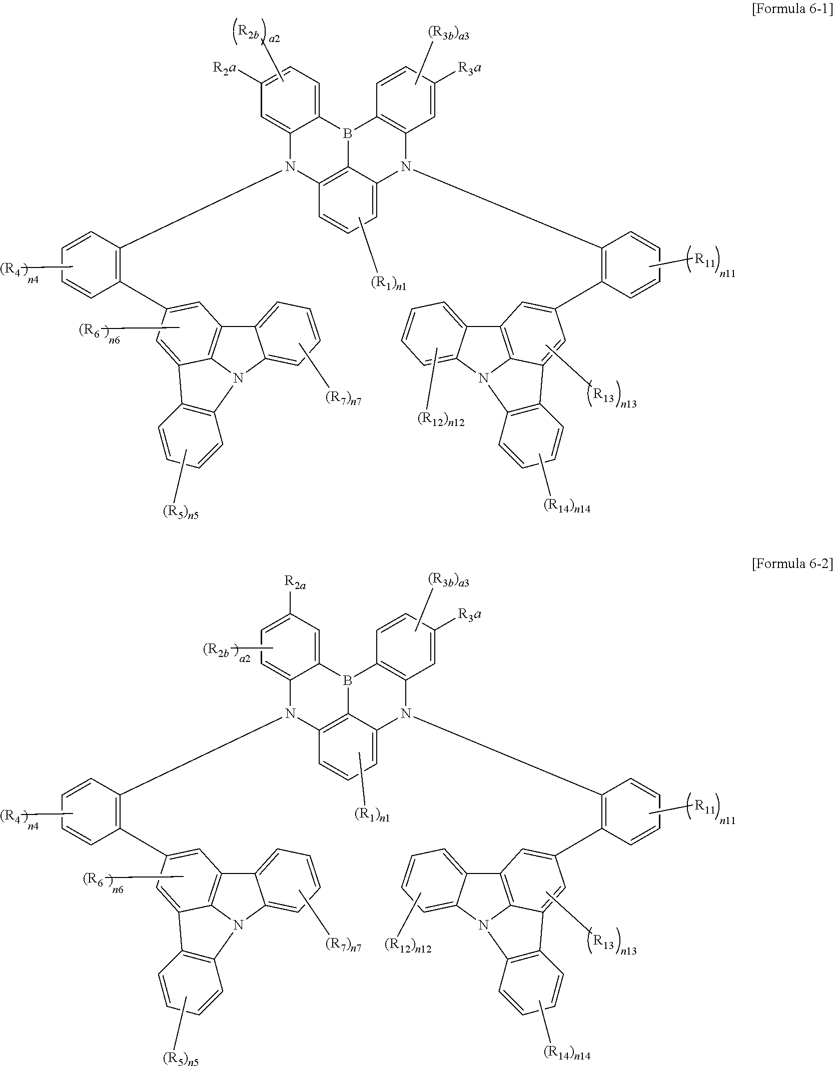 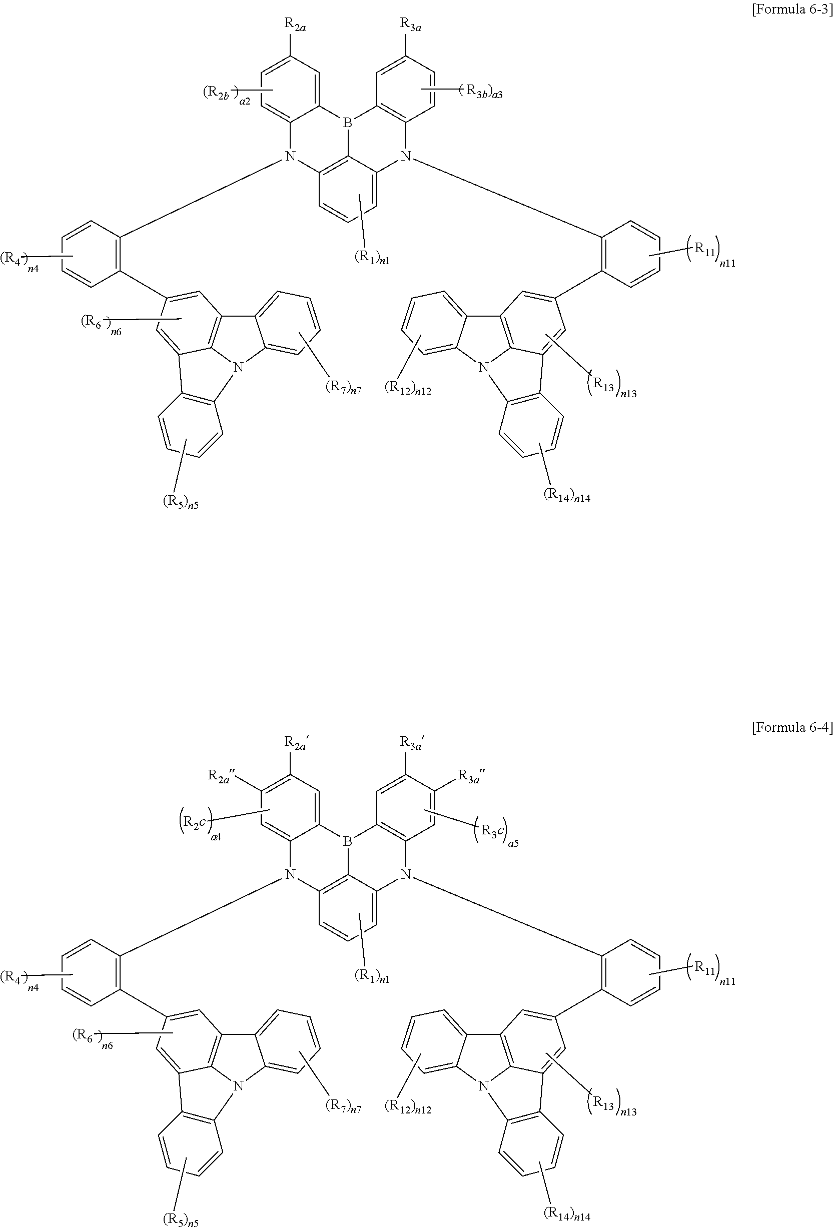
wherein in Formula 6-1 to Formula 6-4,
R₂ₐ, R₂ₐ′, R₂ₐ″, R₃ₐ, R₃ₐ′, and R₃ₐ″ are each independently a group represented by one of Formula A-1 to Formula A-5,
R_{2b}, R_{3b}, R_{2c}, and R_{3c} are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
a2 and a3 are each independently an integer from 0 to 3,
a4 and a5 are each independently an integer of 0 to 2,
R₁, R₄ to R₇, n1, and n4 to n7 are the same as defined in Formula 1, and
R₁₁ to R₁₄ and n11 to n14 are the same as defined in Formula 4: 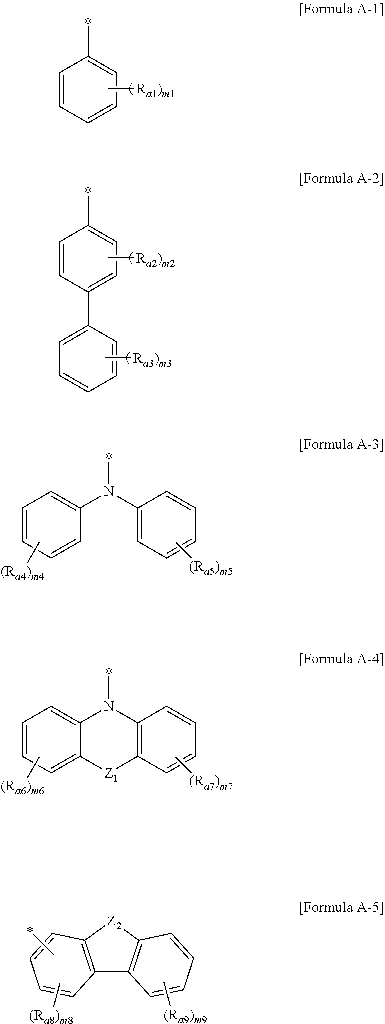
wherein in Formula A-1 to Formula A-5,
Z₁ is a direct linkage, O, or C(Rₐ₁₀)(Rₐ₁₁),
Z₂ is O, S, N(Rₐ₁₂), or C(Rₐ₁₃)(Rₐ₁₄),
Rₐ₁ to Rₐ₁₄ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m1, m3, m4, and m5 are each independently an integer from 0 to 5,
m2, m6, m7, and m9 are each independently an integer from 0 to 4, and
m8 is an integer from 0 to 3.

19. The fused polycyclic compound of claim 16, wherein the fused polycyclic compound represented by Formula 4 is represented by Formula 7-1 or Formula 7-2: 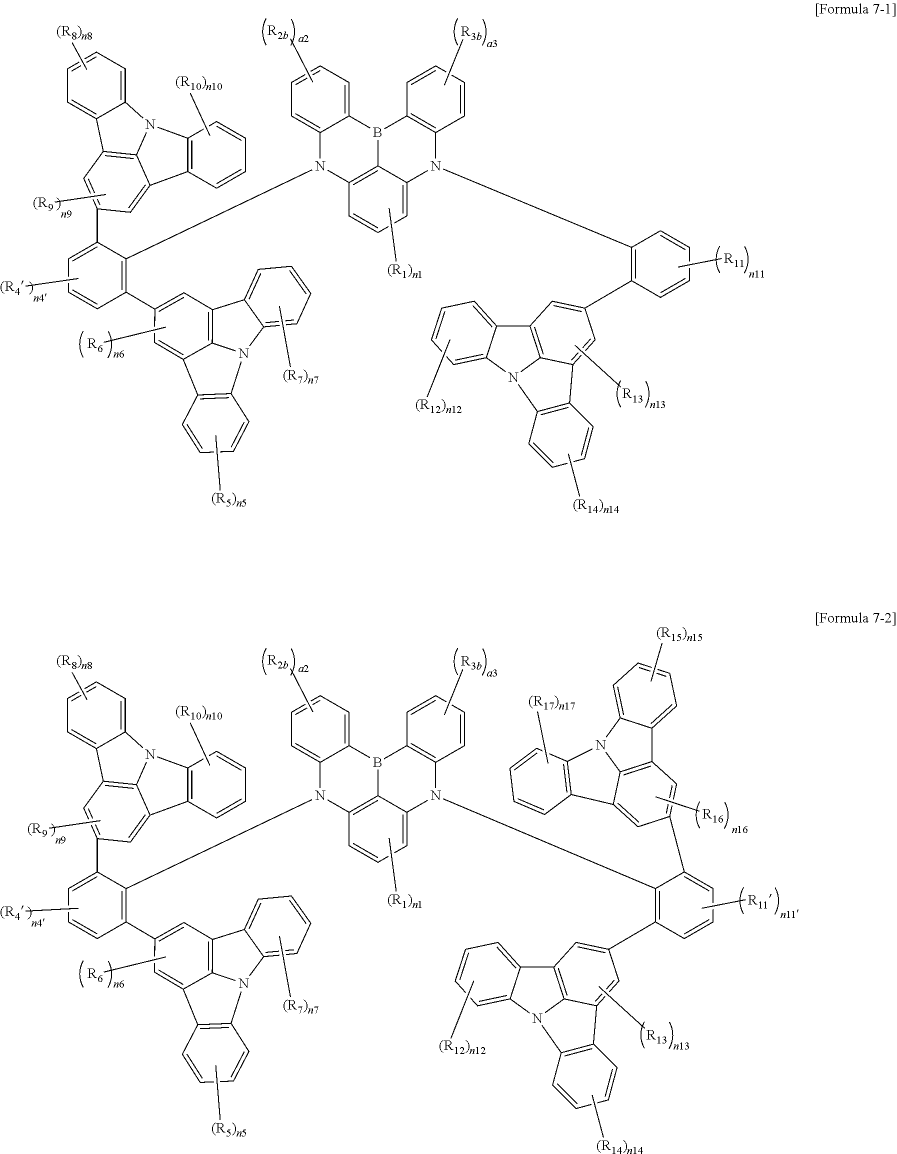
wherein in Formula 7-1 and Formula 7-2,
R₄′, R₈ to R₁₀, R₁₁′, and R₁₅ to R₁₇ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n4′ and n11′ are each independently an integer from 0 to 3,
n8, n10, n15, and n17 are each independently an integer from 0 to 4,
n9 and n16 are each independently an integer from 0 to 2, and
R₁ to R₃, R₅ to R₇, n1 to n3, and n5 to n7 are the same as defined in Formula 1, and
R₁₁ to R₁₄ and n11 to n14 are the same as defined in Formula 4.

20. The fused polycyclic compound of claim 13, wherein the fused polycyclic compound is selected from Compound Group 1: 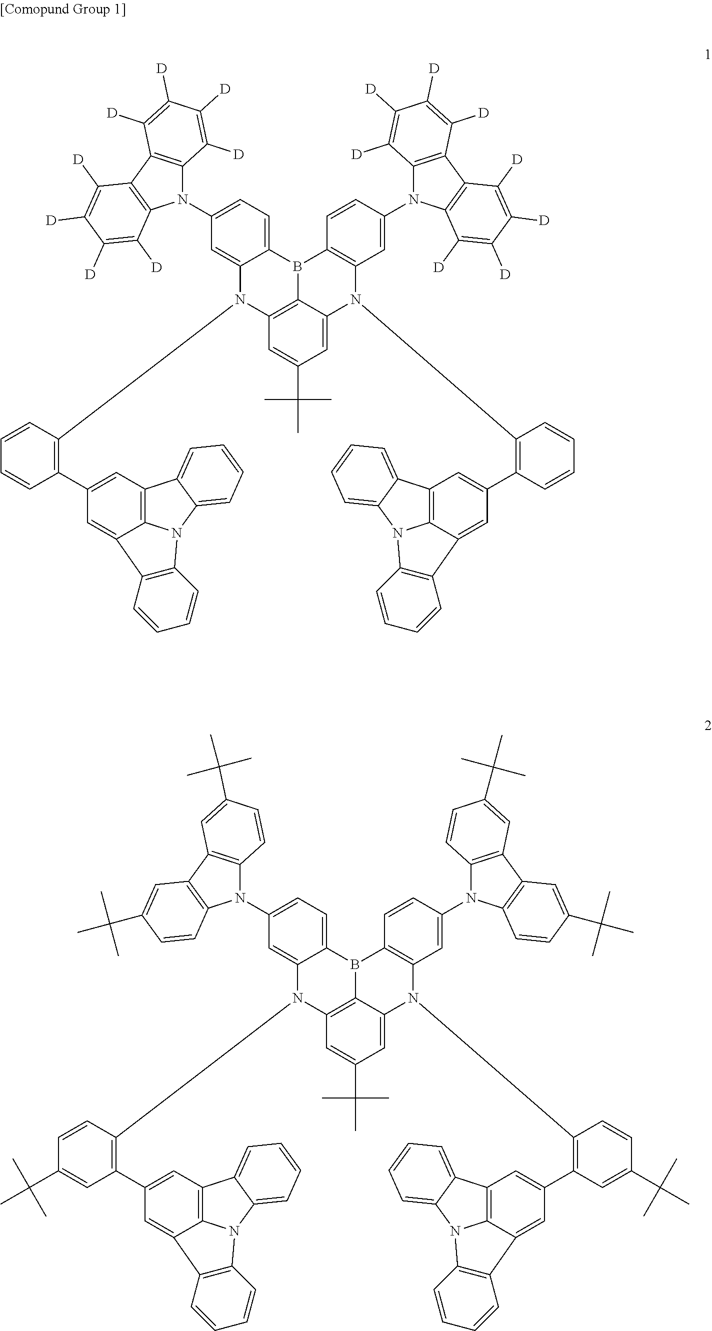 [SMILES: [2H]c1c([2H])c([2H])c2c(c1[2H])c1c([2H])c([2H])c([2H])c([2H])c1n2-c1ccc2c(c1)N(c1ccccc1-c1cc3c4ccccc4n4c5ccccc5c(c1)c34)c1cc(C(C)(C)C)cc3c1B2c1ccc(-n2c4c([2H])c([2H])c([2H])c([2H])c4c4c([2H])c([2H])c([2H])c([2H])c42)cc1N3c1ccccc1-c1cc2c3ccccc3n3c4ccccc4c(c1)c23 ; CC(C)(C)c1ccc(N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(C(C)(C)C)cc4-c4cc5c6ccccc6n6c7ccccc7c(c4)c56)c4cc(C(C)(C)C)cc2c43)c(-c2cc3c4ccccc4n4c5ccccc5c(c2)c34)c1] 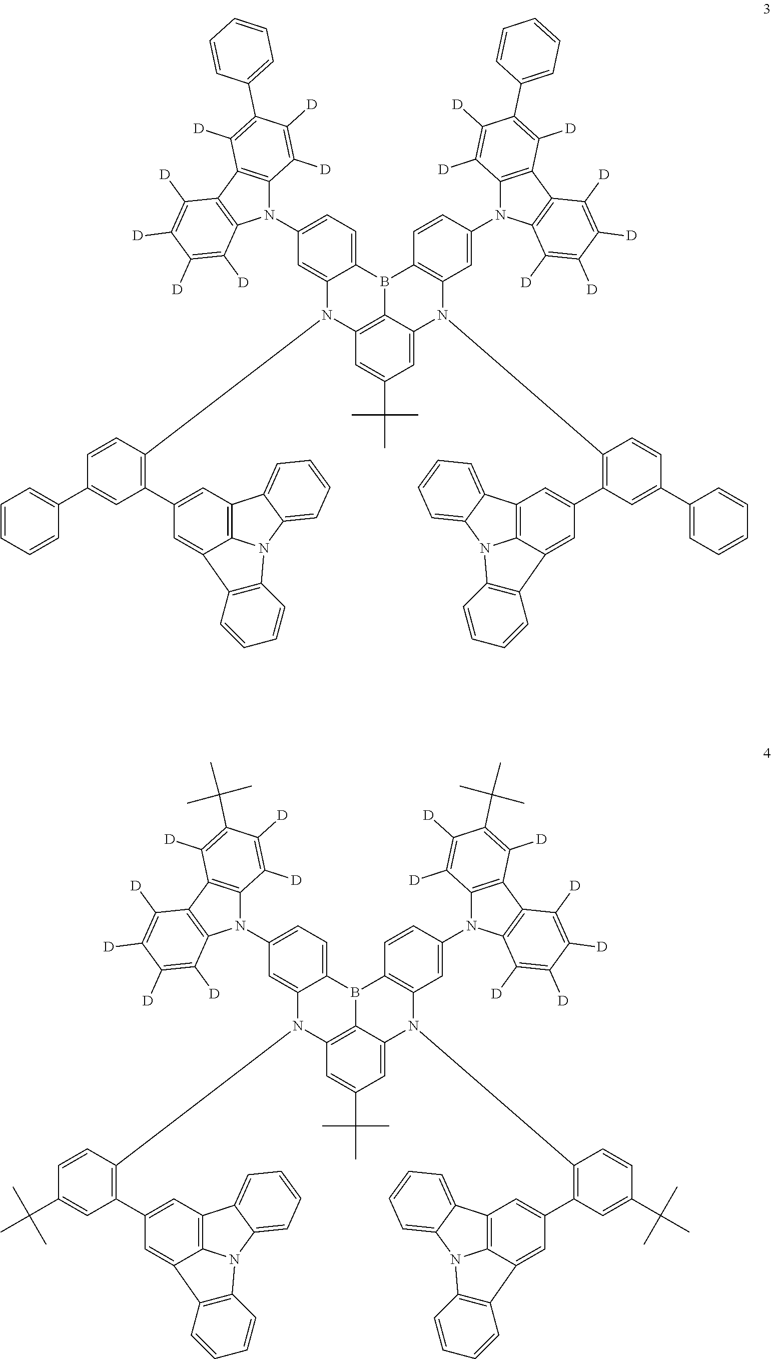 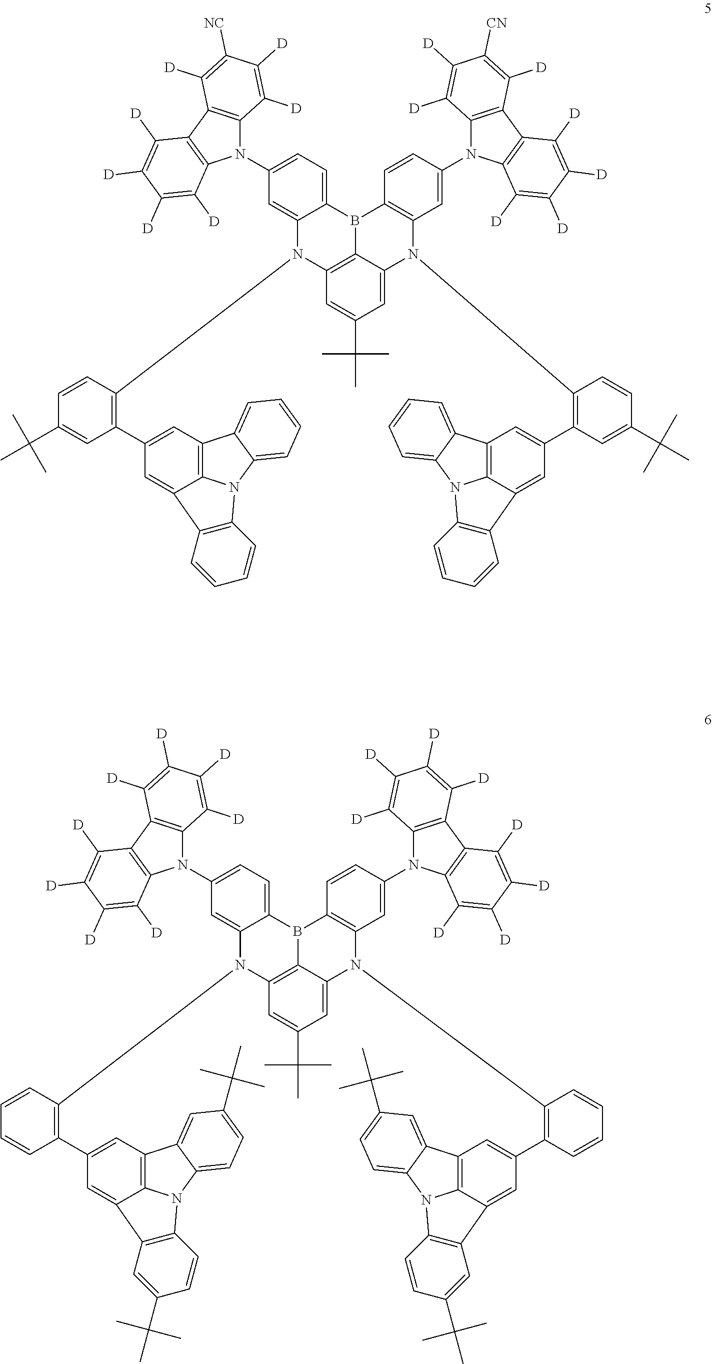 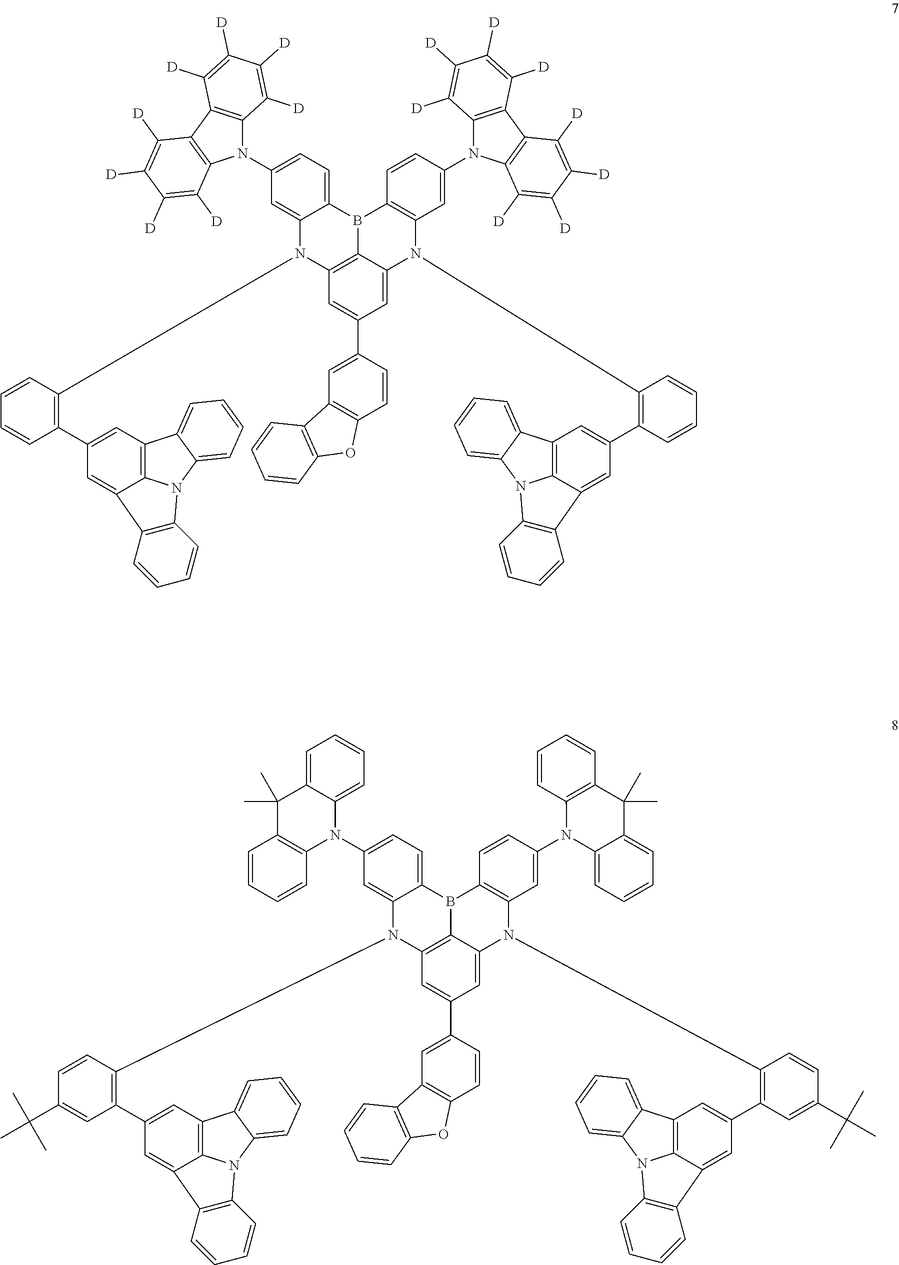 [SMILES: [2H]c1c([2H])c([2H])c2c(c1[2H])c1c([2H])c([2H])c([2H])c([2H])c1n2-c1ccc2c(c1)N(c1ccccc1-c1cc3c4ccccc4n4c5ccccc5c(c1)c34)c1cc(-c3ccc4oc5ccccc5c4c3)cc3c1B2c1ccc(-n2c4c([2H])c([2H])c([2H])c([2H])c4c4c([2H])c([2H])c([2H])c([2H])c42)cc1N3c1ccccc1-c1cc2c3ccccc3n3c4ccccc4c(c1)c23 ; CC(C)(C)c1ccc(N2c3cc(N4c5ccccc5C(C)(C)c5ccccc54)ccc3B3c4ccc(N5c6ccccc6C(C)(C)c6ccccc65)cc4N(c4ccc(C(C)(C)C)cc4-c4cc5c6ccccc6n6c7ccccc7c(c4)c56)c4cc(-c5ccc6oc7ccccc7c6c5)cc2c43)c(-c2cc3c4ccccc4n4c5ccccc5c(c2)c34)c1] 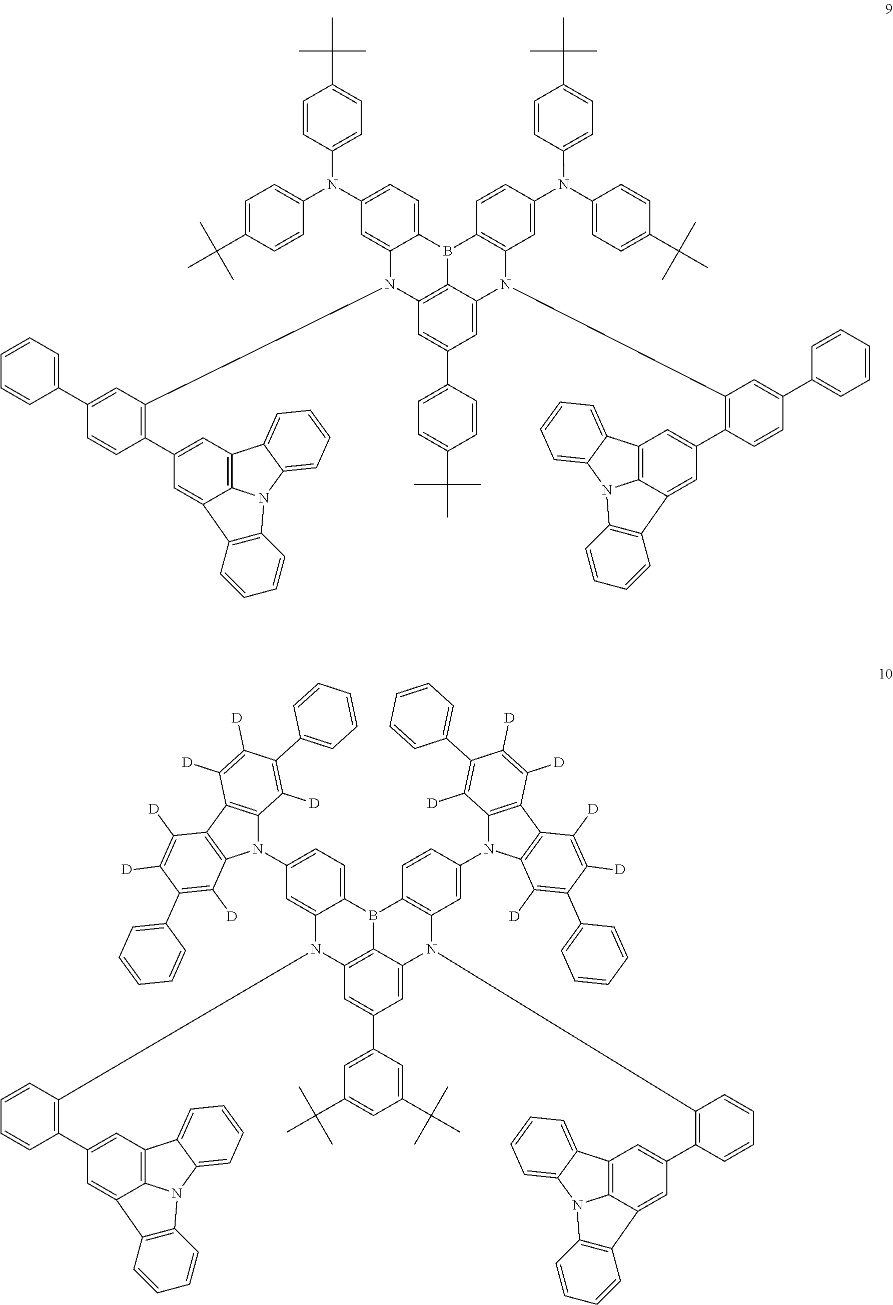 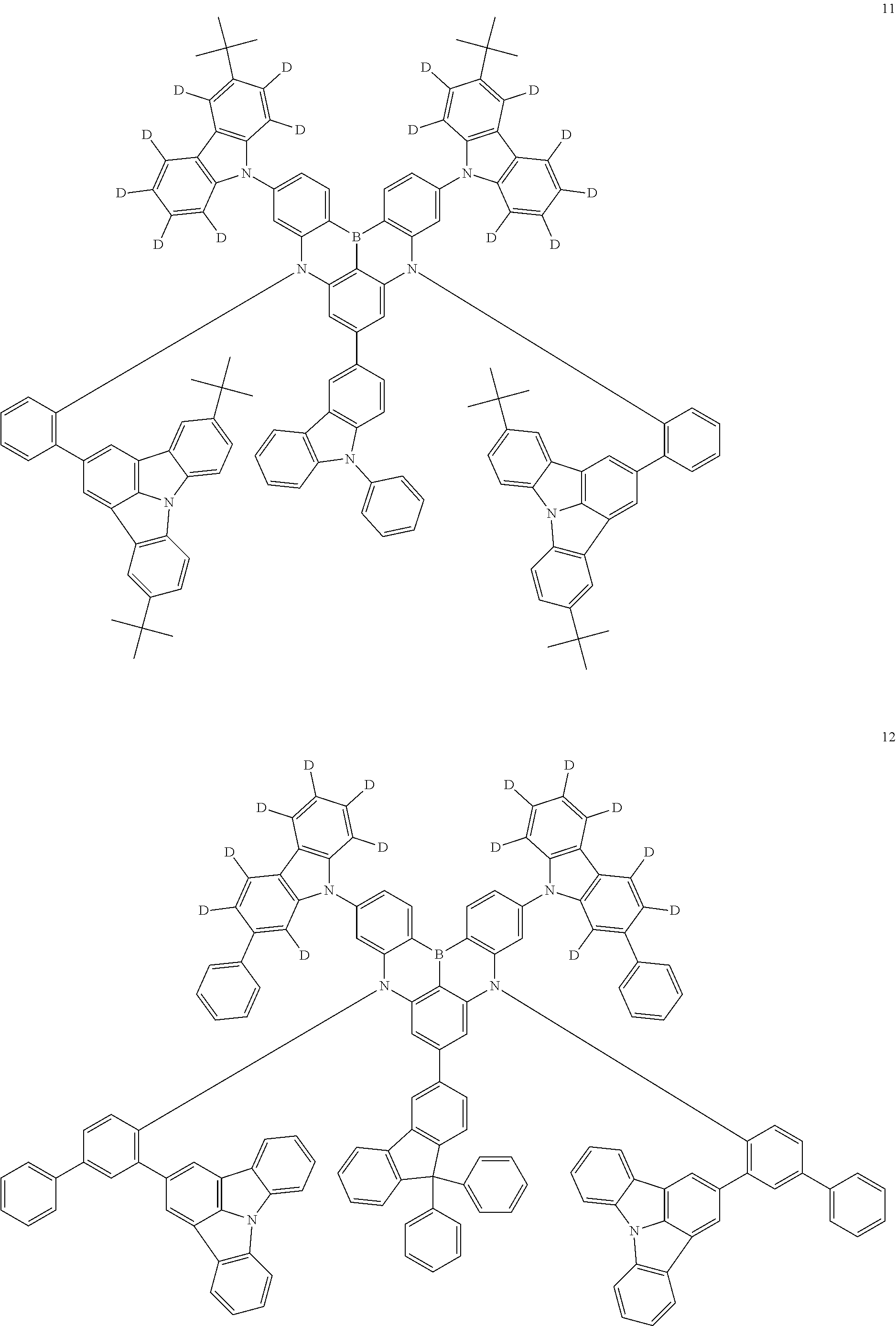 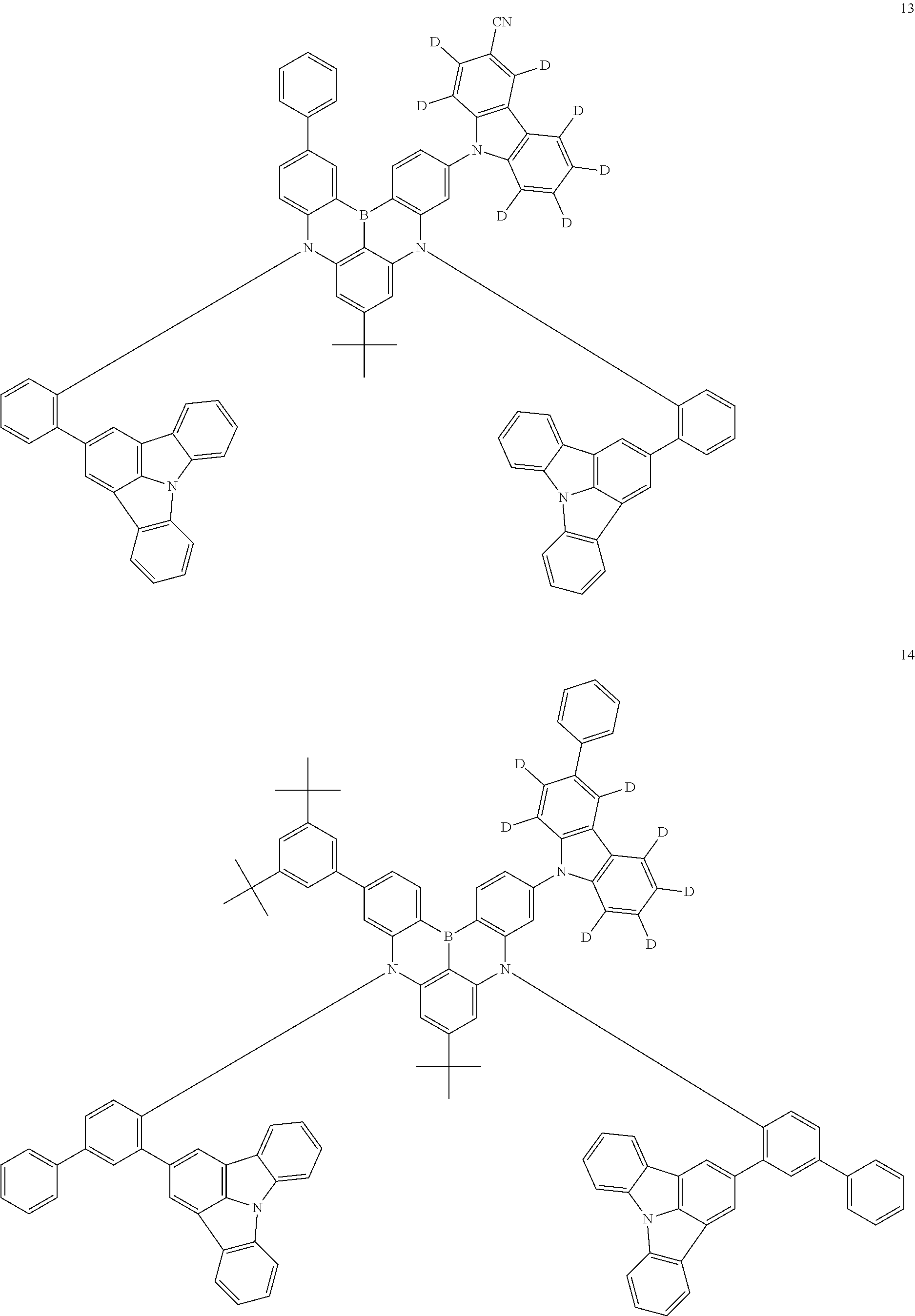 [SMILES: [2H]c1c([2H])c([2H])c2c(c1[2H])c1c([2H])c(C#N)c([2H])c([2H])c1n2-c1ccc2c(c1)N(c1ccccc1-c1cc3c4ccccc4n4c5ccccc5c(c1)c34)c1cc(C(C)(C)C)cc3c1B2c1cc(-c2ccccc2)ccc1N3c1ccccc1-c1cc2c3ccccc3n3c4ccccc4c(c1)c23 ; [2H]c1c([2H])c([2H])c2c(c1[2H])c1c([2H])c(-c3ccccc3)c([2H])c([2H])c1n2-c1ccc2c(c1)N(c1ccc(-c3ccccc3)cc1-c1cc3c4ccccc4n4c5ccccc5c(c1)c34)c1cc(C(C)(C)C)cc3c1B2c1ccc(-c2cc(C(C)(C)C)cc(C(C)(C)C)c2)cc1N3c1ccc(-c2ccccc2)cc1-c1cc2c3ccccc3n3c4ccccc4c(c1)c23] 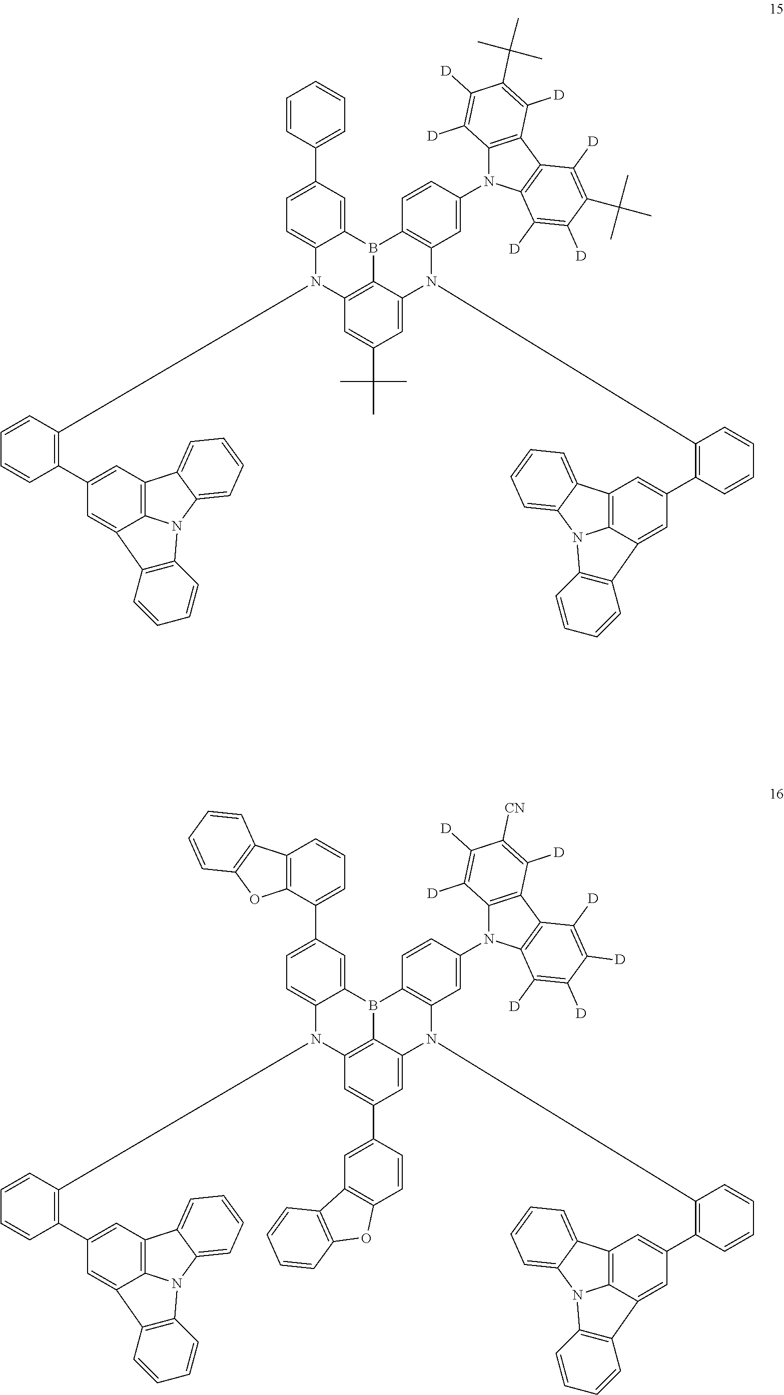 [SMILES: [2H]c1c(C(C)(C)C)c([2H])c2c3c([2H])c(C(C)(C)C)c([2H])c([2H])c3n(-c3ccc4c(c3)N(c3ccccc3-c3cc5c6ccccc6n6c7ccccc7c(c3)c56)c3cc(C(C)(C)C)cc5c3B4c3cc(-c4ccccc4)ccc3N5c3ccccc3-c3cc4c5ccccc5n5c6ccccc6c(c3)c45)c2c1[2H] ; [2H]c1c([2H])c([2H])c2c(c1[2H])c1c([2H])c(C#N)c([2H])c([2H])c1n2-c1ccc2c(c1)N(c1ccccc1-c1cc3c4ccccc4n4c5ccccc5c(c1)c34)c1cc(-c3ccc4oc5ccccc5c4c3)cc3c1B2c1cc(-c2cccc4c2oc2ccccc24)ccc1N3c1ccccc1-c1cc2c3ccccc3n3c4ccccc4c(c1)c23] 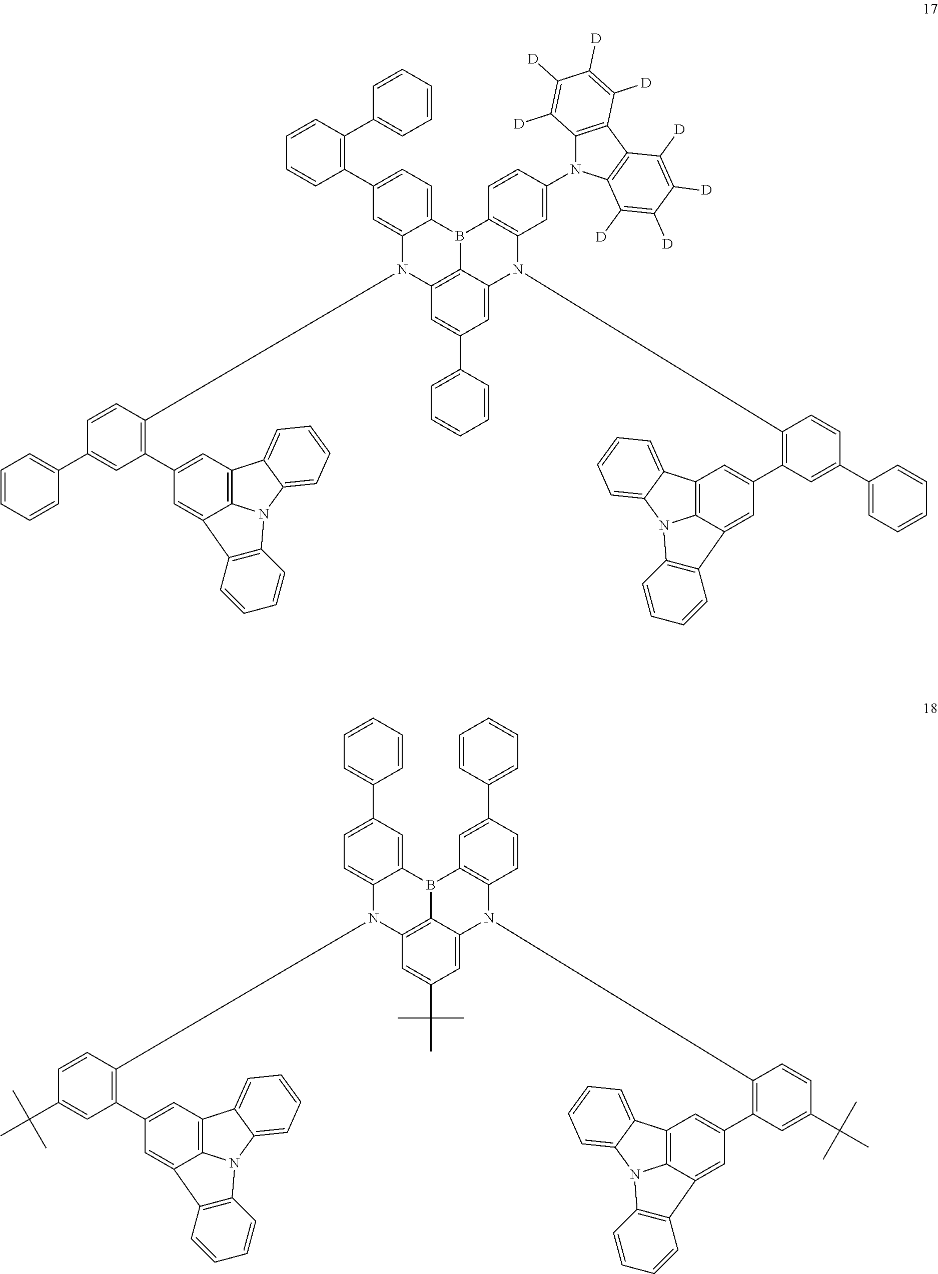 [SMILES: [2H]c1c([2H])c([2H])c2c(c1[2H])c1c([2H])c([2H])c([2H])c([2H])c1n2-c1ccc2c(c1)N(c1ccc(-c3ccccc3)cc1-c1cc3c4ccccc4n4c5ccccc5c(c1)c34)c1cc(-c3ccccc3)cc3c1B2c1ccc(-c2ccccc2-c2ccccc2)cc1N3c1ccc(-c2ccccc2)cc1-c1cc2c3ccccc3n3c4ccccc4c(c1)c23 ; CC(C)(C)c1ccc(N2c3ccc(-c4ccccc4)cc3B3c4cc(-c5ccccc5)ccc4N(c4ccc(C(C)(C)C)cc4-c4cc5c6ccccc6n6c7ccccc7c(c4)c56)c4cc(C(C)(C)C)cc2c43)c(-c2cc3c4ccccc4n4c5ccccc5c(c2)c34)c1] 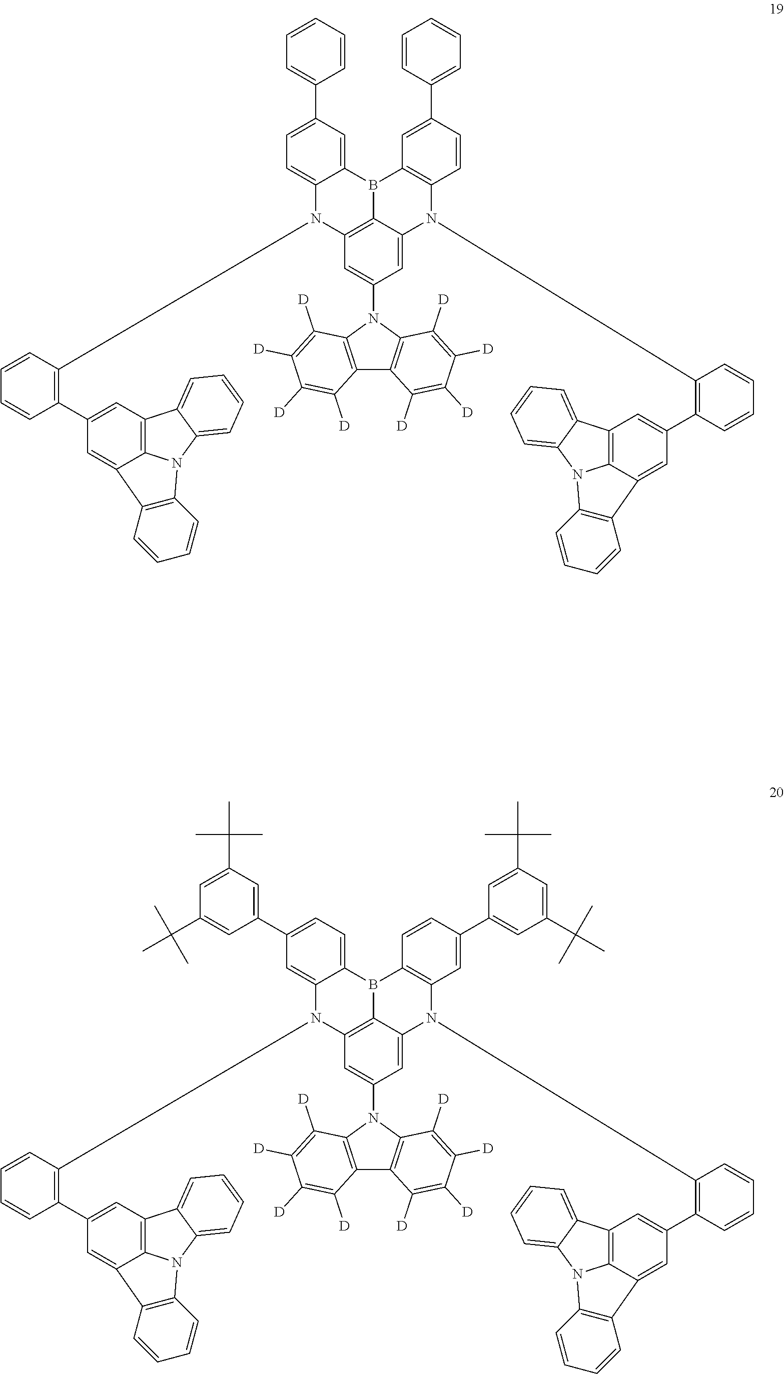 [SMILES: [2H]c1c([2H])c([2H])c2c(c1[2H])c1c([2H])c([2H])c([2H])c([2H])c1n2-c1cc2c3c(c1)N(c1ccccc1-c1cc4c5ccccc5n5c6ccccc6c(c1)c45)c1ccc(-c4ccccc4)cc1B3c1cc(-c3ccccc3)ccc1N2c1ccccc1-c1cc2c3ccccc3n3c4ccccc4c(c1)c23 ; [2H]c1c([2H])c([2H])c2c(c1[2H])c1c([2H])c([2H])c([2H])c([2H])c1n2-c1cc2c3c(c1)N(c1ccccc1-c1cc4c5ccccc5n5c6ccccc6c(c1)c45)c1cc(-c4cc(C(C)(C)C)cc(C(C)(C)C)c4)ccc1B3c1ccc(-c3cc(C(C)(C)C)cc(C(C)(C)C)c3)cc1N2c1ccccc1-c1cc2c3ccccc3n3c4ccccc4c(c1)c23] 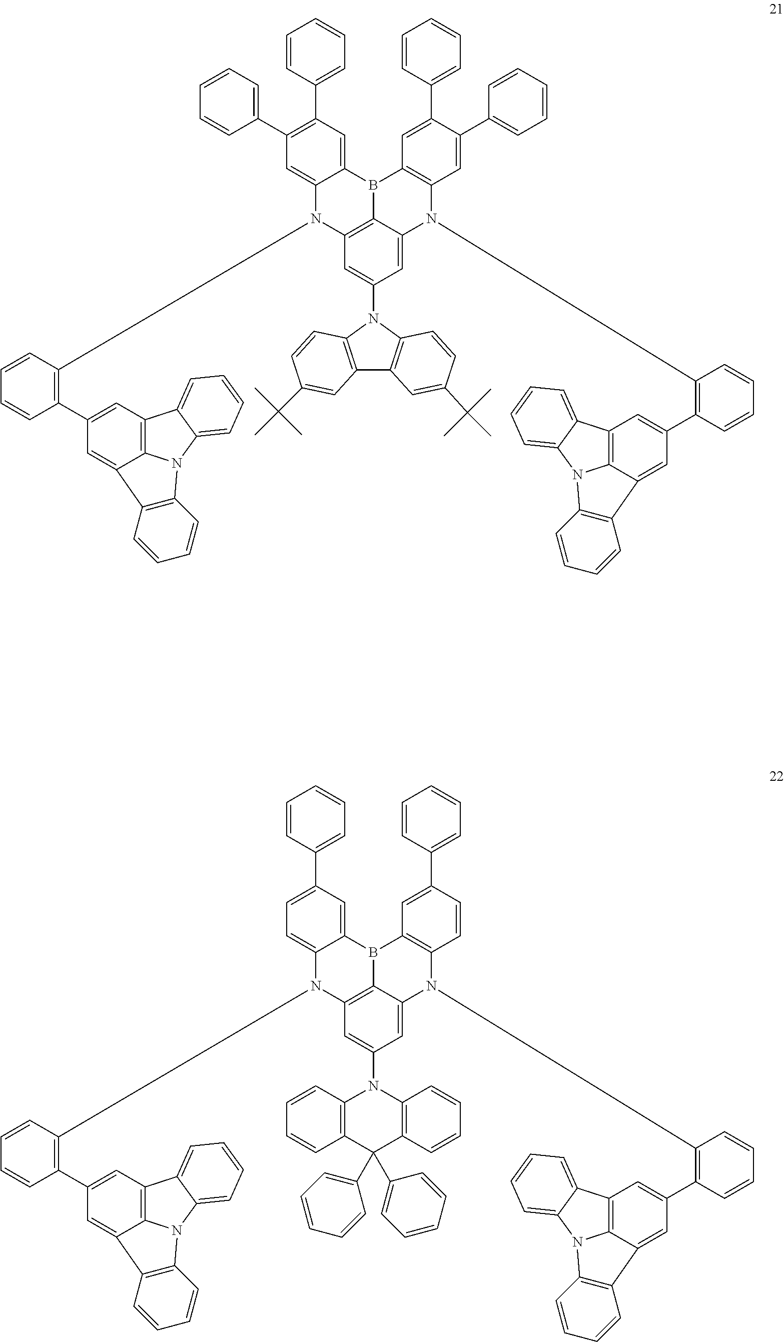 [SMILES: CC(C)(C)c1ccc2c(c1)c1cc(C(C)(C)C)ccc1n2-c1cc2c3c(c1)N(c1ccccc1-c1cc4c5ccccc5n5c6ccccc6c(c1)c45)c1cc(-c4ccccc4)c(-c4ccccc4)cc1B3c1cc(-c3ccccc3)c(-c3ccccc3)cc1N2c1ccccc1-c1cc2c3ccccc3n3c4ccccc4c(c1)c23 ; c1ccc(-c2ccc3c(c2)B2c4cc(-c5ccccc5)ccc4N(c4ccccc4-c4cc5c6ccccc6n6c7ccccc7c(c4)c56)c4cc(N5c6ccccc6C(c6ccccc6)(c6ccccc6)c6ccccc65)cc(c42)N3c2ccccc2-c2cc3c4ccccc4n4c5ccccc5c(c2)c34)cc1] 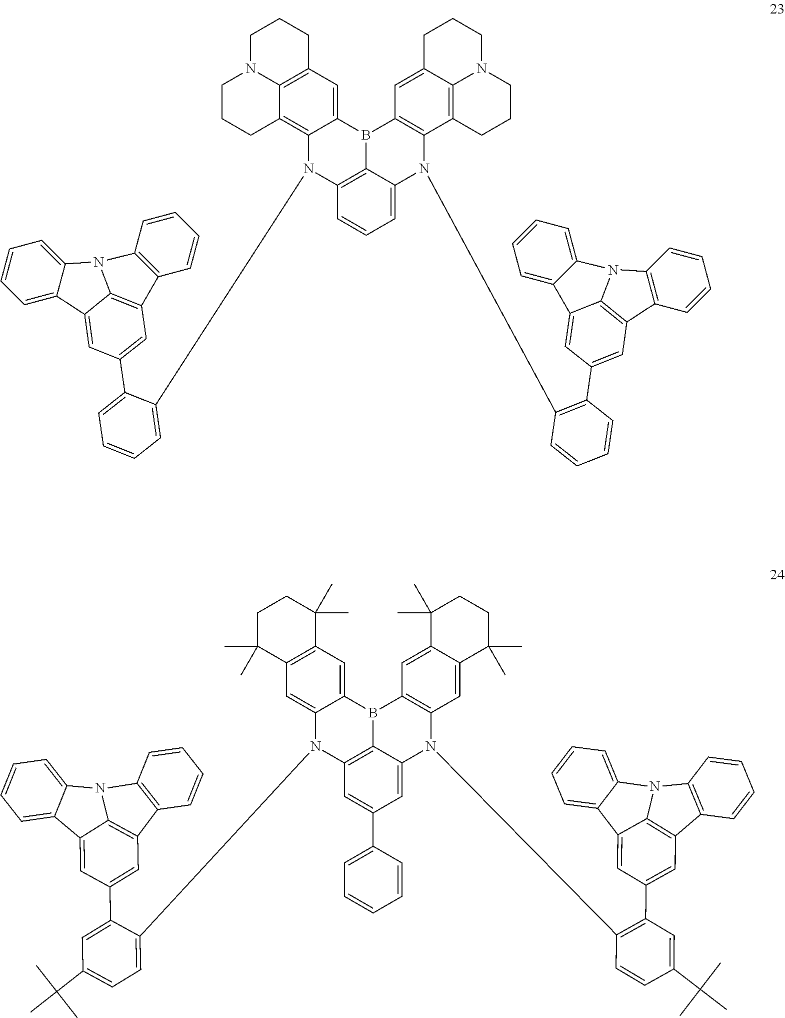 [SMILES: c1ccc(N2c3cccc4c3B(c3cc5c6c(c32)CCCN6CCC5)c2cc3c5c(c2N4c2ccccc2-c2cc4c6ccccc6n6c7ccccc7c(c2)c46)CCCN5CCC3)c(-c2cc3c4ccccc4n4c5ccccc5c(c2)c34)c1 ; CC(C)(C)c1ccc(N2c3cc4c(cc3B3c5cc6c(cc5N(c5ccc(C(C)(C)C)cc5-c5cc7c8ccccc8n8c9ccccc9c(c5)c78)c5cc(-c7ccccc7)cc2c53)C(C)(C)CCC6(C)C)C(C)(C)CCC4(C)C)c(-c2cc3c4ccccc4n4c5ccccc5c(c2)c34)c1] 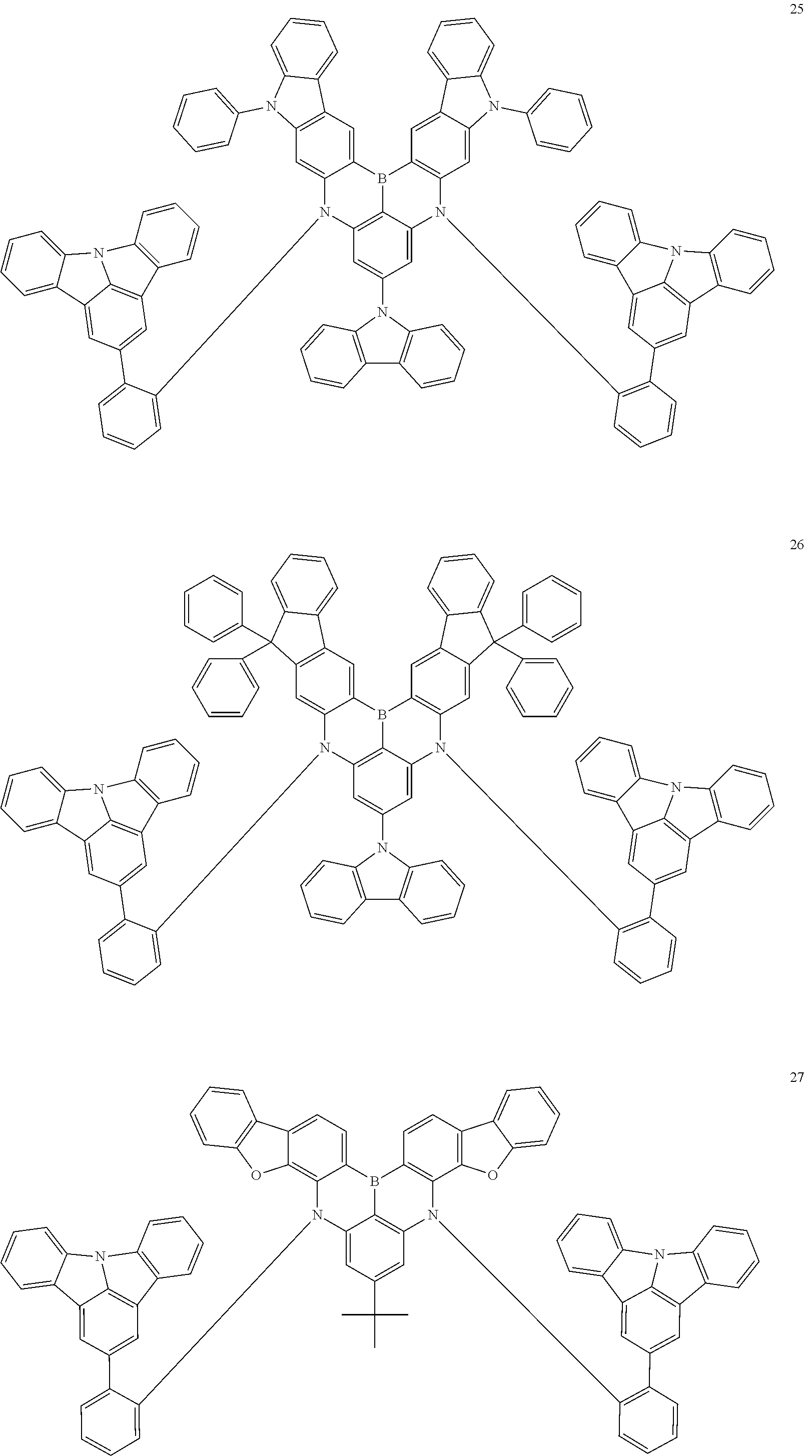 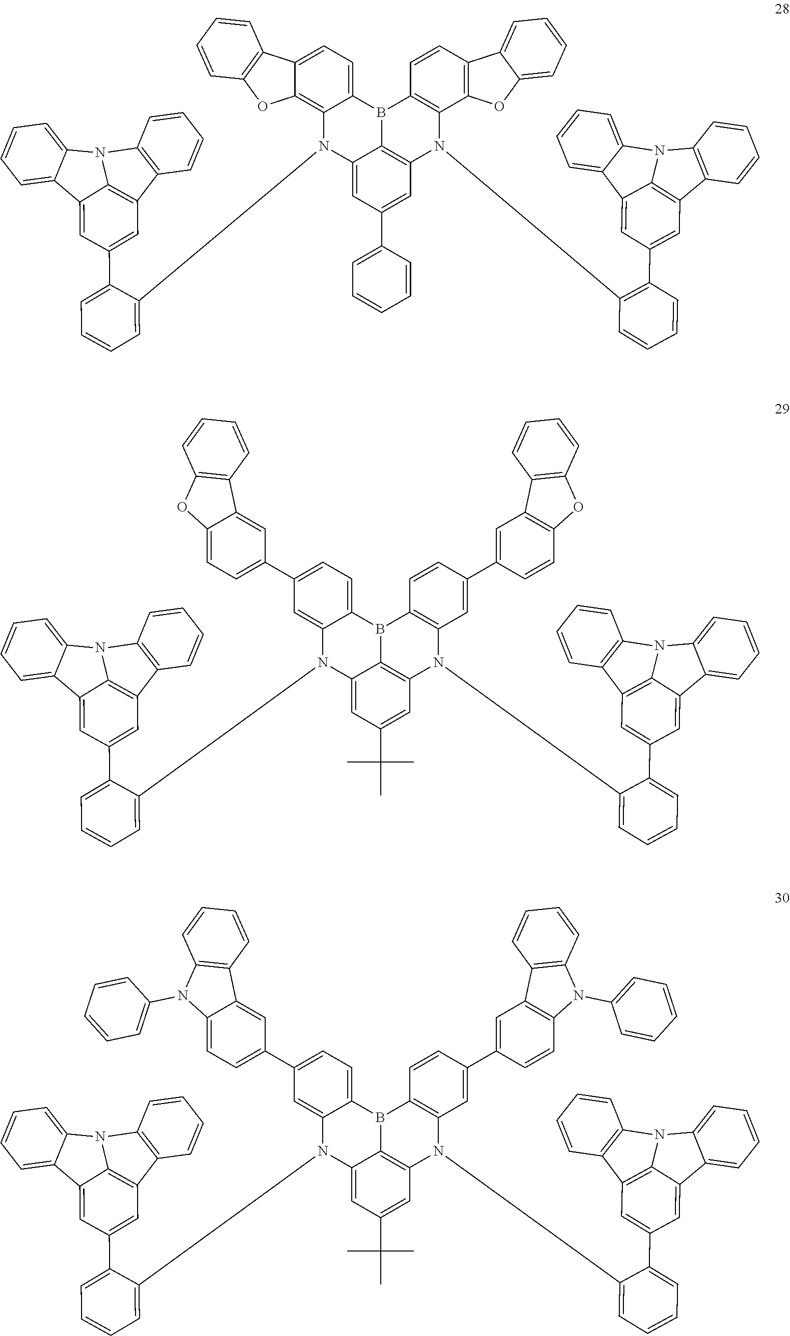 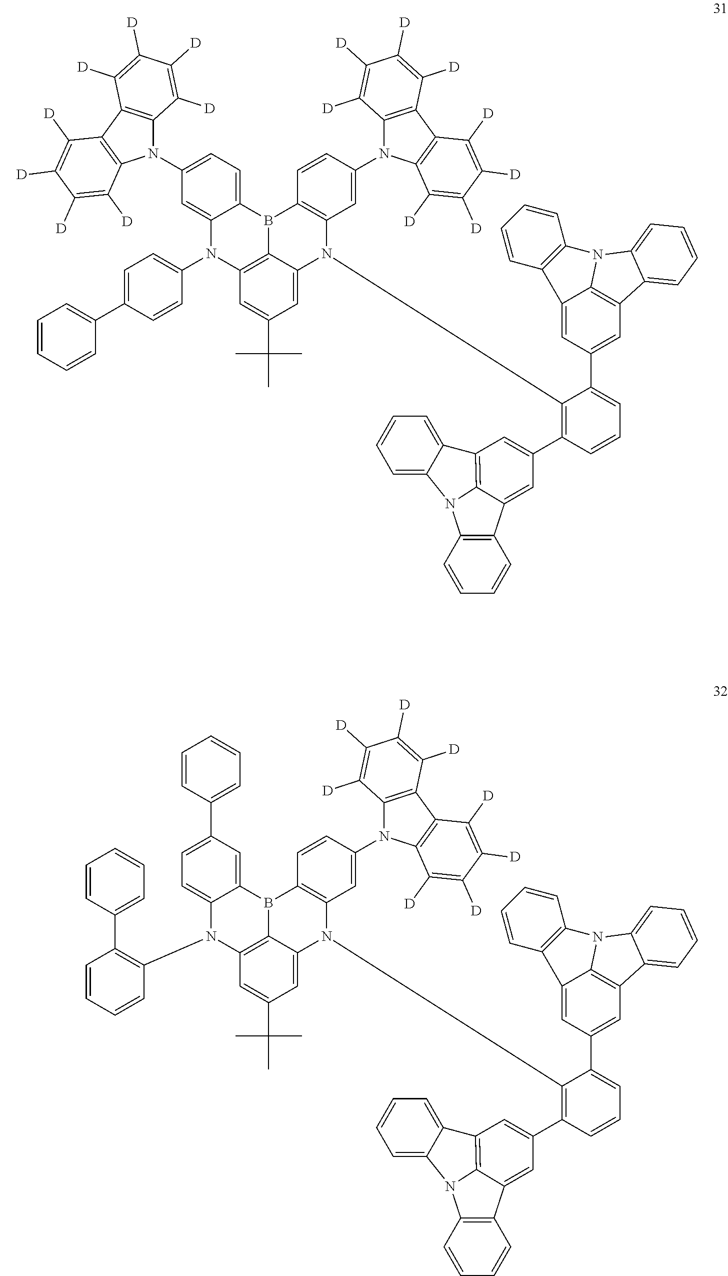 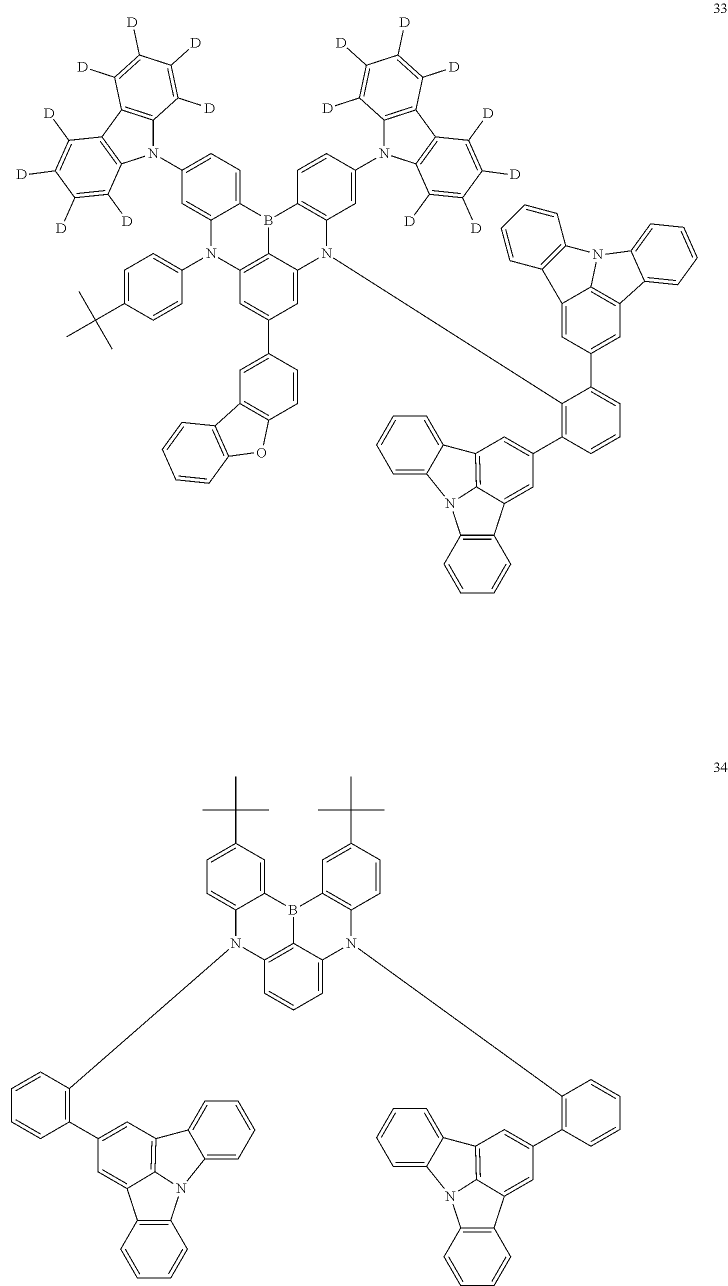 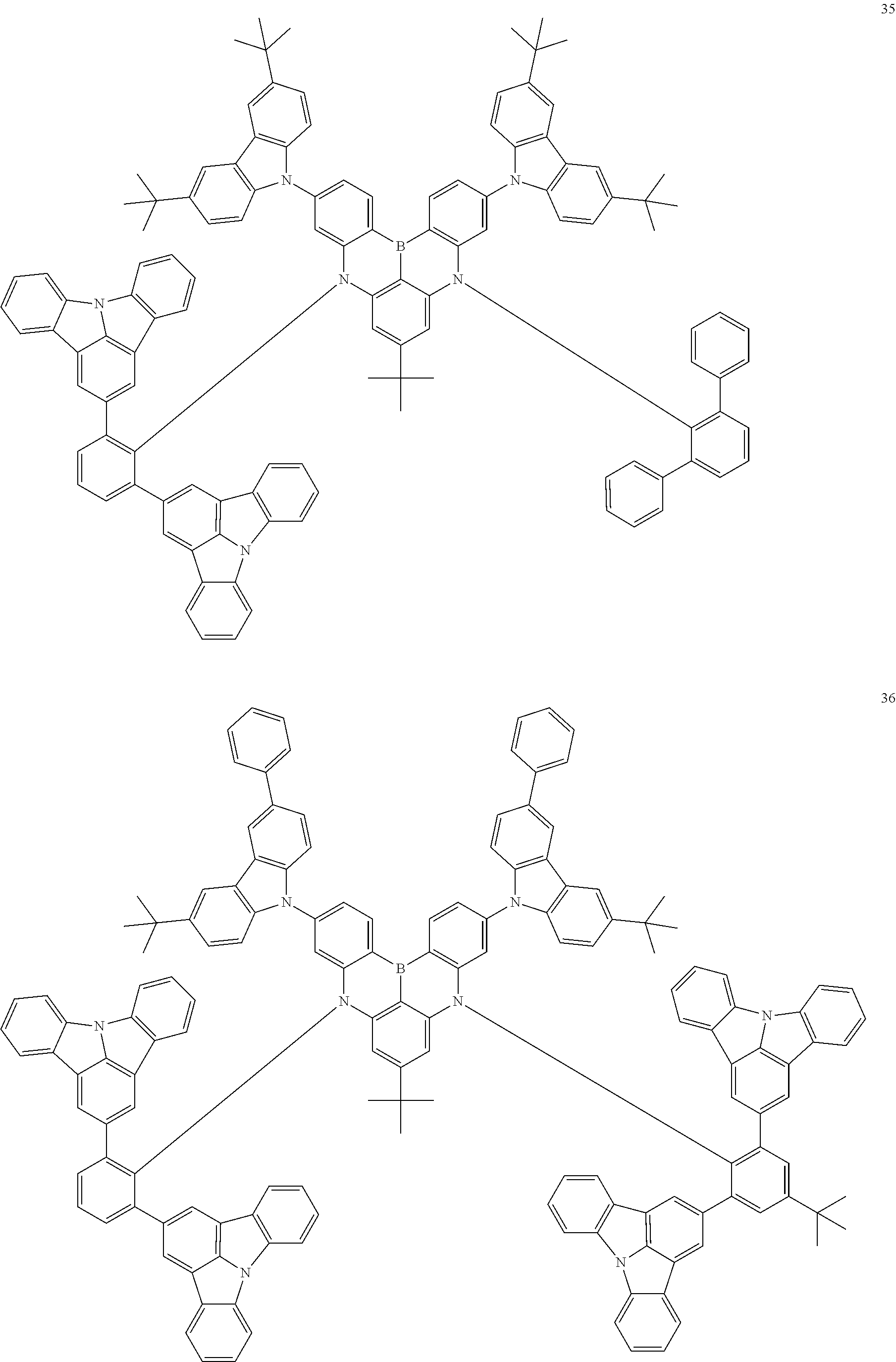 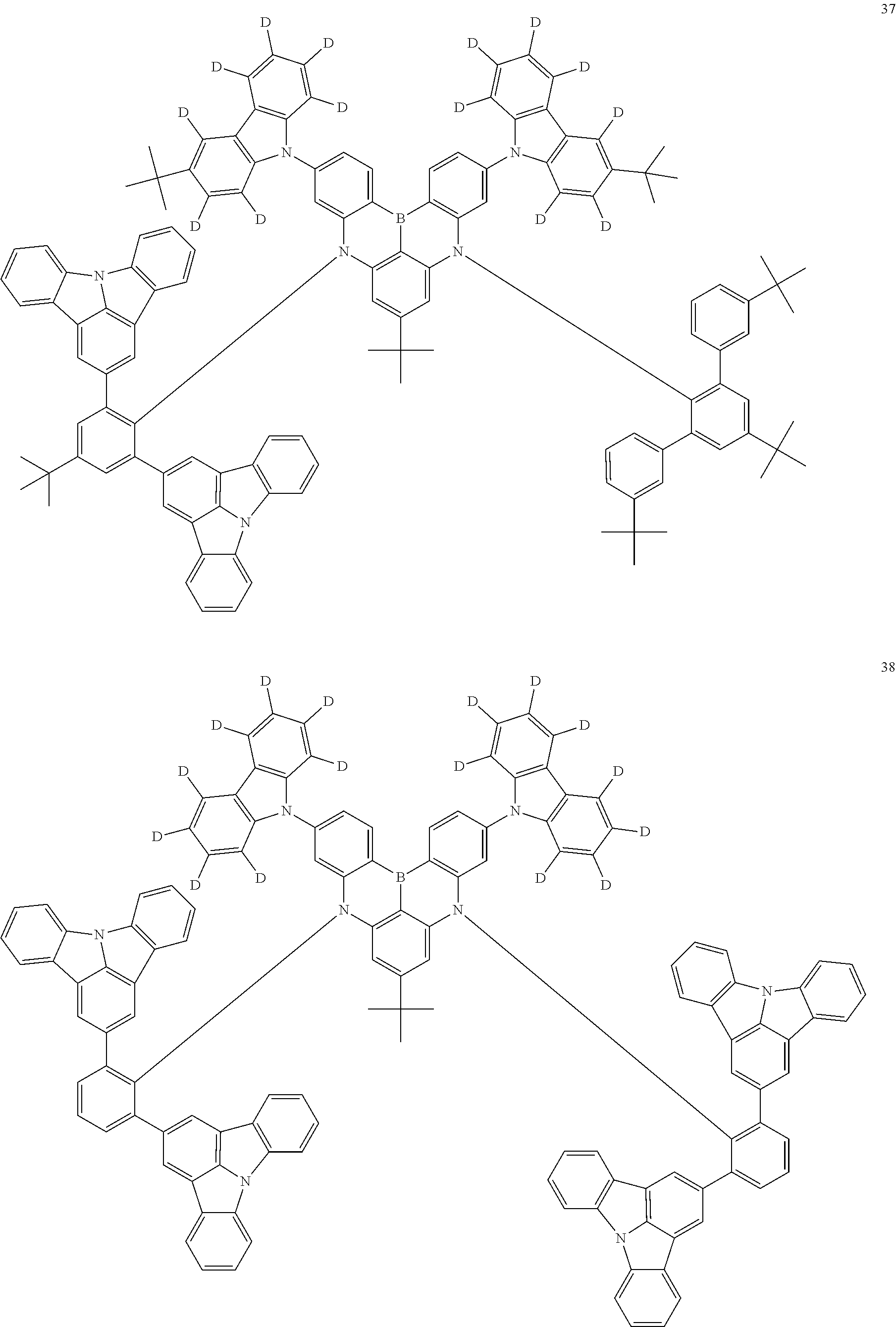 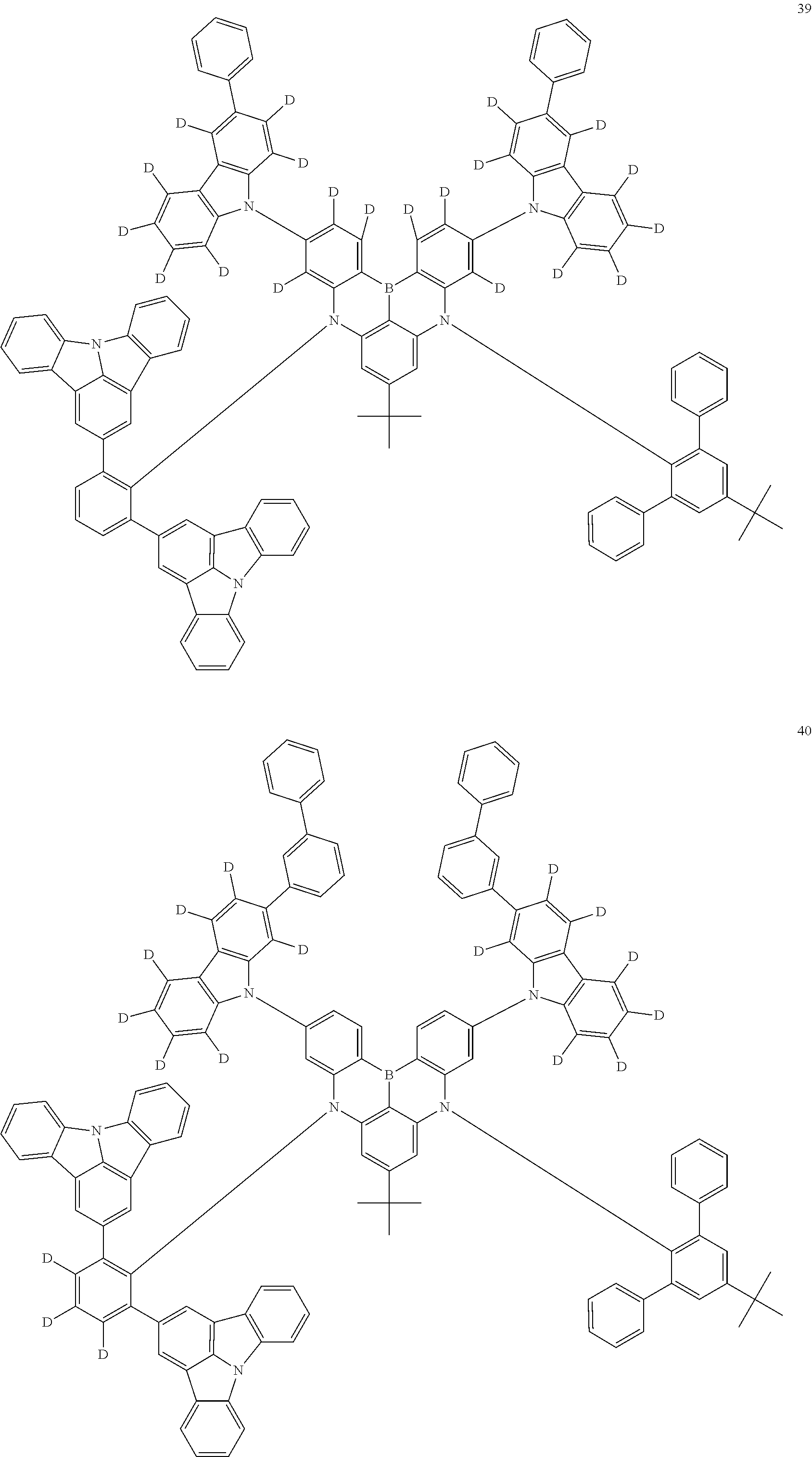 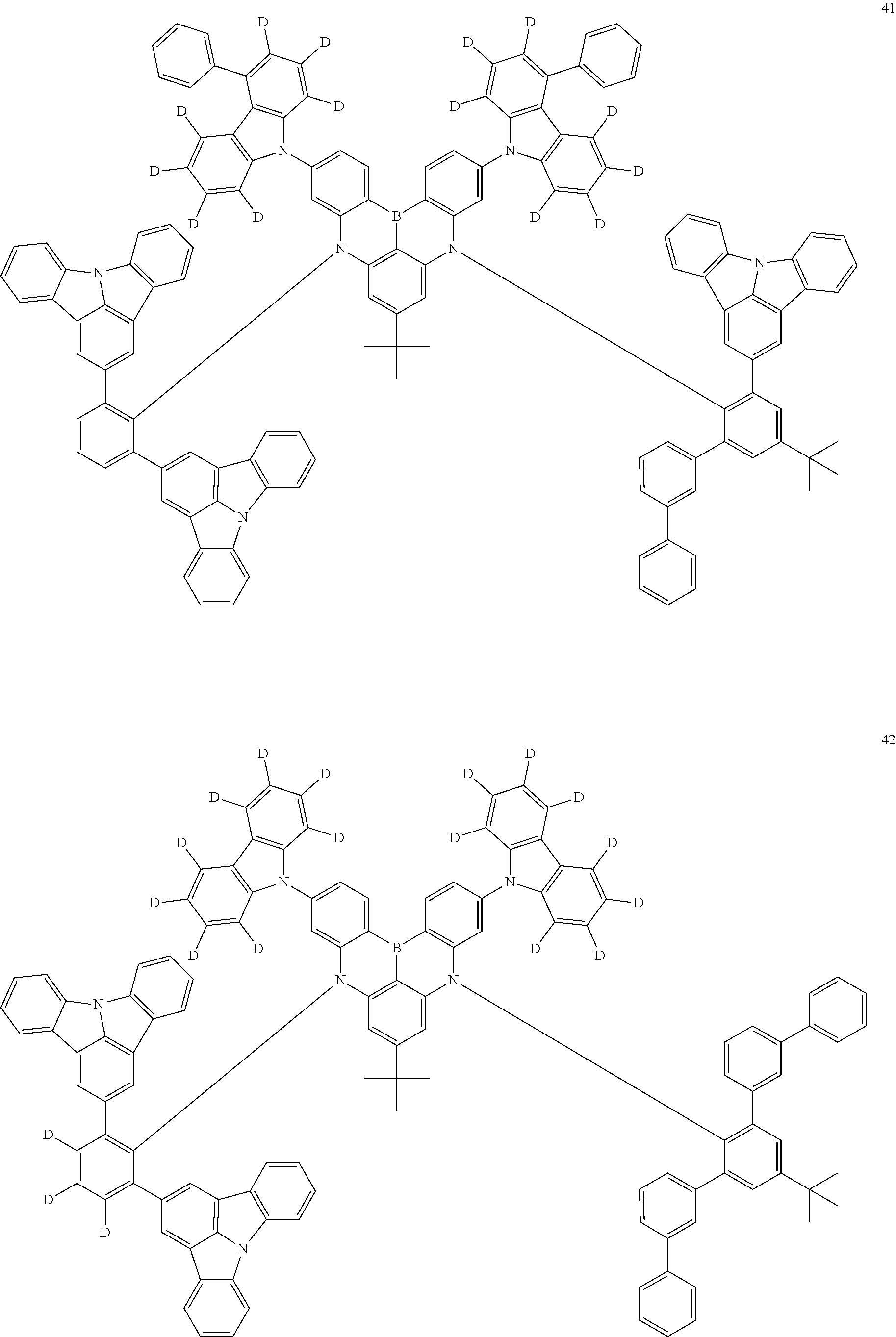 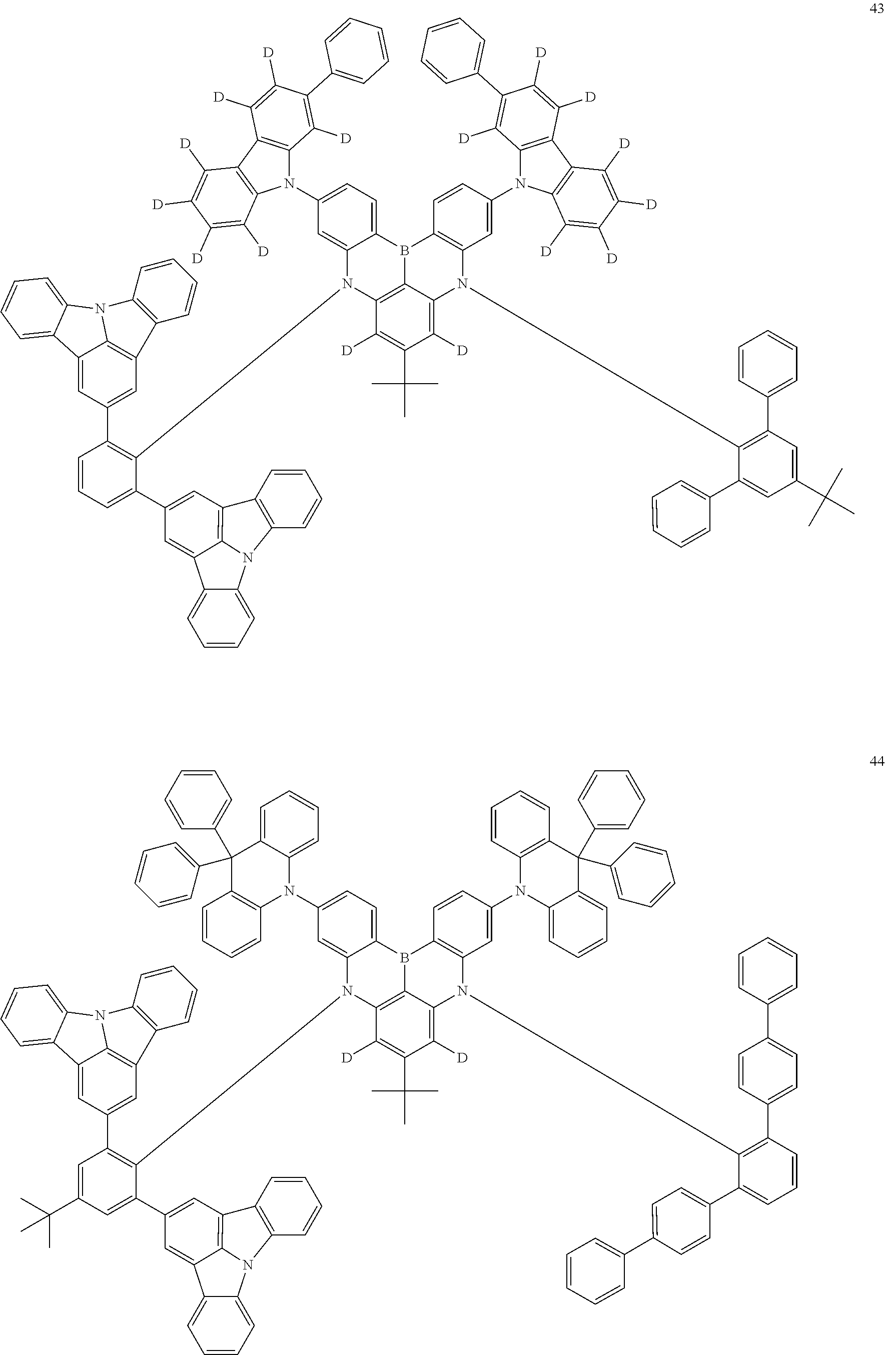 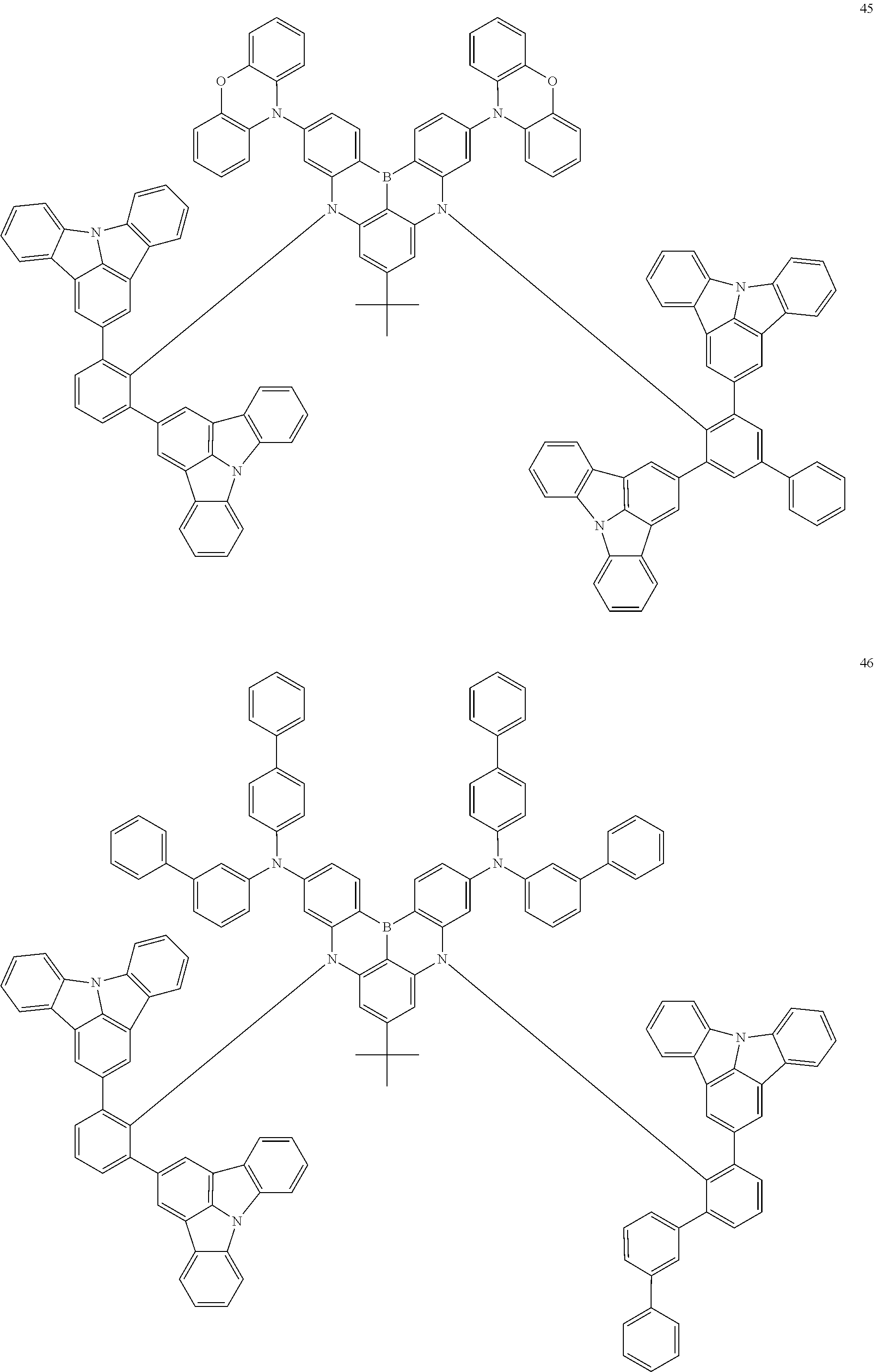 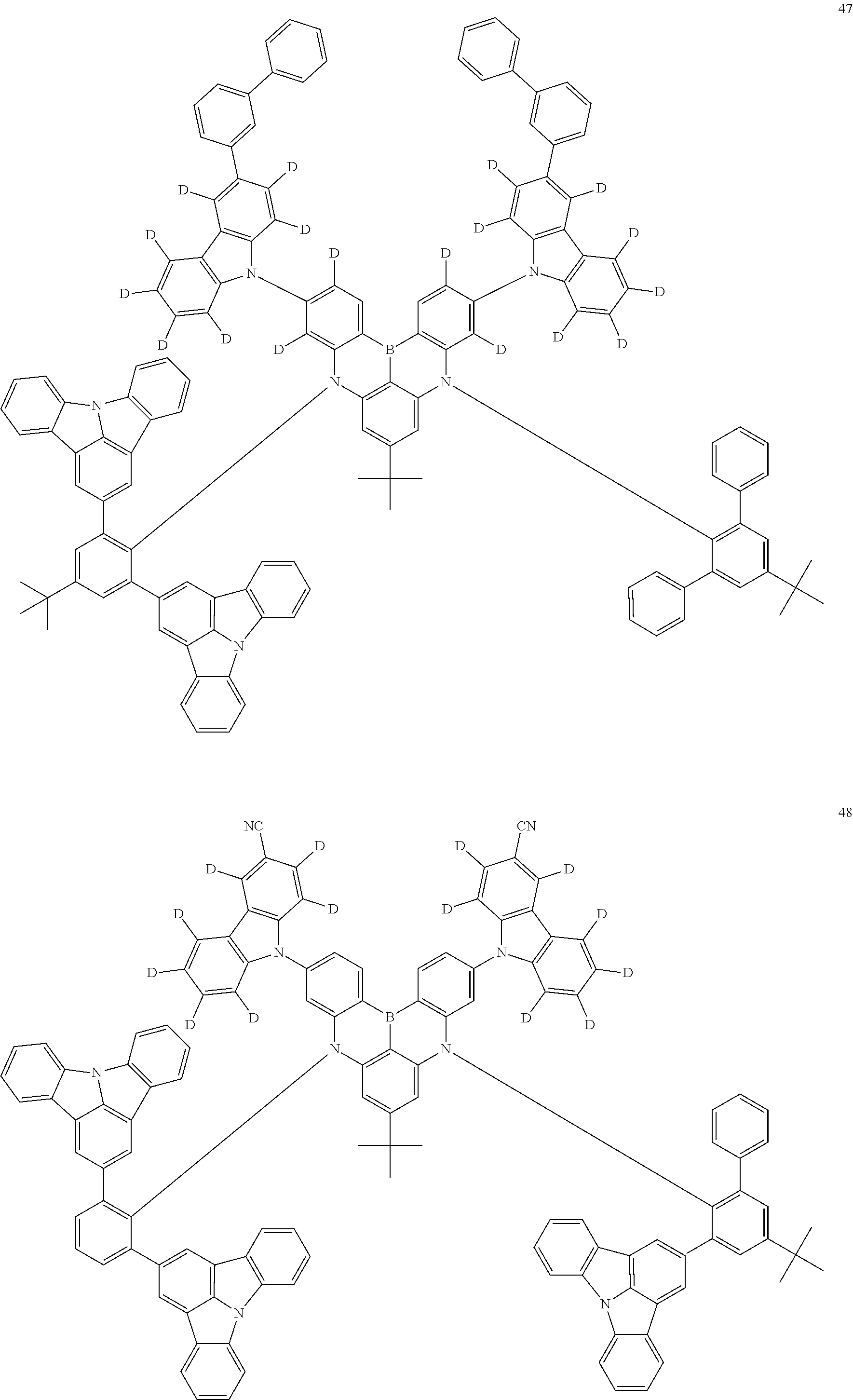 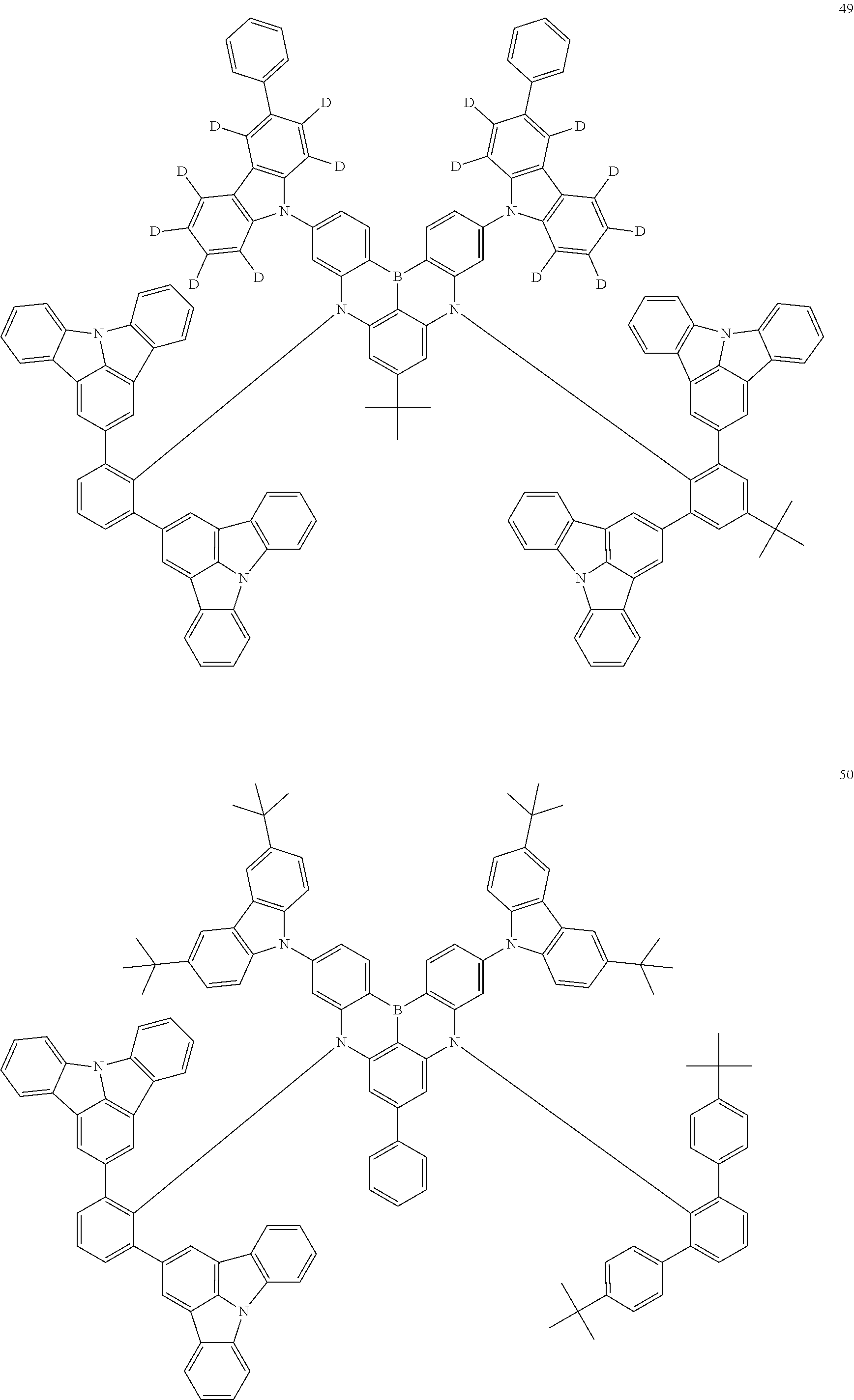 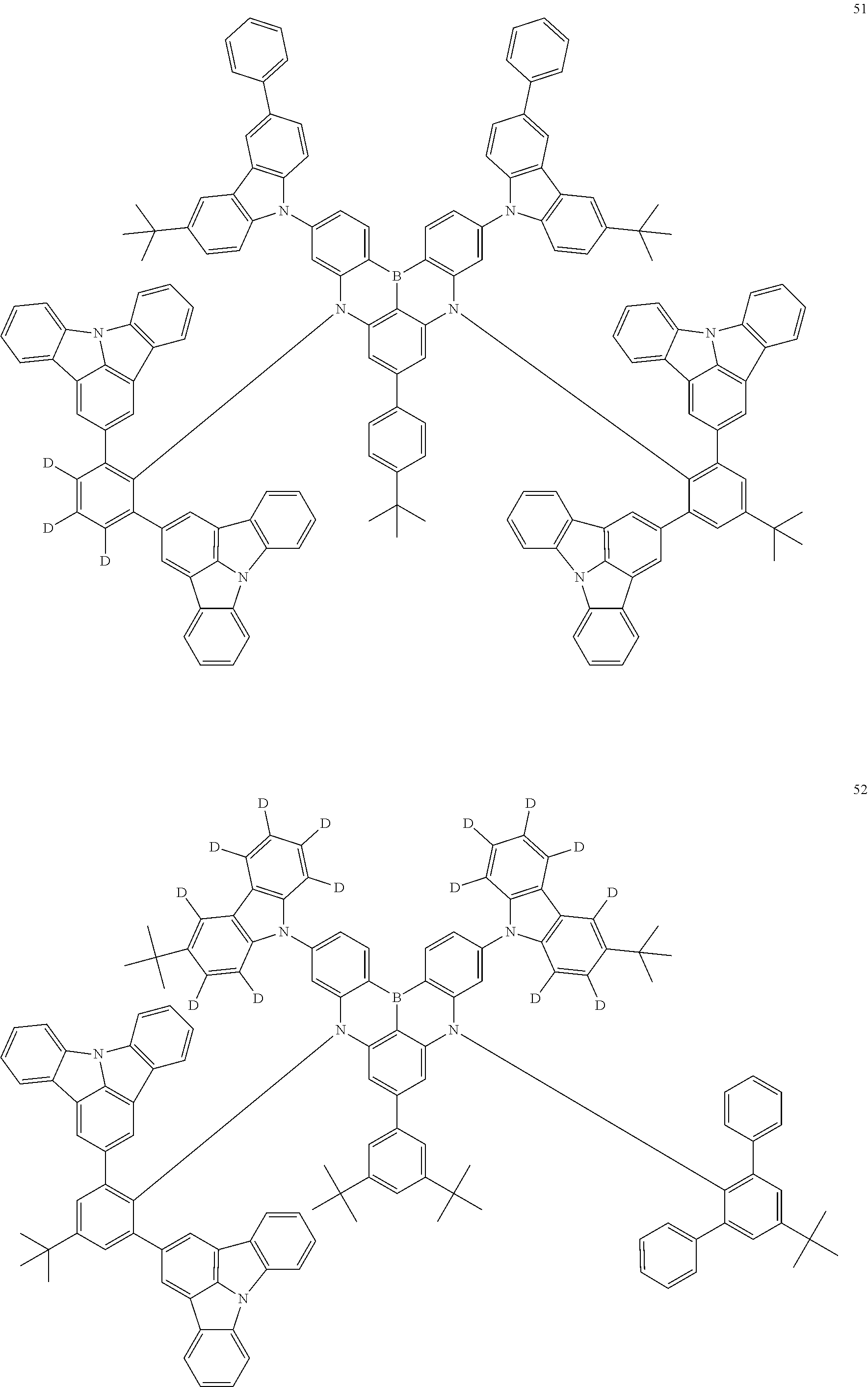 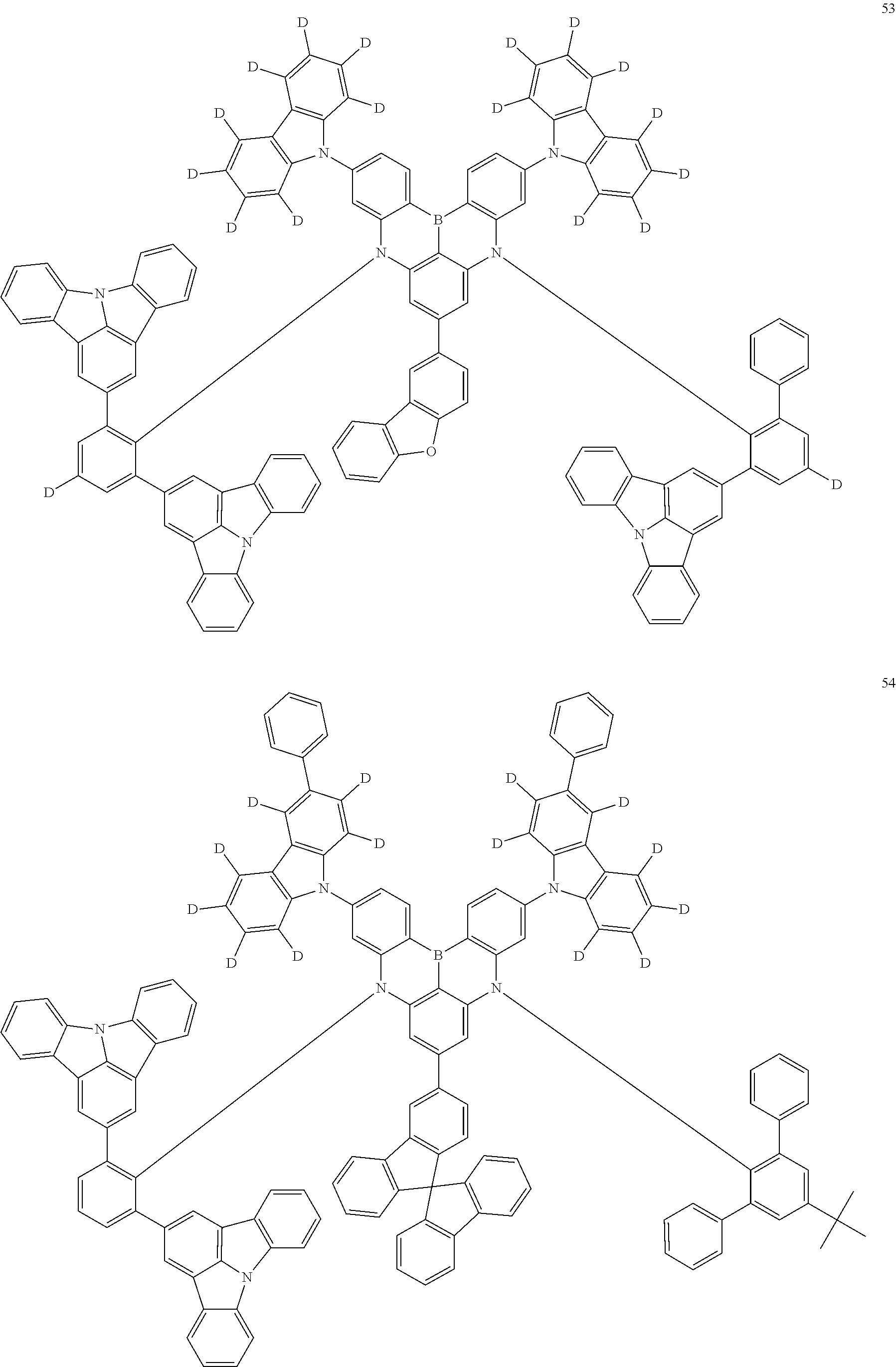 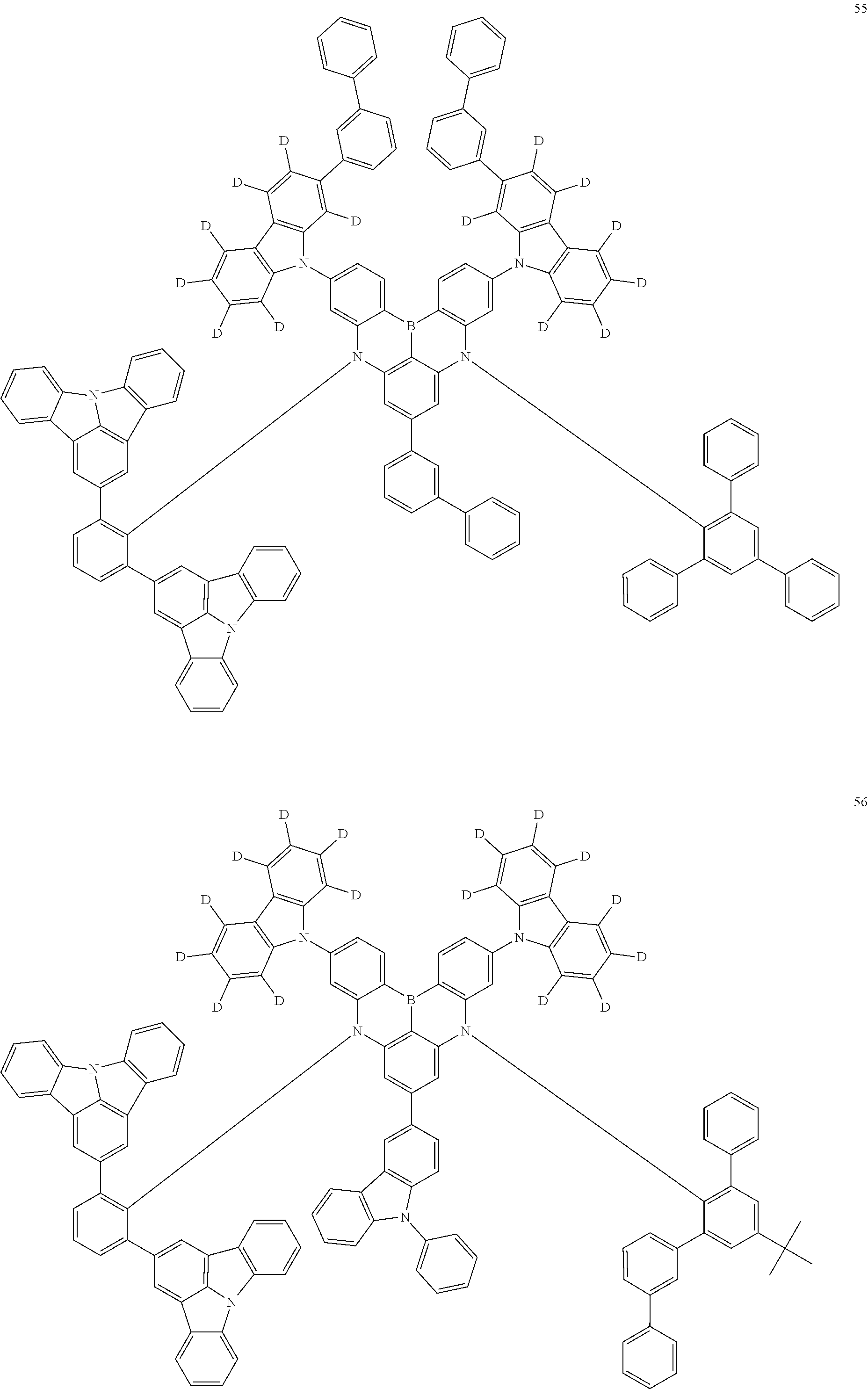 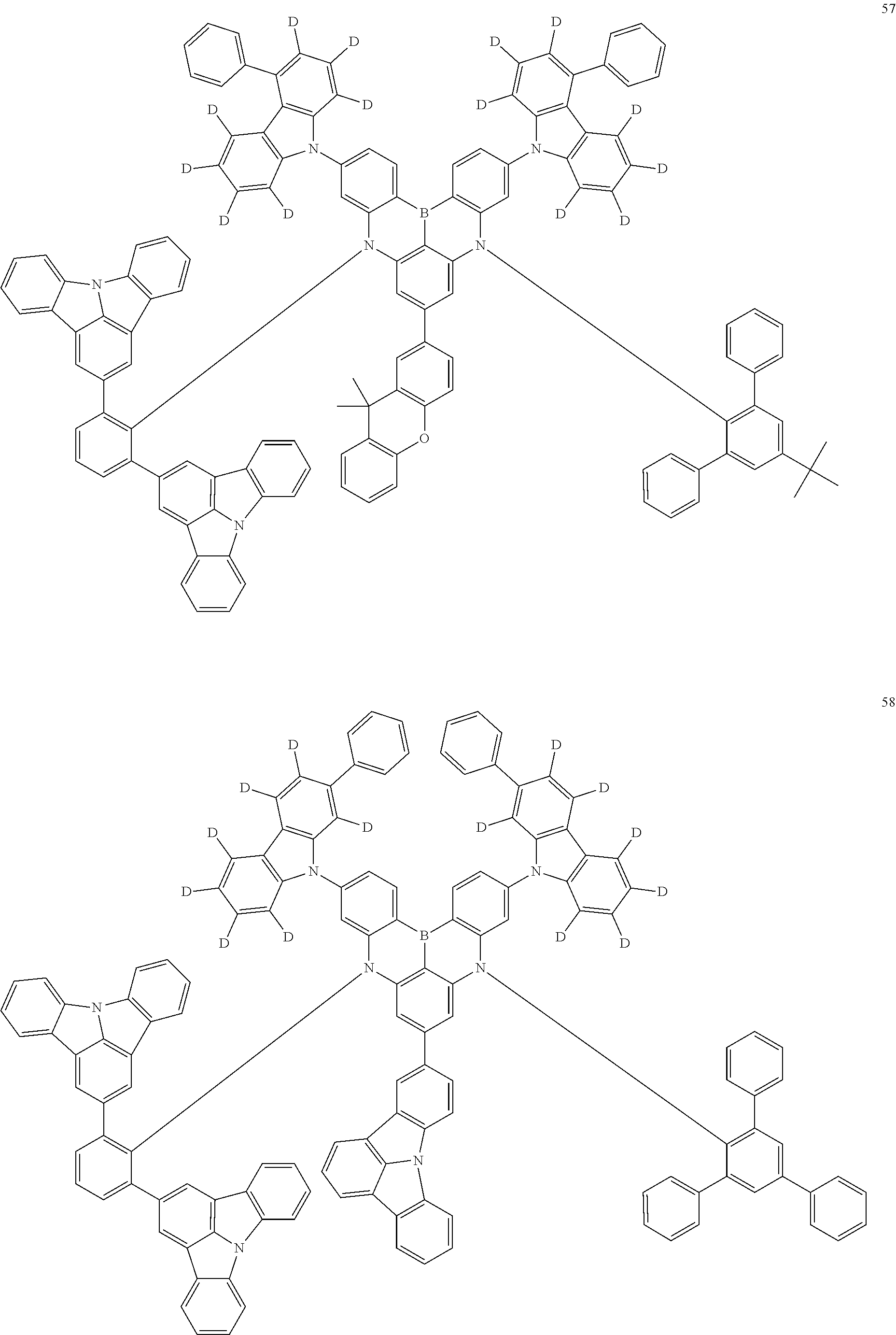 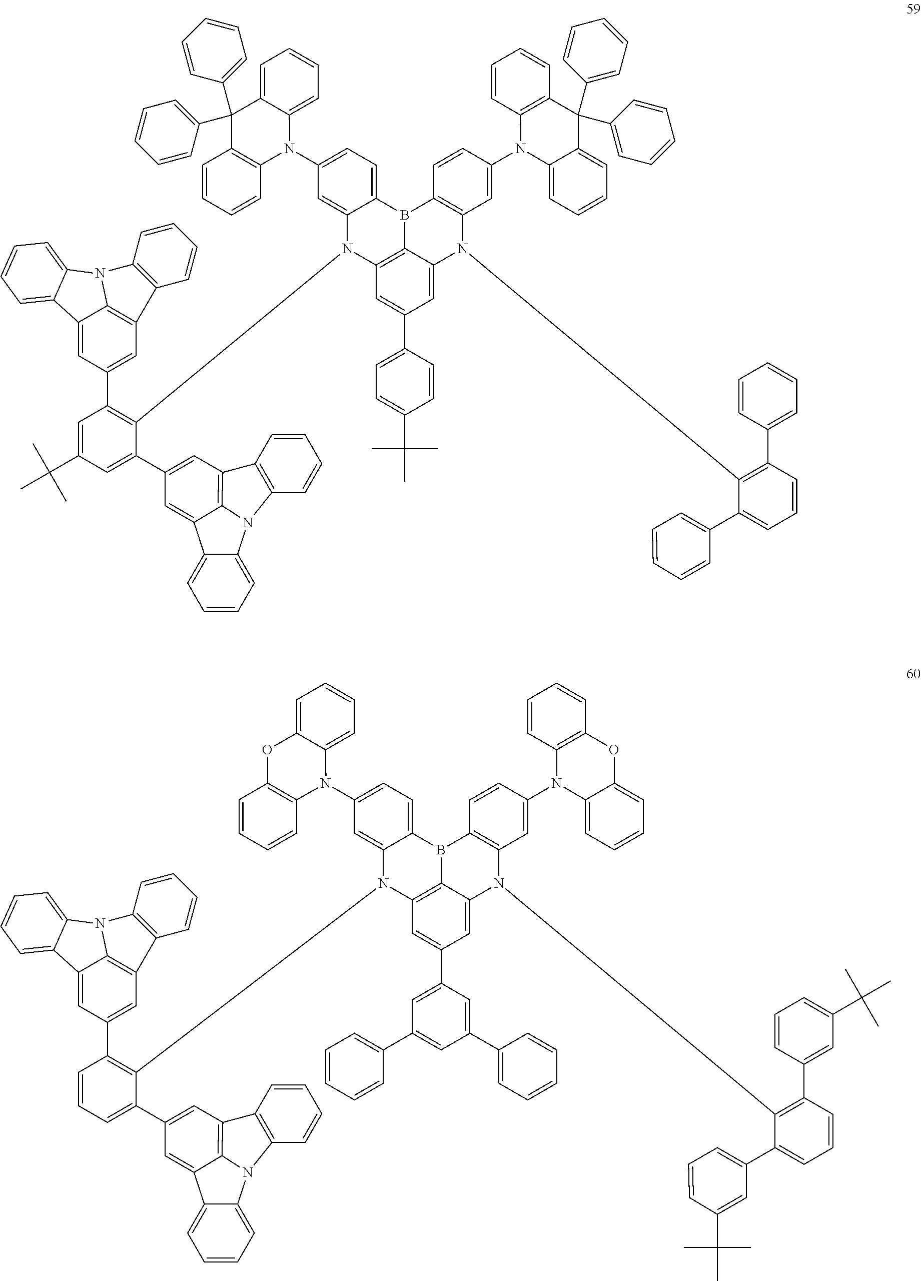 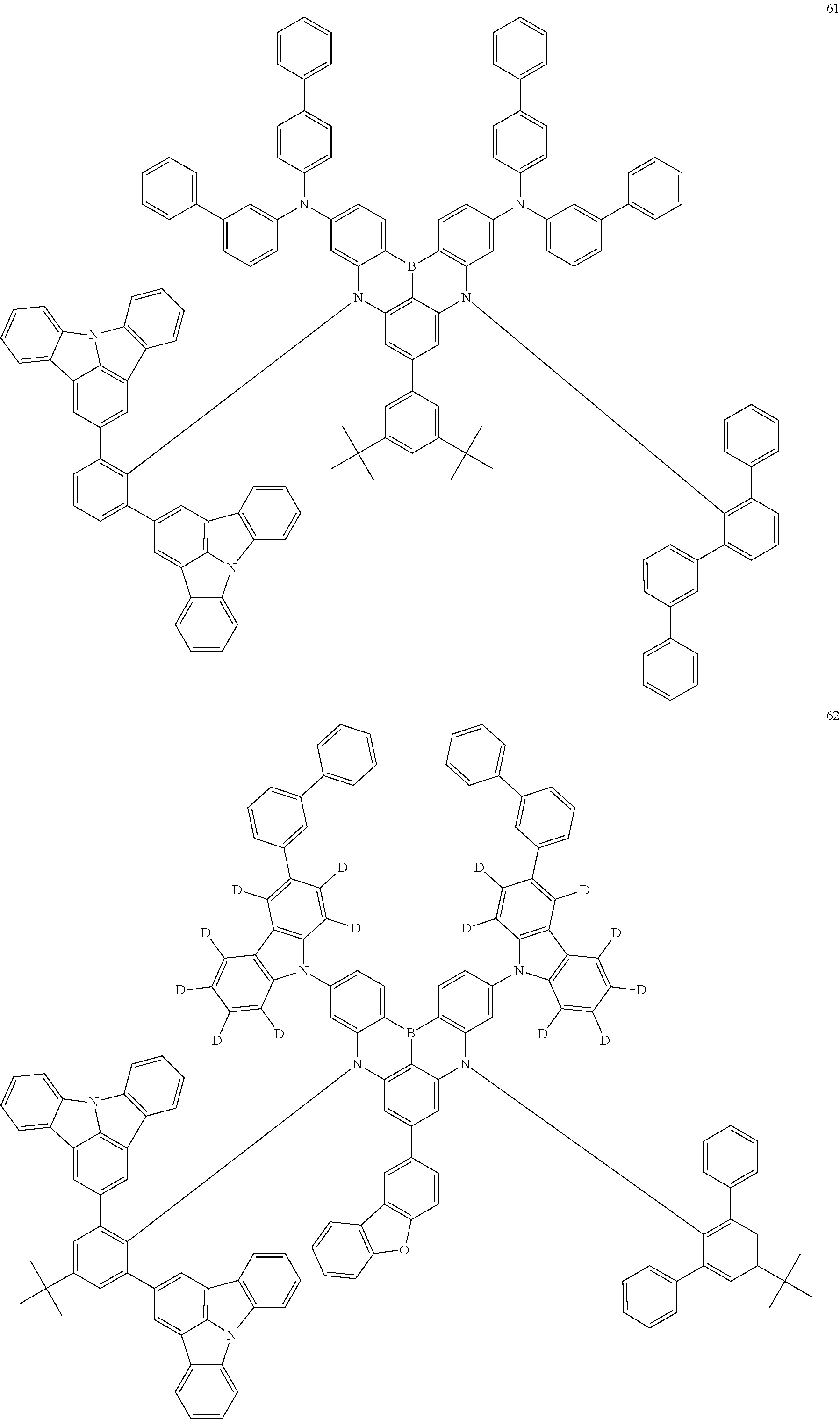 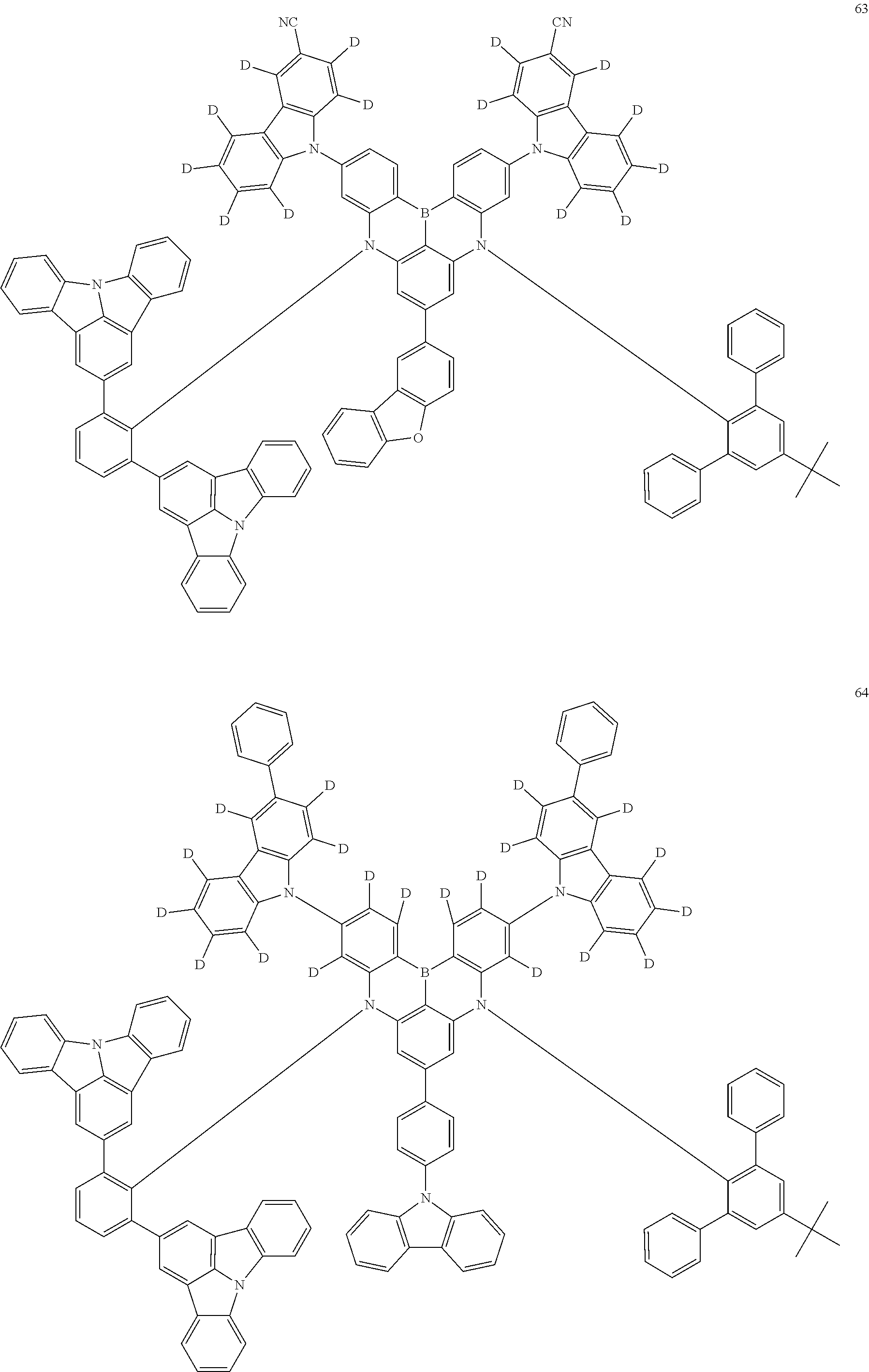 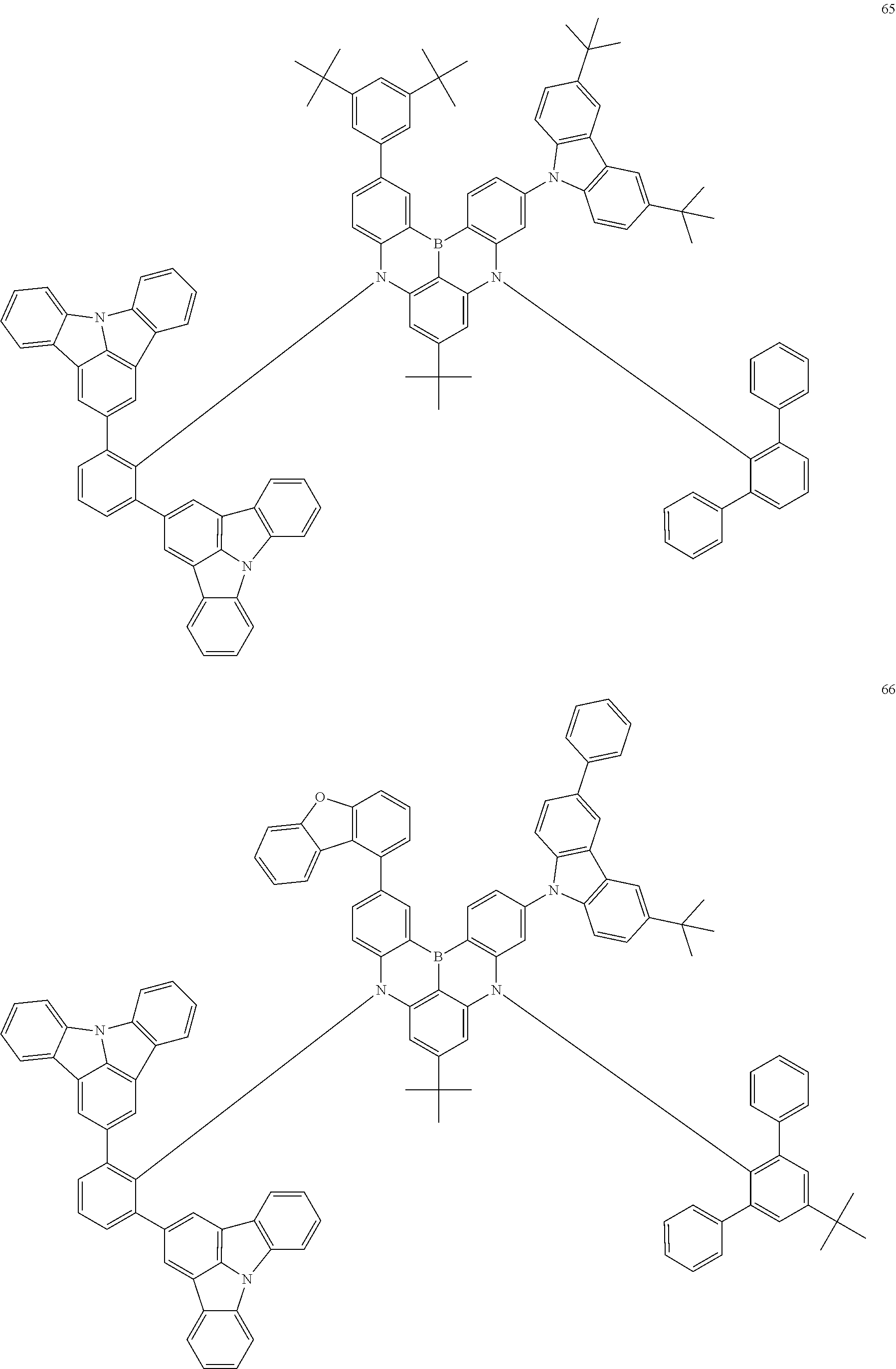 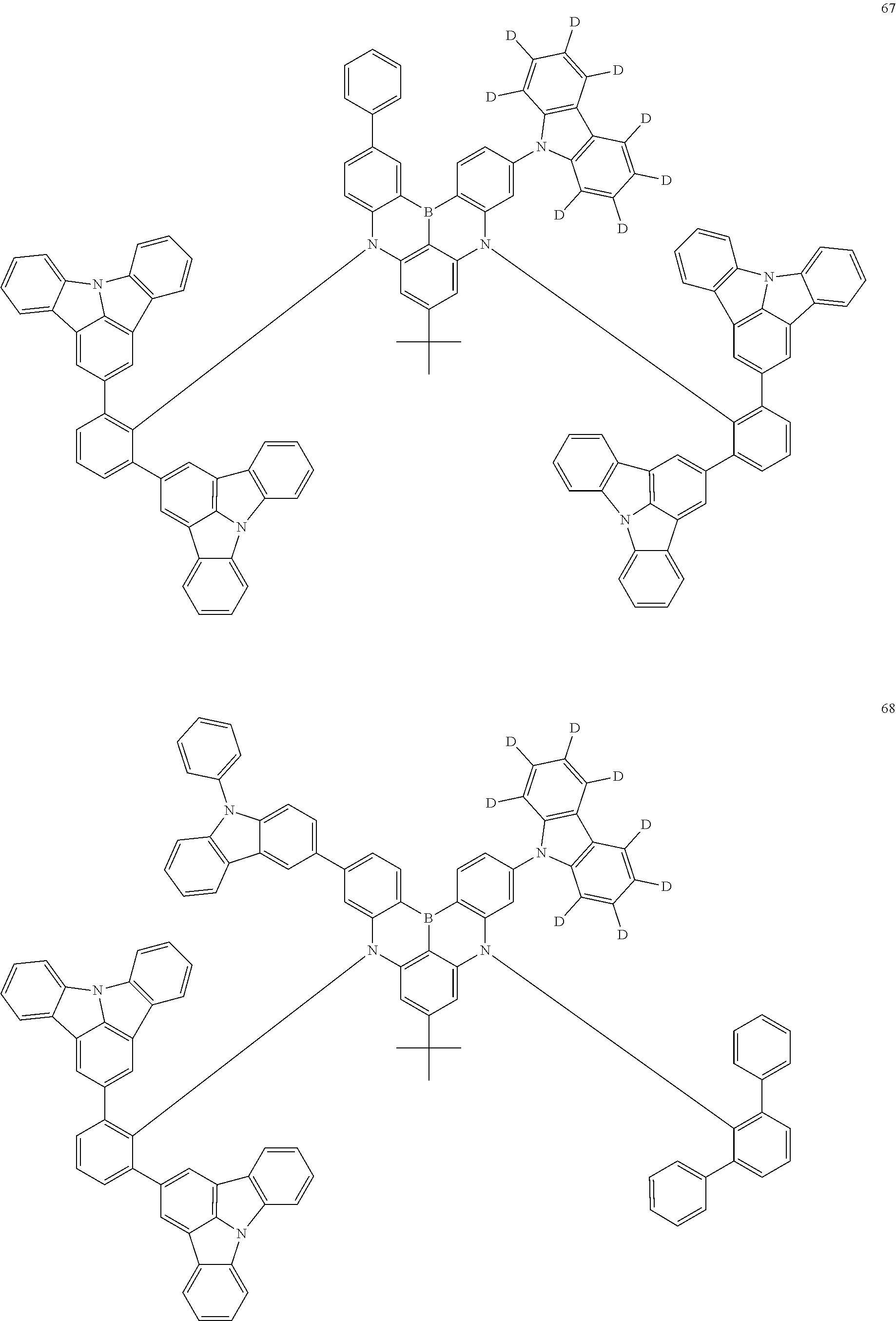 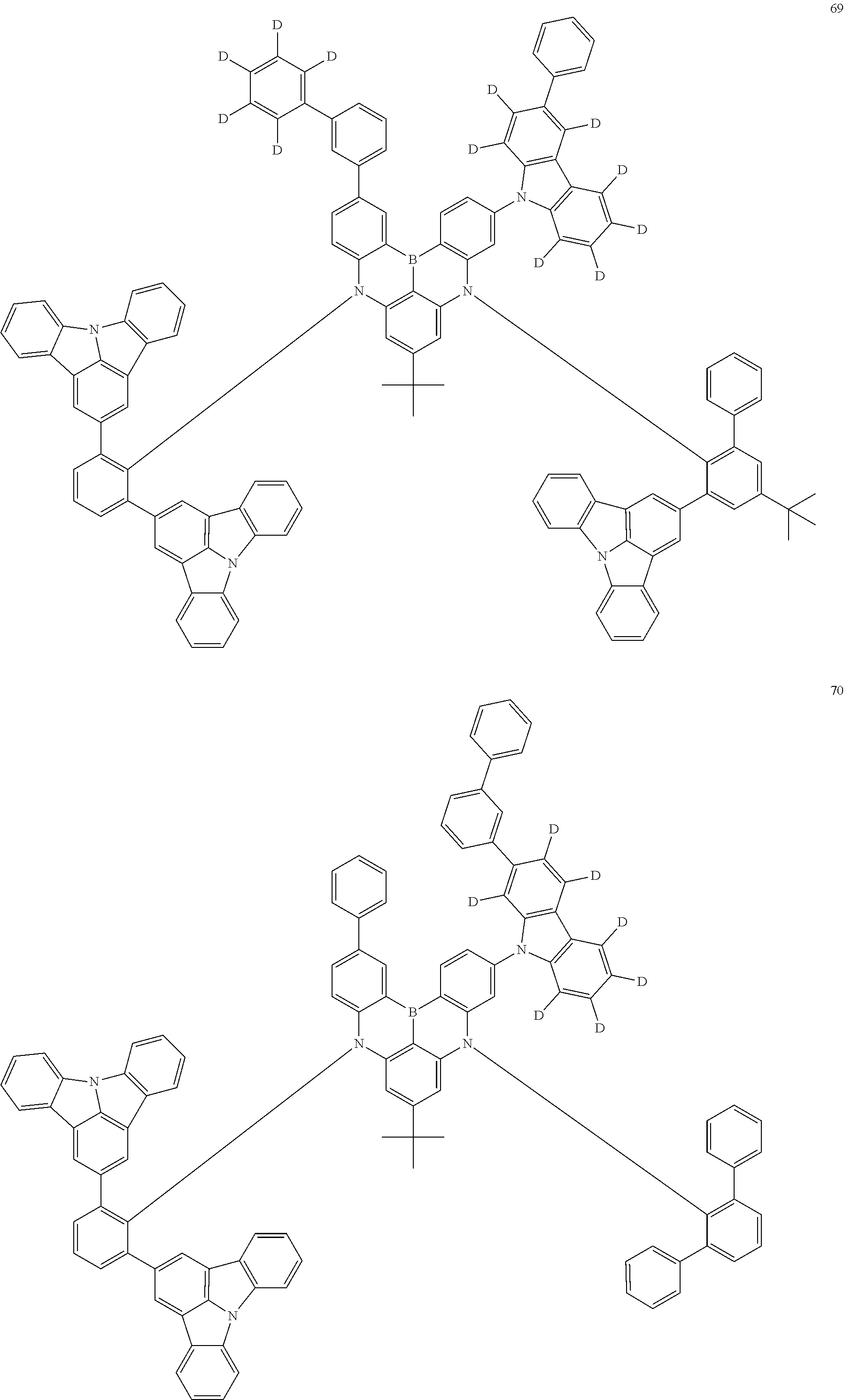 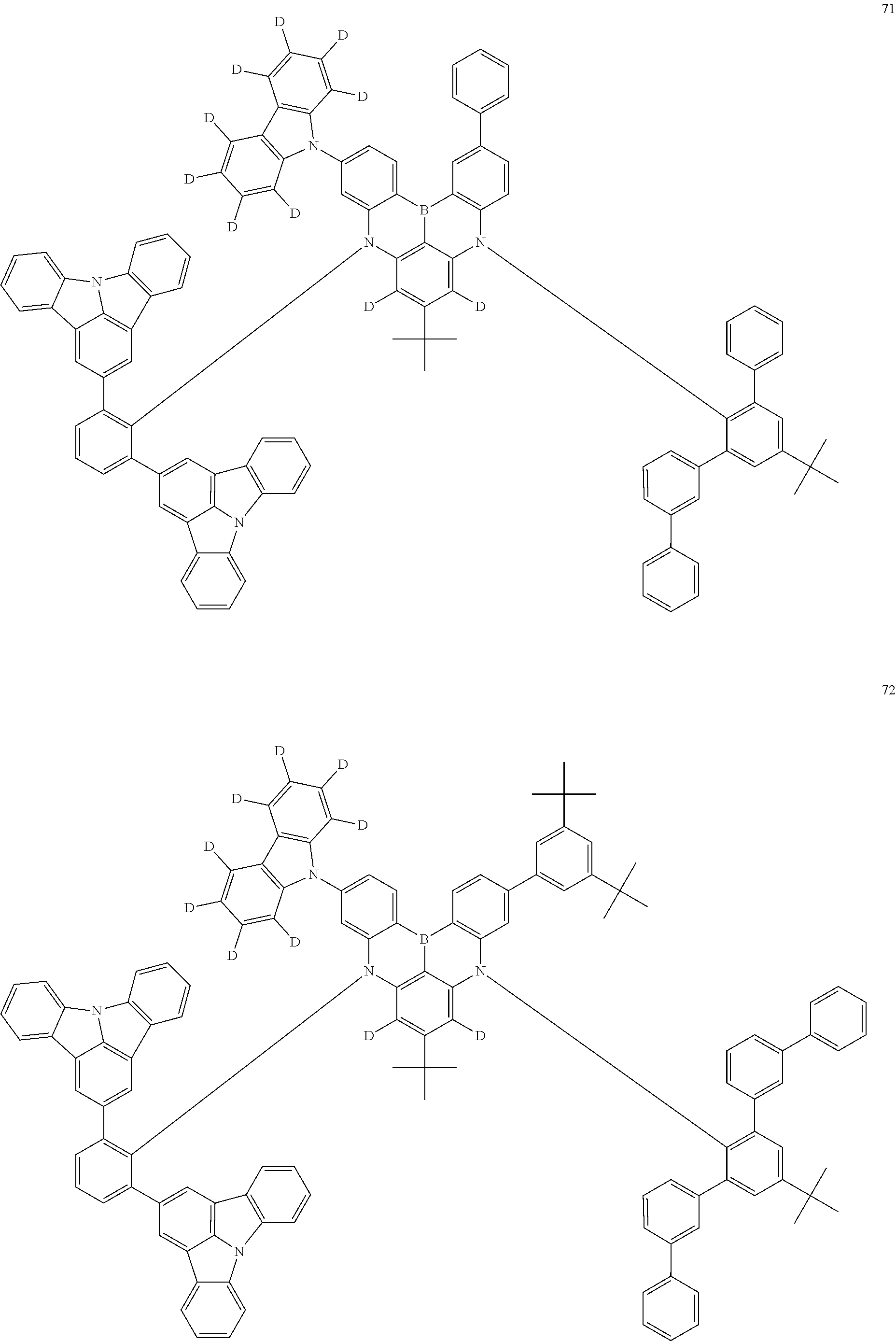 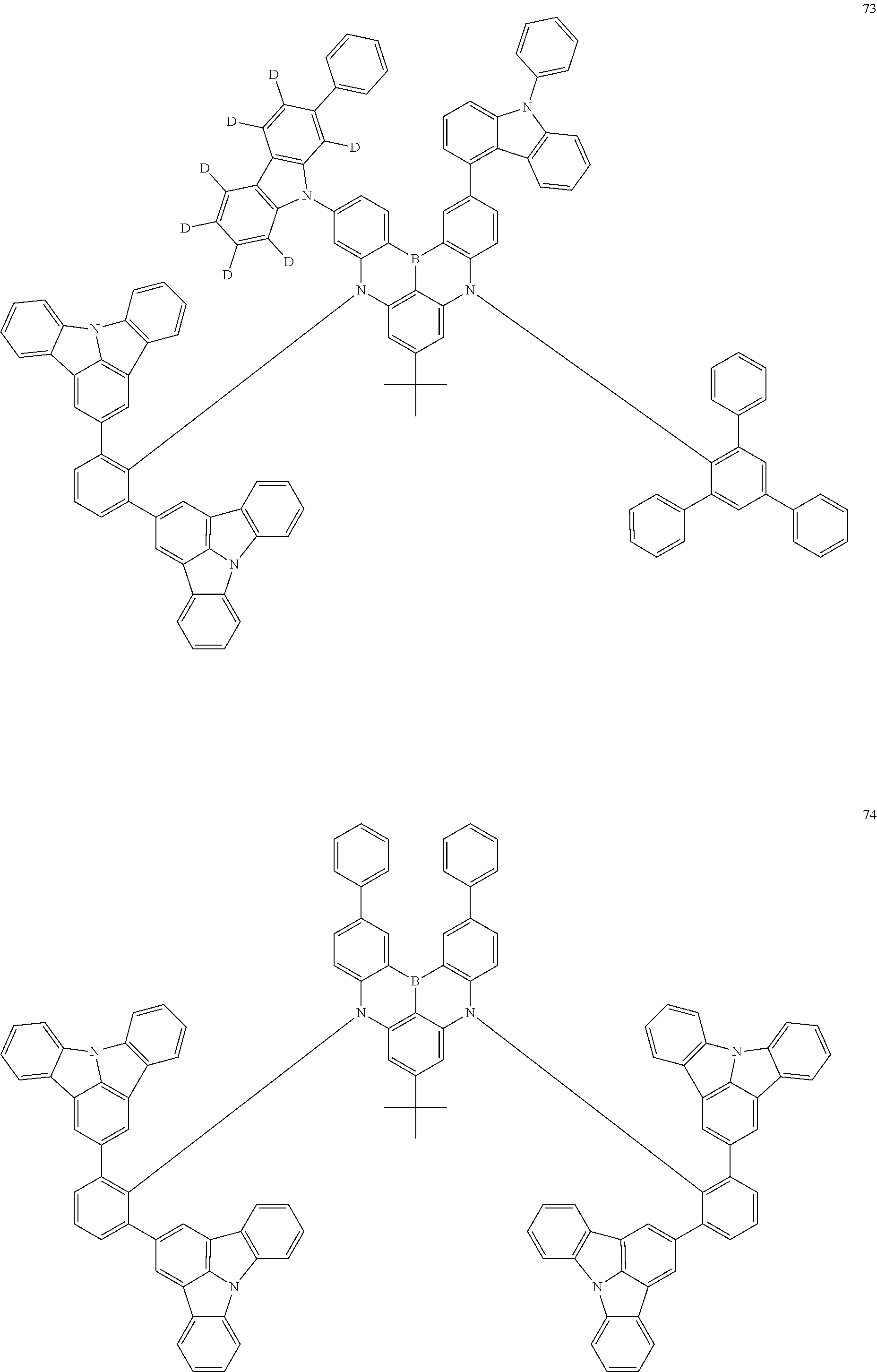 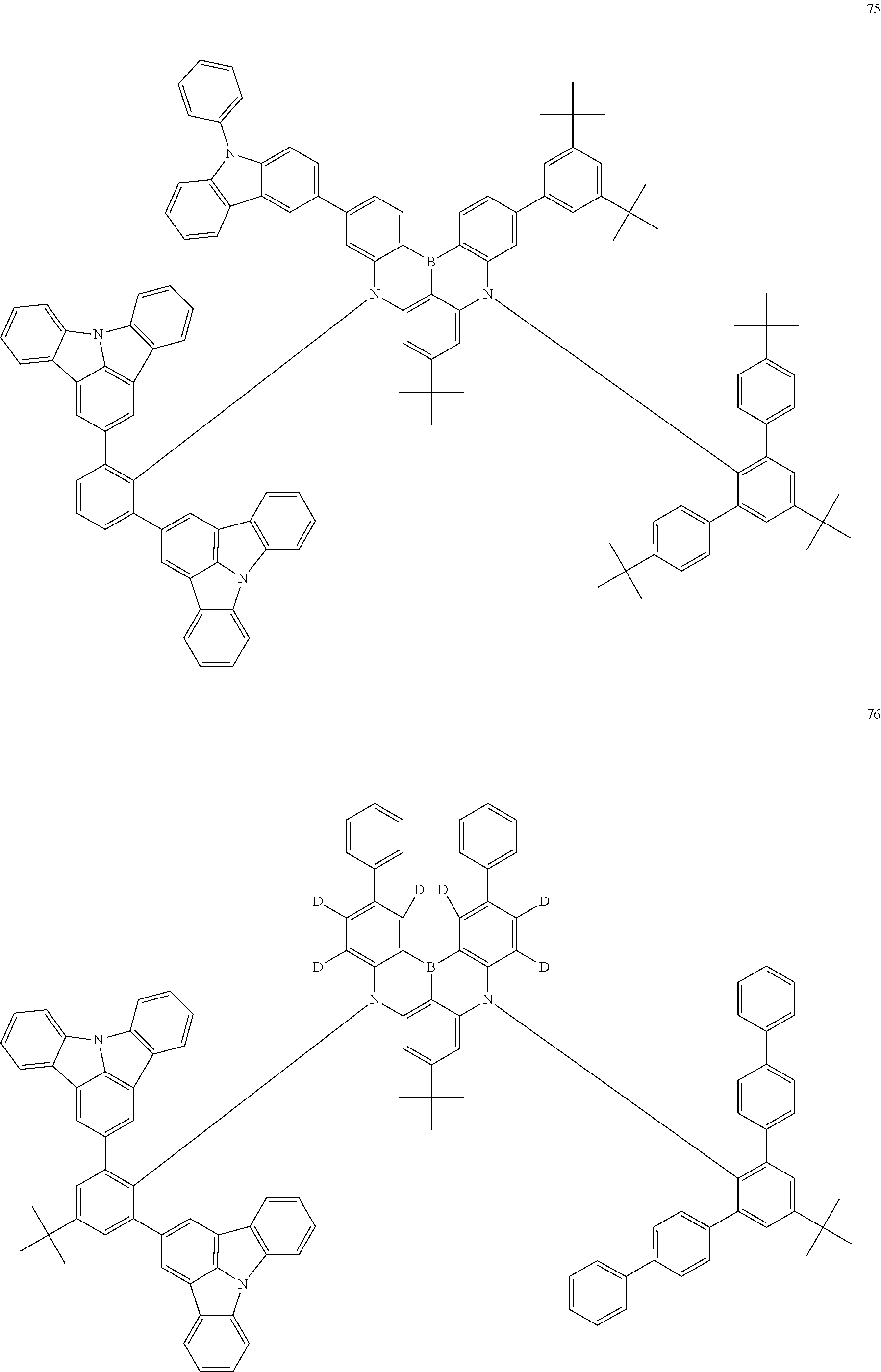 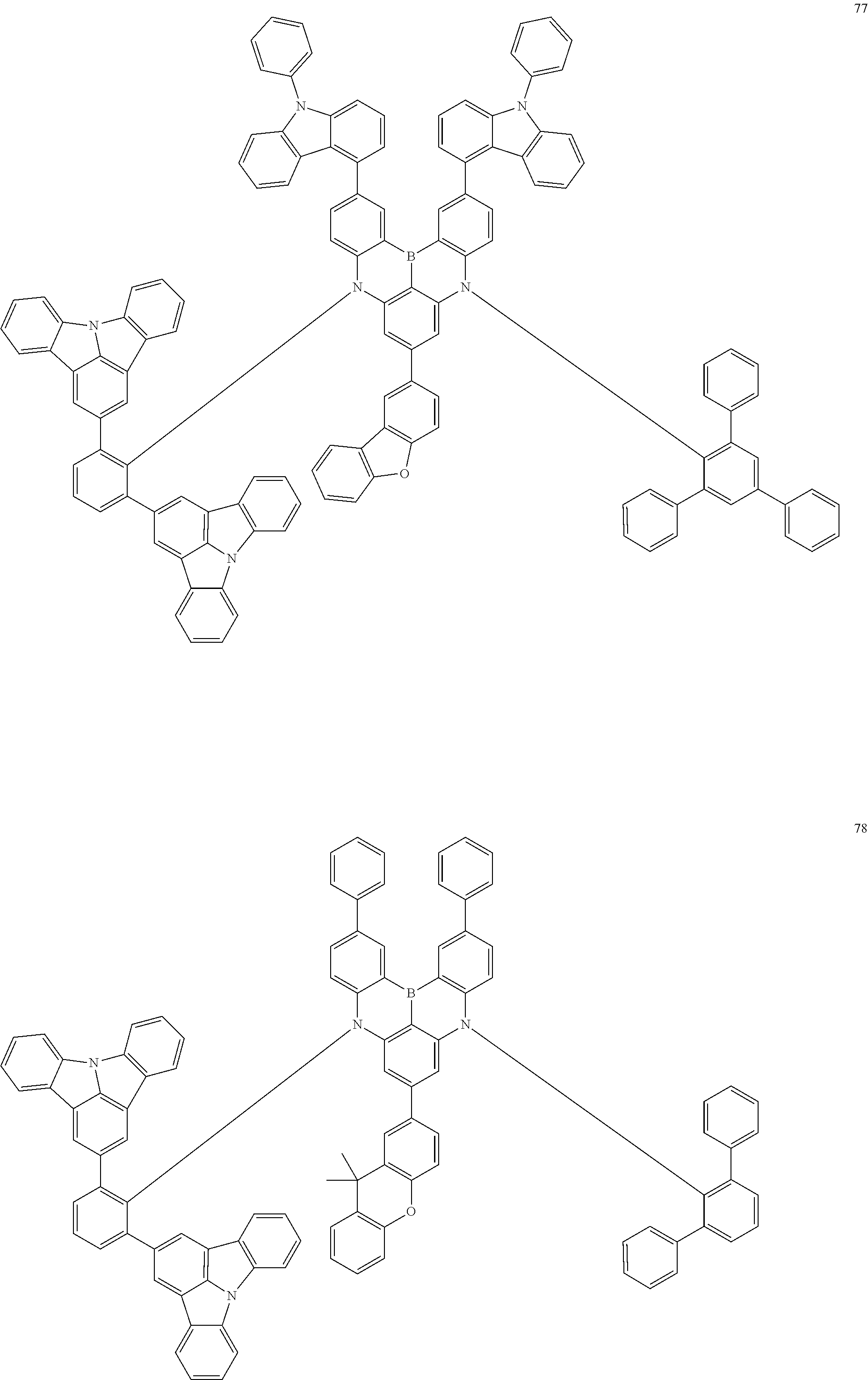 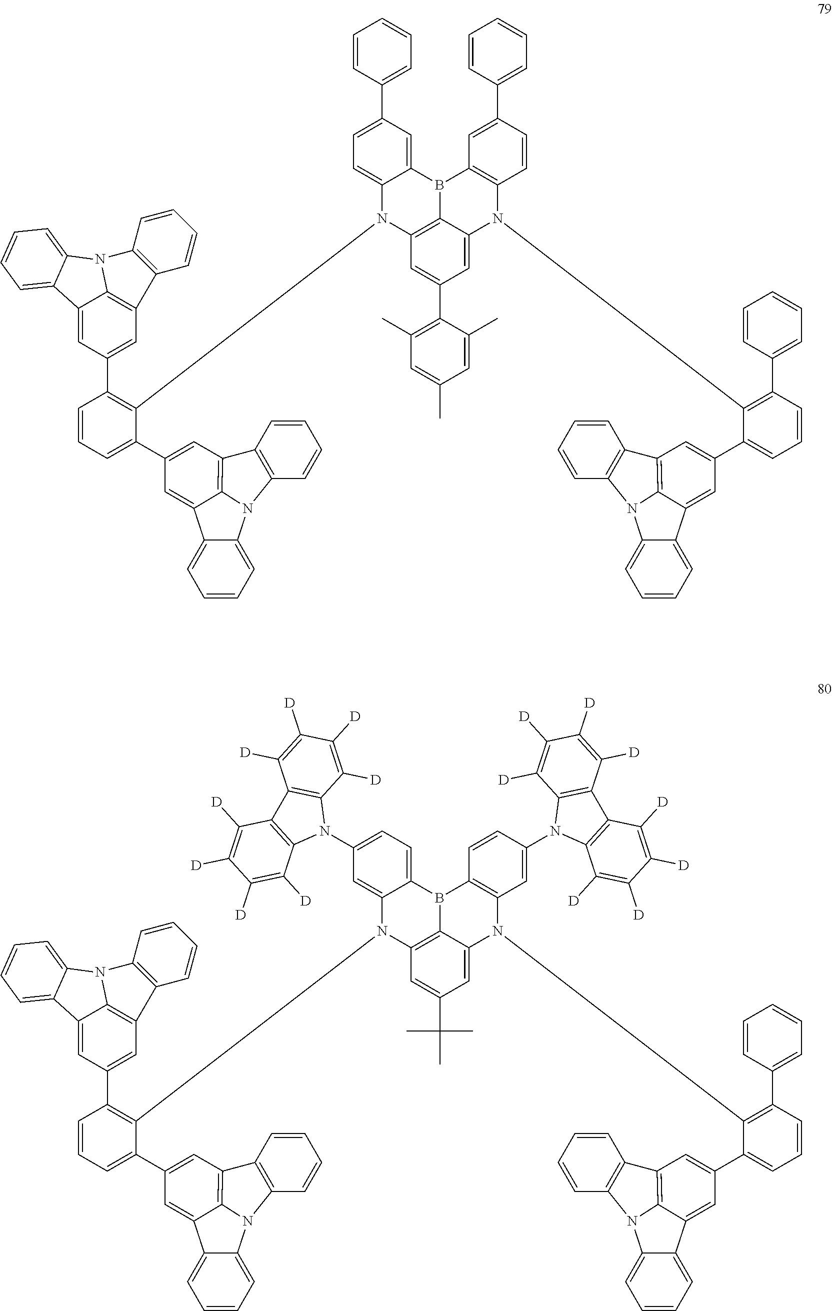 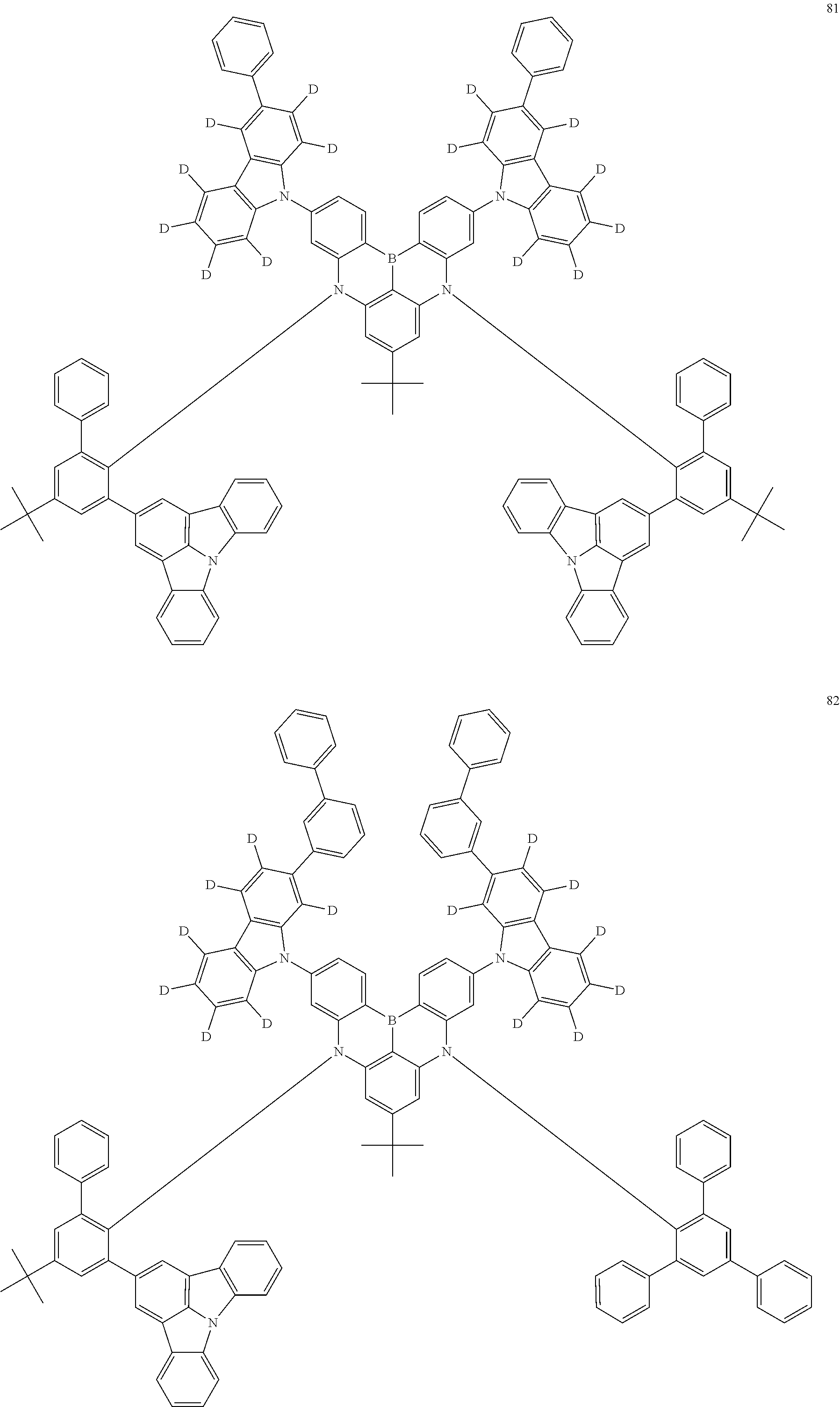 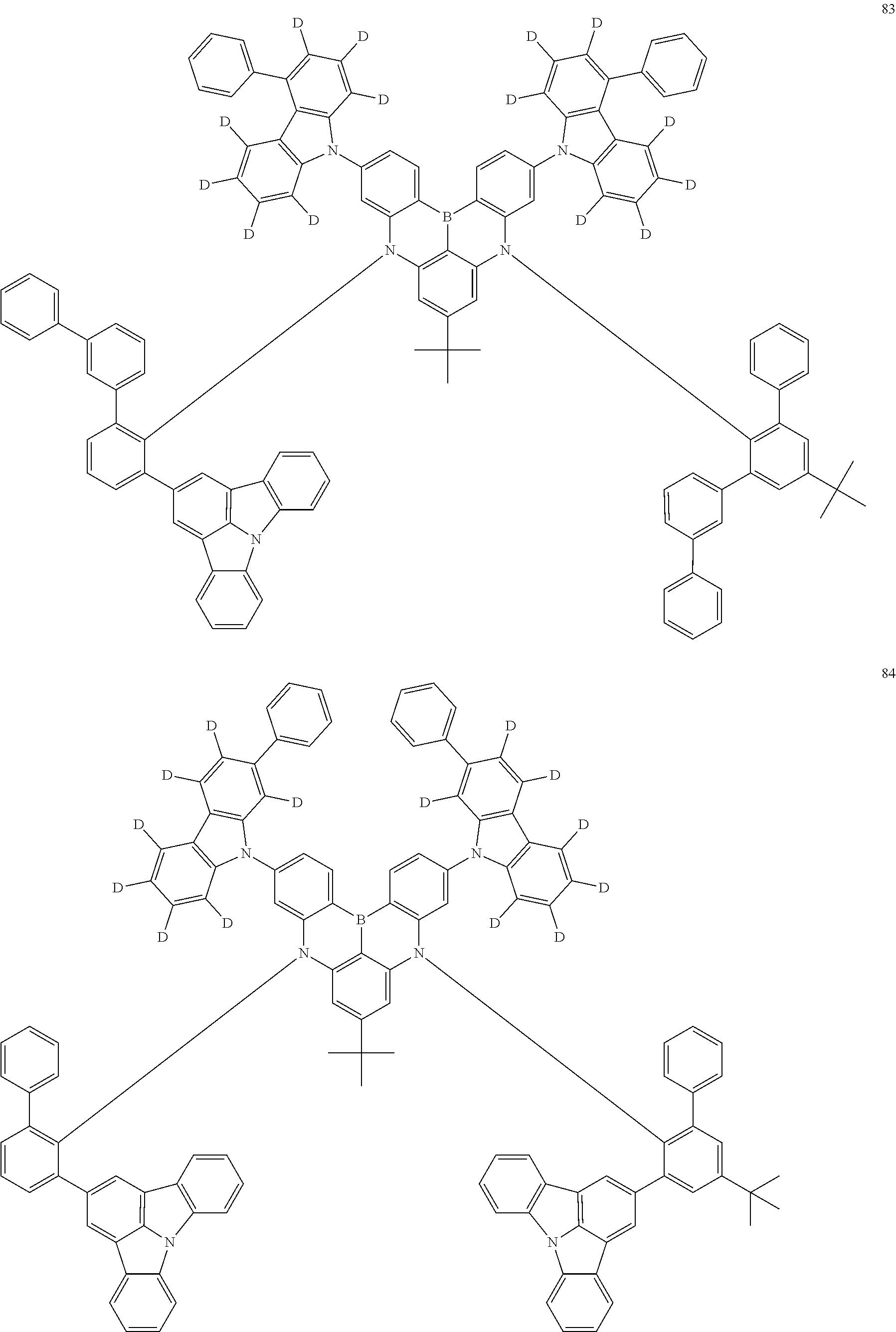 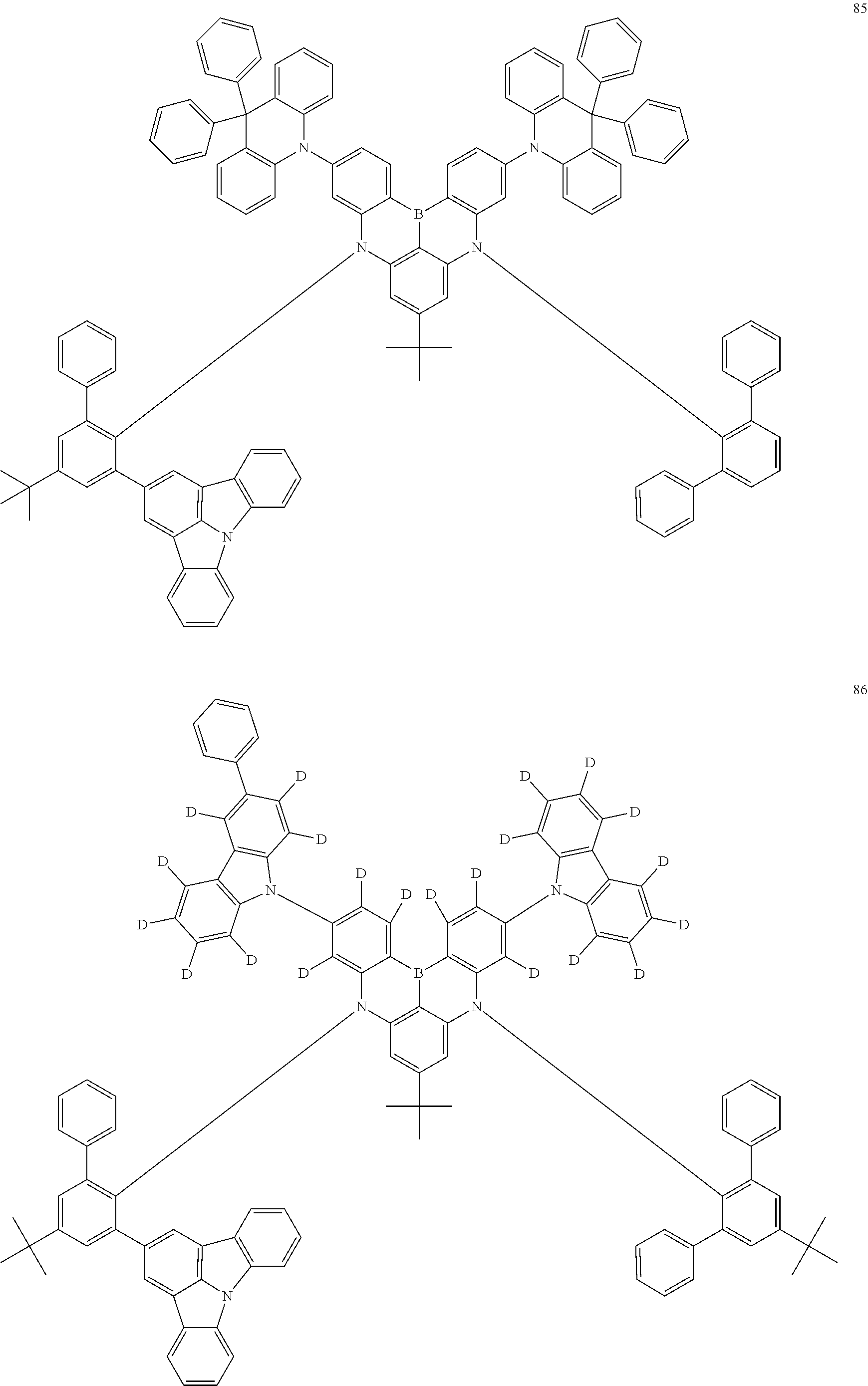 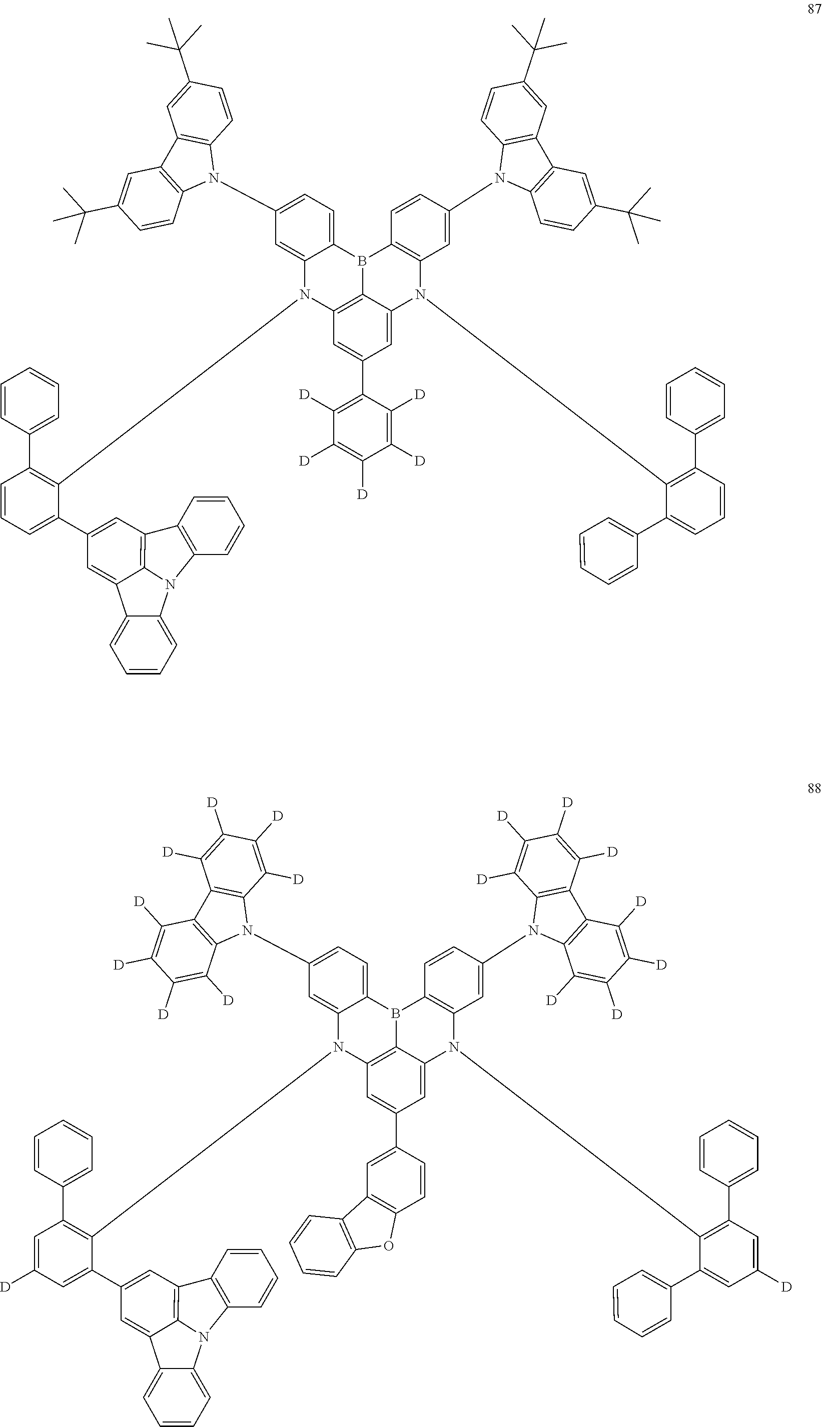 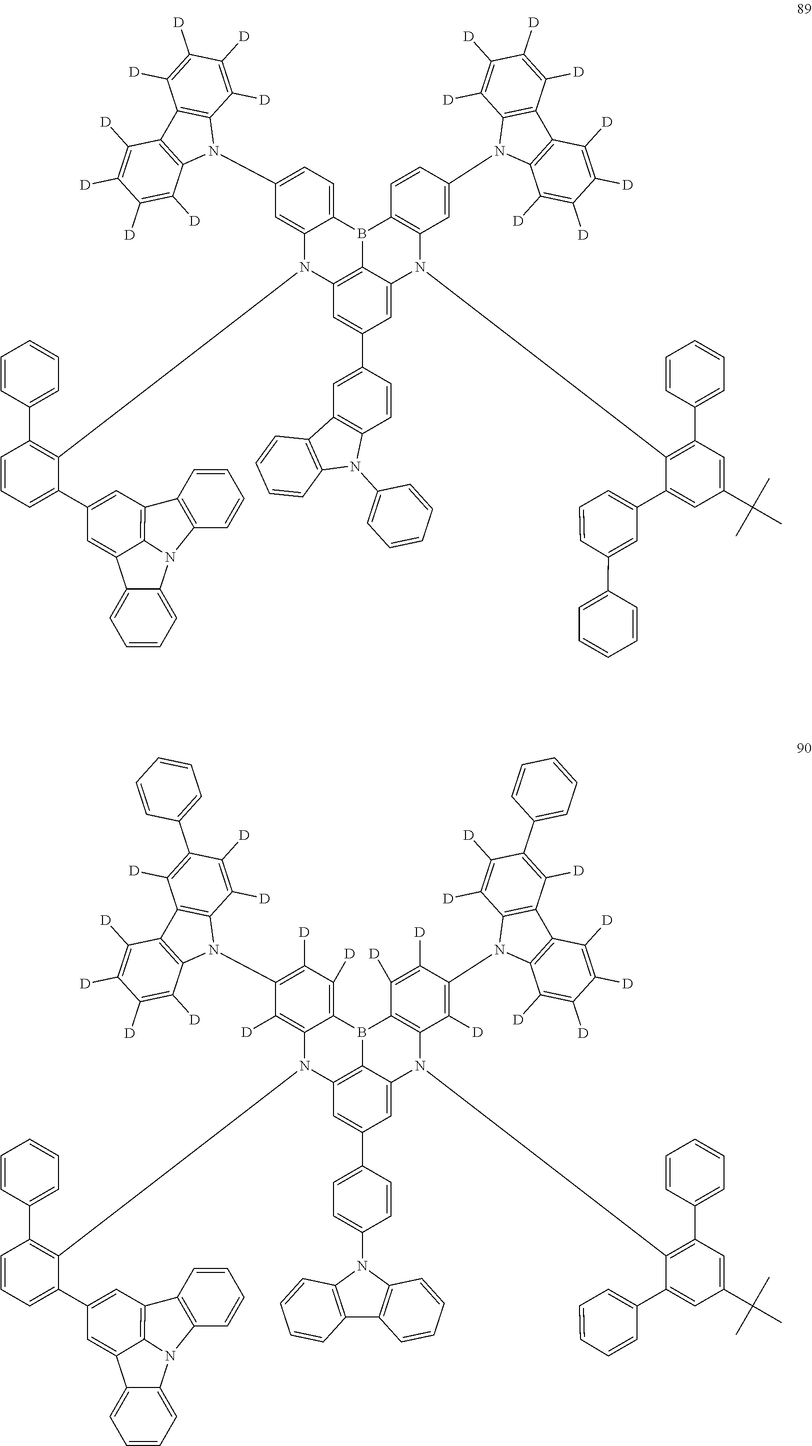 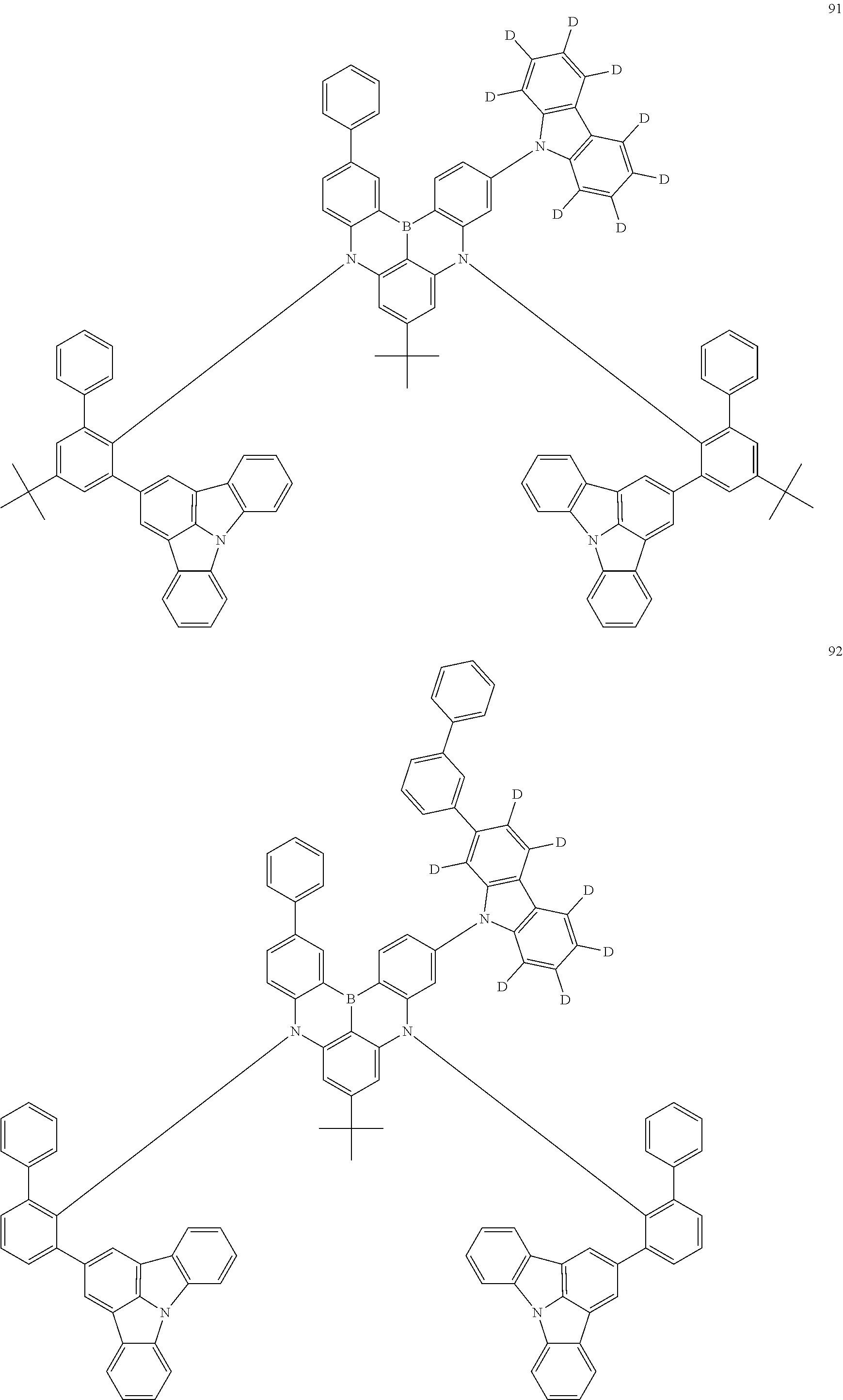 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cc3c4ccccc4n4c5ccccc5c(c1)c34)c1cc(C(C)(C)C)cc3c1B2c1cc(-c2ccccc2)ccc1N3c1c(-c2ccccc2)cc(C(C)(C)C)cc1-c1cc2c3ccccc3n3c4ccccc4c(c1)c23 ; [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1cc3c4ccccc4n4c5ccccc5c(c1)c34)c1cc(C(C)(C)C)cc3c1B2c1cc(-c2ccccc2)ccc1N3c1c(-c2ccccc2)cccc1-c1cc2c3ccccc3n3c4ccccc4c(c1)c23] 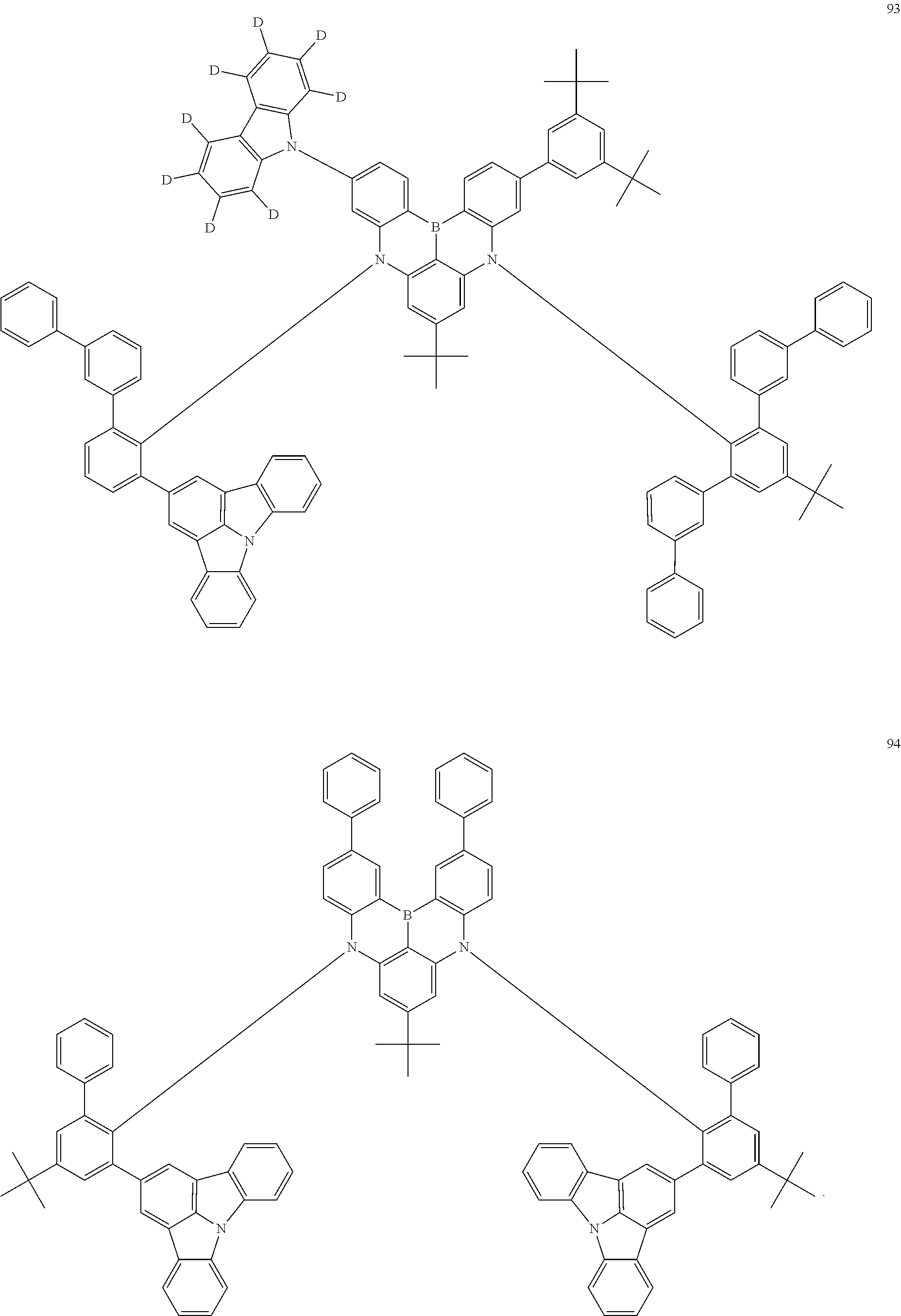 [SMILES: [2H]c1c([2H])c([2H])c2c(c1[2H])c1c([2H])c([2H])c([2H])c([2H])c1n2-c1ccc2c(c1)N(c1c(-c3cccc(-c4ccccc4)c3)cccc1-c1cc3c4ccccc4n4c5ccccc5c(c1)c34)c1cc(C(C)(C)C)cc3c1B2c1ccc(-c2cc(C(C)(C)C)cc(C(C)(C)C)c2)cc1N3c1c(-c2cccc(-c3ccccc3)c2)cc(C(C)(C)C)cc1-c1cccc(-c2ccccc2)c1 ; CC(C)(C)c1cc(-c2ccccc2)c(N2c3ccc(-c4ccccc4)cc3B3c4cc(-c5ccccc5)ccc4N(c4c(-c5ccccc5)cc(C(C)(C)C)cc4-c4cc5c6ccccc6n6c7ccccc7c(c4)c56)c4cc(C(C)(C)C)cc2c43)c(-c2cc3c4ccccc4n4c5ccccc5c(c2)c34)c1]
